(19) United States
(12) Patent Application Publication
(10) Pub. No.: US 2022/0310940 A1
(43) Pub. Date: Sep. 29, 2022

(54) ORGANOMETALLIC COMPOUND, ORGANIC LIGHT-EMITTING DEVICE INCLUDING THE SAME, AND ELECTRONIC APPARATUS INCLUDING THE ORGANIC LIGHT-EMITTING DEVICE

(71) Applicant: Samsung Electronics Co., Ltd., Suwon-si (KR)

(72) Inventors: Kyuyoung HWANG, Anyang-si (KR); Byungjoon KANG, Seoul (KR); Seungyeon KWAK, Suwon-si (KR); Hyungjun KIM, Suwon-si (KR); Yong Joo LEE, Suwon-si (KR); Jeoungin YI, Seoul (KR); Byoungki CHOI, Hwaseong-si (KR)

(21) Appl. No.: 17/690,280

(22) Filed: Mar. 9, 2022

(30) Foreign Application Priority Data
Mar. 12, 2021 (KR) 10-2021-0033000
Mar. 8, 2022 (KR) 10-2022-0029586

(51) Int. Cl. H01L 51/00; C09K 11/06; C09K 11/02; C07F 15/00

(52) U.S. Cl. CPC H01L 51/0085; C09K 11/06; C09K 11/02; C07F 15/0033; H01L 51/0094; C09K 2211/185; C09K 2211/1007; C09K 2211/1044; C09K 2211/1029; C09K 2211/1088; H01L 51/5012

(57) ABSTRACT

Provided are an organometallic compound represented by Formula 1, an organic light-emitting device including the same, and an electronic apparatus including the organic light-emitting device.

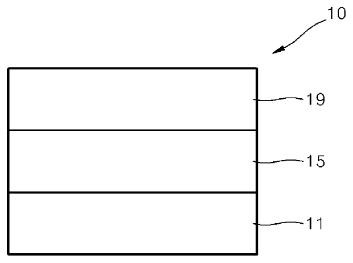

M(L₁)ₙ₁(L₂)ₙ₂ Formula 1

M, L₁, L₂, n1, and n2 in Formula 1 are the same as described in the present specification.

### CROSS-REFERENCE TO RELATED APPLICATION

This application is claims priority under 35 U.S.C. § 119 to Korean Patent Applications No. 10-2021-0033000, filed on Mar. 12, 2021, and No. 10-2022-0029586, filed on Mar. 8, 2022, in the Korean Intellectual Property Office, the contents of which are incorporated by reference herein in their entirety.

### BACKGROUND

### 1. Field

One or more embodiments relate to organometallic compounds, organic light-emitting devices including the same, and electronic apparatuses including the organic light-emitting devices.

### 2. Description of the Related Art

Organic light-emitting devices are self-emissive devices, which have improved characteristics in terms of viewing angles, response time, brightness, driving voltage, and response speed, and produce full-color images.

In an example, an organic light-emitting device includes an anode, a cathode, and an organic layer located between the anode and the cathode, wherein the organic layer includes an emission layer. A hole transport region may be located between the anode and the emission layer, and an electron transport region may be located between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. The excitons may transition from an excited state to a ground state, thus generating light.

### SUMMARY

One or more embodiments relate to an organometallic compound, an organic light-emitting device including the same, and an electronic apparatus including the organic light-emitting device.

Additional aspects will be set forth in part in the description which follows and, in part, will be apparent from the description, or may be learned by practice of the presented embodiments of the disclosure.

According to one aspect, an organometallic compound represented by Formula 1 is provided:

M(L₁)ₙ₁(L₂)ₙ₂ Formula 1
wherein, in Formula 1,
M is iridium,
L₁ is a ligand represented by Formula 2A,
n1 is 2, and two L₁(s) may be identical to or different from each other,
L₂ is a ligand represented by Formula 2B,
n2 is 1,
L₁ and L₂ may be different from each other,

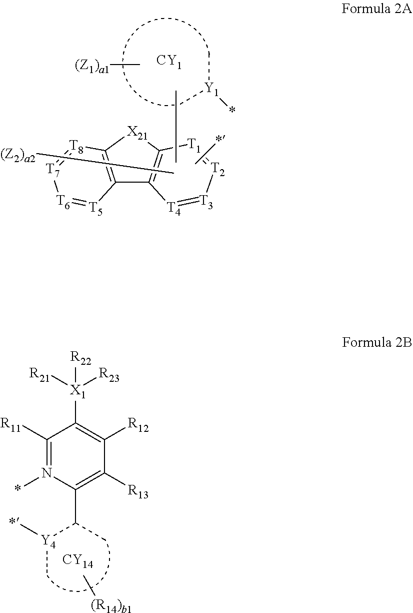

wherein, in Formulae 2A and 2B,
Y₁ and Y₄ are each independently C or N,
X₁ is Si or Ge,
X₂₁ is O, S, S(═O), N(Z₂₉), C(Z₂₉)(Z₃₀), or Si(Z₂₉)(Z₃₀),
T₁ to T₄ are each independently C, N, carbon bonded to ring CY₁, or carbon bonded to M in Formula 1, and one of T₁ to T₄ is carbon bonded to M in Formula 1, and one of the others of T₁ to T₄ which are not bonded to M is carbon bonded to ring CY₁,
T₅ to T₈ are each independently C or N,
ring CY₁ and ring CY₁₄ are each independently a C₅-C₃₀ carbocyclic group or a C₁-C₃₀ heterocyclic group,
R₂₁ to R₂₃ are each independently a C₁-C₆₀ alkyl group or a C₆-C₆₀ aryl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₃-C₁₀ cycloalkyl group, a phenyl group, or any combination thereof,
Z₁, Z₂, Z₂₉, Z₃₀, and R₁₁ to R₁₄ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
a1 and b1 are each independently an integer from 0 to 20, wherein when a1 is 2 or more, two or more of Z₁(s) may be identical to or different from each other, and when b1 is 2 or more, two or more of R₁₄(s) may be identical to or different from each other,
a2 is an integer from 0 to 6, wherein, when a2 is 2 or more, two or more of Z₂(s) may be identical to or different from each other,
at least one of Z₁(s) in the number of a1 in Formula 2A is not hydrogen,
two or more of R₂₁ to R₂₃ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of Z₁(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of Z₂(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
R₁₂ and R₁₃ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of R₁₄(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of Z₁, Z₂ and R₁₁ to R₁₄ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
R₁₀ₐ is the same as described in connection with R₁₄,
and *′ in Formulae 2A and 2B each indicate a binding site to M in Formula 1,
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group,
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof,
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof,
wherein Q₁ to Q₉, Q₁₁ to Q₁₉, Q₂₁ to Q₂₉, and Q₃₁ to Q₃₉ used herein are each independently: hydrogen; deuterium; —F; —Cl; —Br; —I; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group which is unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group which is unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

According to another aspect, provided is an organic light-emitting device including a first electrode, a second electrode, and an organic layer including an emission layer located between the first electrode and the second electrode, wherein the organic layer includes at least one organometallic compound represented by Formula 1.

The organometallic compound may be included in the emission layer of the organic layer, and the organometallic compound included in the emission layer may act as a dopant.

Another aspect of the present disclosure provides an electronic apparatus including the organic light-emitting device.

### BRIEF DESCRIPTION OF THE DRAWING

The above and other aspects, features, and advantages of certain embodiments of the disclosure will be more apparent from the following description taken in conjunction with FIGURE which shows a schematic cross-sectional view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the FIGURES, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise.

“Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the FIGURES. It will be understood that relative terms are intended to encompass different orientations of the device in addition to the orientation depicted in the FIGURES. For example, if the device in one of the FIGURES is turned over, elements described as being on the “lower” side of other elements would then be oriented on “upper” sides of the other elements. The exemplary term “lower,” can therefore, encompasses both an orientation of “lower” and “upper,” depending on the particular orientation of the FIGURE. Similarly, if the device in one of the FIGURES is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features Moreover, sharp angles that are illustrated may be rounded. Thus, the regions illustrated in the figures are schematic in nature and their shapes are not intended to illustrate the precise shape of a region and are not intended to limit the scope of the present claims.

The organometallic compound may be represented by Formula 1:

M(L₁)ₙ₁(L₂)ₙ₂ Formula 1
M in Formula 1 may be iridium.

L₁ in Formula 1 may be a ligand represented by Formula 2A, and n1 in Formula 1 may be the number of L₁(s) in Formula 1, and may be 2. Two L₁(s) in the number of n1 may be identical to or different from each other. In one or more embodiments, two L₁(s) may be identical to each other.

L₂ in Formula 1 may be a ligand represented by Formula 2B, and n2 in Formula 1 indicates the number of L₂ in Formula 1, and may be 1.

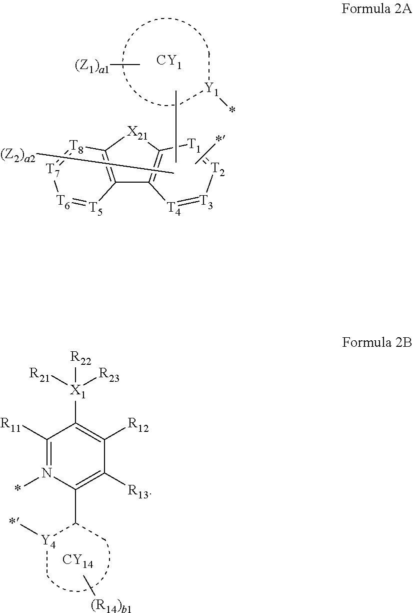

Formula 2A and 2B may be understood by referring to the related description to be presented later.

L₁ and L₂ in Formula 1 may be different from each other. That is, the organometallic compound represented by Formula 1 may be a heteroleptic complex.

Y₁ and Y₄ in Formula 2B may each independently be C or N.

For example, Y₁ in Formula 2A may be N, and Y₄ in Formula 2B may be C.

X₁ in Formula 2B may be Si or Ge.

X₂₁ in Formula 2A may be O, S, S(═O), N(Z₂₉), C(Z₂₉)(Z₃₀), or Si(Z₂₉)(Z₃₀). Z₂₉ and Z₃₀ may each be the same as described in the present specification.

For example, X₂₁ in Formula 2A may be O or S.

In one or more embodiments, X₂₁ in Formula 2A may be O.

In one or more embodiments, X₂₁ in Formula 2A may be S.

T₁ to T₄ in Formula 2A may each independently be C, N, carbon bonded to ring CY₁, or carbon bonded to M in Formula 1, and one of T₁ to T₄ is carbon bonded to M in Formula 1, and one of the others of T₁ to T₄ which are not bonded to M is carbon bonded to ring CY₁, and T₅ to T₈ may each independently be C or N.

In one or more embodiments, each of T₁ to T₈ may not be N.

In one or more embodiments, at least one of T₁ to T₈ may be N.

In one or more embodiments, one or two of T₁ to T₈ may be N.

In one or more embodiments, each of T₁ to T₇ may not be N, and T₈ may be N.

In one or more embodiments, when X₁ is Si, each of T₁ to T₈ may not be N.

Ring CY₁ and ring CY₁₄ in Formulae 2A and 2B may each independently be a C₅-C₃₀ carbocyclic group or a C₁-C₃₀ heterocyclic group.

For example, ring CY₁ and ring CY₁₄ may each independently be i) a first ring, ii) a second ring, iii) a condensed ring in which at least two first rings are condensed, iv) a condensed ring in which at least two second rings are condensed, or v) a condensed ring in which at least one first ring and at least one second ring are condensed, the first ring may be a cyclopentane group, a cyclopentadiene group, a furan group, a thiophene group, a pyrrole group, a silole group, an indene group, a benzofuran group, a benzothiophene group, an indole group, a benzosilole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and the second ring may be an adamantane group, a norbornane group, a norbornene group, a cyclohexane group, a cyclohexene group, a benzene group, a pyridine group, a pyrimidine group, a pyrazine group, a pyridazine group, or a triazine group.

In one or more embodiments, ring CY₁ and ring CY₁₄ in Formulae 2A and 2B may each independently be a cyclopentane group, a cyclohexane group, a cycloheptane group, a cyclopentene group, a cyclohexene group, a cycloheptene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an iso-oxazole group, a thiazole group, an isothiazole group, an oxadiazole group, a thiadiazole group, a benzopyrazole group, a benzimidazole group, a benzoxazole group, a benzothiazole group, a pyridoimidazole group, a pyridooxazole group, a pyridothiazole group, a naphthoimidazole group, a naphthooxazole group, a naphthothiazole group, a benzoxadiazole group, a benzothiadiazole group, a 5,6,7,8-tetrahydroisoquinoline group, a 5,6,7,8-tetrahydroquinoline group, an adamantane group, a norbornane group, or a norbornene group.

In one or more embodiments, ring CY₁ may be a pyridine group, a pyrimidine group, an imidazole group, an oxazole group, a thiazole group, a benzimidazole group, a benzoxazole group, a benzothiazole group, a pyridoimidazole group, a pyridooxazole group, a pyridothiazole group, a naphthoimidazole group, a naphthooxazole group, or a naphthothiazole group.

In one or more embodiments, ring CY₁₄ may be a benzene group, a naphthalene group, a 1,2,3,4-tetrahydronaphthalene group, a phenanthrene group, a pyridine group, a pyrimidine group, a pyrazine group, a triazine group, a benzofuran group, a benzothiophene group, a fluorene group, a carbazole group, a dibenzofuran group, a dibenzothiophene group, a dibenzosilole group, an azafluorene group, an azacarbazole group, an azadibenzofuran group, an azadibenzothiophene group, or an azadibenzosilole group.

In one or more embodiments, ring CY₁₄ in Formula 2B may be a benzene group, a naphthalene group, or a 1,2,3,4-tetrahydronaphthalene group.

R₂₁ to R₂₃ in Formula 2B may each independently be a C₁-C₆₀ alkyl group or a C₆-C₆₀ aryl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₃-C₁₀ cycloalkyl group, a phenyl group, or any combination thereof.

For example, R₂₁ to R₂₃ in Formula 2B may each independently a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a phenyl group, a biphenyl group, or a naphthyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₃-C₁₀ cycloalkyl group, a phenyl group, or any combination thereof.

In one or more embodiments, R₂₁ to R₂₃ in Formula 2B may each independently be —CH₃, —CH₂CH₃, —CD₃, —CD₂H, —CDH₂, —CH₂CD₃, or —CD₂CH₃.

In one or more embodiments, R₂₁ to R₂₃ in Formula 2B may be identical to each other.

In one or more embodiments, two or more of R₂₁ to R₂₃ in Formula 2B may be different from each other.

Z₁, Z₂, Z₂₉, Z₃₀, and R₁₁ to R₁₄ in Formulae 2A and 2B may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉). Q₁ to Q₉ are the same as described above.

For example, Z₁, Z₂, Z₂₉, Z₃₀, and R₁₁ to R₁₄ in Formulae 2A and 2B may each independently be:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or any combination thereof; or
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group or azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, —Si(Q₃₃)(Q₃₄)(Q₃₅), —Ge(Q₃₃)(Q₃₄)(Q₃₅), or any combination thereof.

a1 and b1 in Formulae 2A and 2B respectively indicate the number of Z₁(s) and the number of R₁₄(s), and may each independently be an integer from 0 to 20. When a1 is 2 or more, two or more of Z₁(s) may be identical to or different from each other, and when b1 is 2 or more, two or more of R₁₄(s) may be identical to or different from each other. For example, a1 and b1 may each independently be an integer from 0 to 10.

a2 in Formula 2A indicates the number of Z₂(s), and may be an integer from 0 to 6. When a2 is 2 or more, two or more of Z₂(s) may be identical to or different from each other. For example, a2 may be 0, 1, 2, or 3.

In one or more embodiments, Z₁, Z₂, Z₂₉, Z₃₀ and R₁₁ to R₁₄ in Formulae 2A and 2B may each independently be:
hydrogen, deuterium, —F, or a cyano group;
a C₁-C₂₀ alkyl group, unsubstituted or substituted with deuterium, —F, a cyano group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, or any combination thereof; or a phenyl group, a biphenyl group, a terphenyl group, a naphthyl group, a dibenzofuranyl group, or a dibenzothiophenyl group, each unsubstituted or substituted with —F, a cyano group, a C₁-C₂₀ alkyl group, a deuterated C₁-C₂₀ alkyl group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), —Ge(Q₃₃)(Q₃₄)(Q₃₅), or any combination thereof.

At least one of Z₁(s) in the number of a1 in Formula 2A may not be hydrogen.

In one or more embodiments, at least one of Z₁(s) in the number of a1 in Formula 2A may not be hydrogen or —CD₃.

In one or more embodiments, at least one of Z₁(s) in the number of a1 in Formula 2A may be:
deuterium, —F, or a cyano group;
a C₁-C₂₀ alkyl group, unsubstituted or substituted with deuterium, —F, a cyano group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, or any combination thereof; or
a phenyl group, a biphenyl group, a terphenyl group, a naphthyl group, a dibenzofuranyl group, or a dibenzothiophenyl group, each unsubstituted or substituted with —F, a cyano group, a C₁-C₂₀ alkyl group, a deuterated C₁-C₂₀ alkyl group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), —Ge(Q₃₃)(Q₃₄)(Q₃₅), or any combination thereof.

In one or more embodiments, in Formula 2A,
Y₁ may be N,
ring CY₁ may be a pyridine group, and
at least one of Z₁(s) in the number of a1 may be a C₁-C₂₀ alkyl group, unsubstituted or substituted with deuterium, —F, a cyano group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl) C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, or any combination thereof.

In one or more embodiments, in Formula 2A,
Y₁ may be N,
ring CY₁ may be a benzimidazole group, a benzoxazole group, a benzothiazole group, a pyridoimidazole group, a pyridooxazole group, a pyridothiazole group, a naphthoimidazole group, a naphthooxazole group, or a naphthothiazole group, and

at least one of Z₁(s) in the number of a1 may be a phenyl group, a biphenyl group, a terphenyl group, a naphthyl group, a dibenzofuranyl group, or a dibenzothiophenyl group, each unsubstituted or substituted with —F, a cyano group, a C₁-C₂₀ alkyl group, a deuterated C₁-C₂₀ alkyl group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), —Ge(Q₃₃)(Q₃₄)(Q₃₅), or any combination thereof.

In one or more embodiments, R₁₂ in Formula 2B may not be hydrogen or a methyl group.

In one or more embodiments, R₁₂ in Formula 2B may be hydrogen or a methyl group.

In one or more embodiments, Y₁ in Formula 2A may be N, ring CY₁ may be a benzimidazole group, a benzoxazole group, a benzothiazole group, a pyridoimidazole group, a pyridooxazole group, a pyridothiazole group, a naphthoimidazole group, a naphthooxazole group, or a naphthothiazole group, and R₁₂ in Formula 2B may be hydrogen or a methyl group.

In one or more embodiments, the organometallic compound represented by Formula 1 may satisfy at least one of Condition (1) and Condition (2):
Condition (1)
in Formula 2B, R₁₄ is not hydrogen and b1 is an integer from 1 to 20;
Condition (2)
in Formula 2A, Z₂ is not hydrogen and a2 is an integer from 1 to 6.

In one or more embodiments, in Formula 2A, Z₂ may not be hydrogen, a2 may be an integer from 1 to 3, and at least one of Z₂(s) in the number of a2 may each independently be a substituted or unsubstituted C₁-C₆₀ alkyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

In one or more embodiments, the organometallic compound represented by Formula 1 may include at least one fluoro group (—F), at least one cyano group (—CN), at least one deuterium, or any combination thereof.

In one or more embodiments, the organometallic compound represented by Formula 1 may satisfy at least one of Condition A to Condition I.

### Condition A

At least one of Z₁(s) in the number of a1 in Formula 2A includes deuterium.

### Condition B

In Formula 2A, Z₂ is not hydrogen, a2 is an integer from 1 to 6, and at least one of Z₂(s) in the number of a2 includes deuterium.

### Condition C

In Formula 2A, Z₂ is not hydrogen, a2 is an integer from 1 to 6, and at least one of Z₂(s) in the number of a2 includes a fluoro group (—F).

### Condition D

In Formula 2A, Z₂ is not hydrogen, a2 is an integer from 1 to 6, and at least one of Z₂(s) in the number of a2 includes a cyano group (—CN).

### Condition E

In Formula 2A, Z₂ is not hydrogen, a2 is an integer from 1 to 6, at least one of Z₂(s) in the number of a2 is a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

### Condition F

At least one of R₂₁ to R₂₃ in Formula 2B includes deuterium.

### Condition G

R₁₂ in Formula 2B is not hydrogen, and at least one of R₁₂(s) includes deuterium.

### Condition H

In Formula 2B, R₁₄ is not hydrogen, b1 is an integer from 1 to 20, and at least one of R₁₄(s) in the number of b1 includes deuterium.

### Condition I

In Formula 2B, R₁₄ is not hydrogen, b1 is an integer from 1 to 20, and at least one of R₁₄(s) in the number of b1 includes a fluoro group (—F).

In one or more embodiments, in Formula 2A, Z₂ may not be hydrogen, a2 may be an integer from 1 to 3, and at least one of Z₂(s) in the number of a2 may each independently be a substituted or unsubstituted C₁-C₆₀ alkyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

In one or more embodiments, in Formula 2A, Z₂ may not be hydrogen, a2 may be an integer from 1 to 3, and at least one of Z₂(s) in the number of a2 may be a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

In one or more embodiments, Z₁, Z₂, Z₂₉, Z₃₀ and R₁₁ to R₁₄ in Formulae 2A and 2B may each independently be hydrogen, deuterium, —F, a cyano group, a nitro group, —SF₅, —CH₃, —CD₃, —CD₂H, —CDH₂, —CF₃, —CF₂H, —CFH₂, —OCH₃, —OCDH₂, —OCD₂H, —OCD₃, —SCH₃, —SCDH₂, —SCD₂H, —SCD₃, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-233, a group represented by one of Formulae 9-201 to 9-233 in which at least one hydrogen is substituted with deuterium, a group represented by one of Formulae 9-201 to 9-233 in which at least one hydrogen is substituted with —F, a group represented by one of Formulae 10-1 to 10-132, a group represented by one of Formulae 10-1 to 10-132 in which at least one hydrogen is substituted with deuterium, a group represented by one of Formulae 10-1 to 10-132 in which at least one hydrogen is substituted with —F, a group represented by one of Formulae 10-201 to 10-353, a group represented by one of Formulae 10-201 to 10-353 in which at least one hydrogen is substituted with deuterium, or a group represented by one of Formulae 10-201 to 10-353 in which at least one hydrogen is substituted with —F.

In one or more embodiments, at least one of Z₁(s) in the number of a1 in Formula 2A may be a group represented by one of Formulae 9-1 to 9-39 in which at least one hydrogen is substituted with deuterium, a group represented by one of Formulae 9-201 to 9-233 in which at least one hydrogen is substituted with deuterium, a group represented by one of Formulae 10-1 to 10-132 in which at least one hydrogen is substituted with deuterium, or a group represented by one of Formulae 10-201 to 10-353 in which at least one hydrogen is substituted with deuterium:

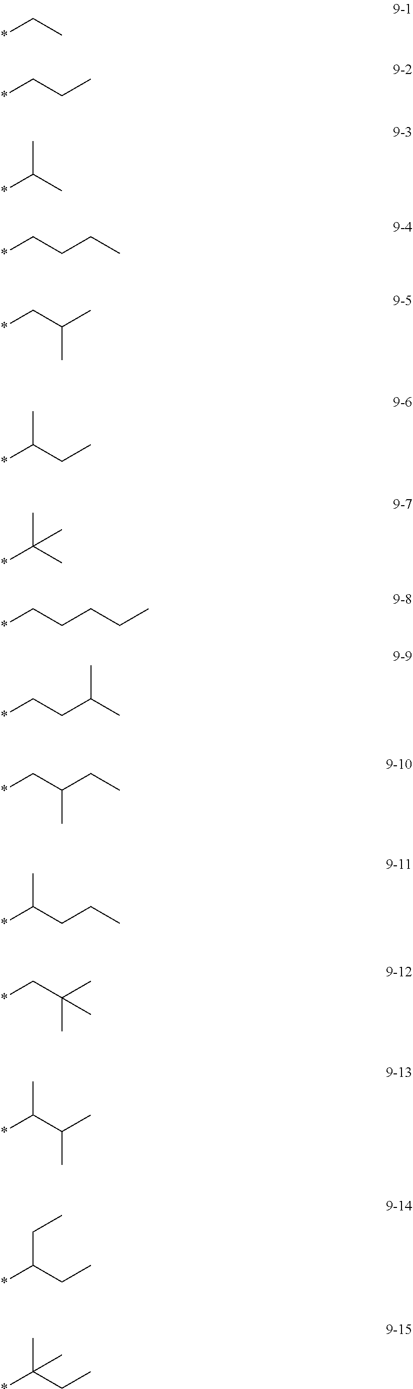

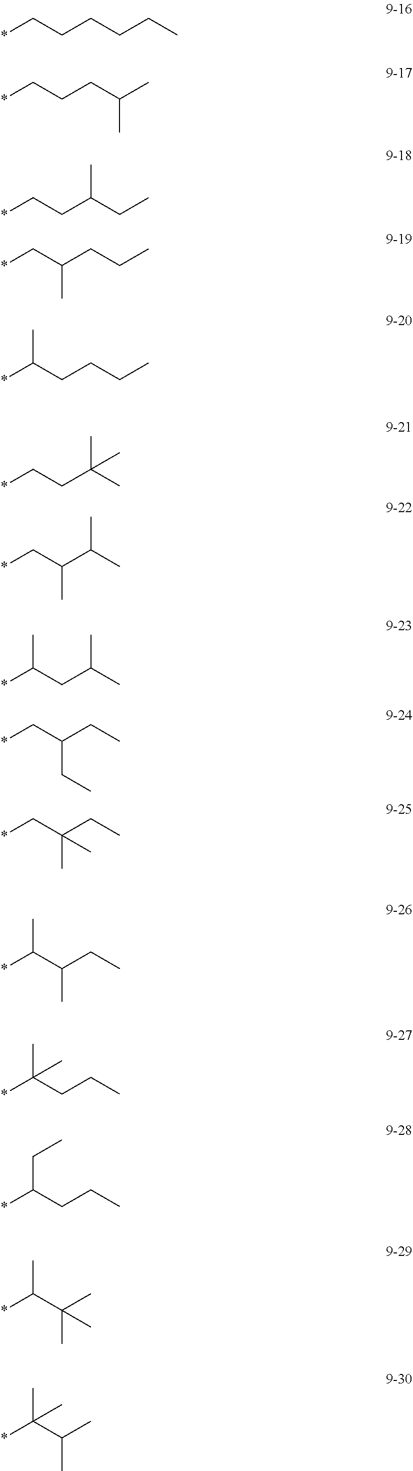

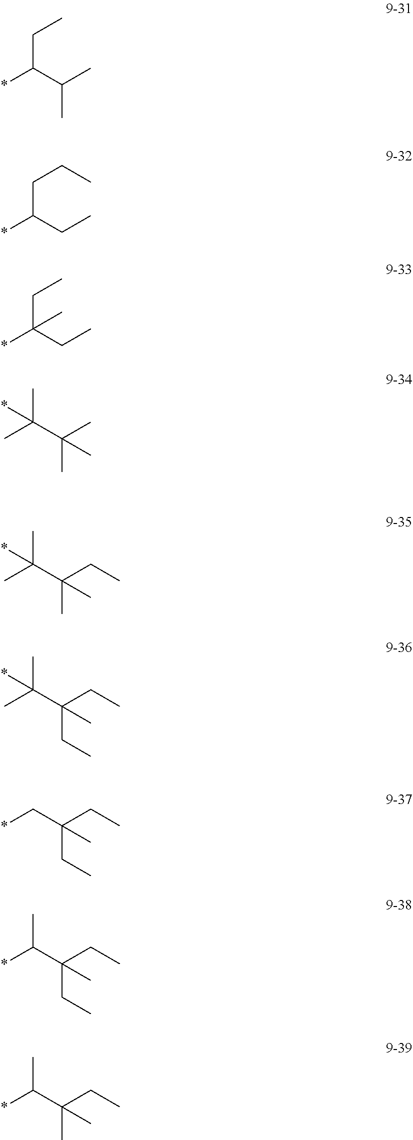

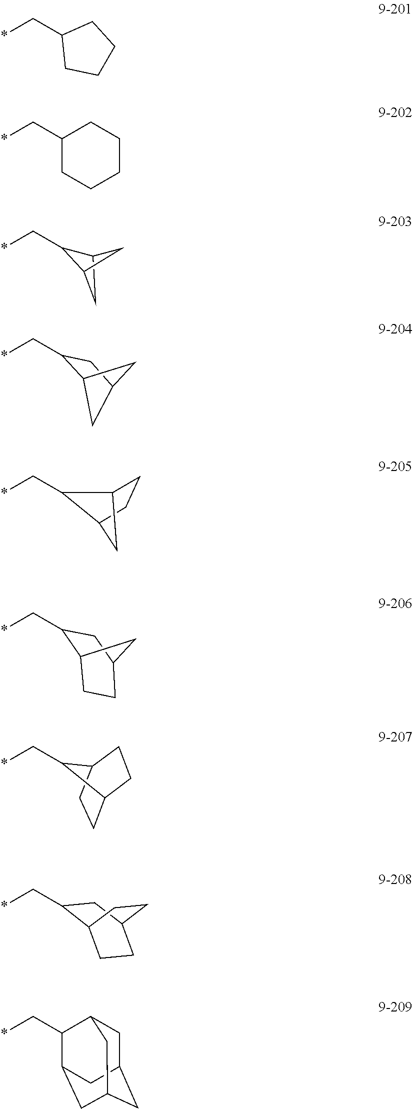

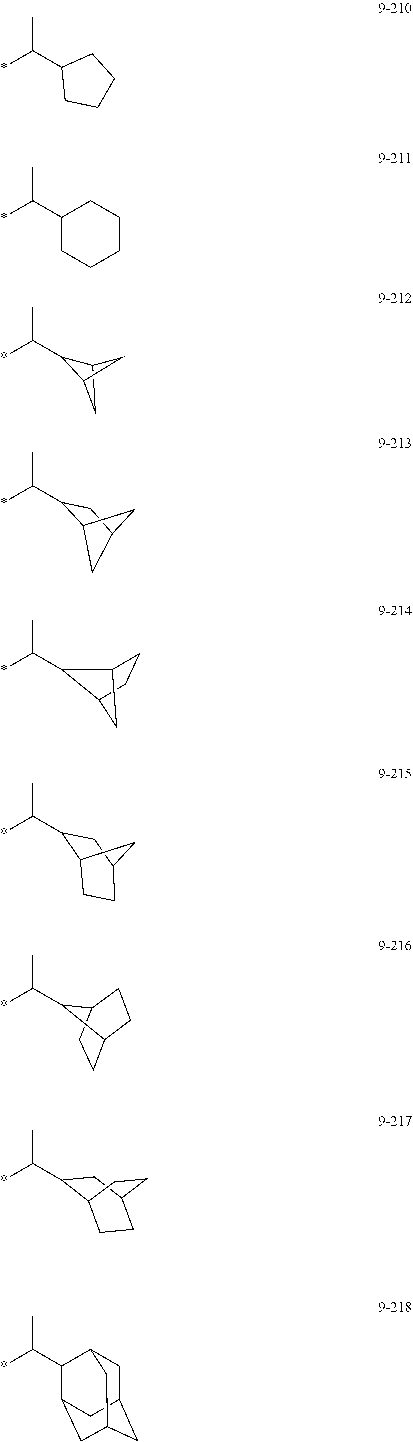

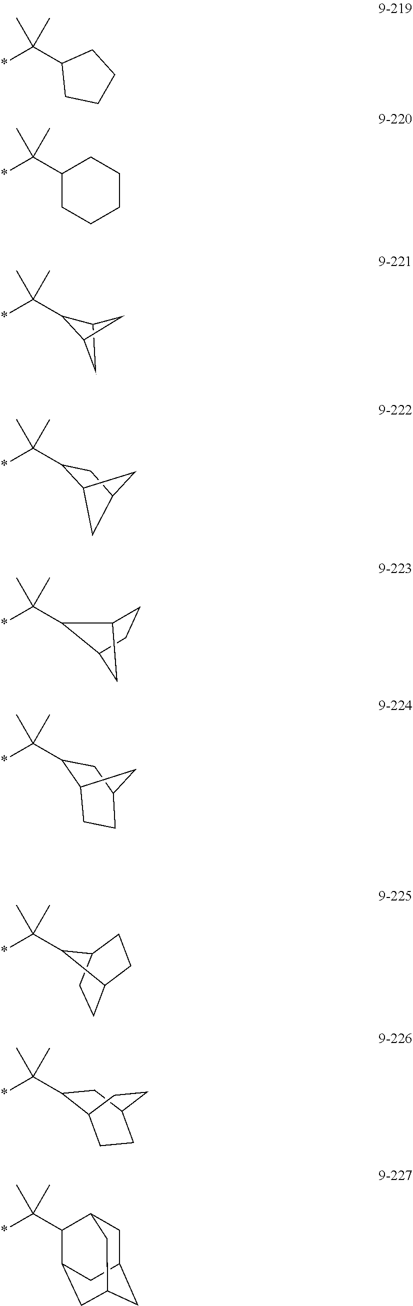

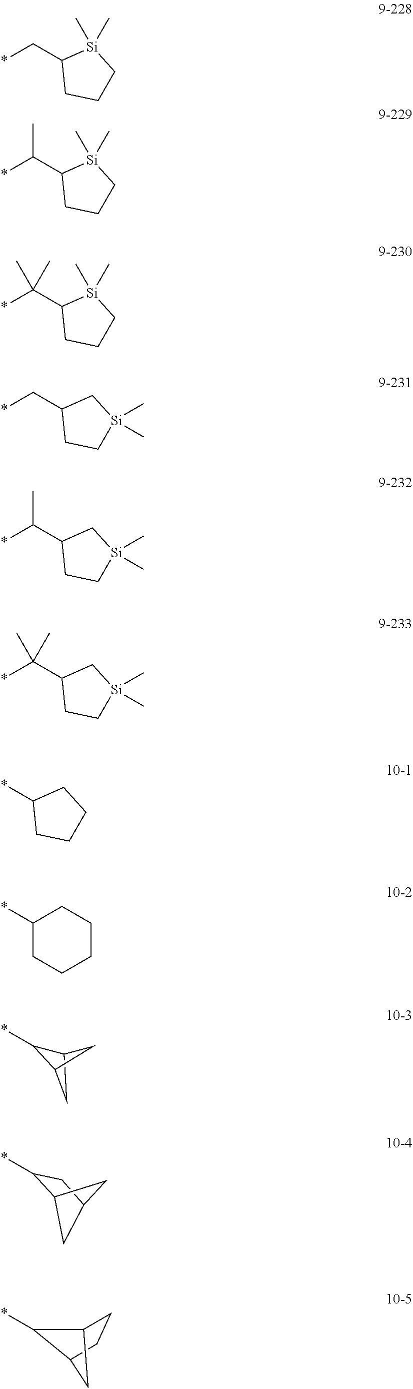

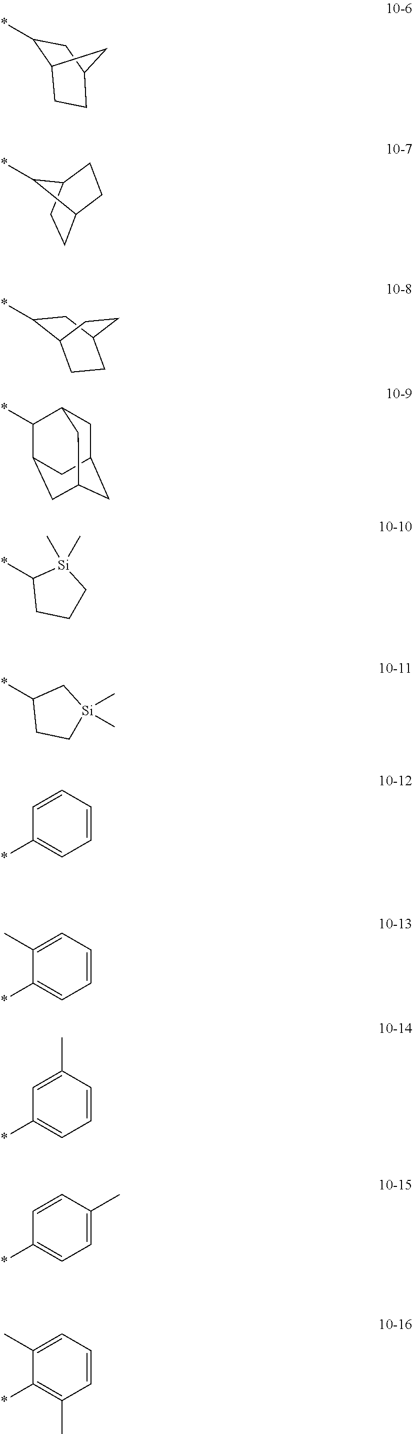

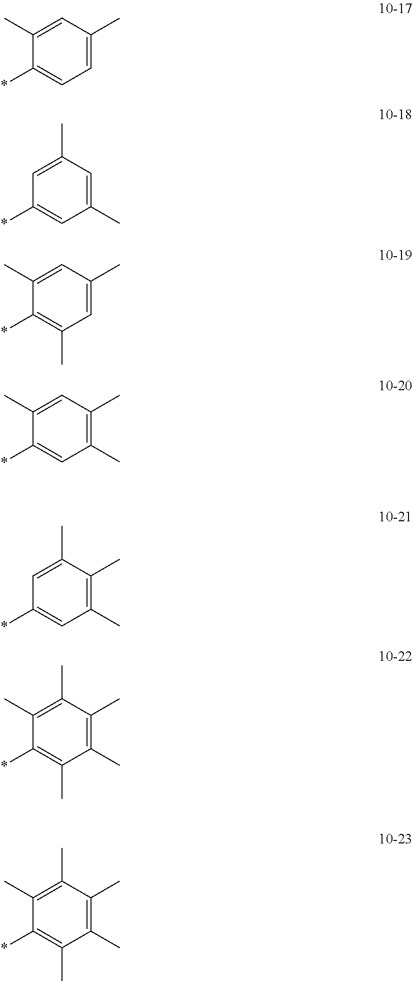

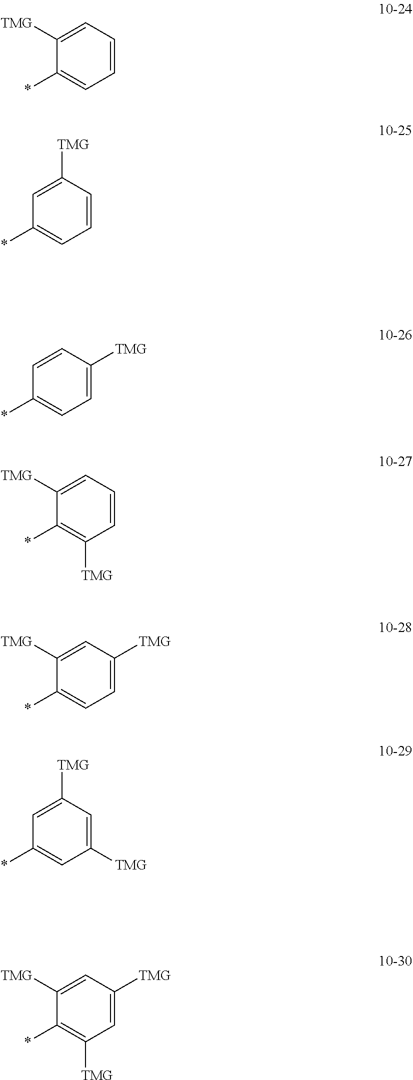

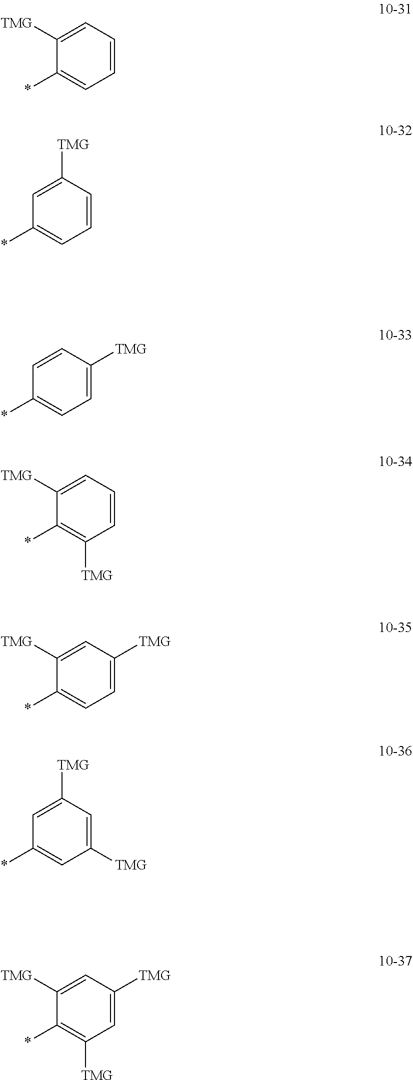

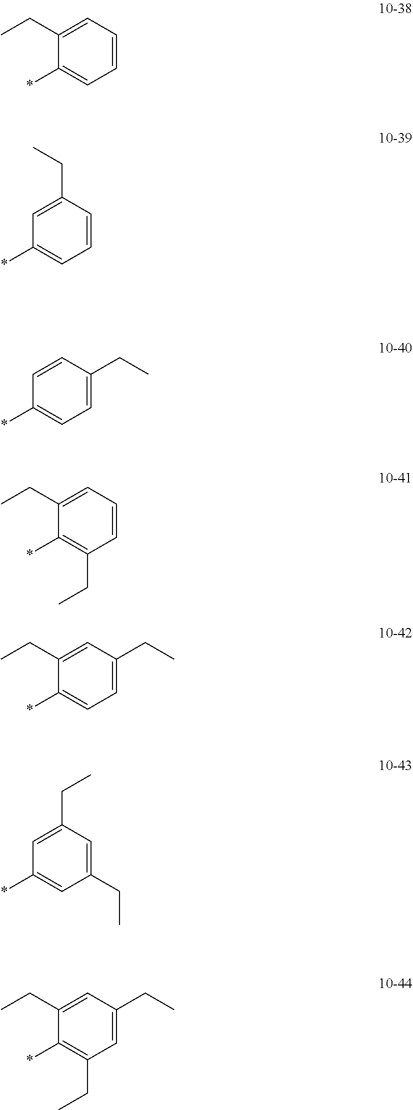

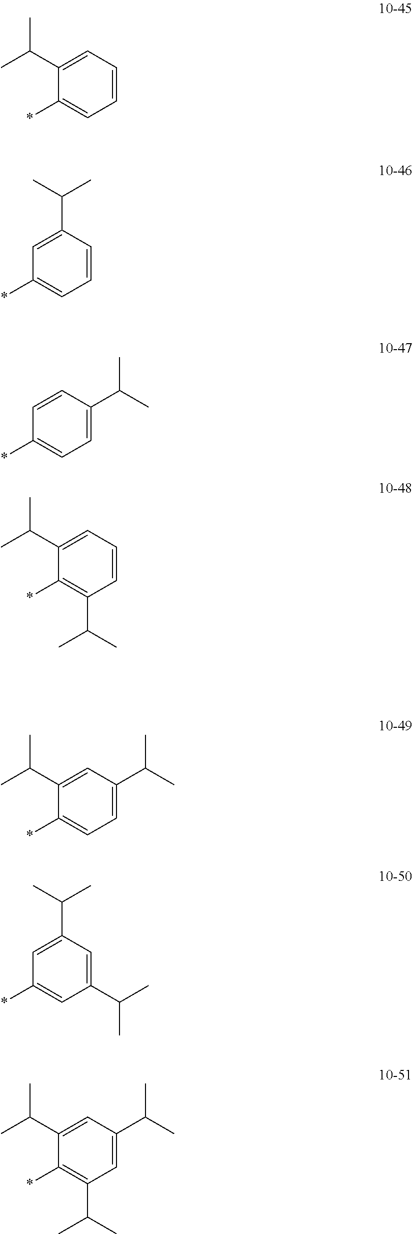

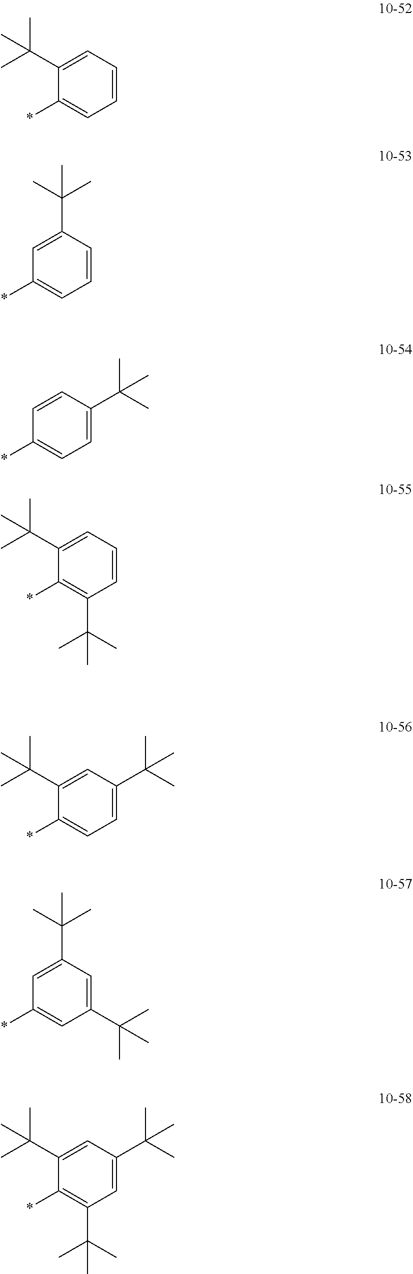

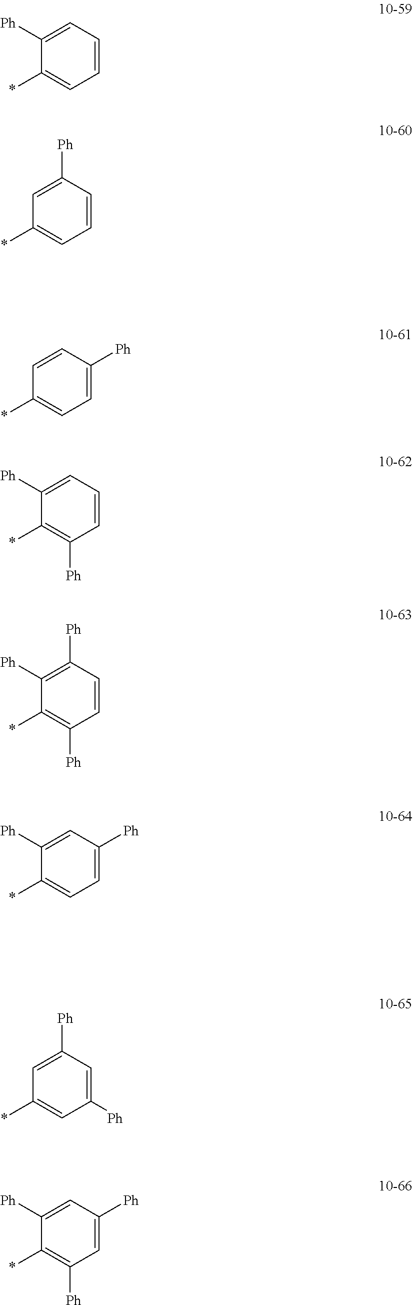

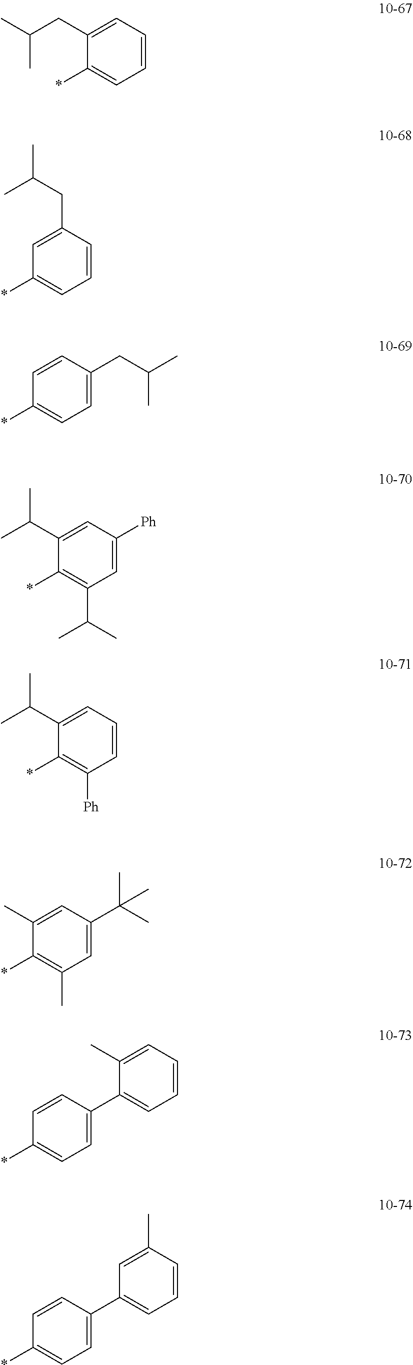

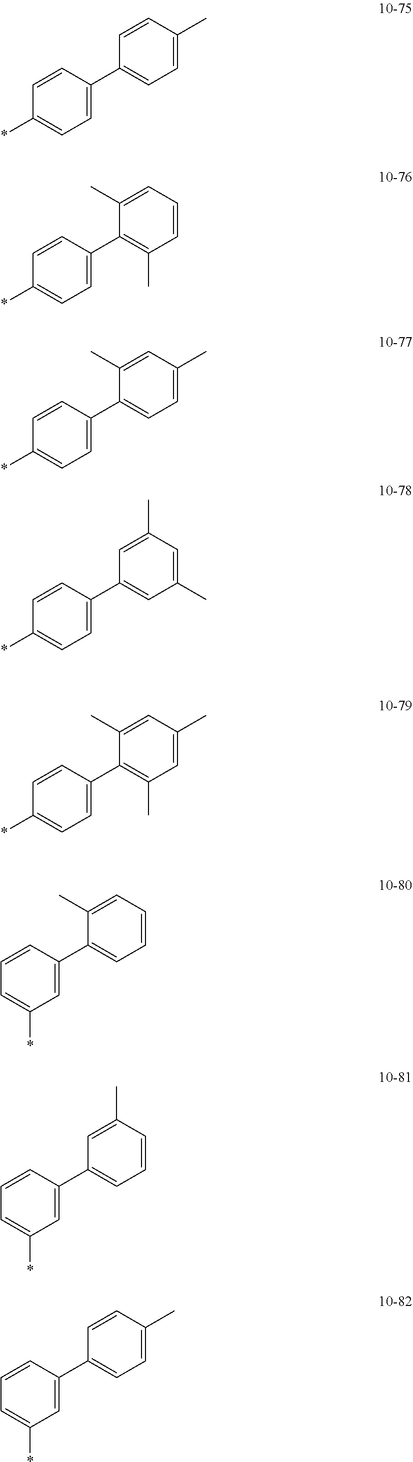

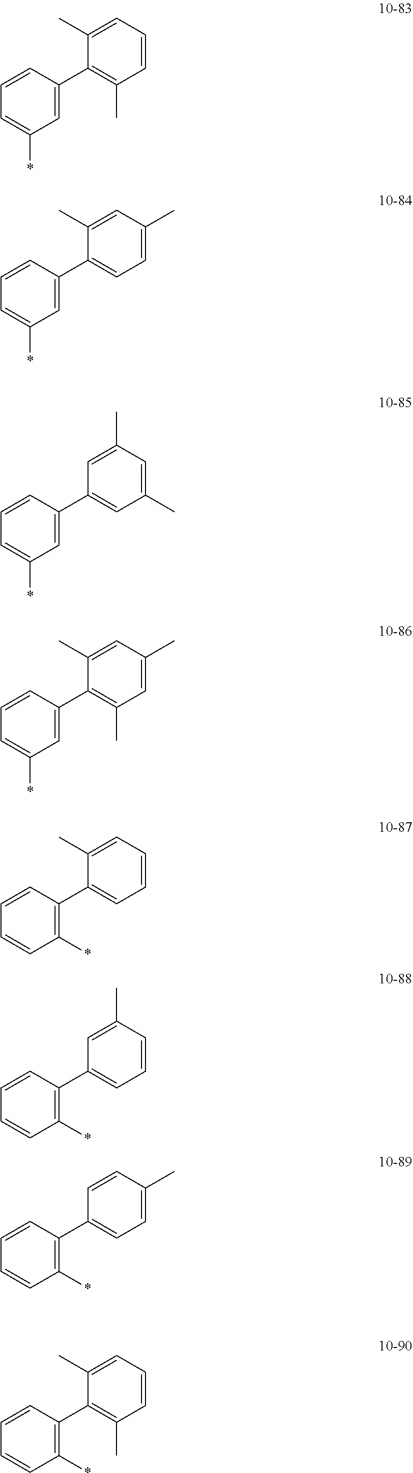

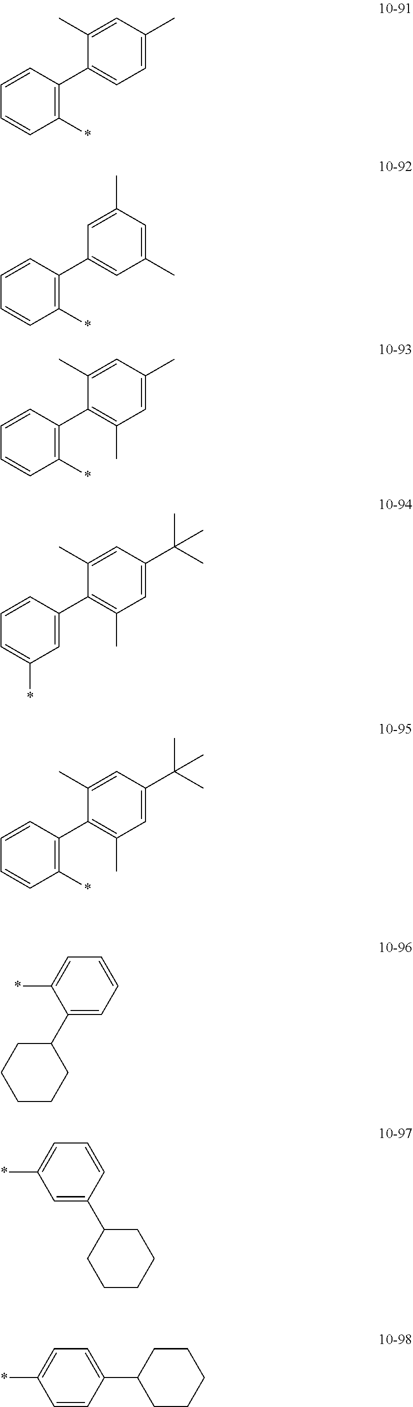

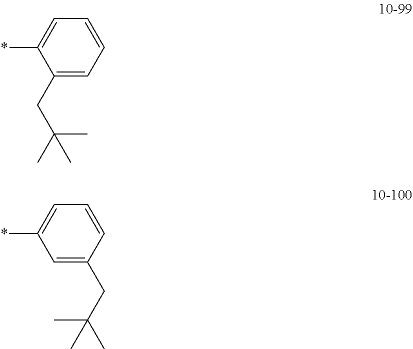

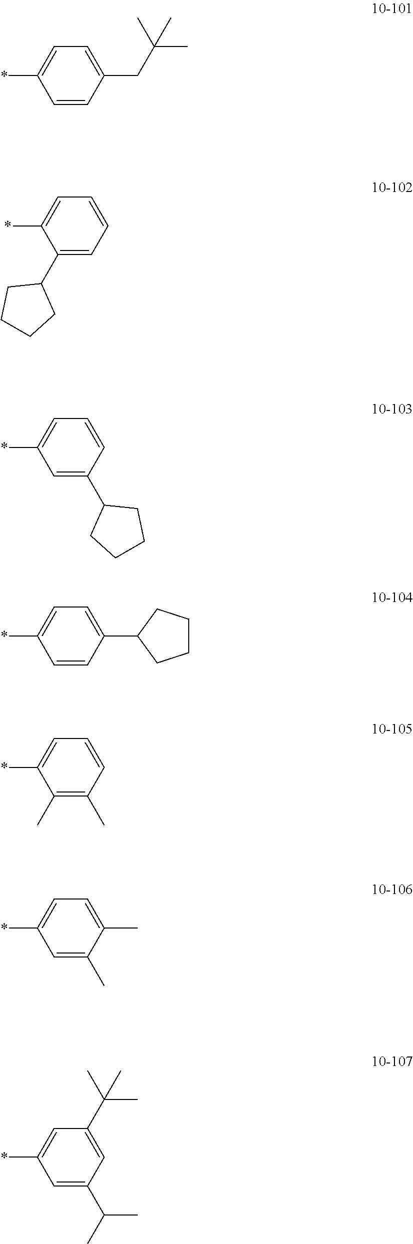

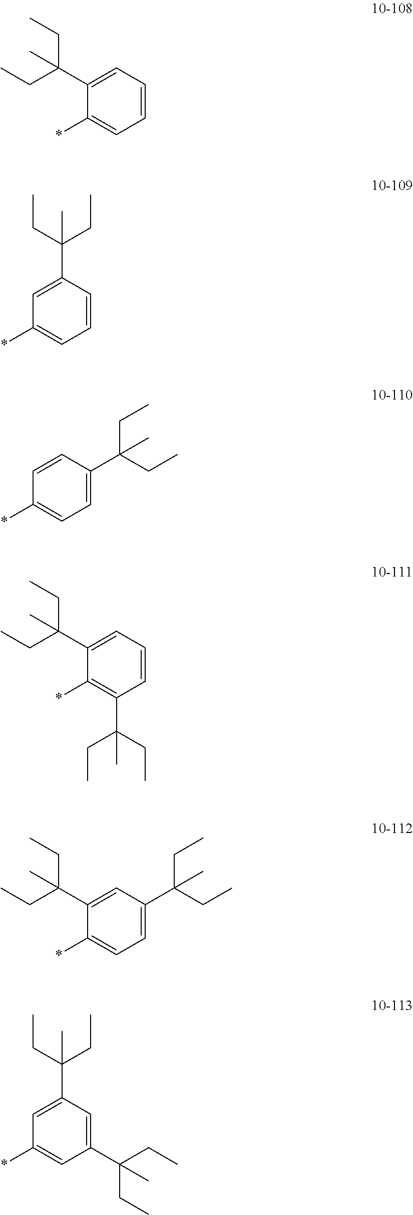

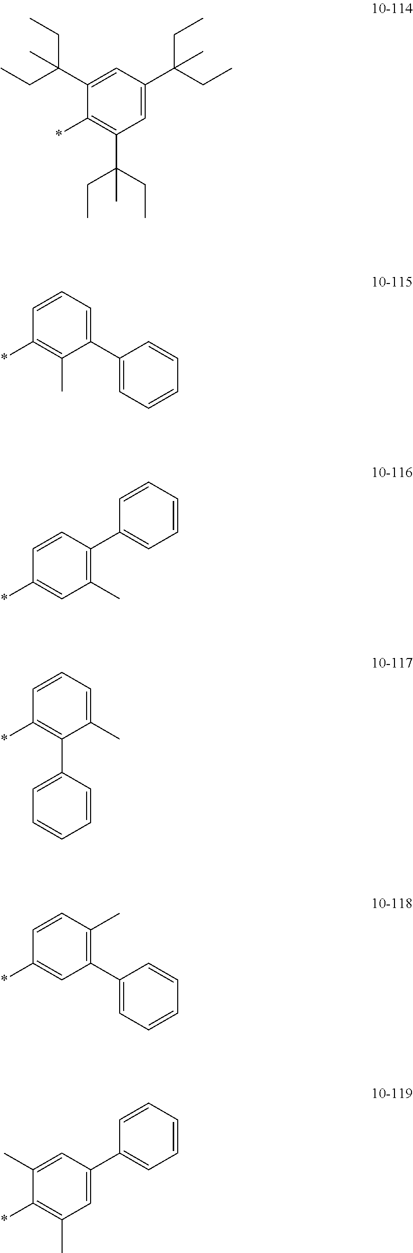 [SMILES: *c1c(C(C)(CC)CC)cc(C(C)(CC)CC)cc1C(C)(CC)CC ; *c1cccc(-c2ccccc2)c1C ; *c1ccc(-c2ccccc2)c(C)c1 ; *c1cccc(C)c1-c1ccccc1 ; *c1ccc(C)c(-c2ccccc2)c1 ; *c1c(C)cc(-c2ccccc2)cc1C]

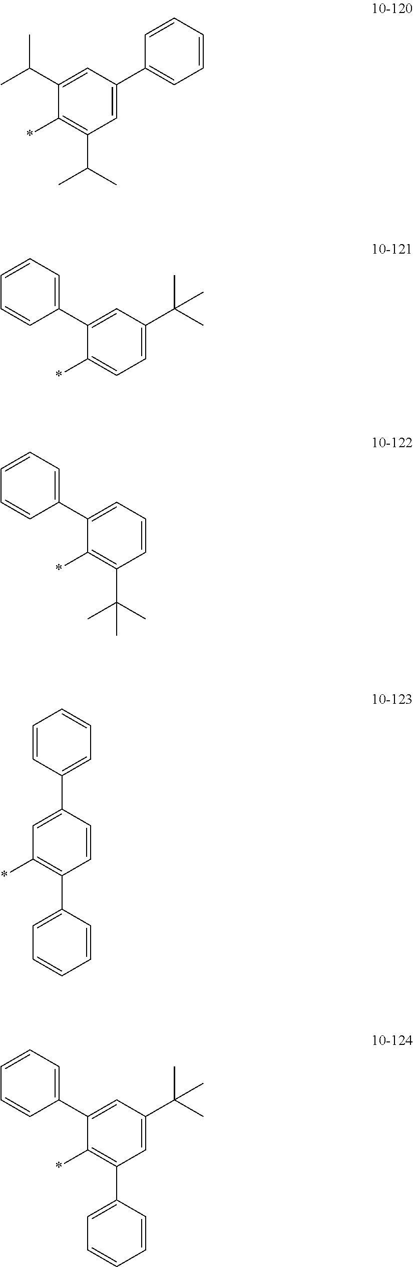 [SMILES: *c1c(C(C)C)cc(-c2ccccc2)cc1C(C)C ; *c1ccc(C(C)(C)C)cc1-c1ccccc1 ; *c1c(-c2ccccc2)cccc1C(C)(C)C ; *c1cc(-c2ccccc2)ccc1-c1ccccc1 ; *c1c(-c2ccccc2)cc(C(C)(C)C)cc1-c1ccccc1]

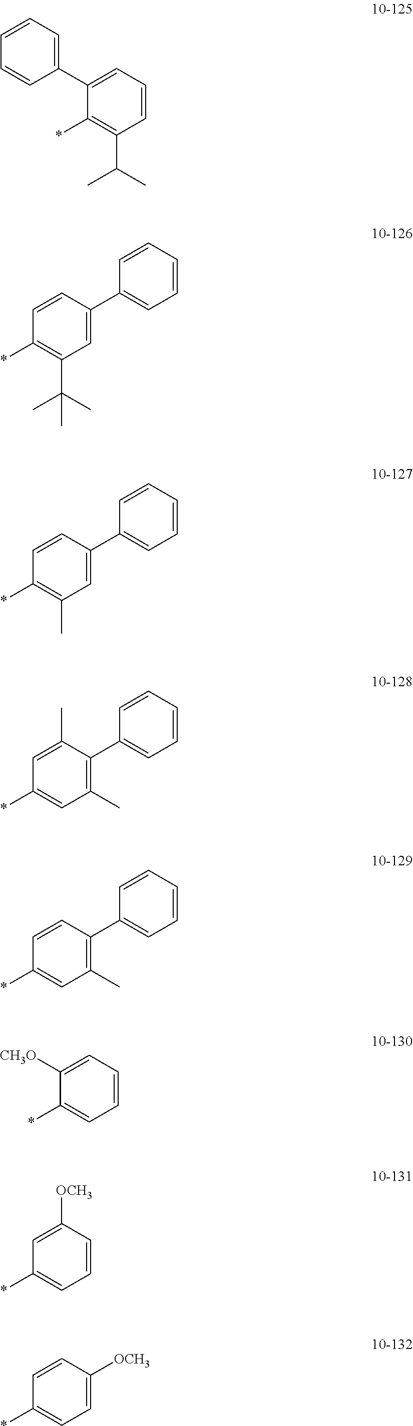

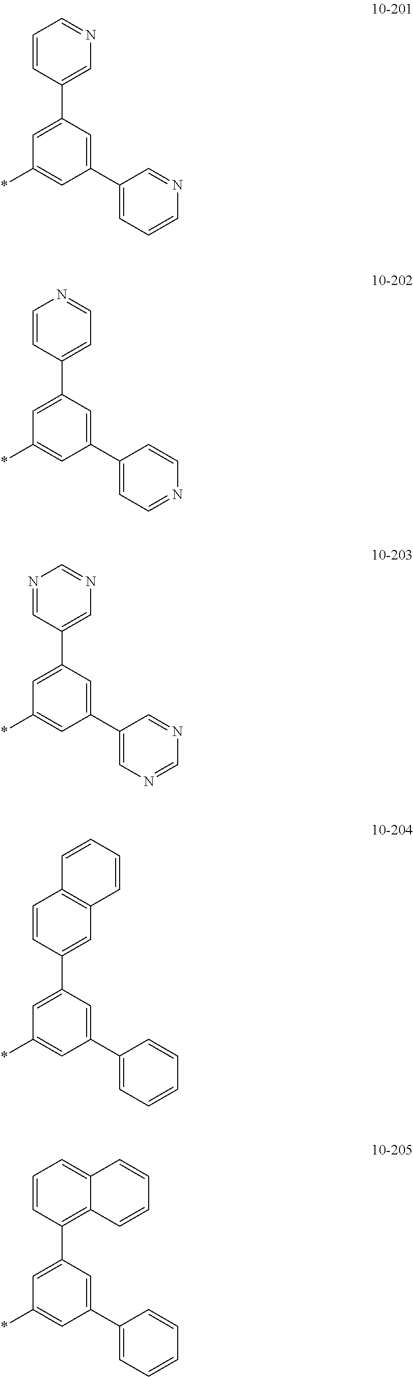 [SMILES: *c1cc(-c2cccnc2)cc(-c2cccnc2)c1 ; *c1cc(-c2ccncc2)cc(-c2ccncc2)c1 ; *c1cc(-c2cncnc2)cc(-c2cncnc2)c1 ; *c1cc(-c2ccccc2)cc(-c2ccc3ccccc3c2)c1 ; *c1cc(-c2ccccc2)cc(-c2cccc3ccccc23)c1]

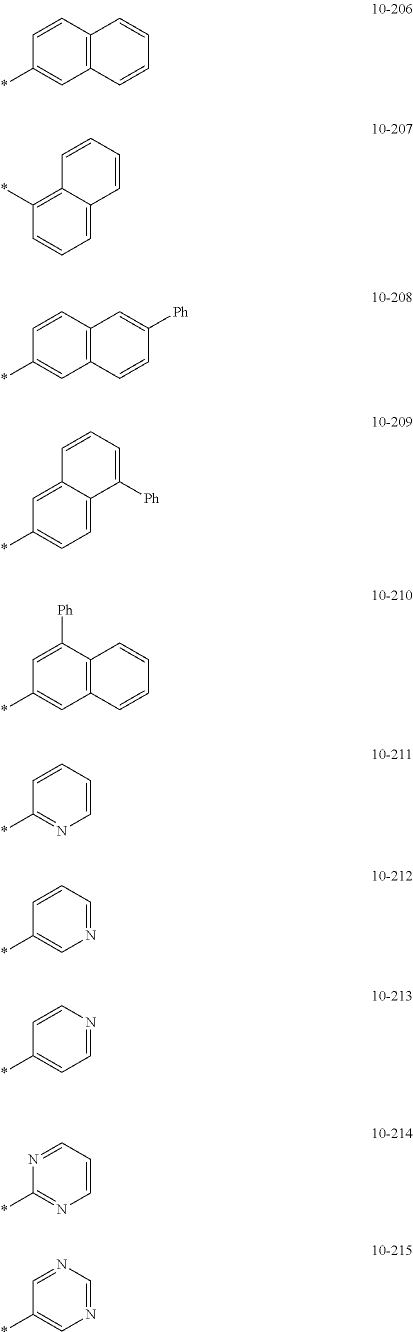

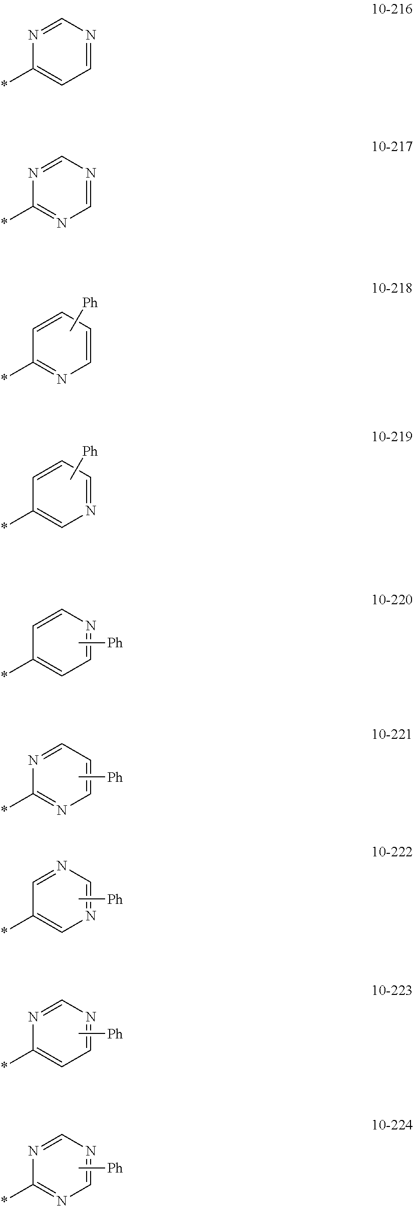

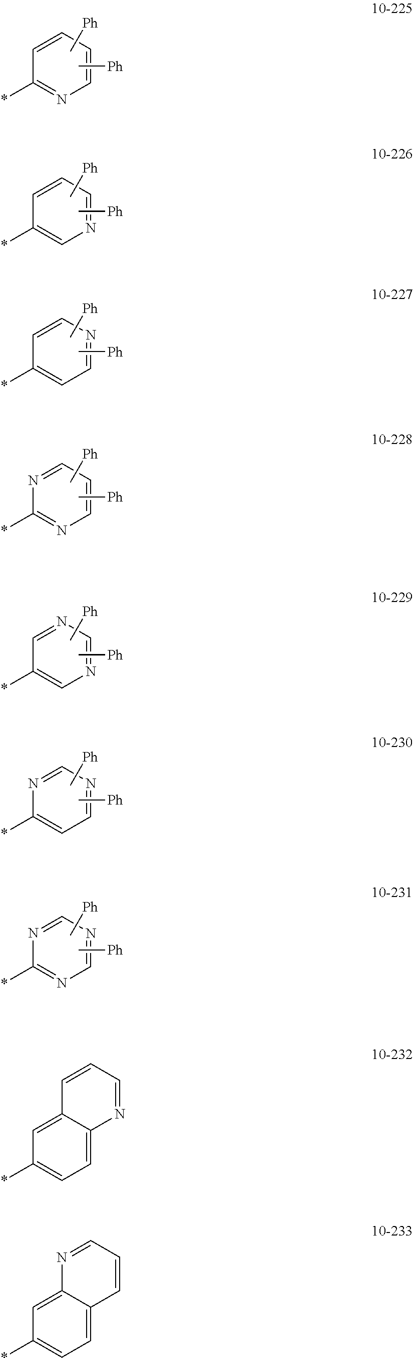

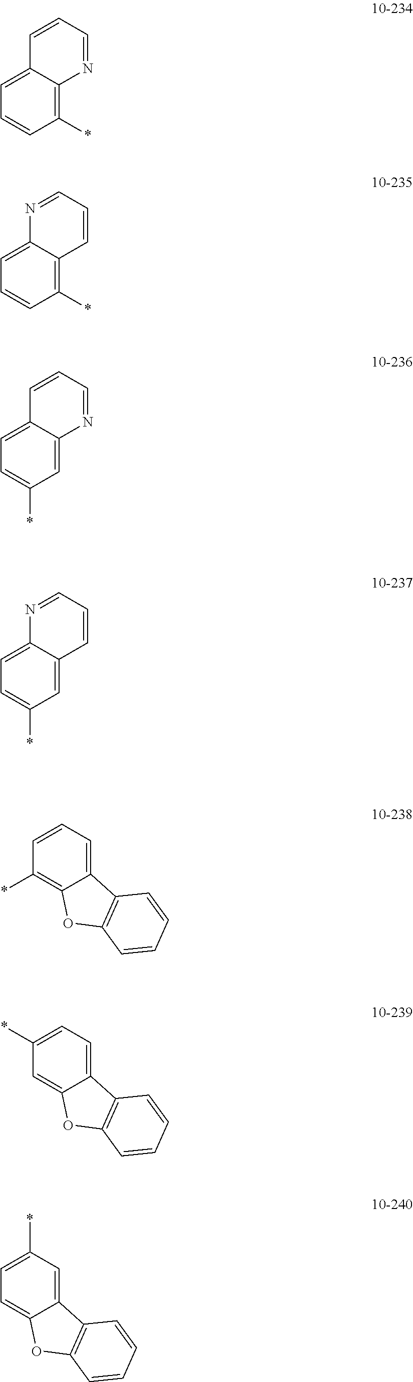

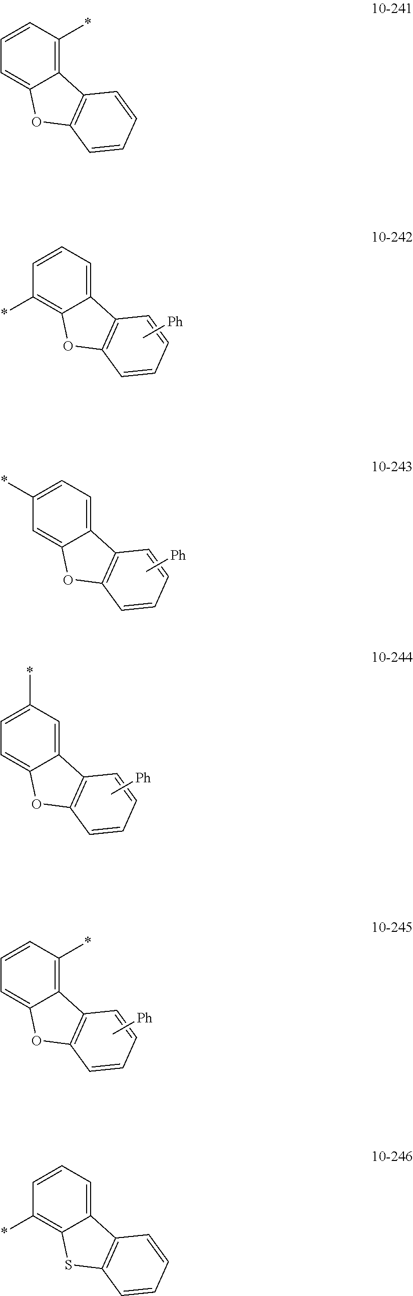

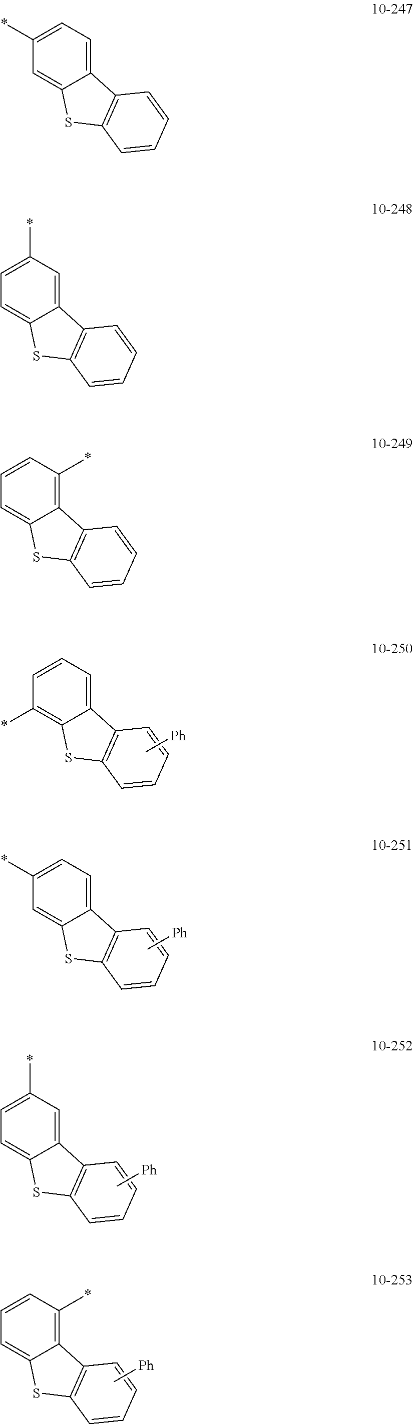

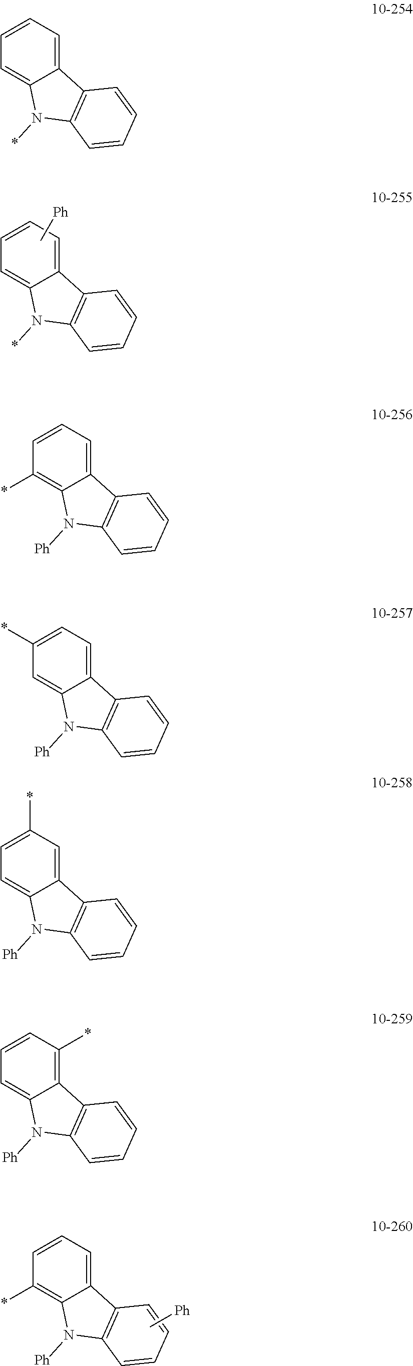

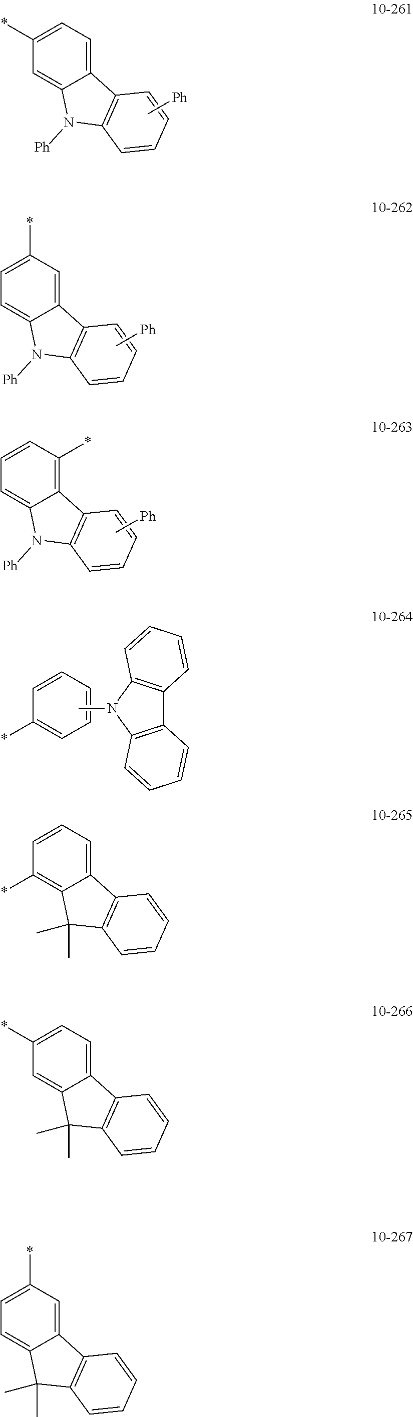

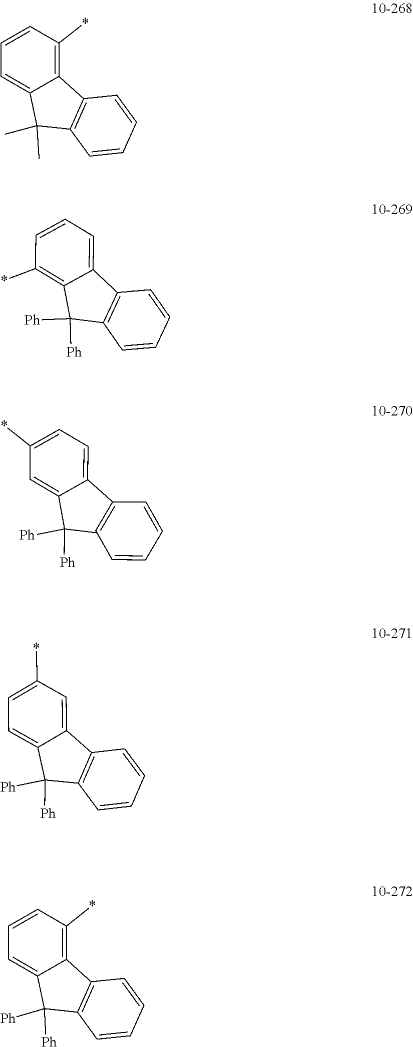

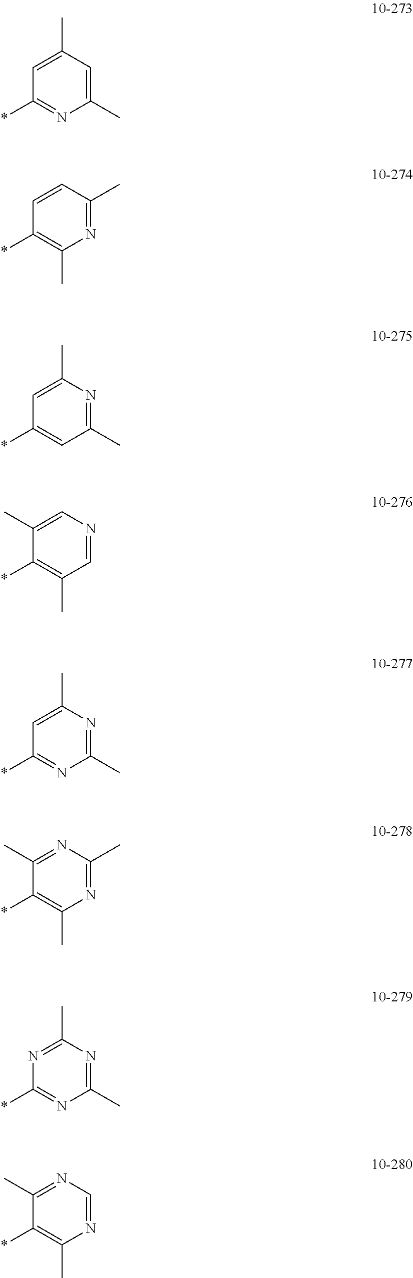

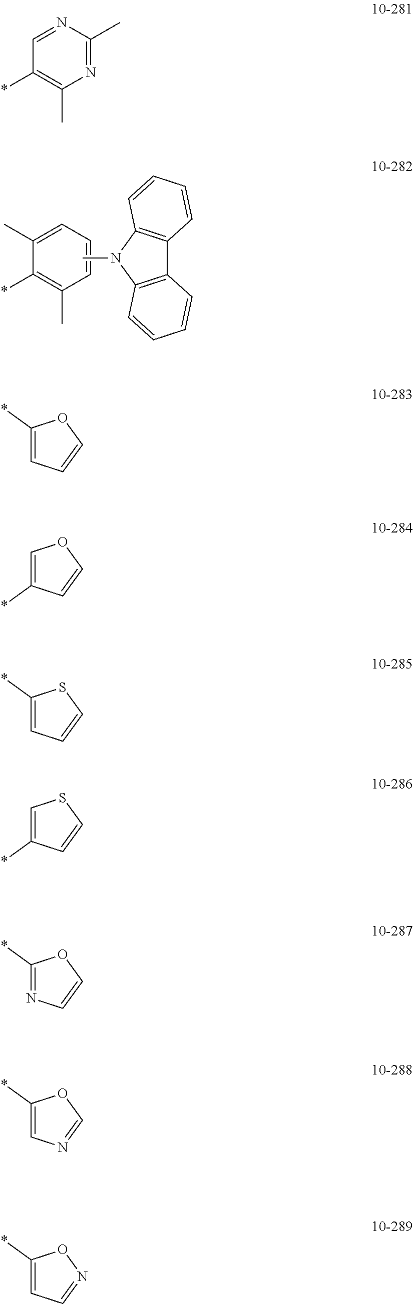

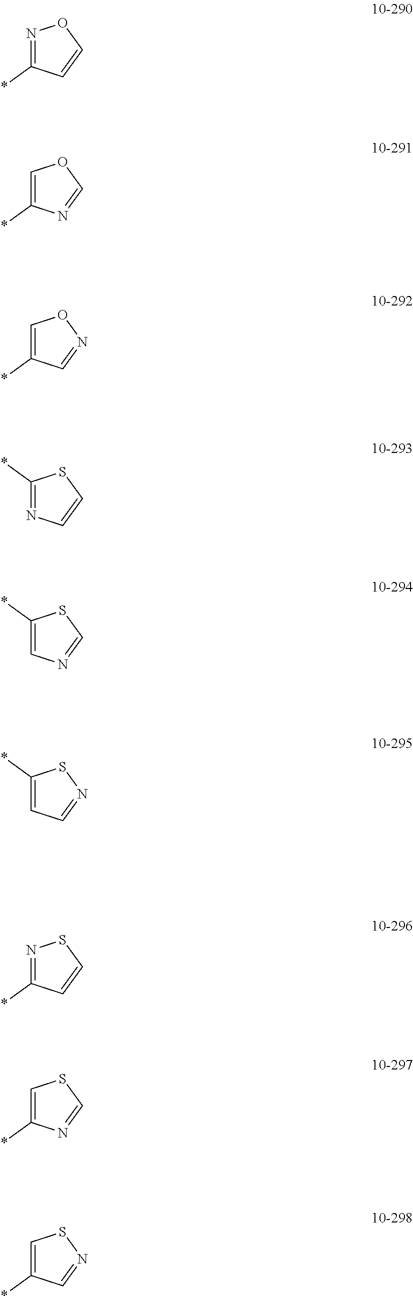

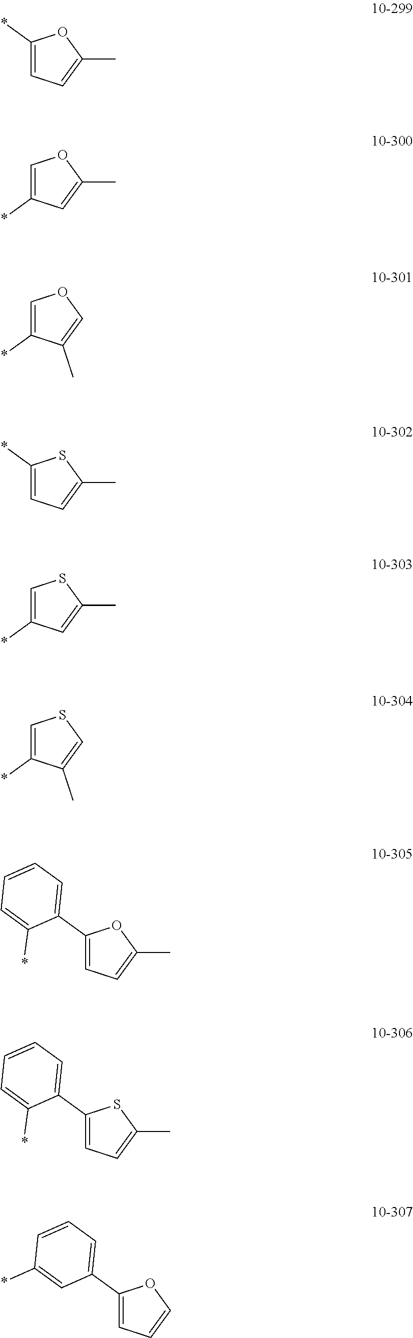

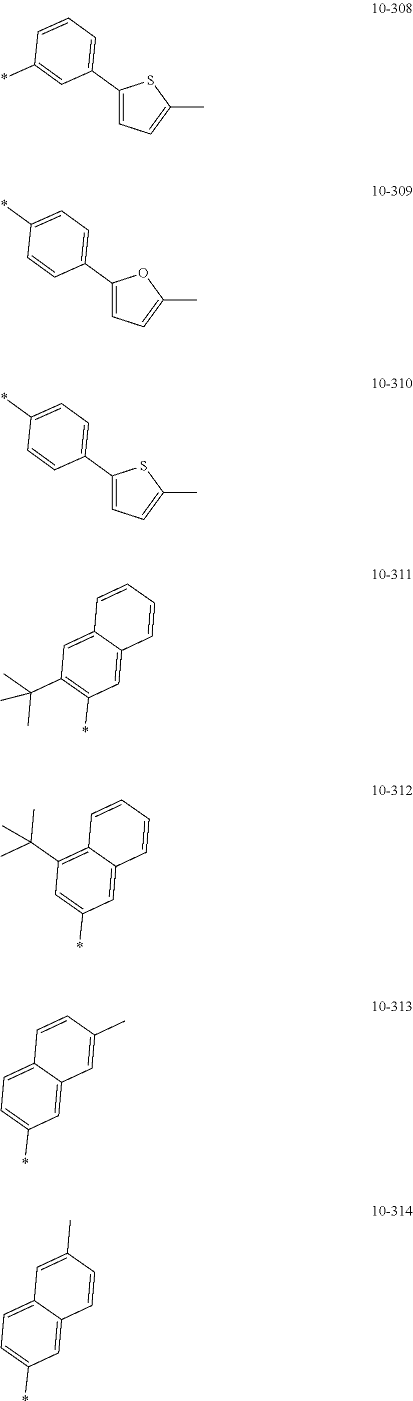

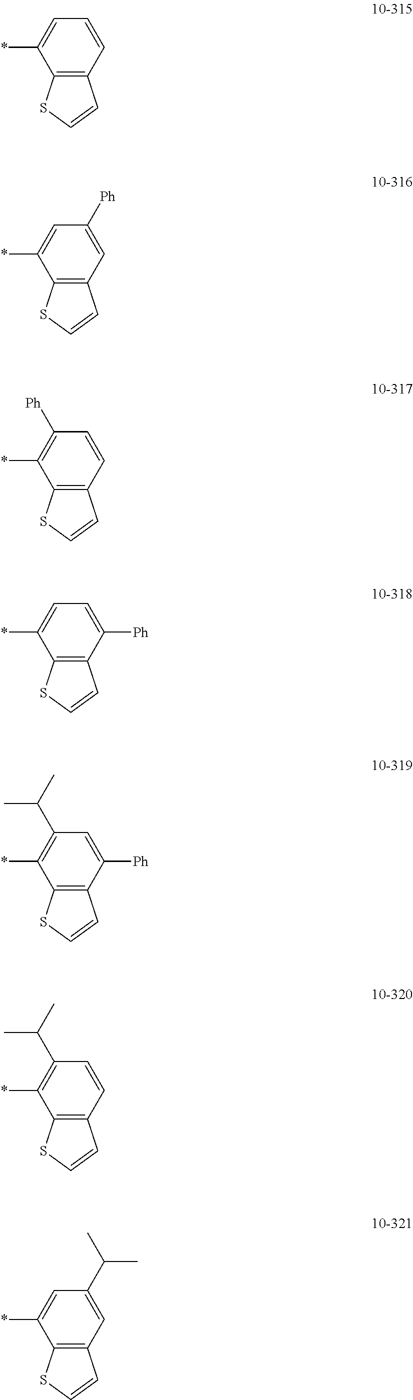

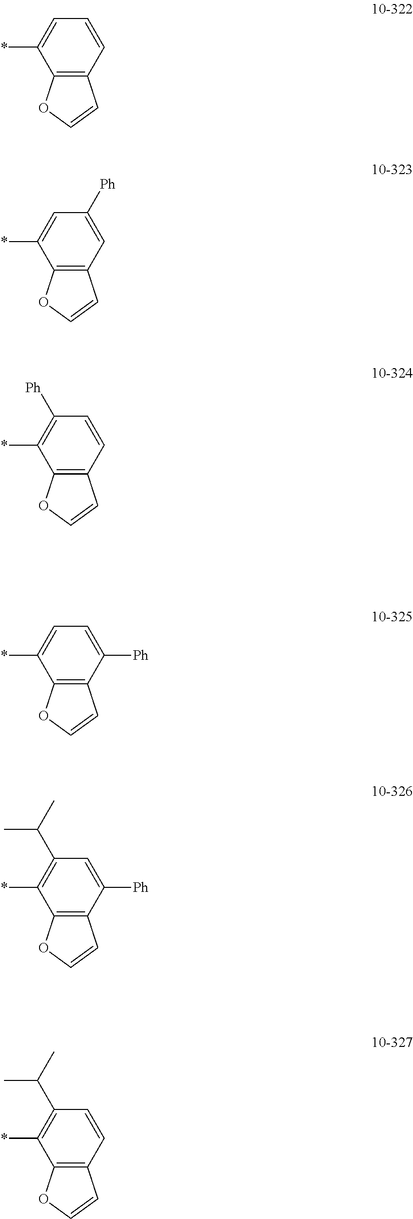 [SMILES: *c1cccc2ccoc12 ; *c1cc(-c2ccccc2)cc2ccoc12 ; *c1c(-c2ccccc2)ccc2ccoc12 ; *c1ccc(-c2ccccc2)c2ccoc12 ; *c1c(C(C)C)cc(-c2ccccc2)c2ccoc12 ; *c1c(C(C)C)ccc2ccoc12]

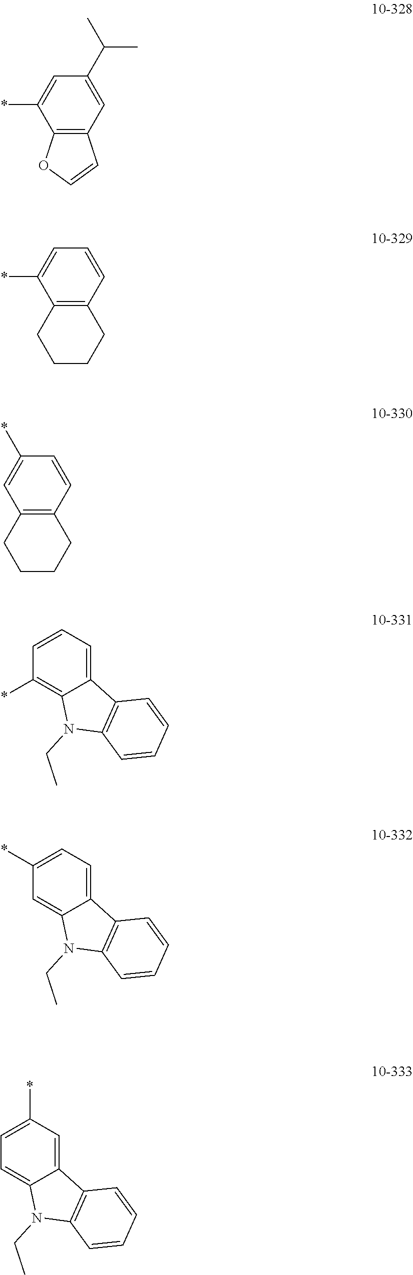 [SMILES: *c1cc(C(C)C)cc2ccoc12 ; *c1cccc2c1CCCC2 ; *c1ccc2c(c1)CCCC2 ; *c1cccc2c3ccccc3n(CC)c12 ; *c1ccc2c3ccccc3n(CC)c2c1 ; *c1ccc2c(c1)c1ccccc1n2CC]

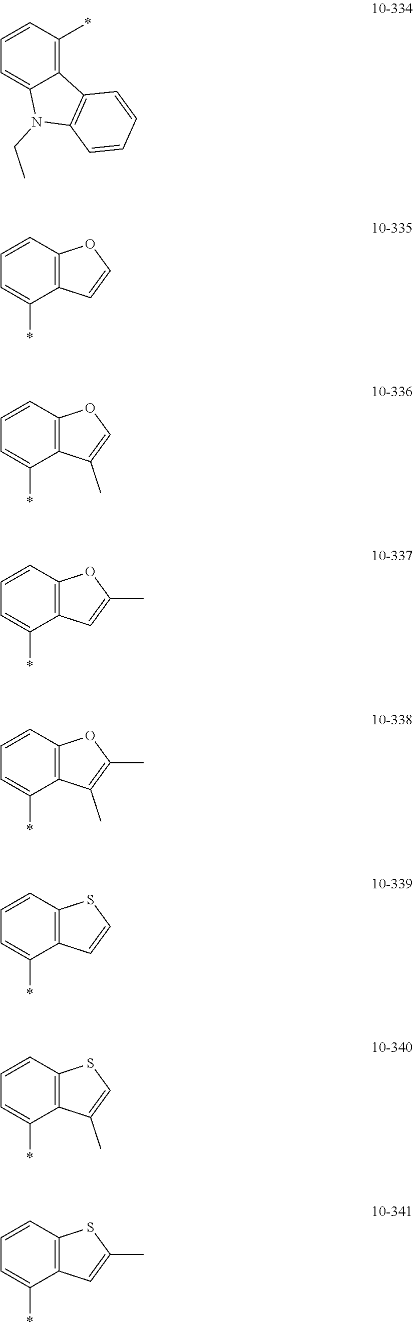

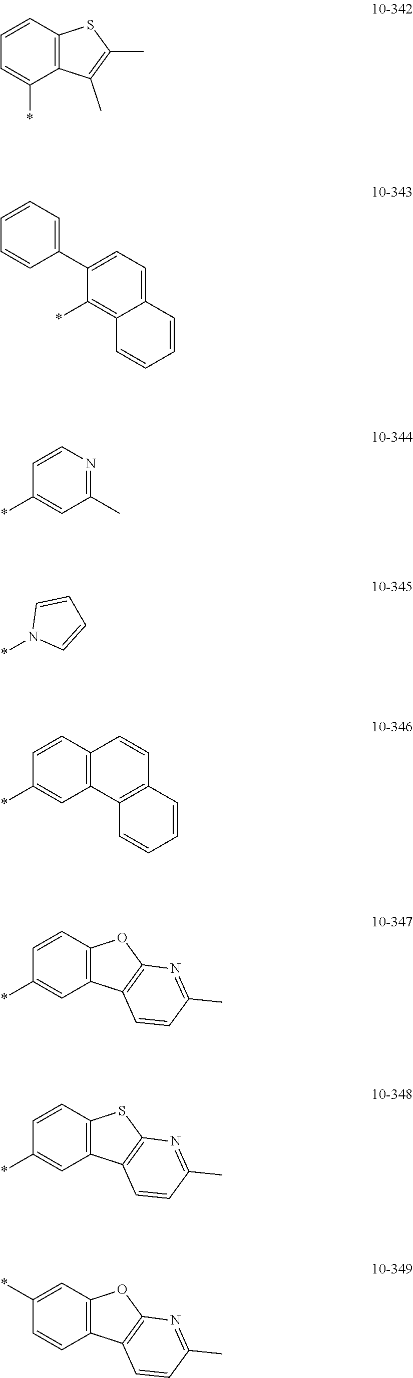

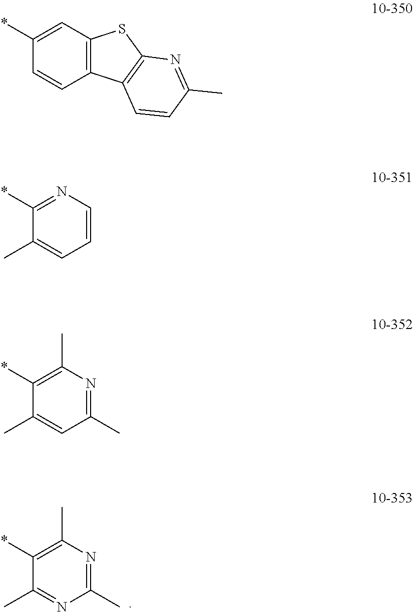

* in Formulae 9-1 to 9-39, 9-201 to 9-233, 10-1 to 10-132, and 10-201 to 10-353 indicates a binding site to a neighboring atom, Ph is a phenyl group, TMS is a trimethylsilyl group, TMG is a trimethylgermyl group, and OMe is a methoxy group.

The “group represented by one of Formulae 9-1 to 9-39 in which at least one hydrogen is substituted with deuterium” and the “group represented by one of Formulae 9-201 to 9-233 in which at least one hydrogen is substituted with deuterium” may each be, for example, a group represented by one of Formulae 9-501 to 9-514 and 9-601 to 9-635:

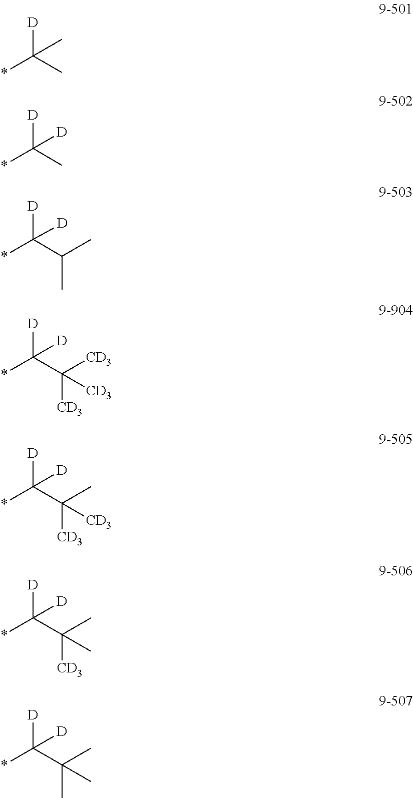

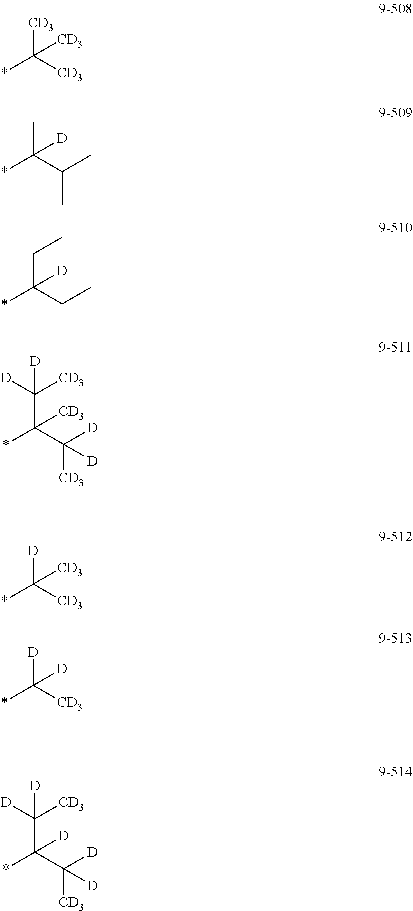

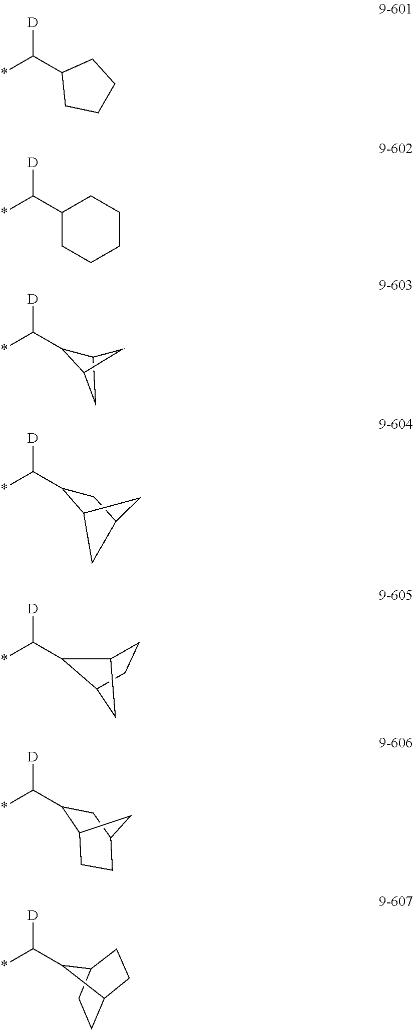

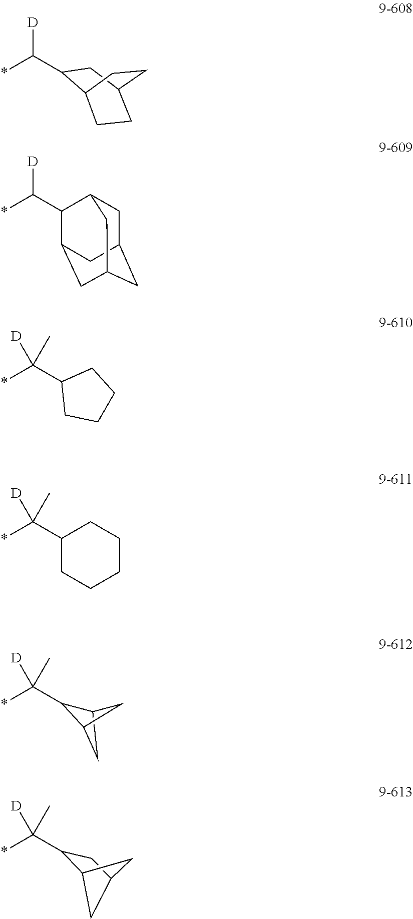

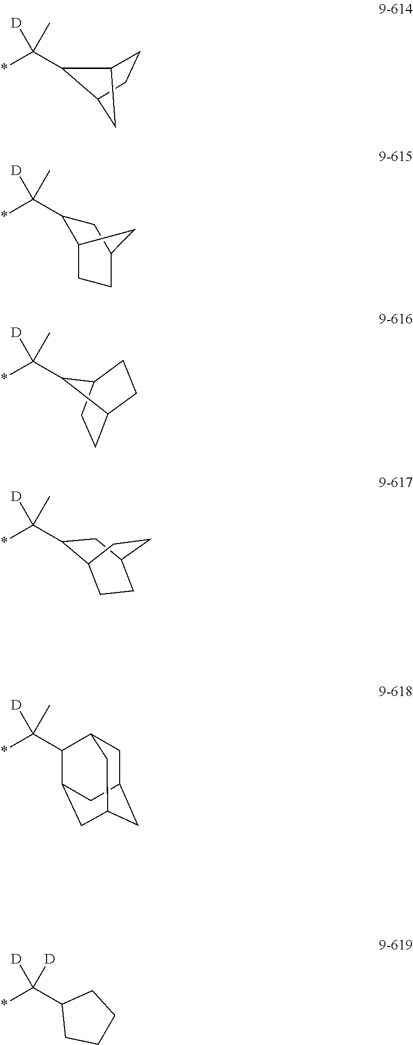

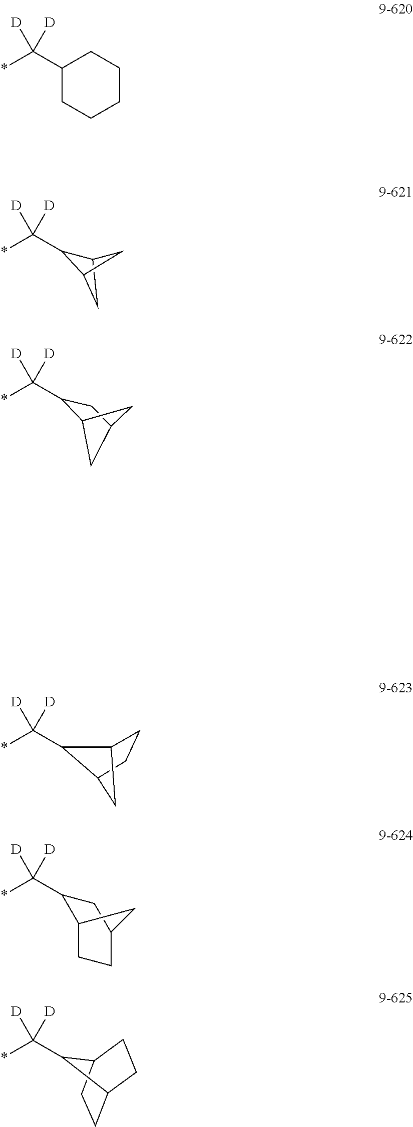 [SMILES: *C([2H])([2H])C1CCCCC1 ; *C([2H])([2H])C1C2CC1C2 ; *C([2H])([2H])C1CC2CC1C2 ; *C([2H])([2H])C1C2CCC1C2 ; *C([2H])([2H])C1CC2CCC1C2 ; *C([2H])([2H])C1C2CCC1CC2]

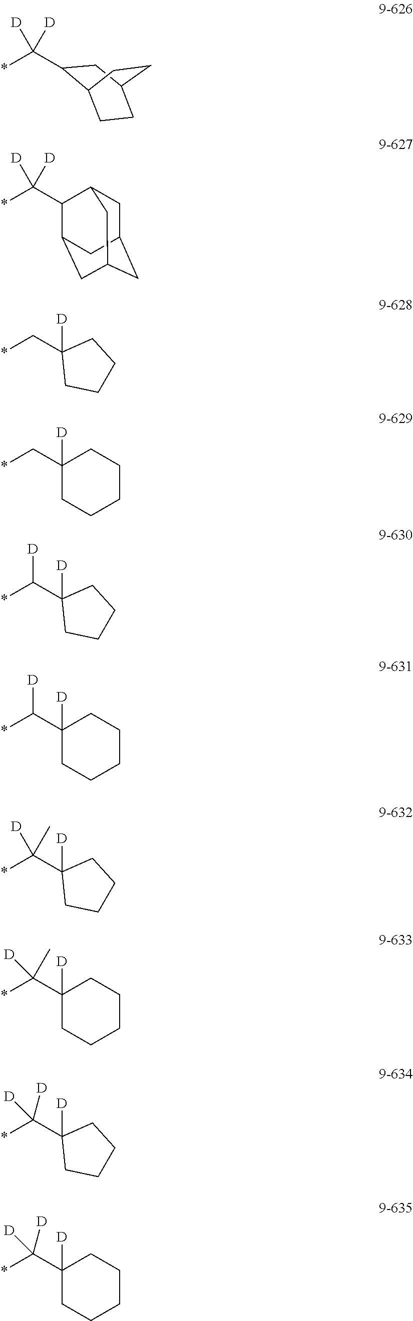

In one or more embodiments, A₁ used herein may be a group represented by one of Formulae 9-501 to 9-514 and 9-601 to 9-635.

The “group represented by Formulae 9-1 to 9-39 in which at least one hydrogen is substituted with —F” and the “group represented by Formulae 9-201 to 9-233 in which at least one hydrogen is substituted with —F” may each be, for example, a group represented by one of Formulae 9-701 to 9-710:

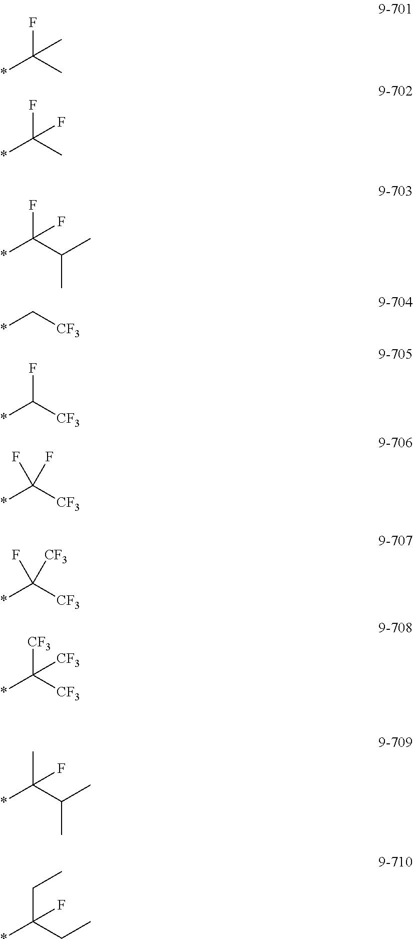

The “group represented by one of Formulae 10-1 to 10-132 in which at least one hydrogen is substituted with deuterium” and “the group represented by one of Formulae 10-201 to 10-353 in which at least one hydrogen is substituted with deuterium” may each be, for example, a group represented by one of Formulae 10-501 to 10-553:

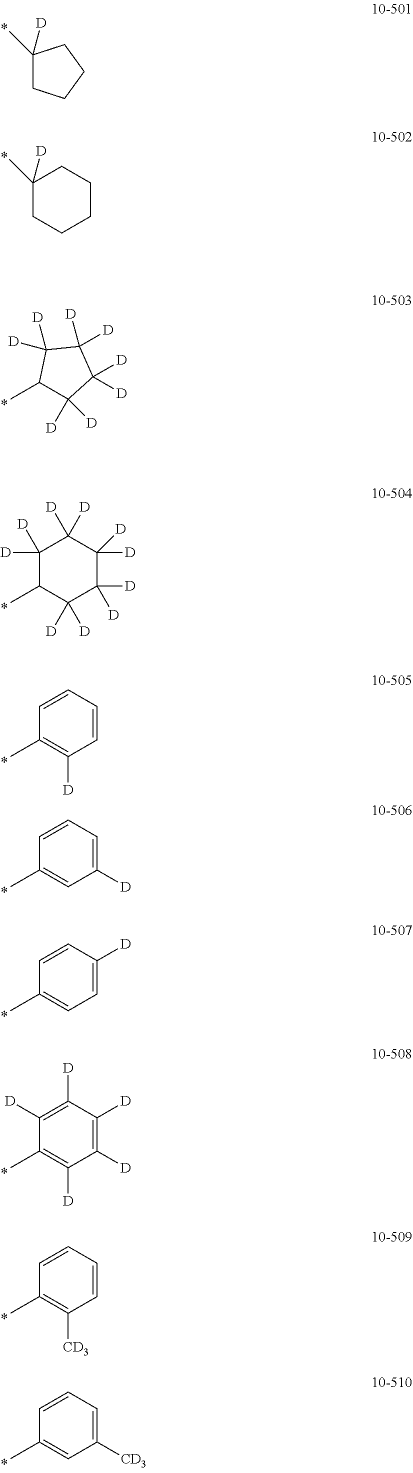

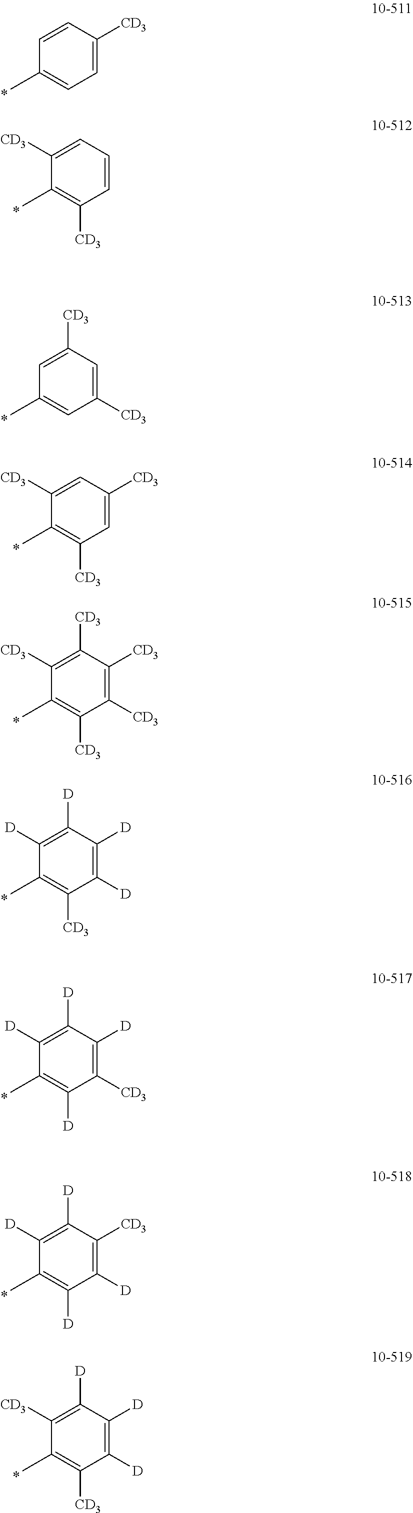

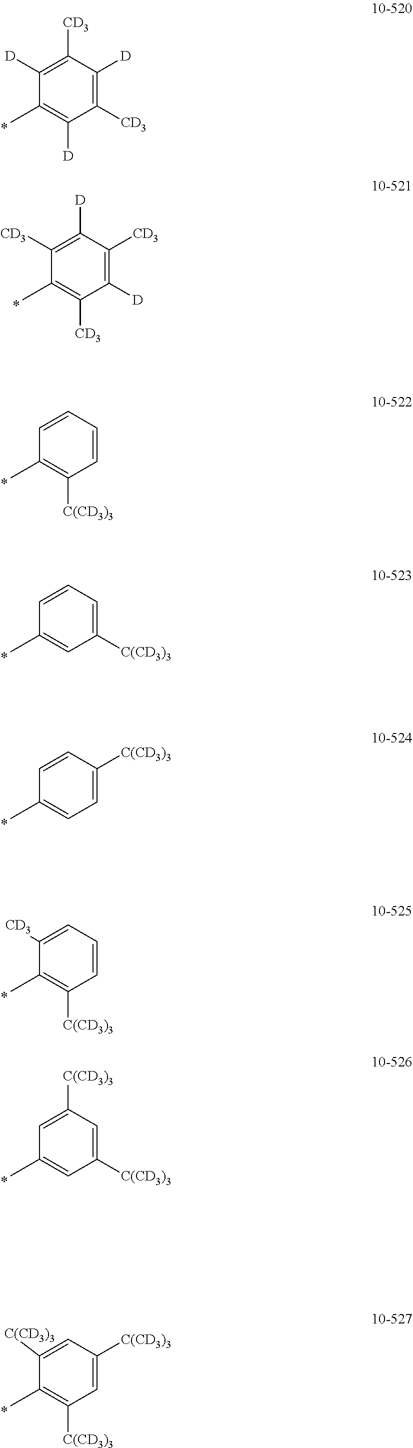

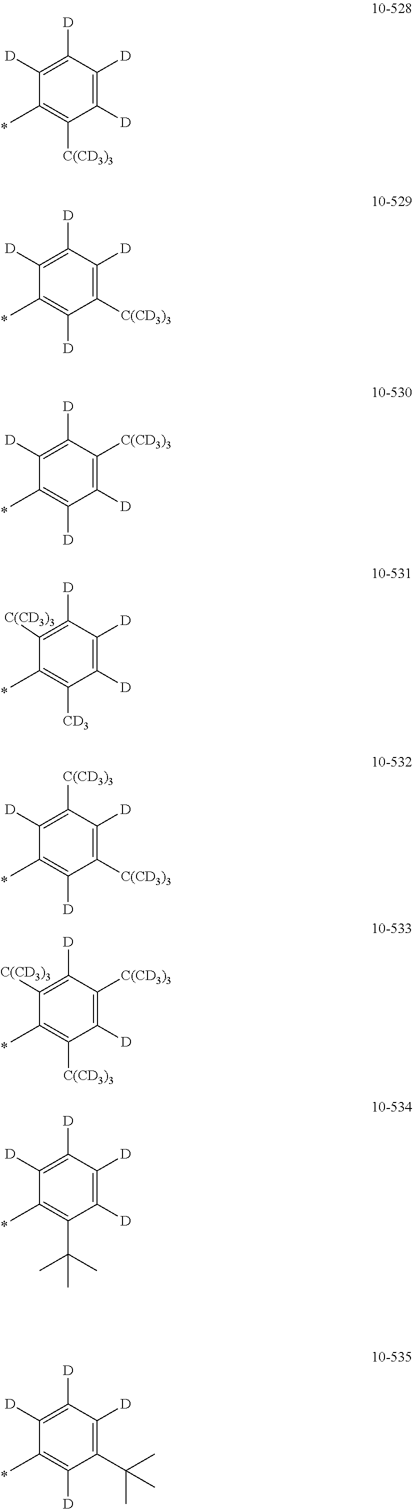

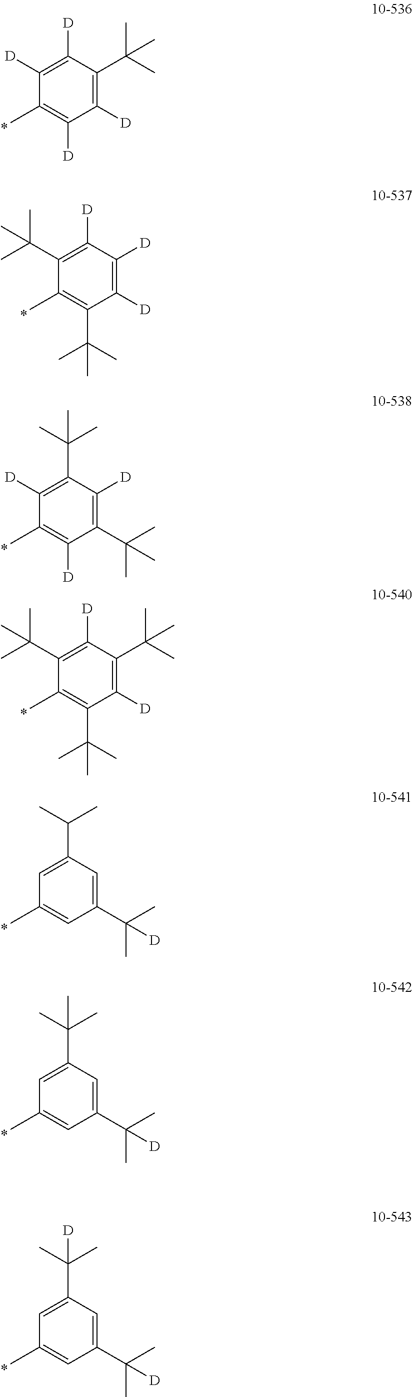

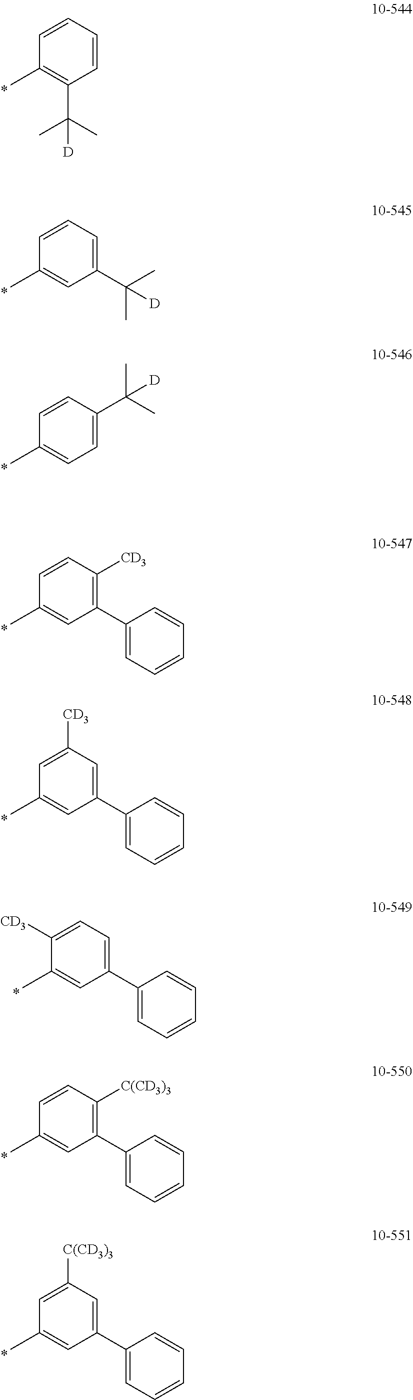

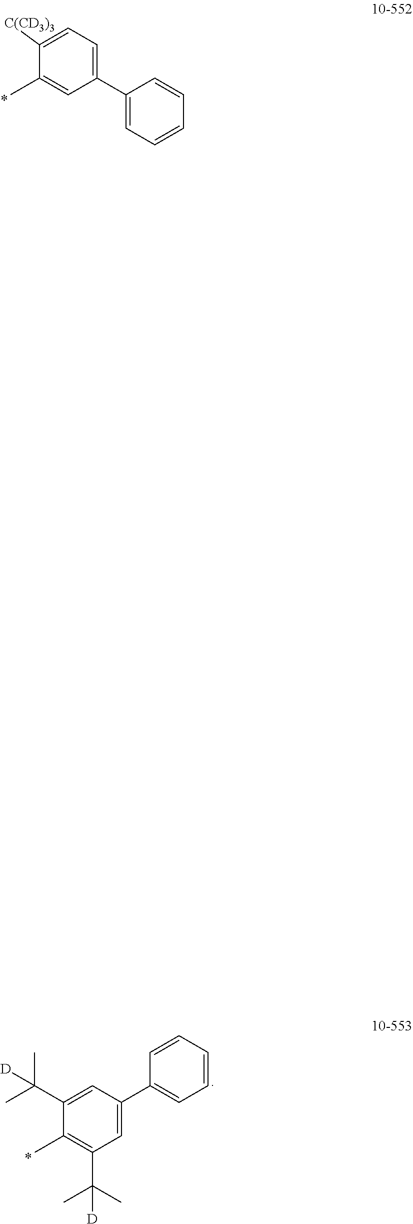

The “group represented by one of Formulae 10-1 to 10-132 in which at least one hydrogen is substituted with —F” and the “group represented by Formulae 10-201 to 10-353 in which at least one hydrogen is substituted with —F” may each be, for example, a group represented by one of Formulae 10-601 to 10-620:

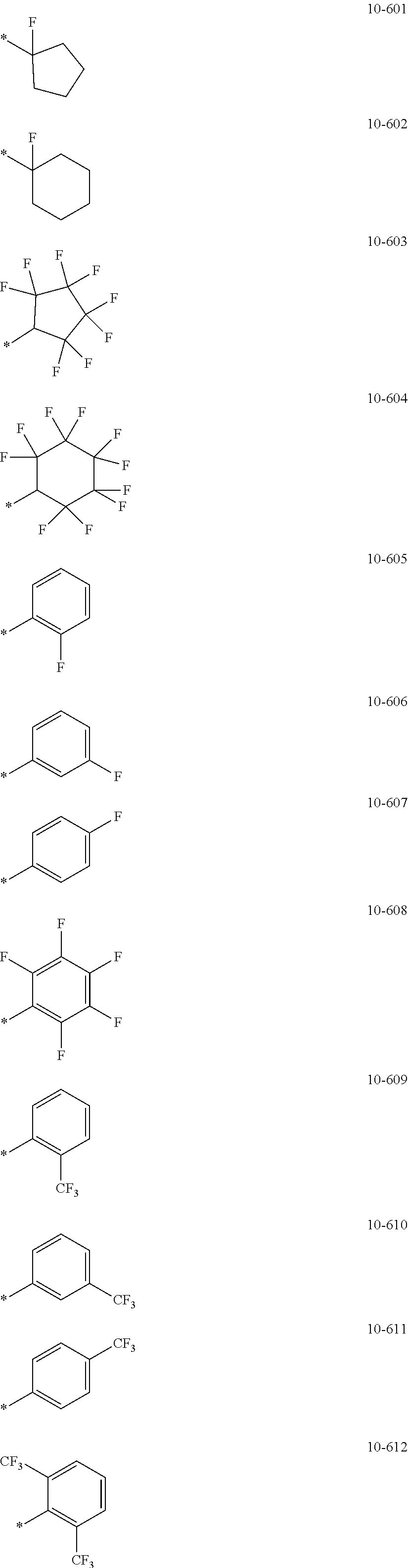

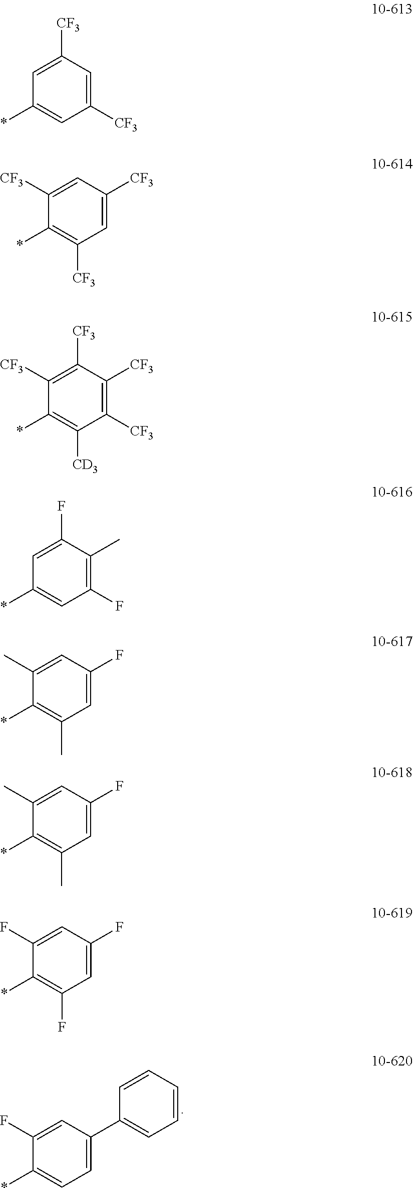

In Formulae 2A and 2B, i) two or more of R₂₁ to R₂₃ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, ii) two or more of a plurality of Z₁(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, iii) two or more of a plurality of Z₂(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, iv) R₁₂ and R₁₃ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, v) two or more of a plurality of R₁₄(s) may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, vi) two or more of Z₁, Z₂ and R₁₁ to R₁₄ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ.

R₁₀ₐ is the same as described in connection with R₁₄.

* and *″ in Formulae 2A and 2B each indicate a binding site to M in Formula 1.

In one or more embodiments, a group represented by

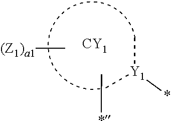

in Formula 2A may be a group represented by one of Formulae CY1-1 to CY1-26:

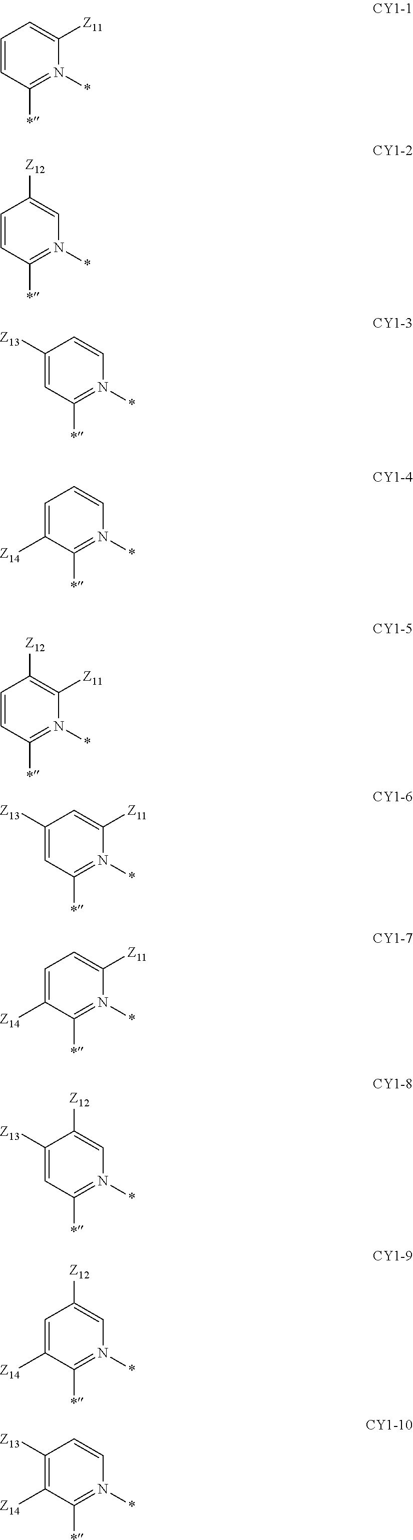

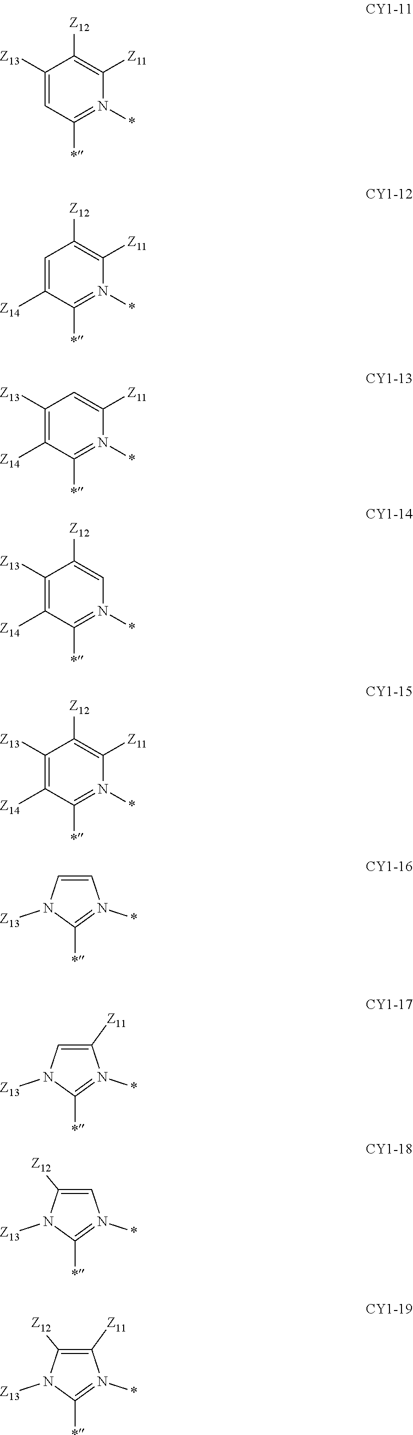

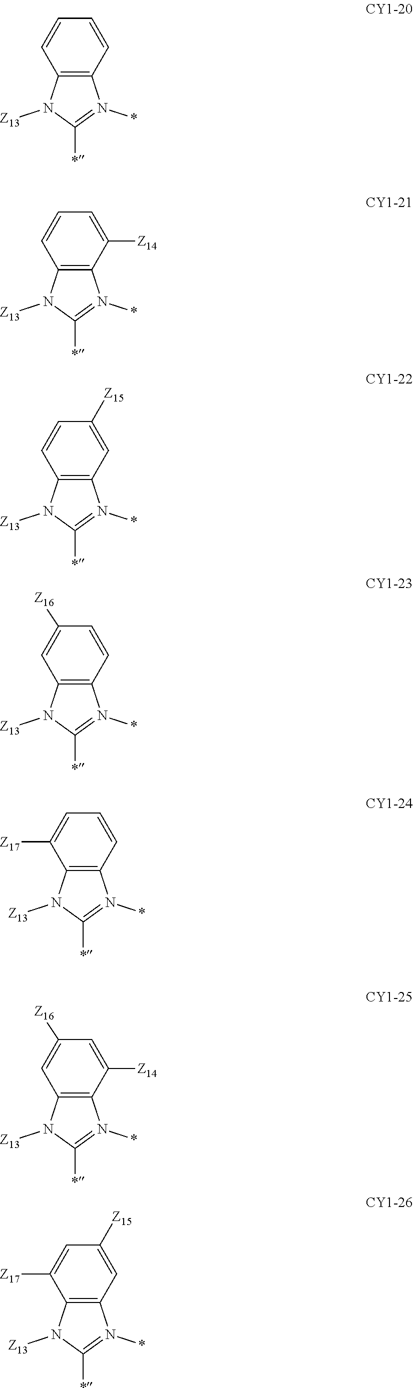

wherein, in Formulae CY1-1 to CY1-26,
Z₁₁ to Z₁₇ are the same as described in connection with Z₁, and each of Z₁₁ to Z₁₇ is not hydrogen,
*indicates a binding site to M in Formula 1, and
*″ is a binding site to one of T₁ to T₄ in Formula 2A.

In one or more embodiments, a group represented by

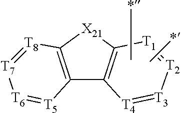

in Formula 2A may be a group represented by one of Formulae CY2-1 to CY2-6:

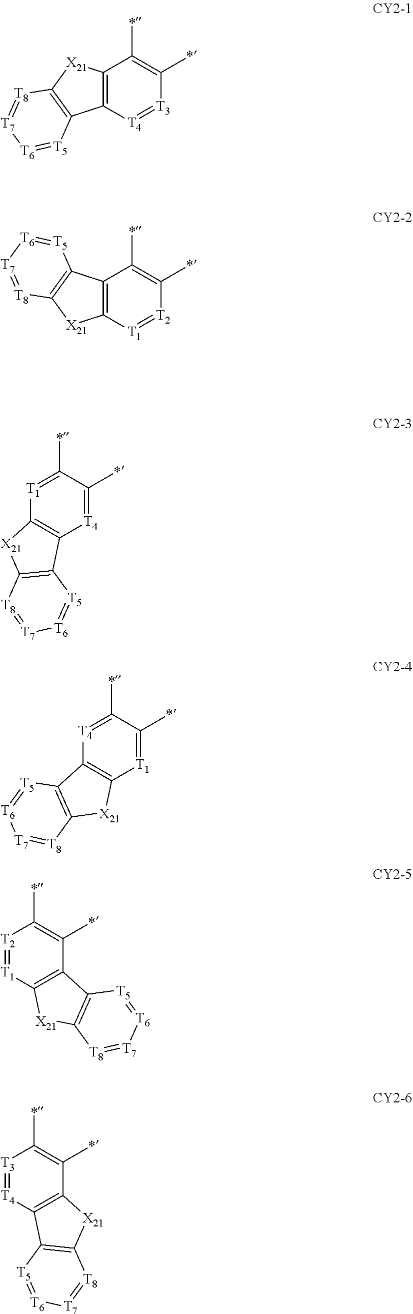

wherein, in Formulae CY2-1 to CY2-6,
T₁ to T₈ may each independently be C or N,
X₂₁ is the same as described above,
*″ is a binding site to ring CY1 in Formula 2A, and
*′ is a binding site to M in Formula 1.

For example,
a) T₁ to T₈ of Formula CY2-1 to CY2-6 may each be C, (and/or)
b) at least one of T₃ to T₈ of Formulae CY2-1 and CY2-6 (for example, one or two of T₃ to T₈) may be N, (and/or)
c) at least one of T₁, T₂ and T₅ to T₈ of Formulae CY2-2 and CY2-5 (for example, one or two of T₁, T₂ and T₅ to T₈) may be N, (and/or)
d) at least one of T₁ and T₄ to T₈ of Formulae CY2-3 and CY2-4 (for example, one or two of T₁ and T₄ to T₈) may be N.

In one or more embodiments,
1) T₁ to T₈ of Formulae CY2-1 to CY2-6 may each be C;
2) in Formula CY2-1, one of T₃ to T₈ may be N, and the others of T₃ to T₈ which are not N, may be C;
3) in Formula CY2-1, T₃ and T₈ may be N, and T₄ to T₇ may each be C;
4) in Formula CY2-1, T₆ and T₈ of may be N, and T₃ to T₅ and T₇ may each be C;
5) in Formula CY2-2, one of T₁, T₂ and T₈ may be N, and the others of T₁, T₂ and T₅ to T₈, which are not N, may be C;
6) in Formula CY2-2, T₁ and T₈ may each be N, and T₂ and T₅ to T₇ may each be C;
7) in Formula CY2-2, T₂ and T₈ may be N, and T₁ and T₅ to T₇ may each be C;
8) in Formulae CY2-3 and CY2-4, one of T₁, T₄ and T₈ may be N, and the others of T₁, T₄ and T₅ to T₈ which are not N, may each be C;
9) in Formulae CY2-3 and CY2-4, T₁ and T₈ may each be N, and T₄ and T₅ to T₇ may each be C;
10) in Formulae CY2-3 and CY2-4, T₄ and T₈ may each be N, and T₁ and T₅ to T₇ may each be C;
11) in Formula CY2-5, one of T₁ and T₈ is N, and the others of T₁, T₂ and T₅ to T₈ which are not N, may be C;
12) in Formula CY2-5, T₁ and T₈ may be N, and T₂ and T₅ to T₇ may each be C;
13) in Formula CY2-6, one of T₄ and T₈ may be N, and the others of T₃ to T₈ which are not N, may be C; or
14) in Formula CY2-6, T₄ and T₈ may each be N, and T₃ and T₅ to T₇ may each be C.

In one or more embodiments, a group represented by

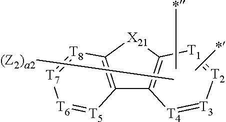

in Formula 2A may be a group represented by one of Formulae CY2-1001 to CY2-1141, CY2-2001 to CY2-2092, CY2-3001 to CY2-3092, CY2-4001 to CY2-4092, CY2-5001 to CY2-5065, and CY2-6001 to CY2-6065:

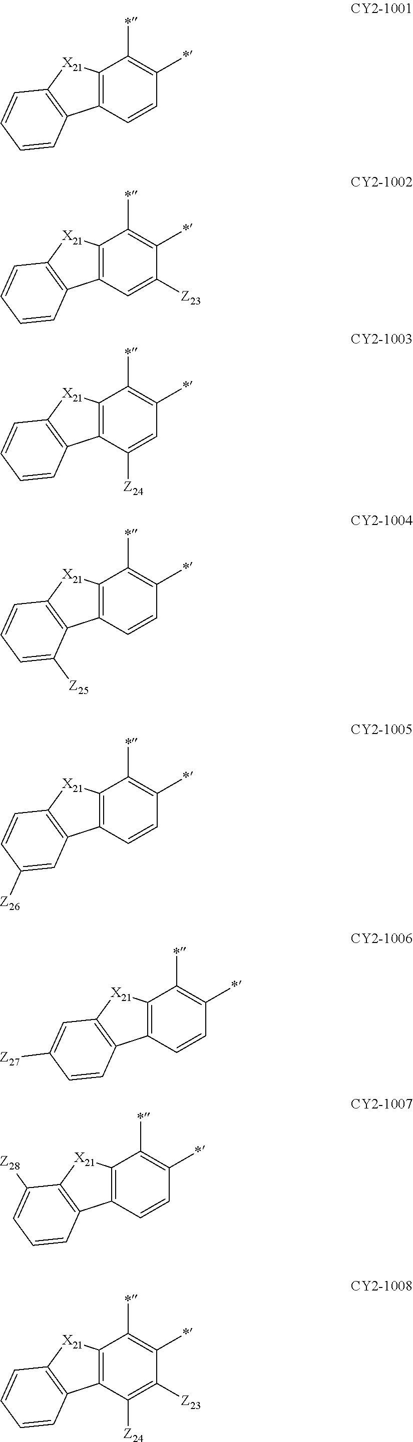

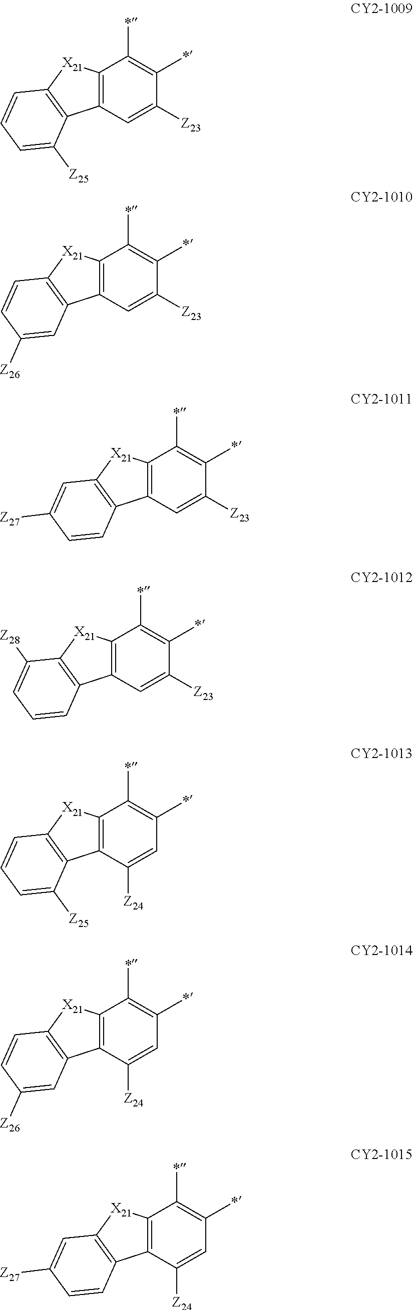

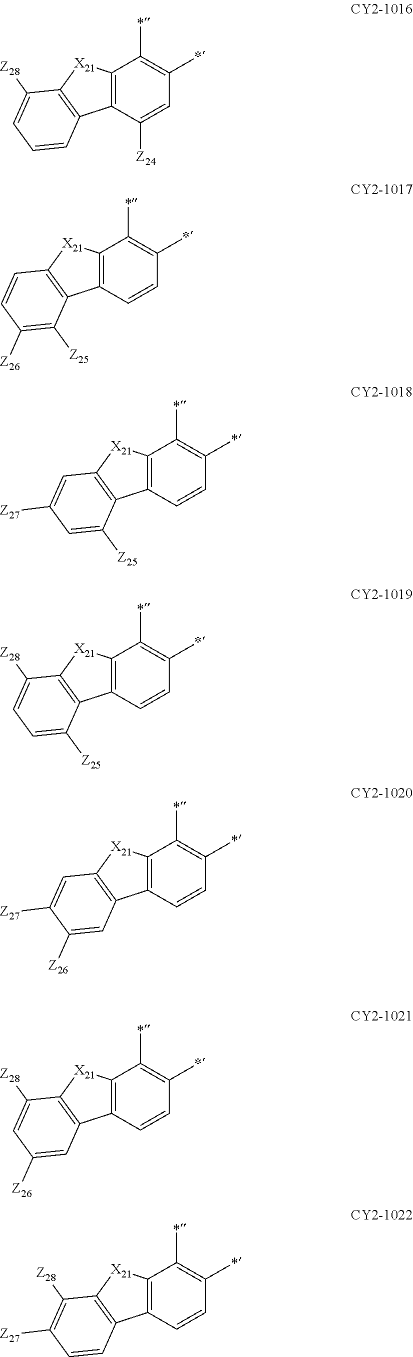

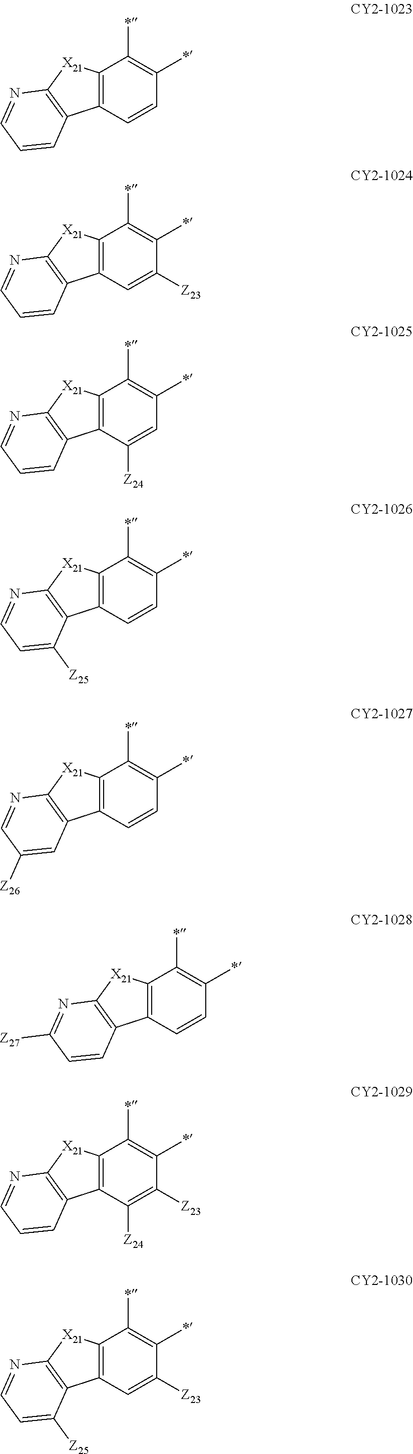

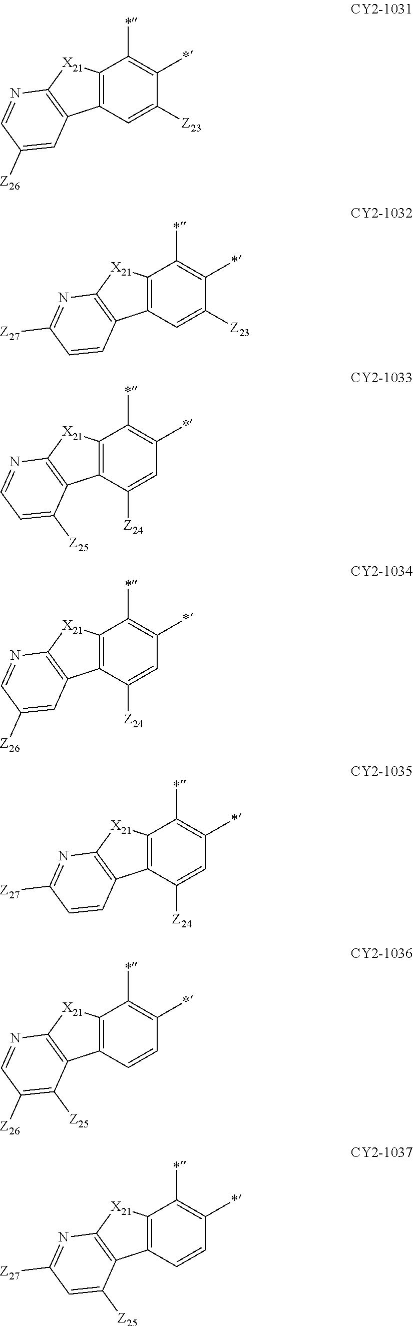

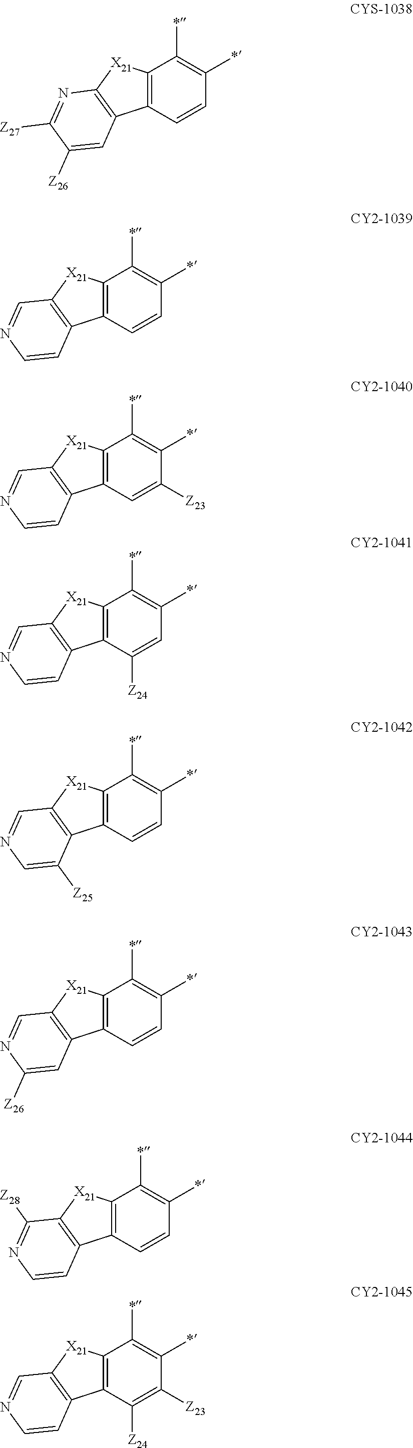

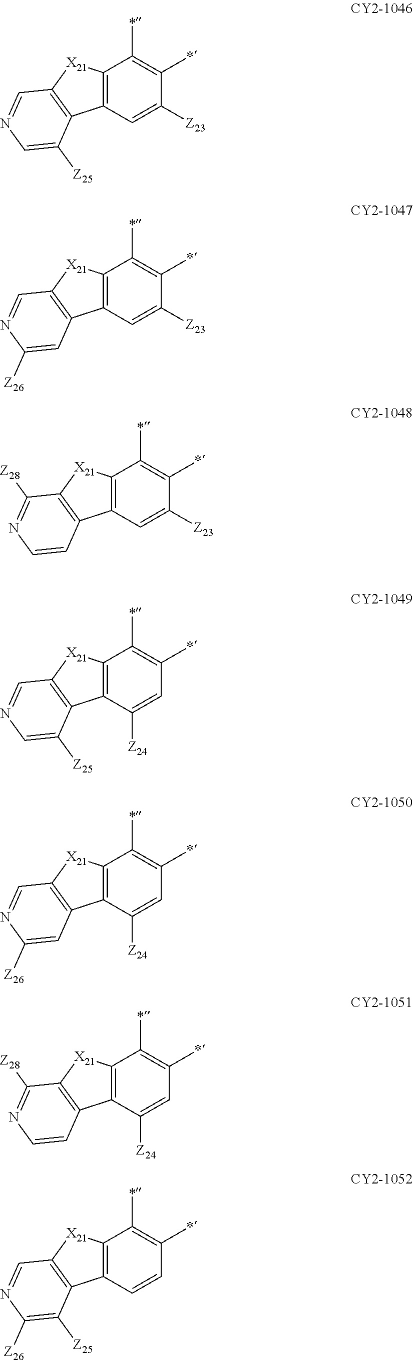

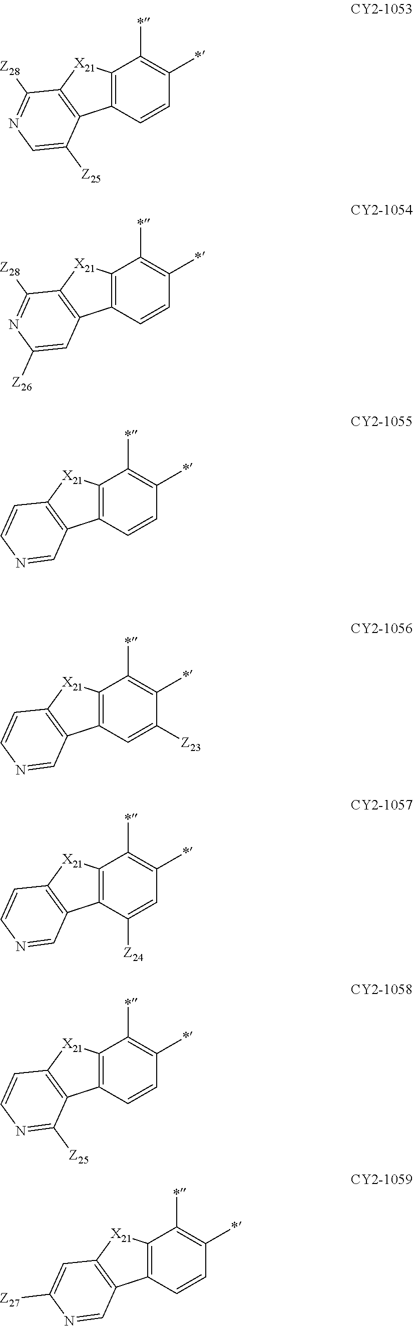

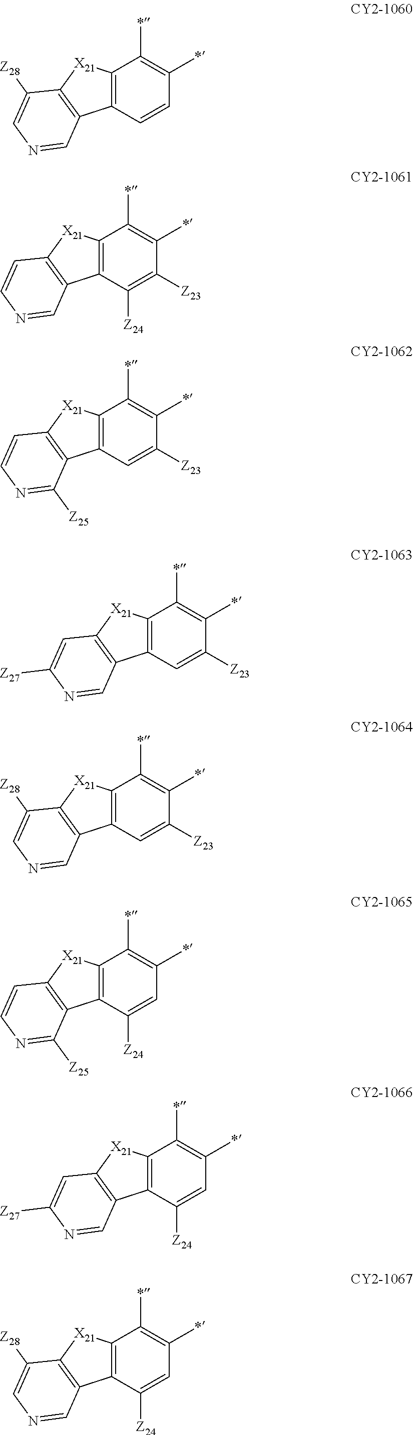

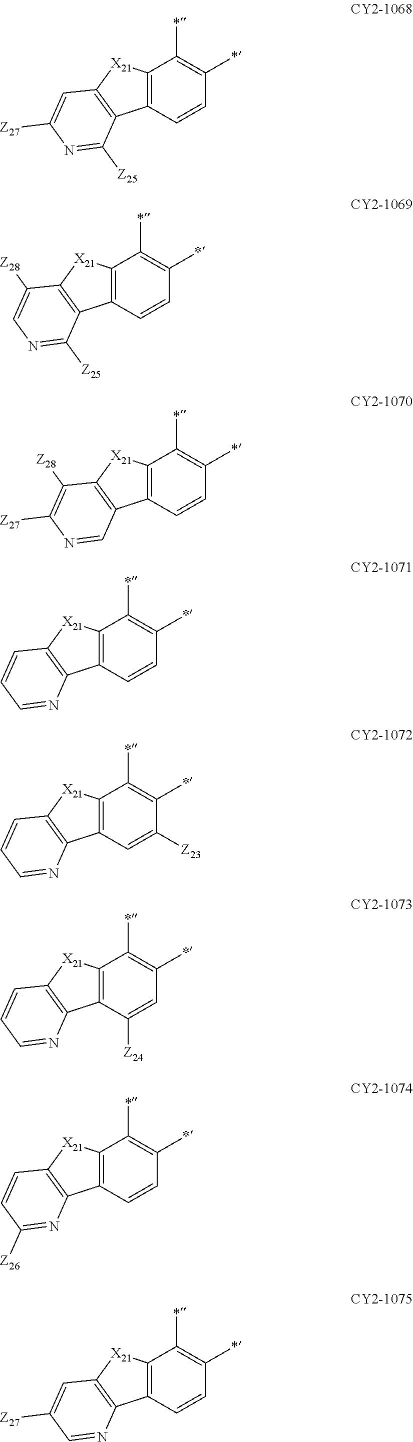

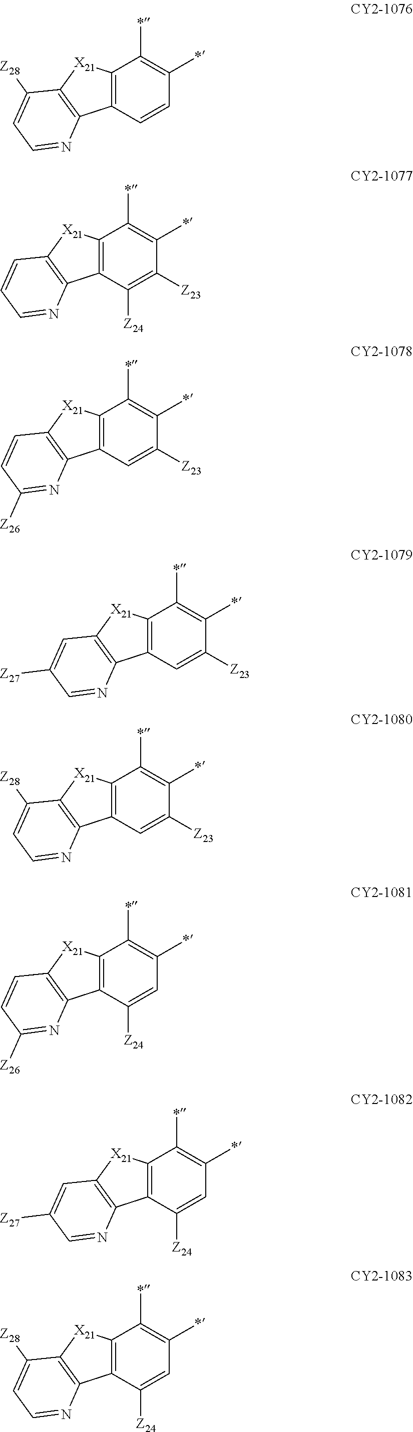

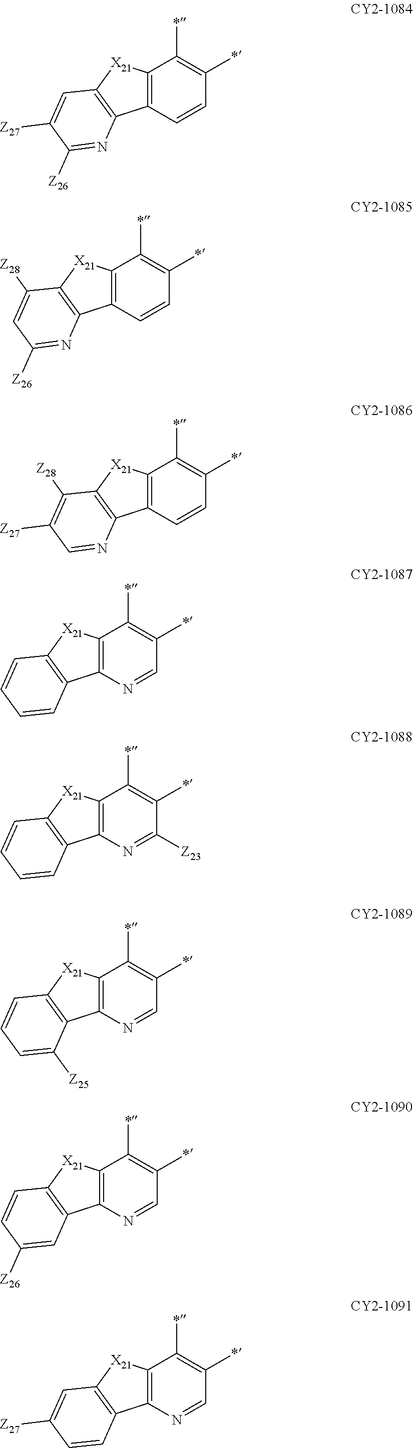

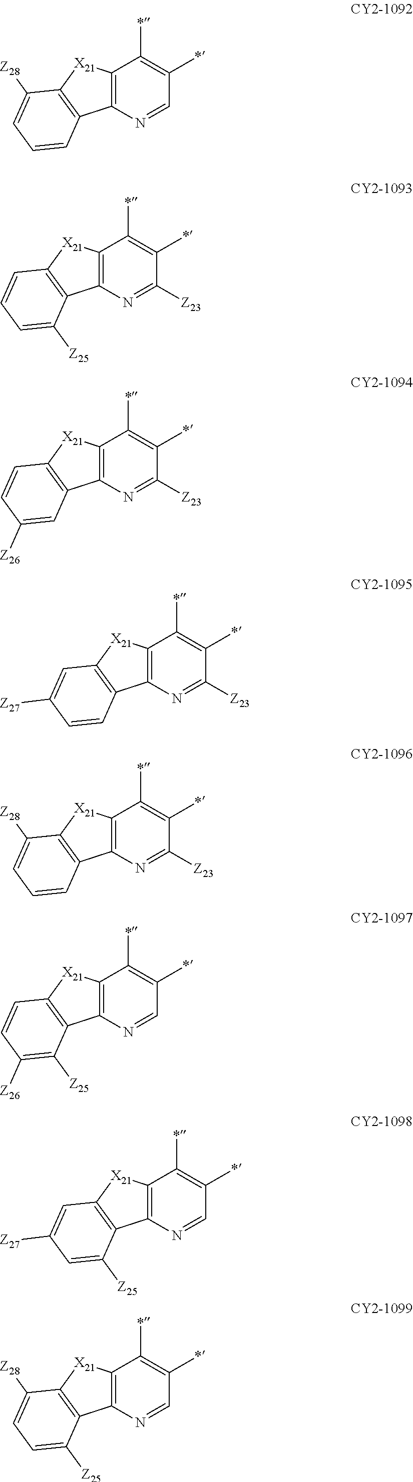

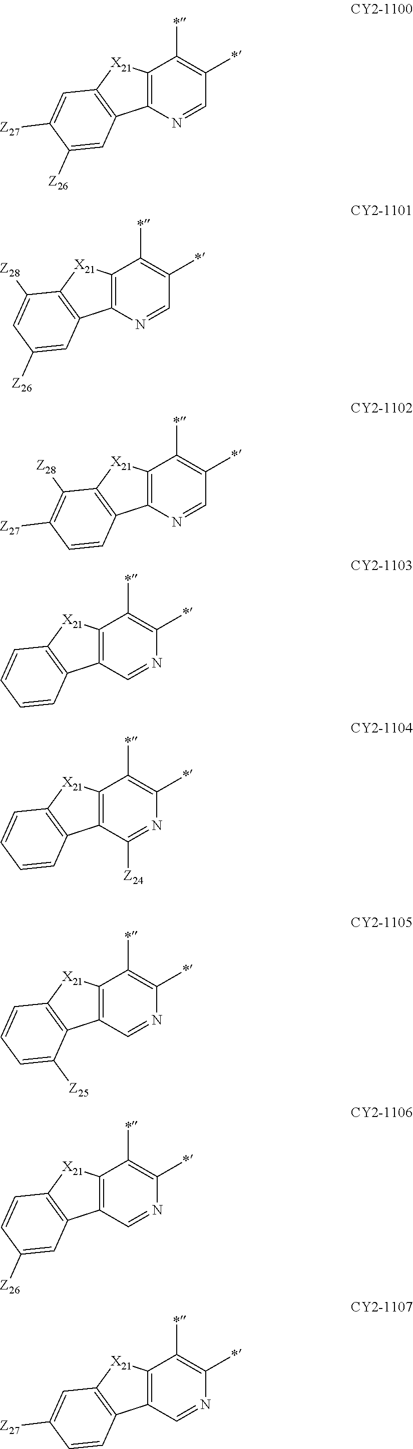

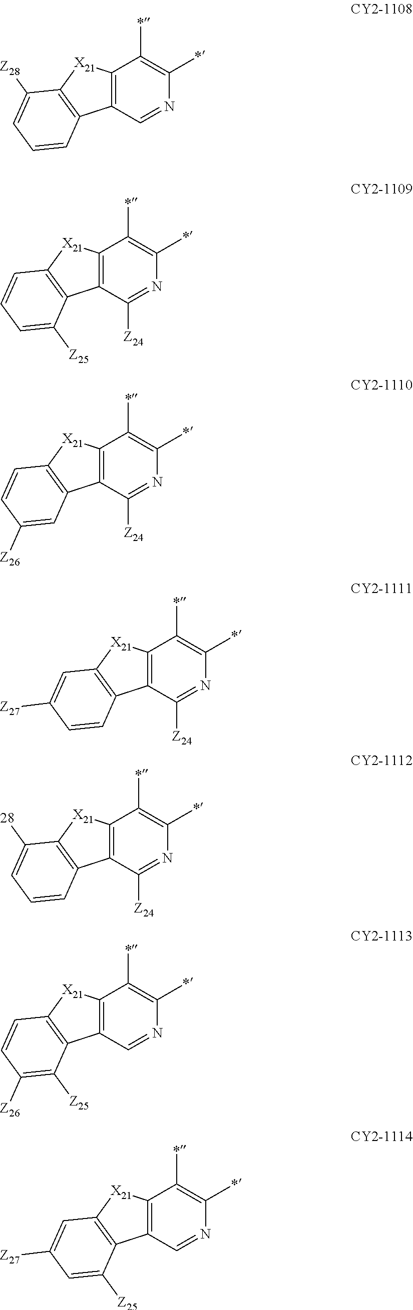

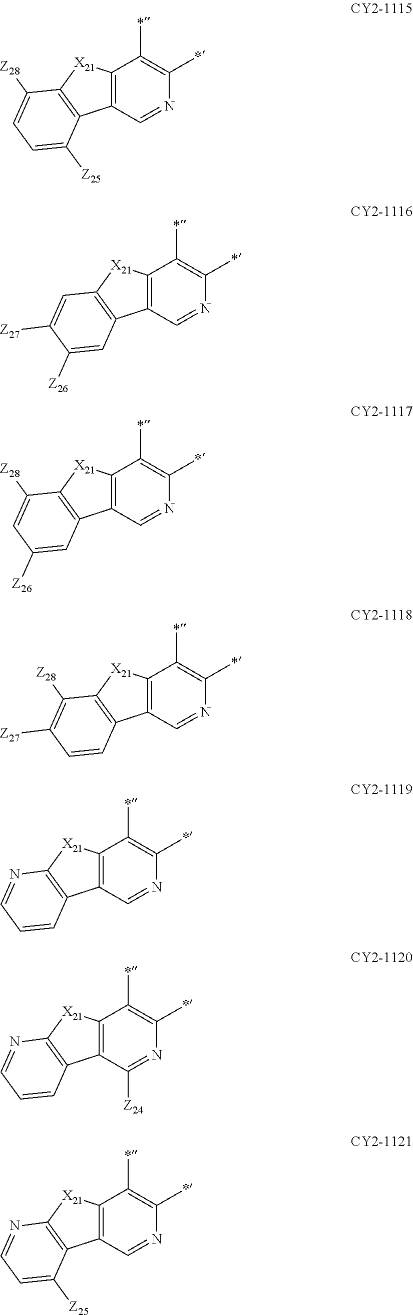

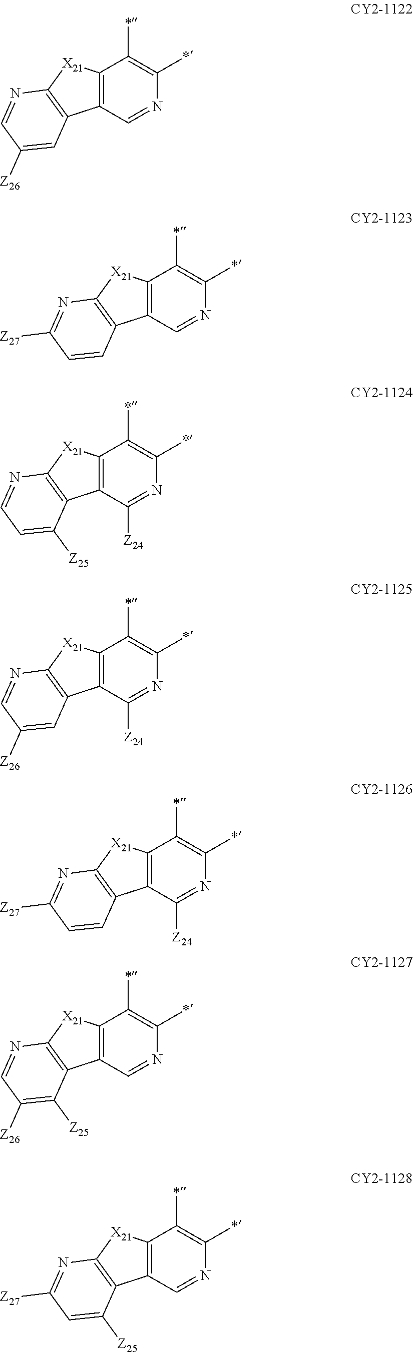

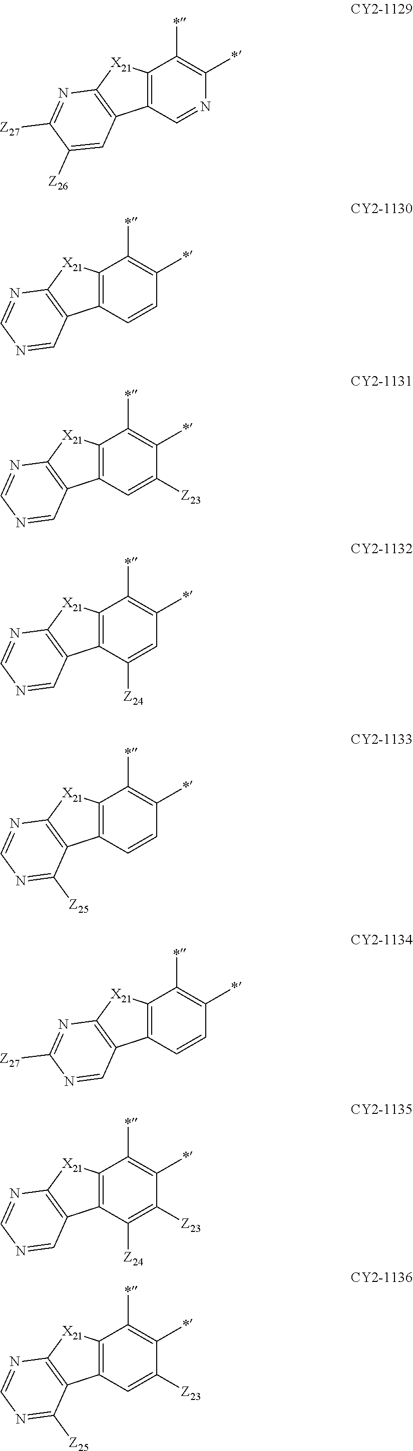

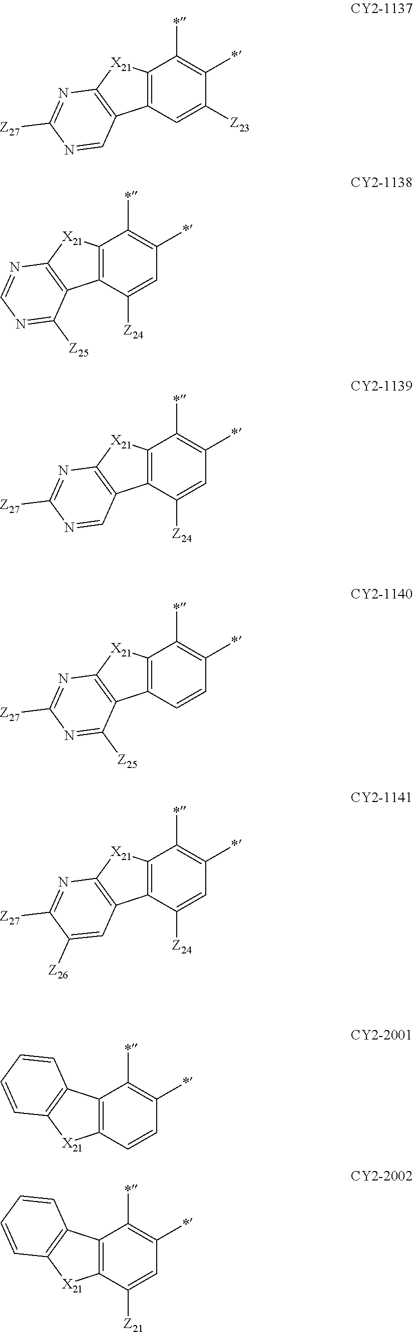

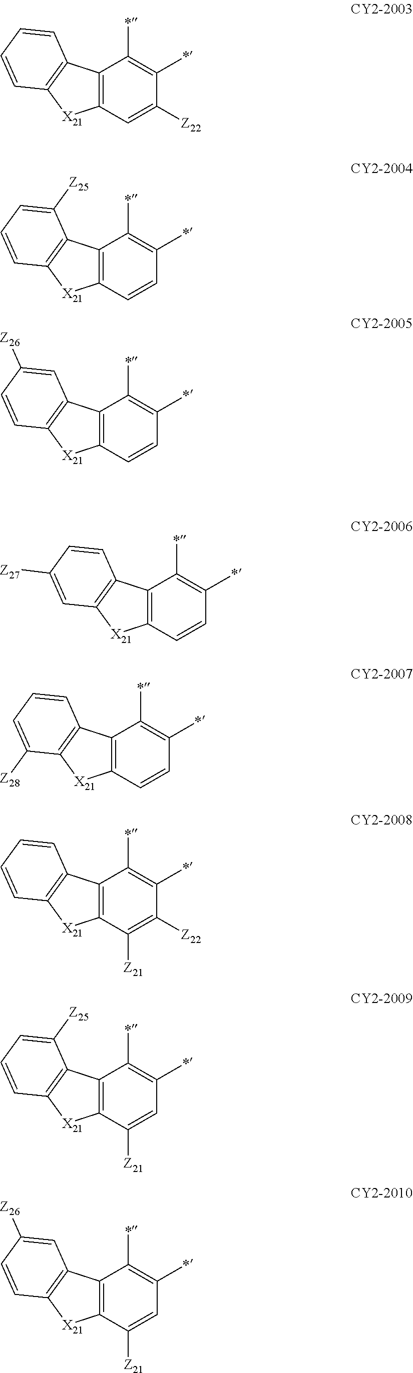

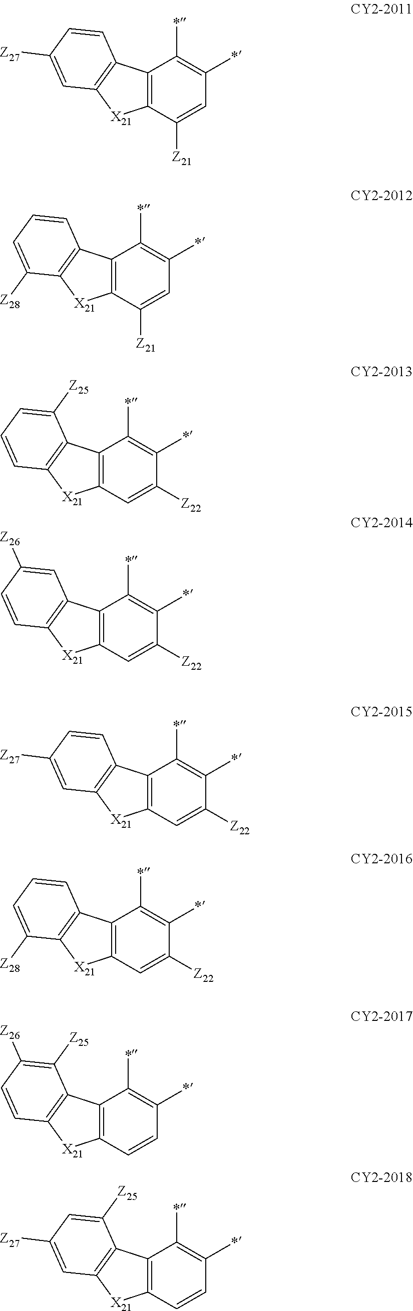

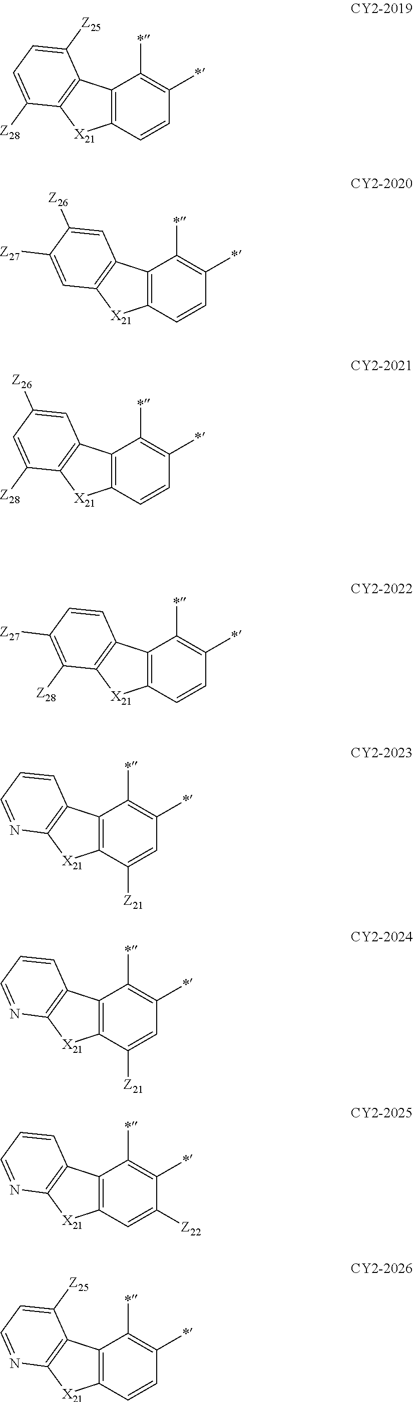

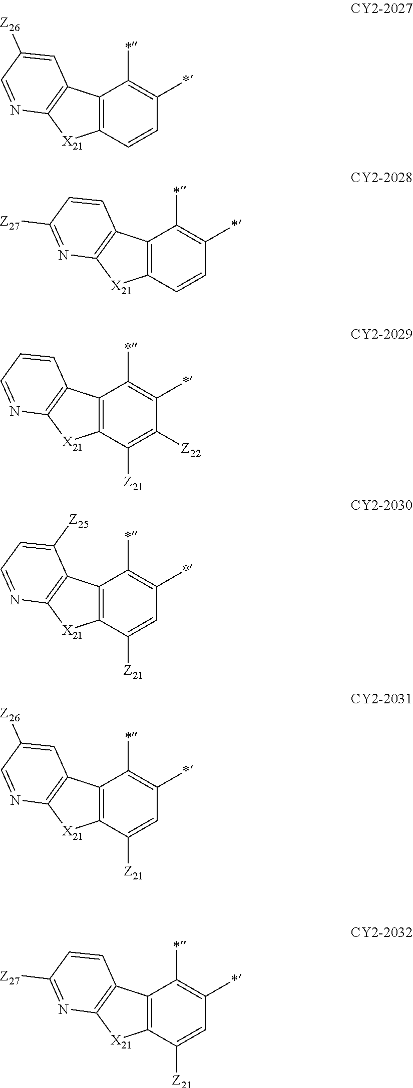

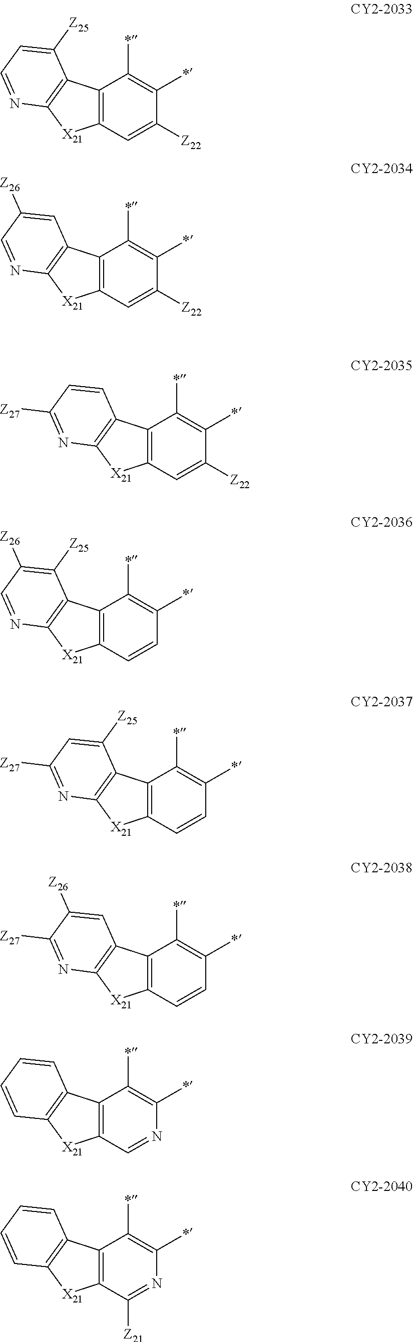

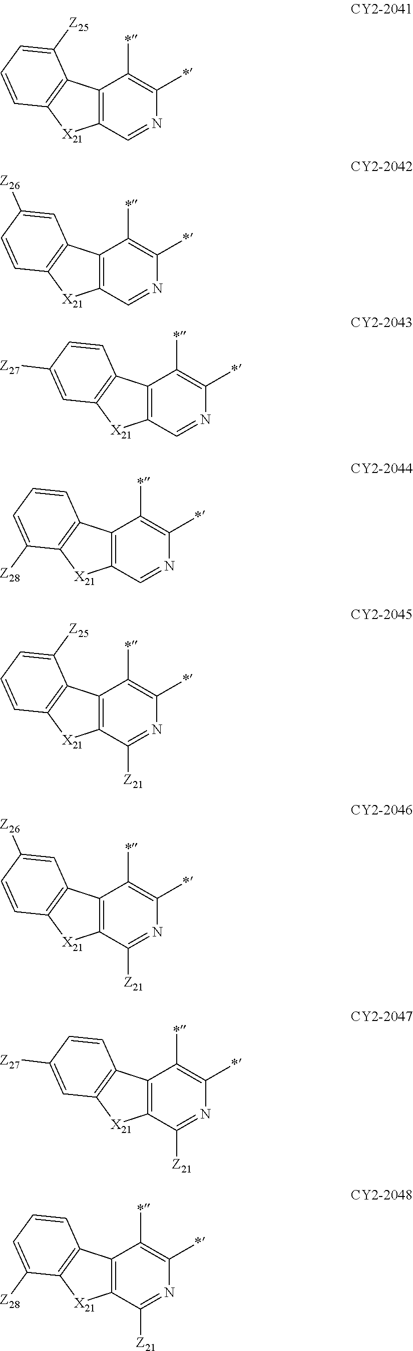

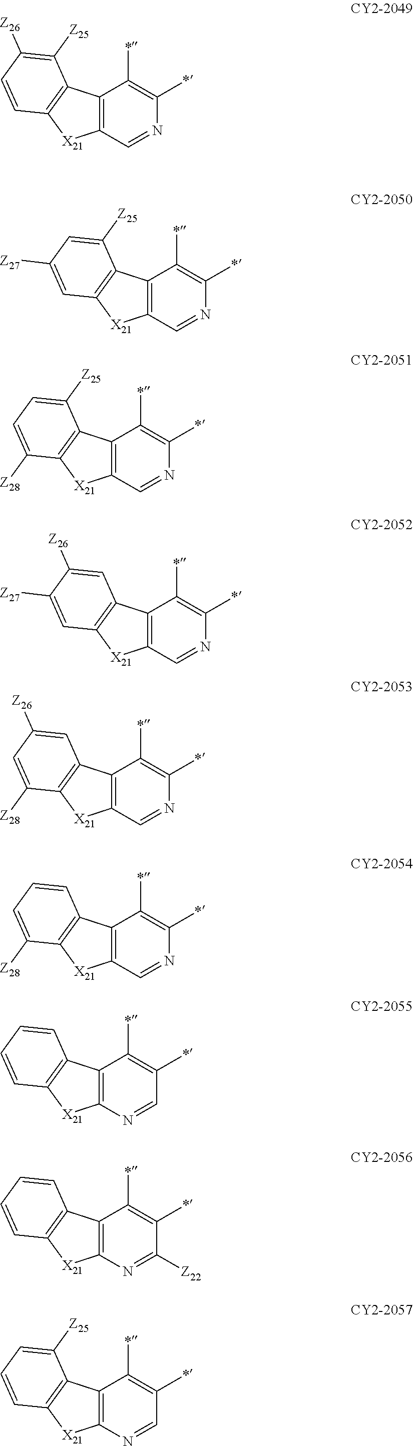

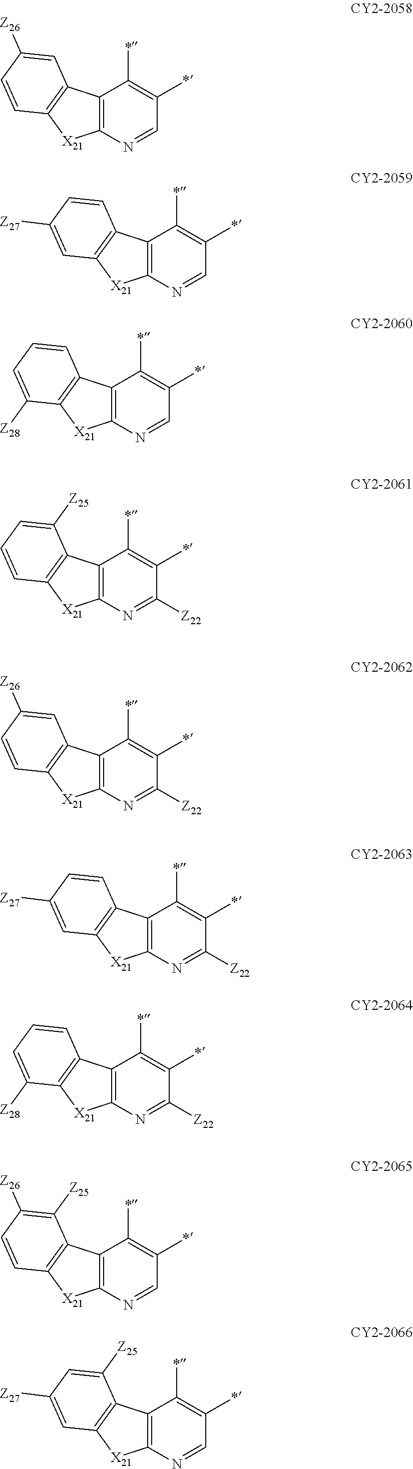

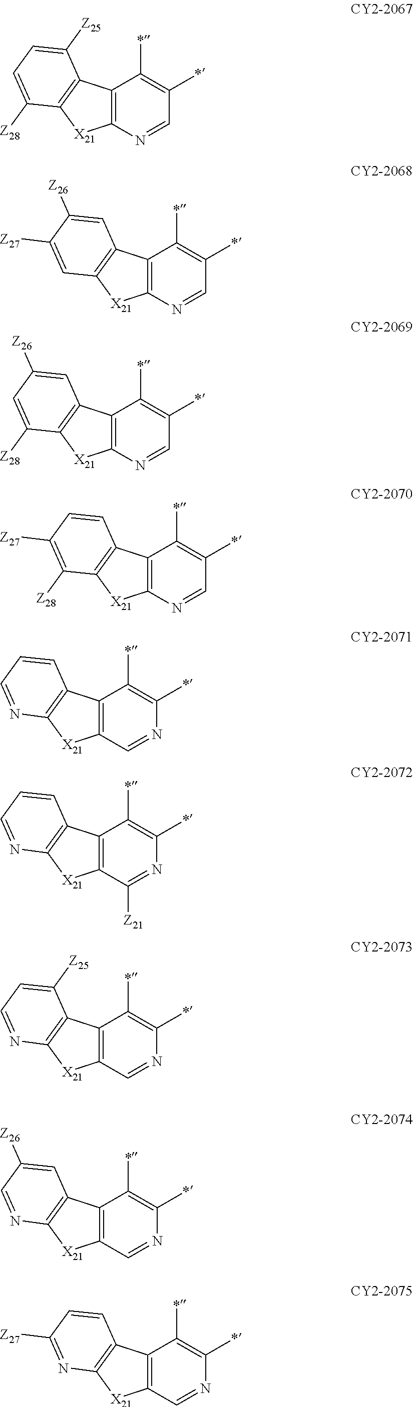

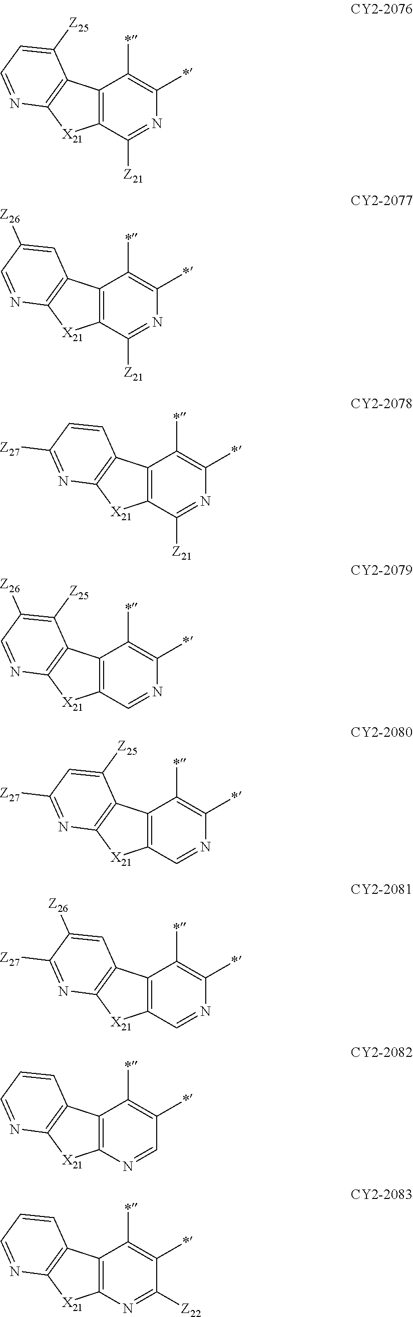

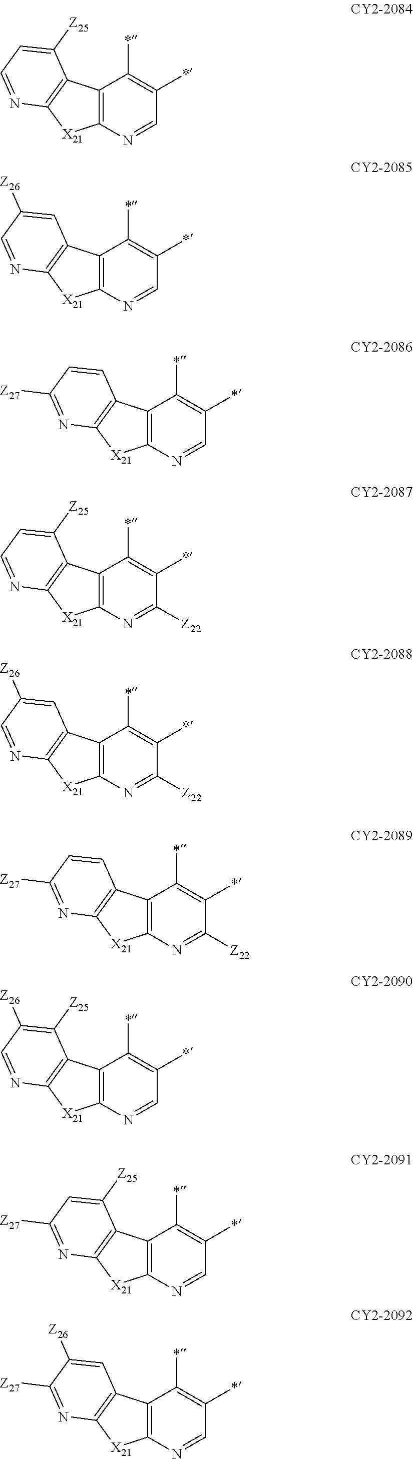

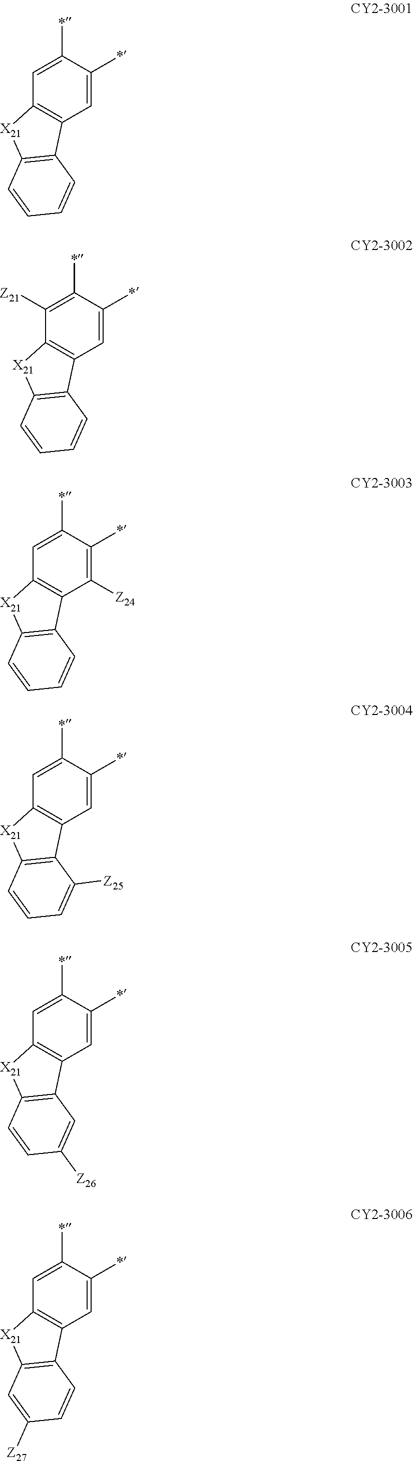

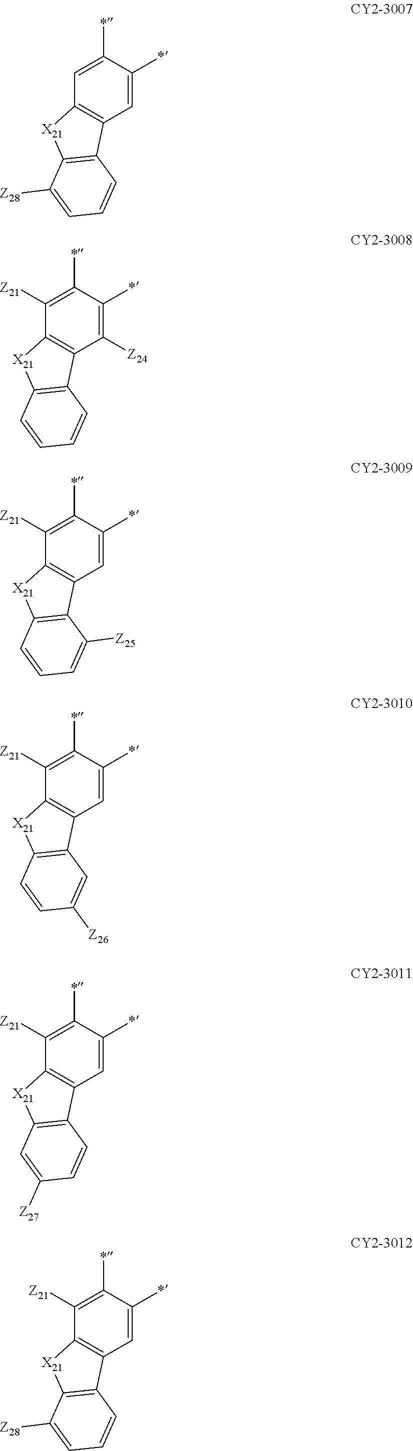

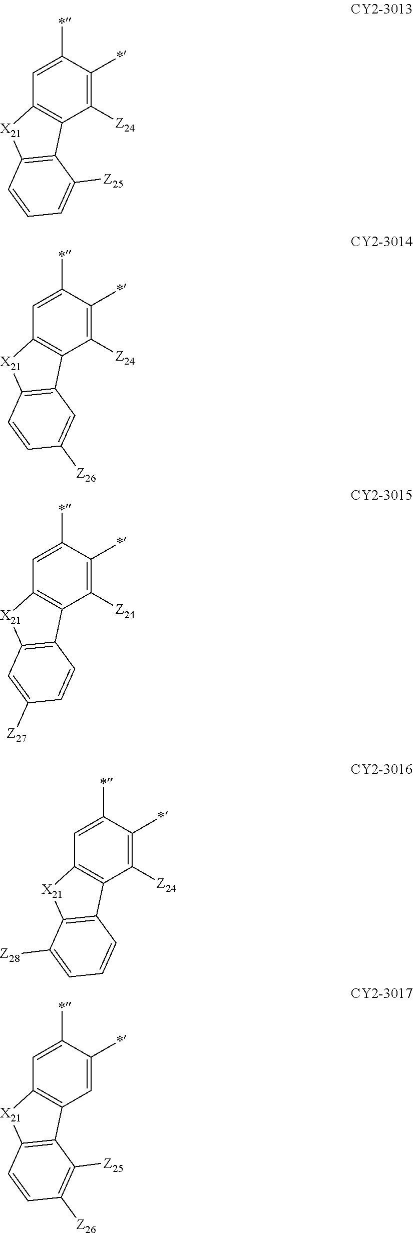

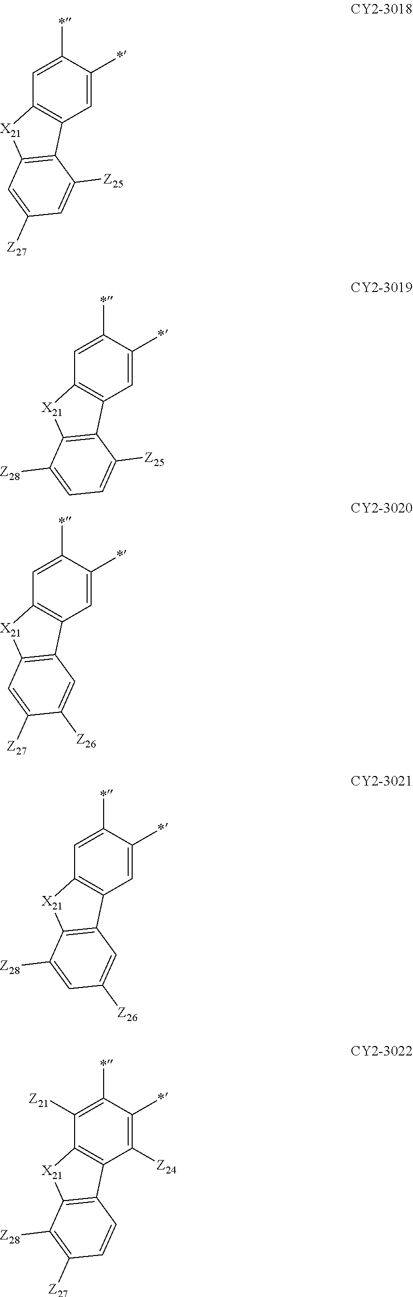

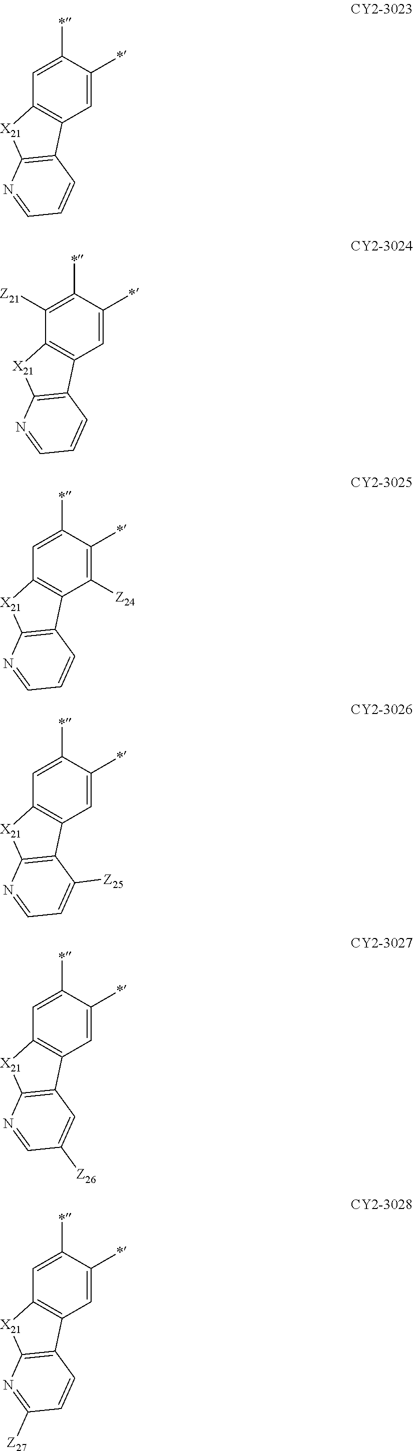

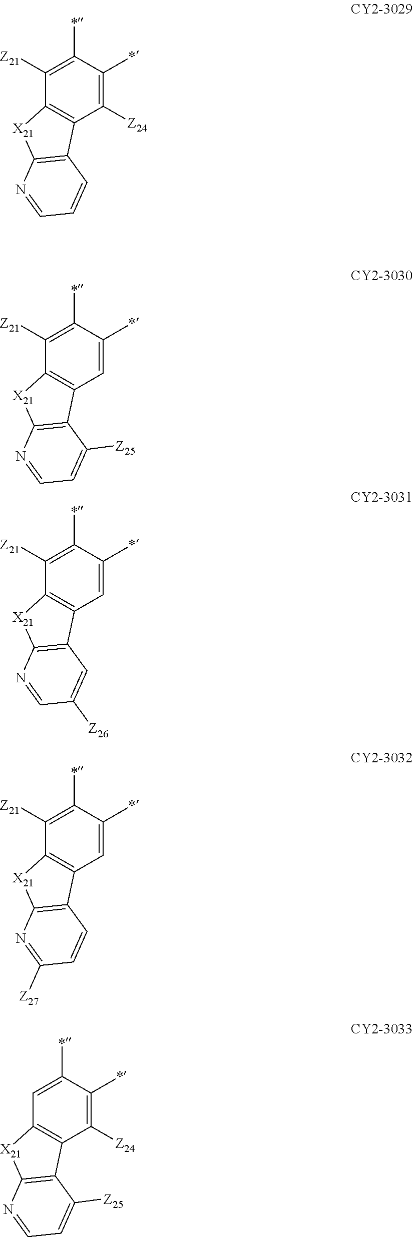

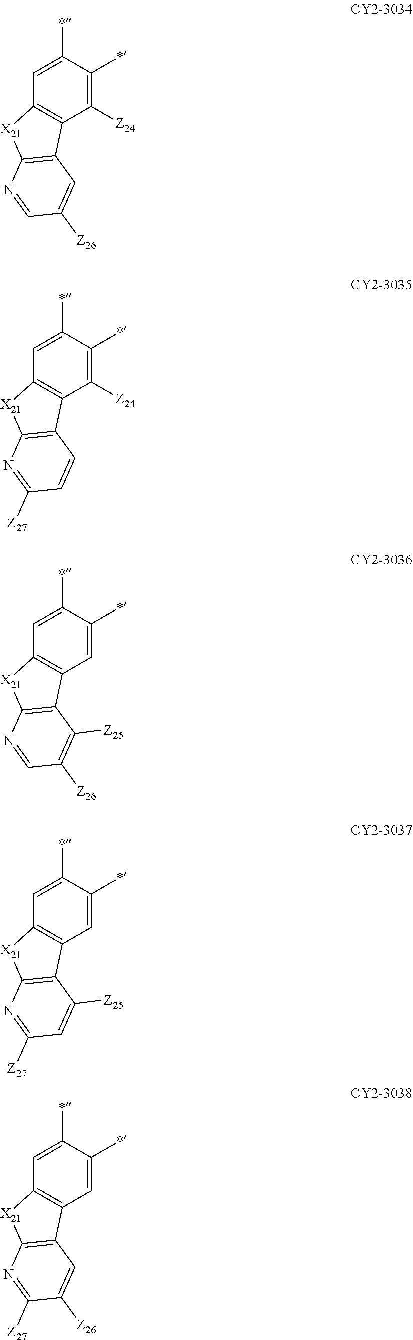

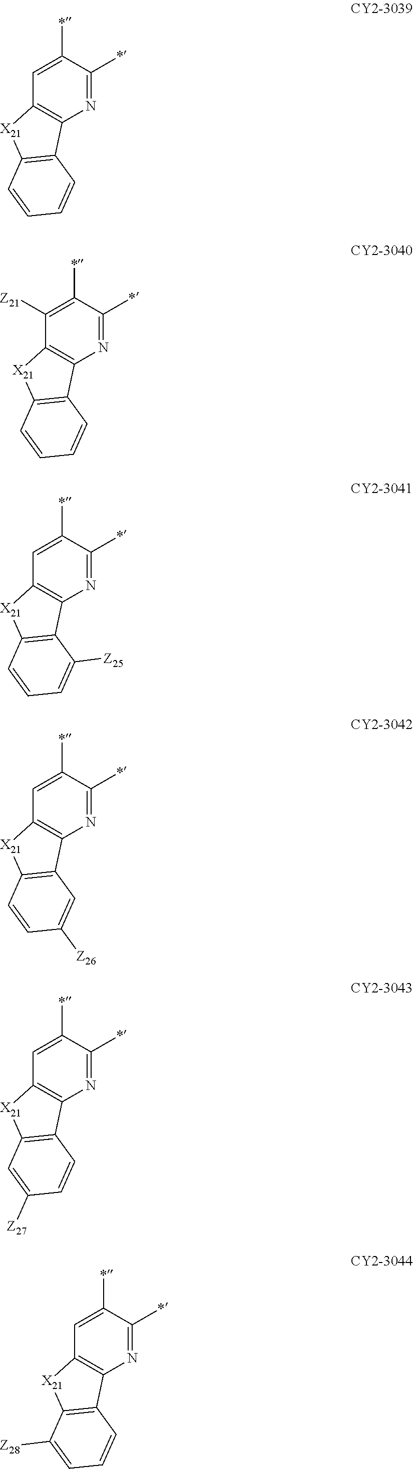

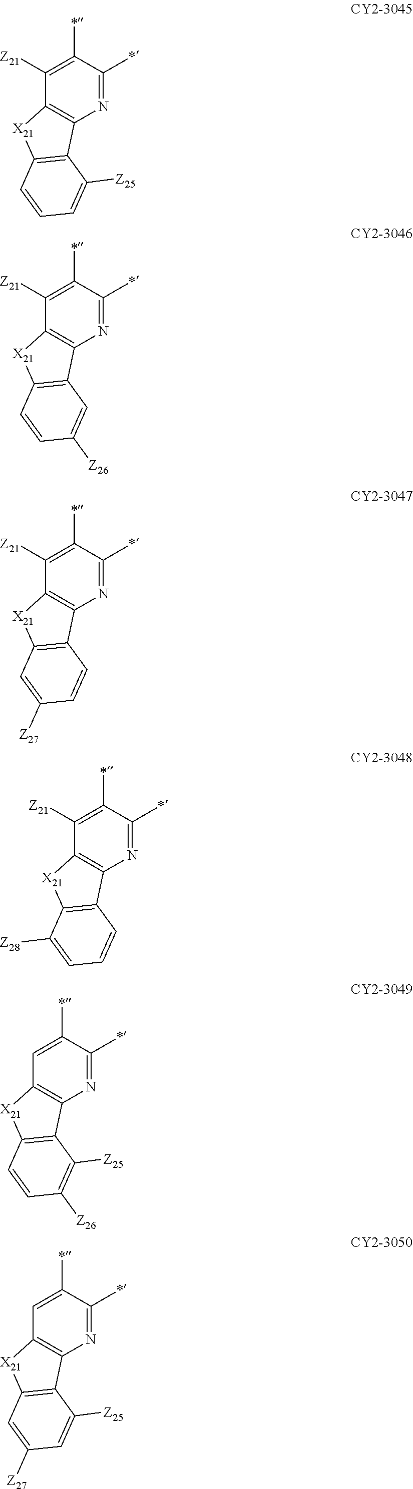

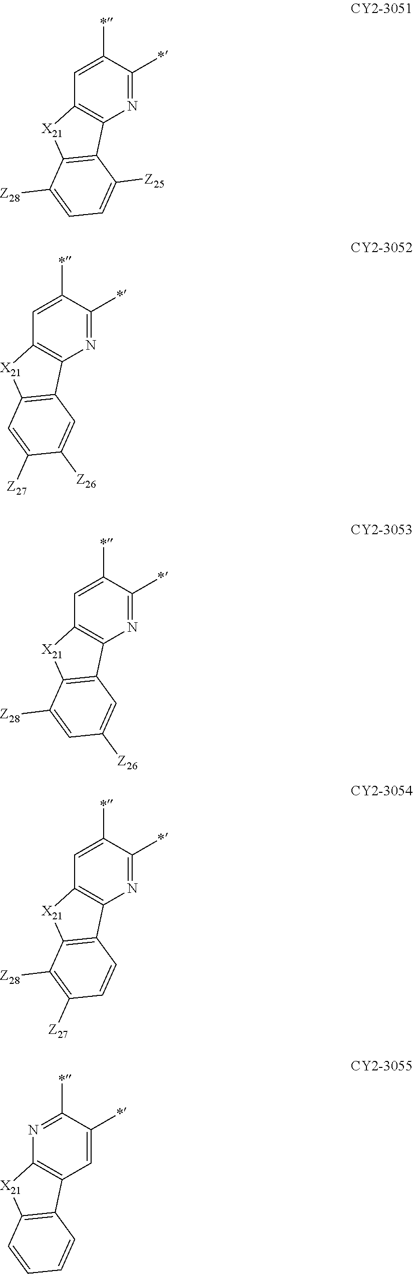

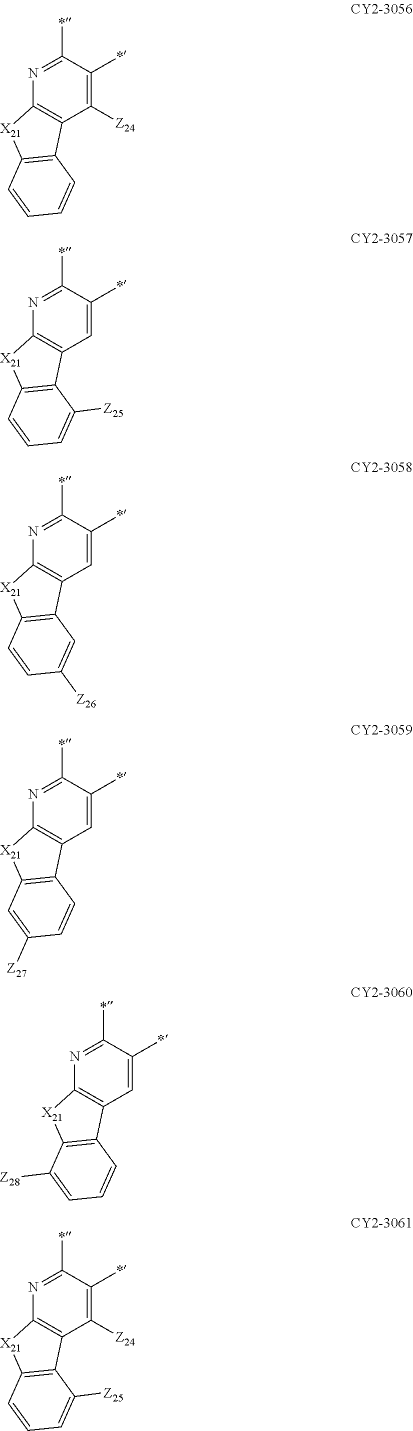

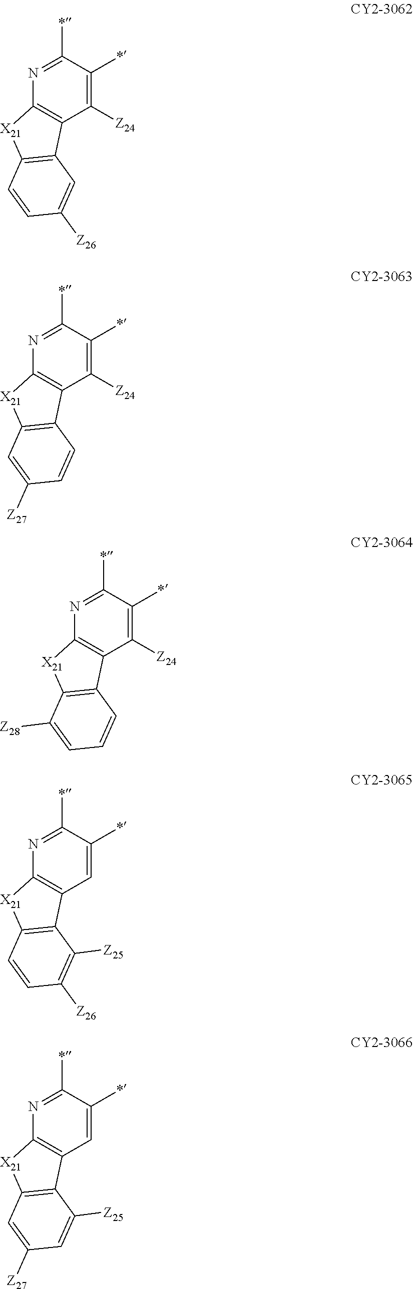

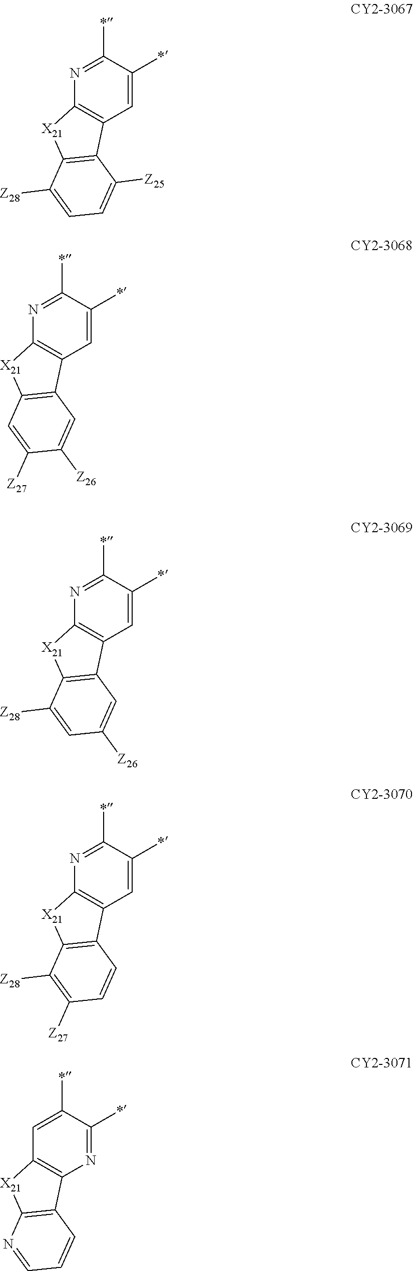

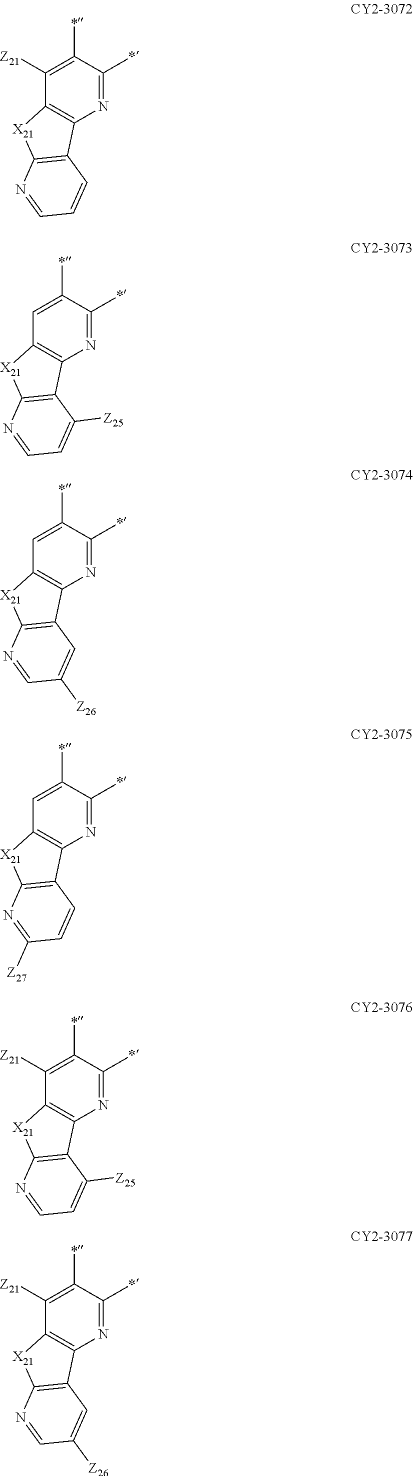

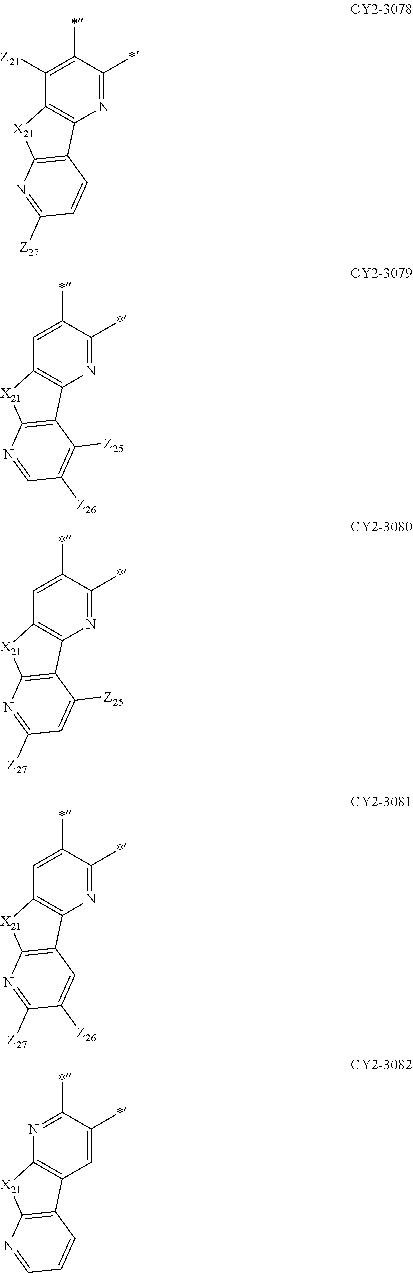

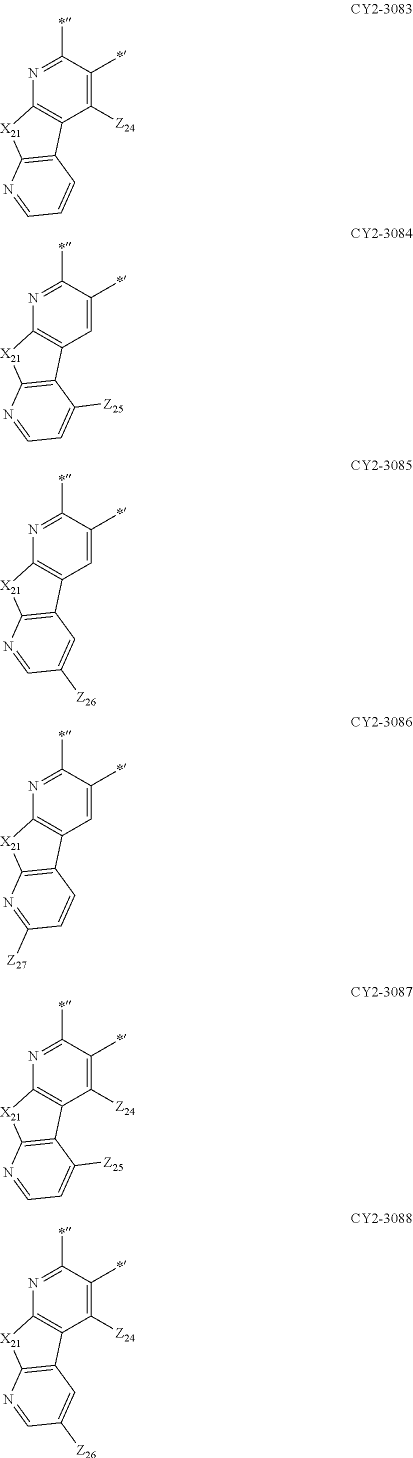

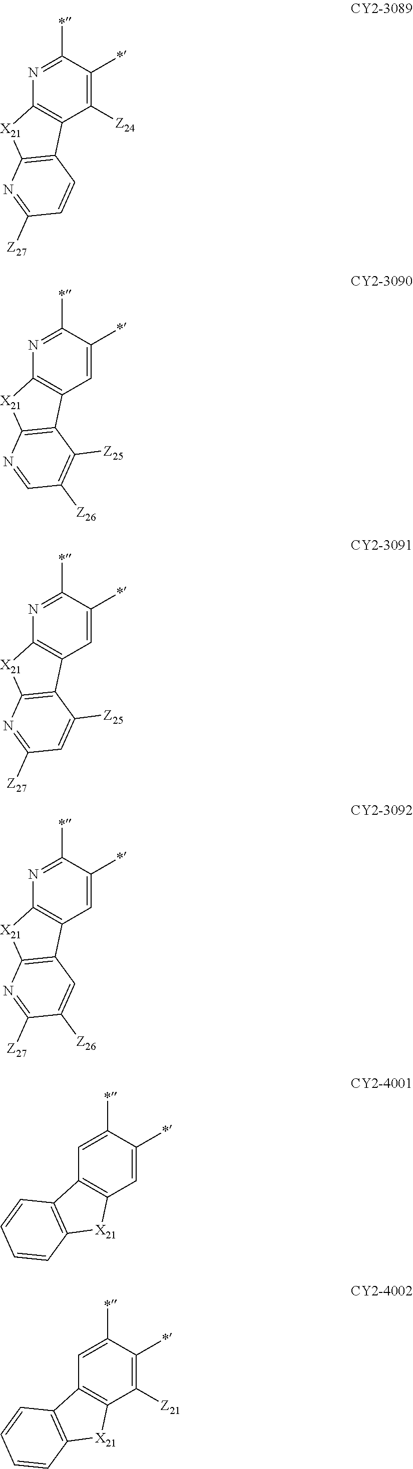

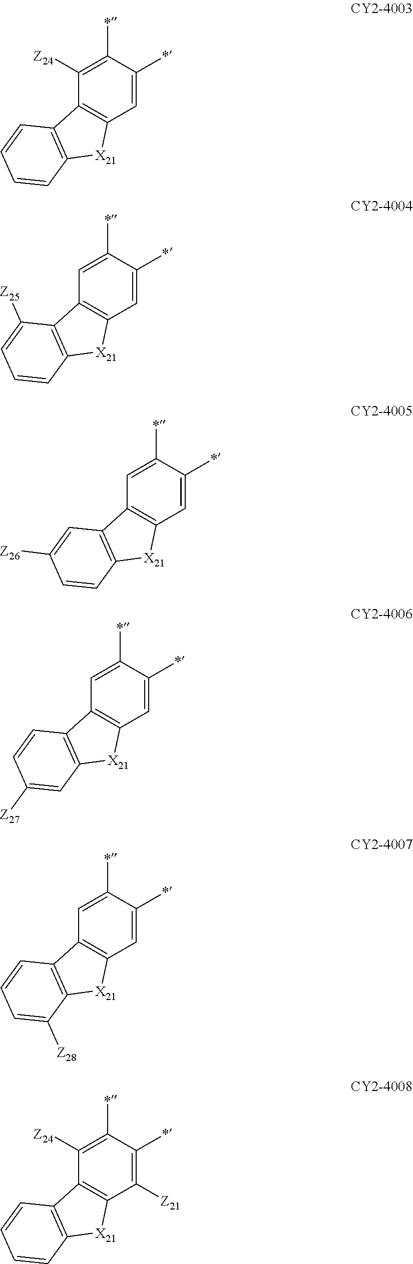

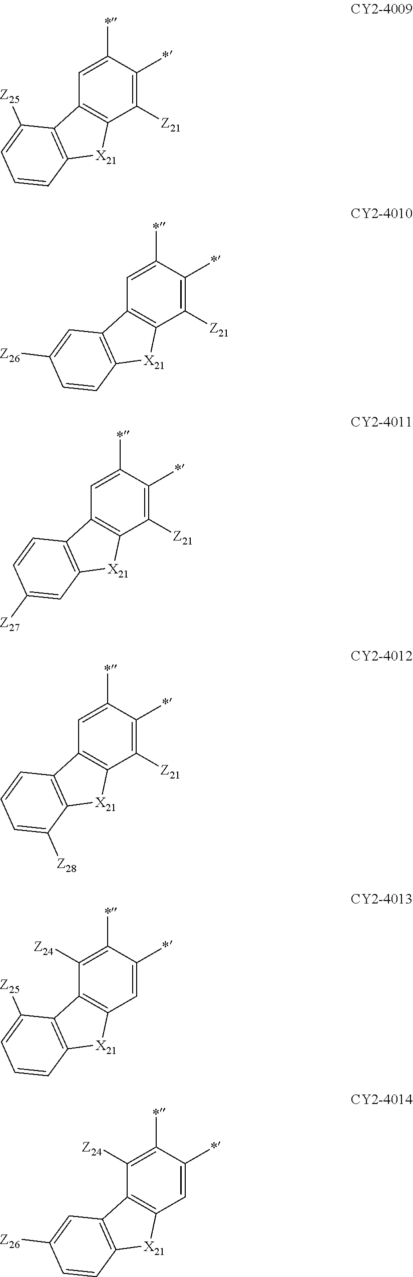

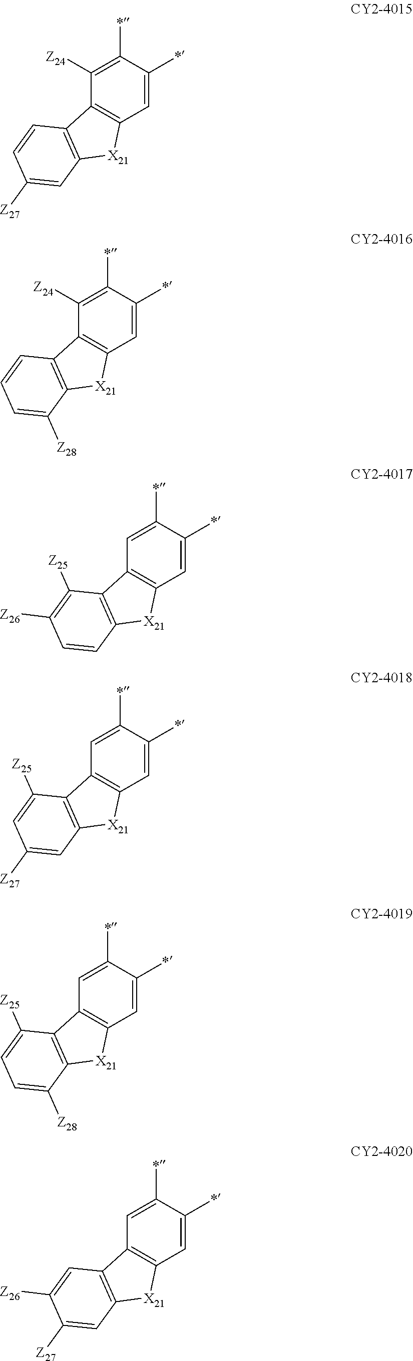

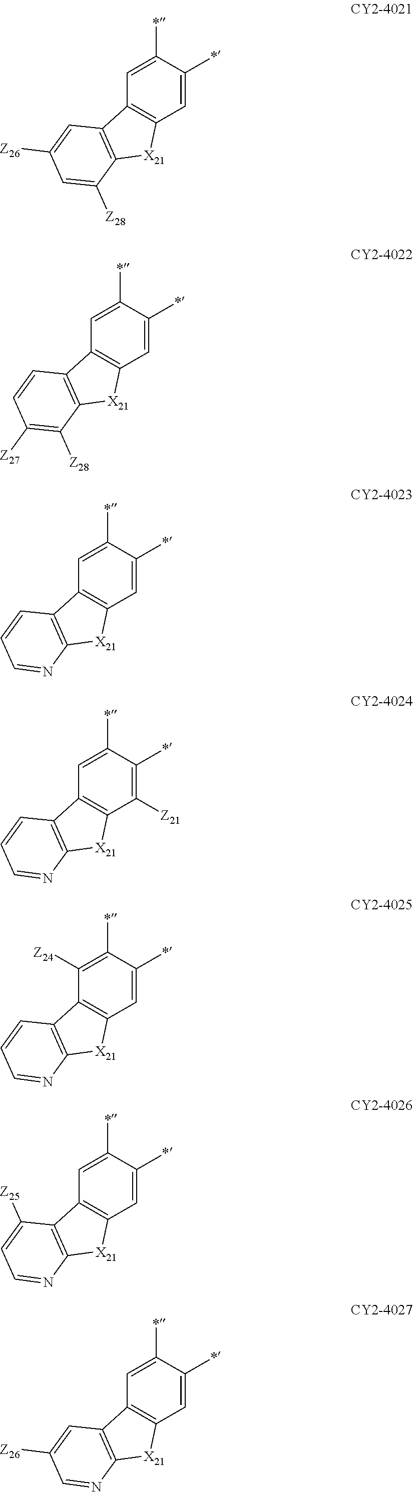

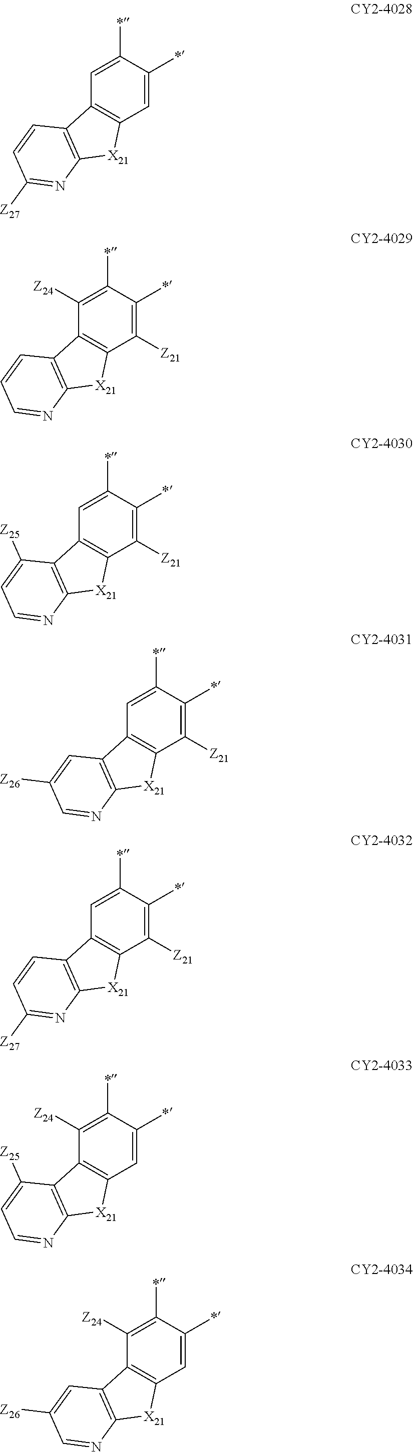

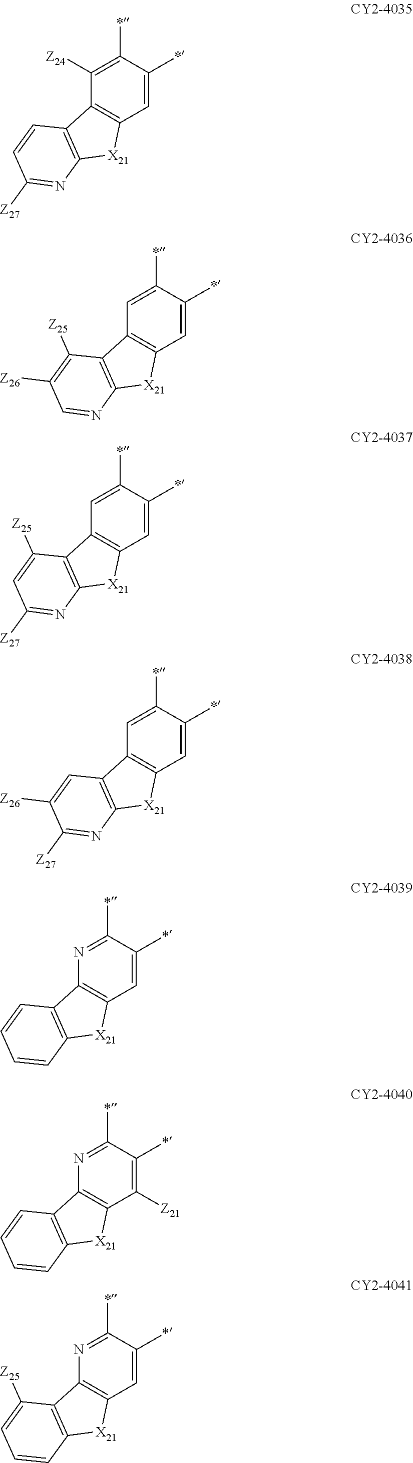

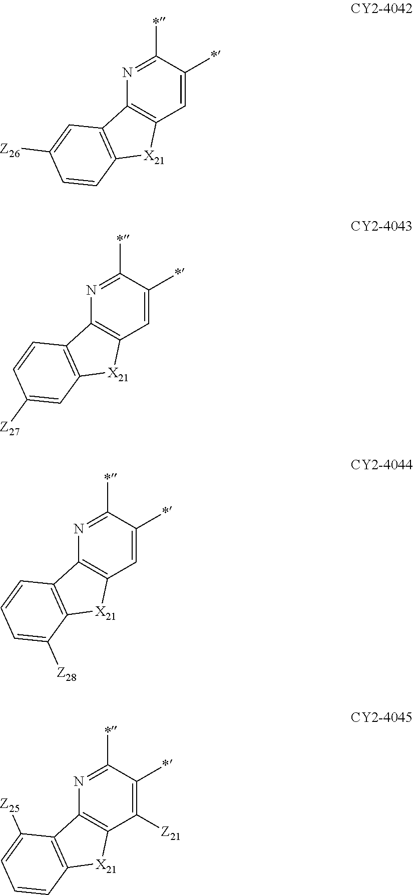

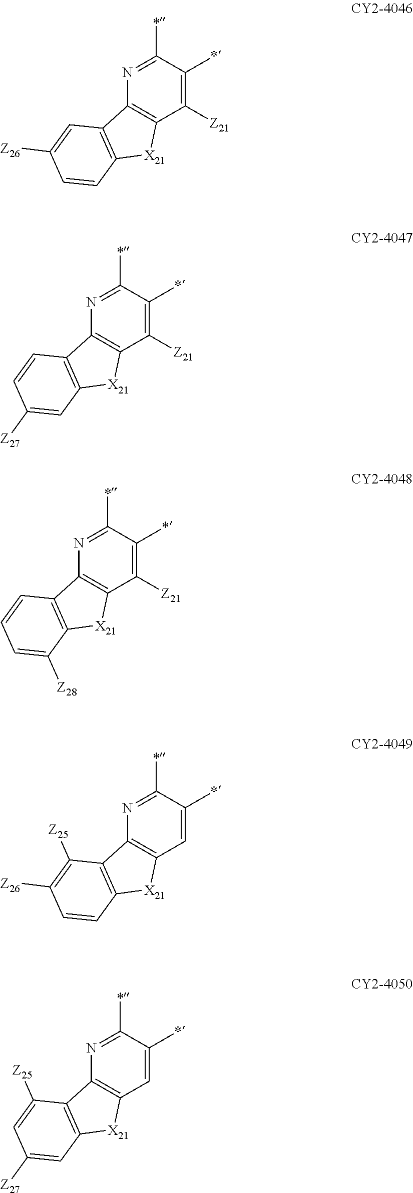

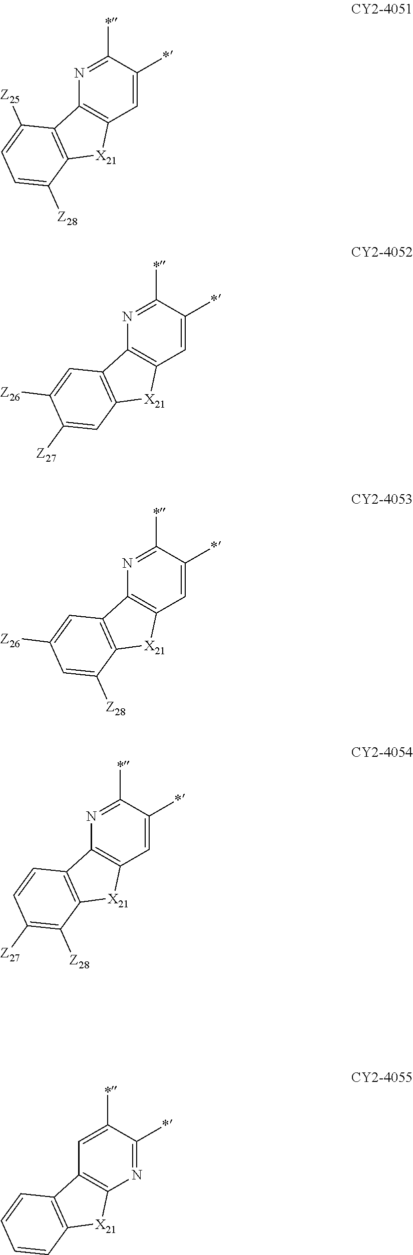

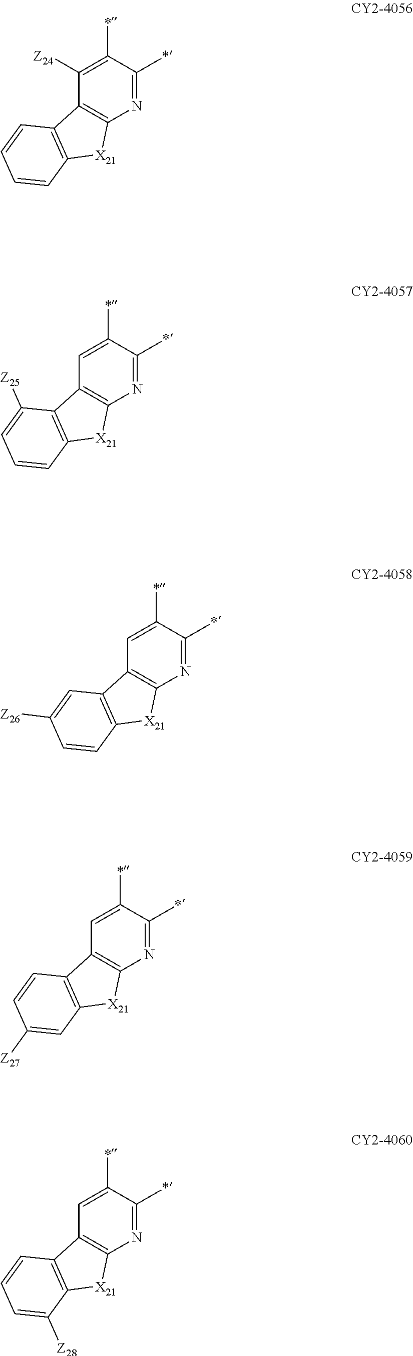

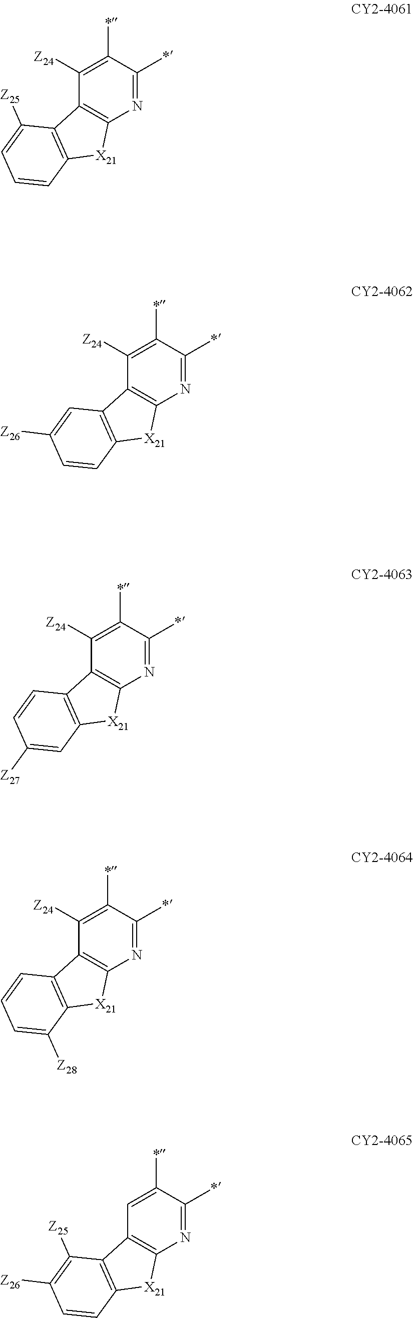

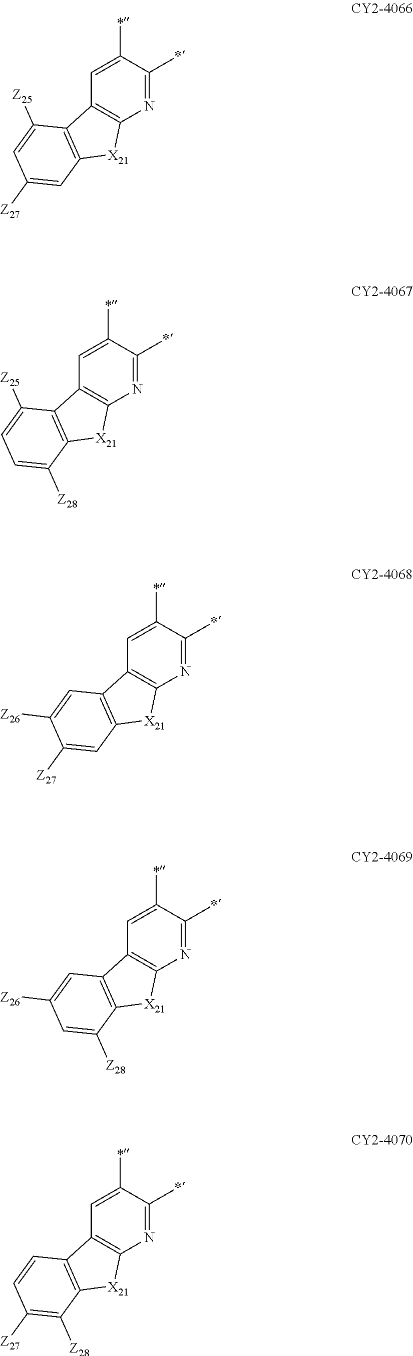

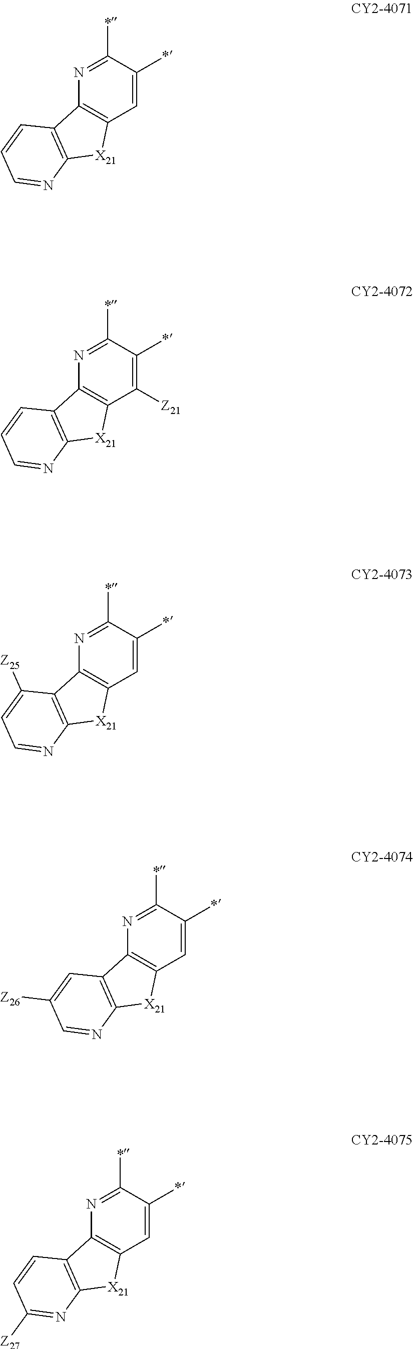

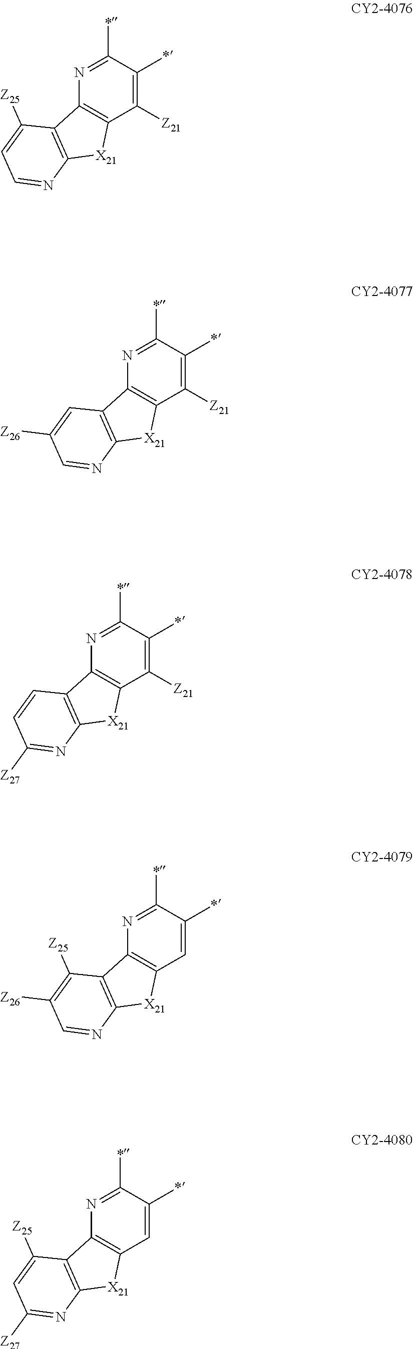

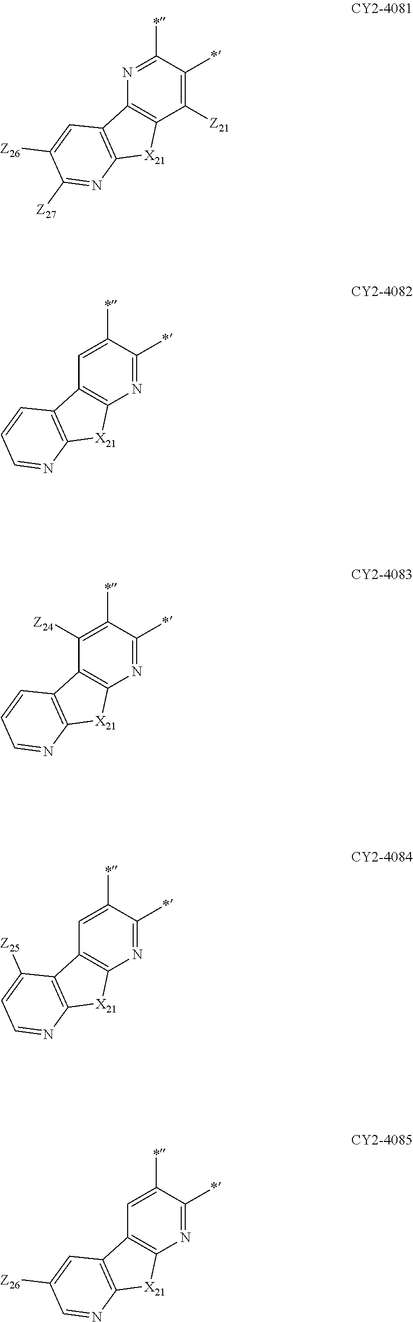

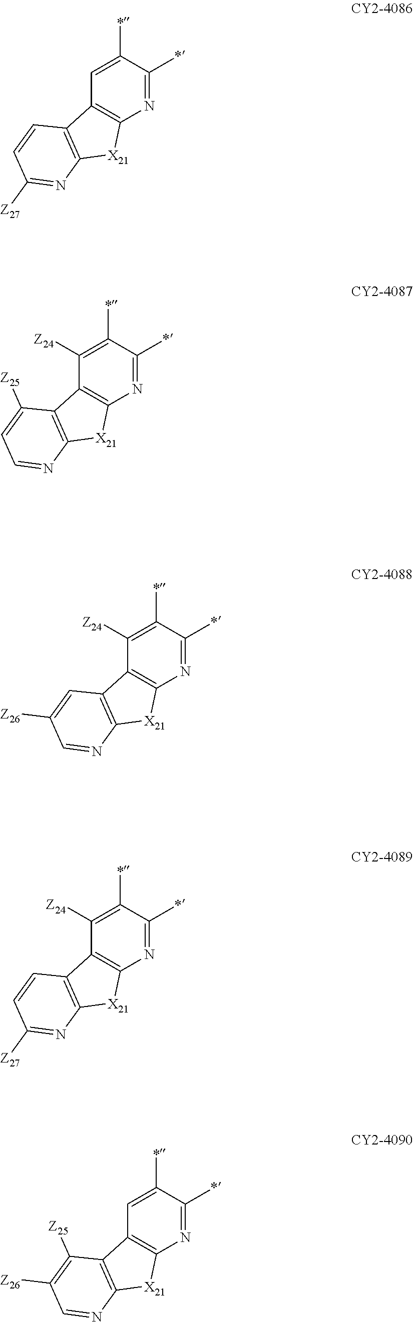

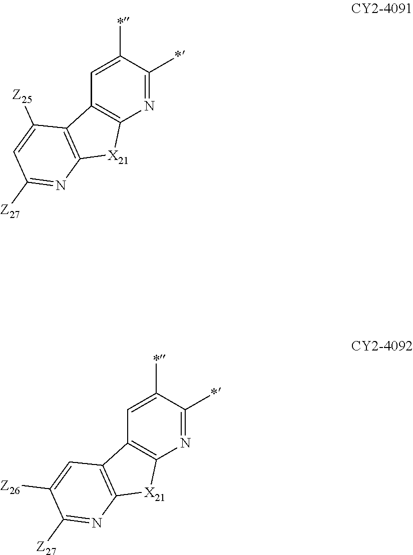

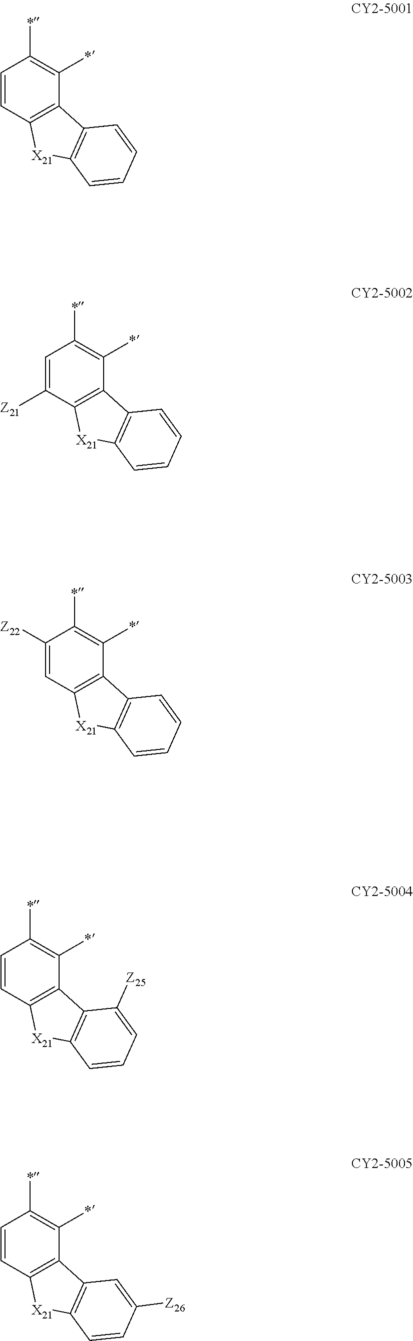

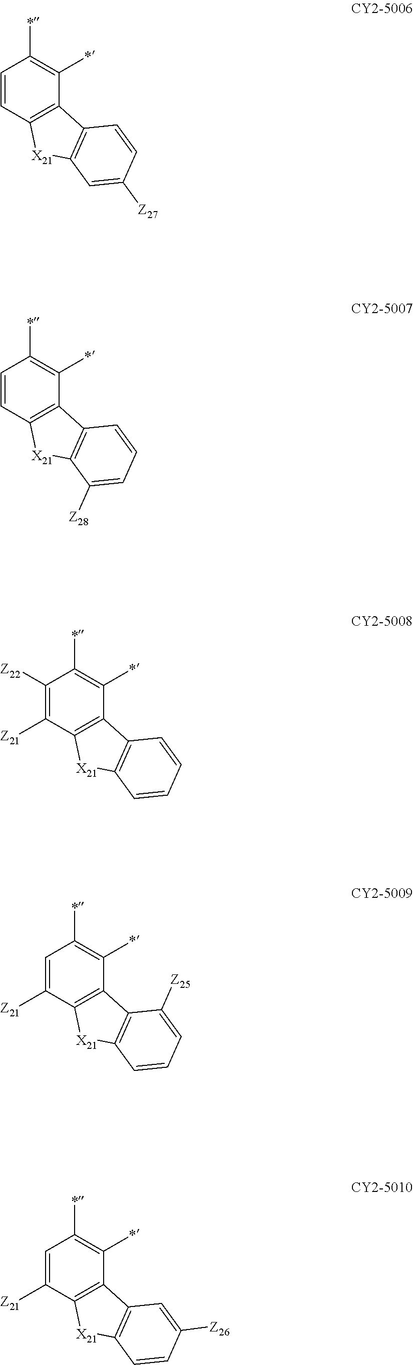

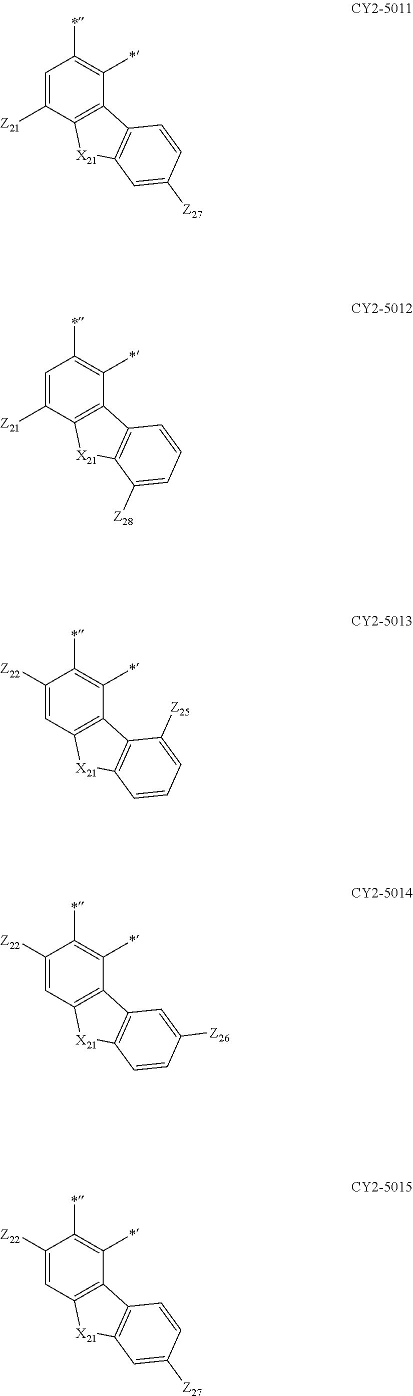

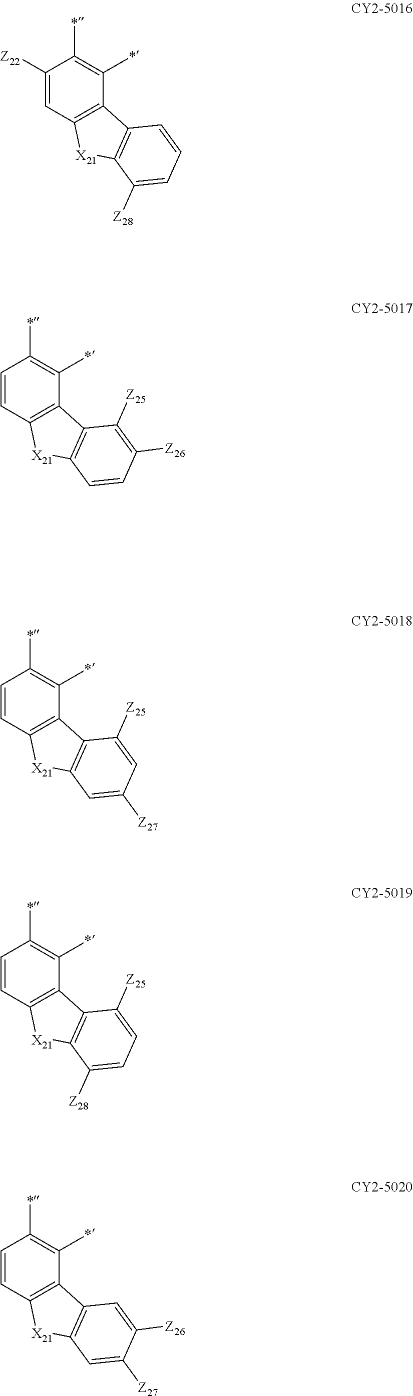

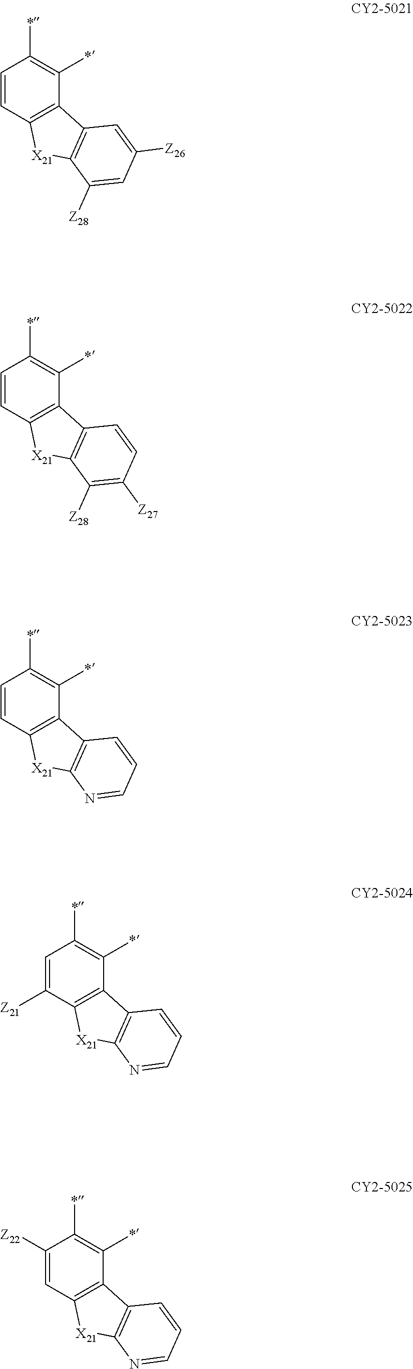

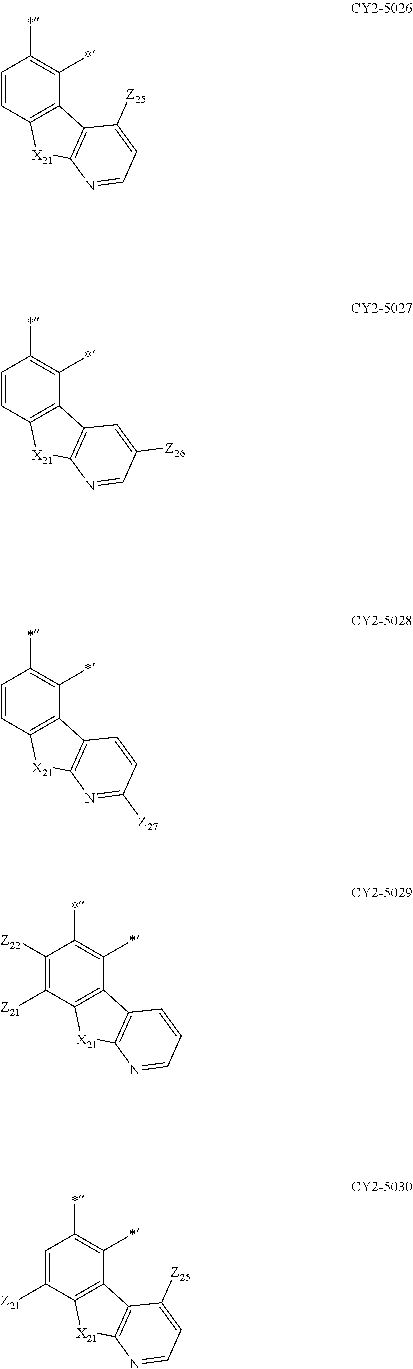

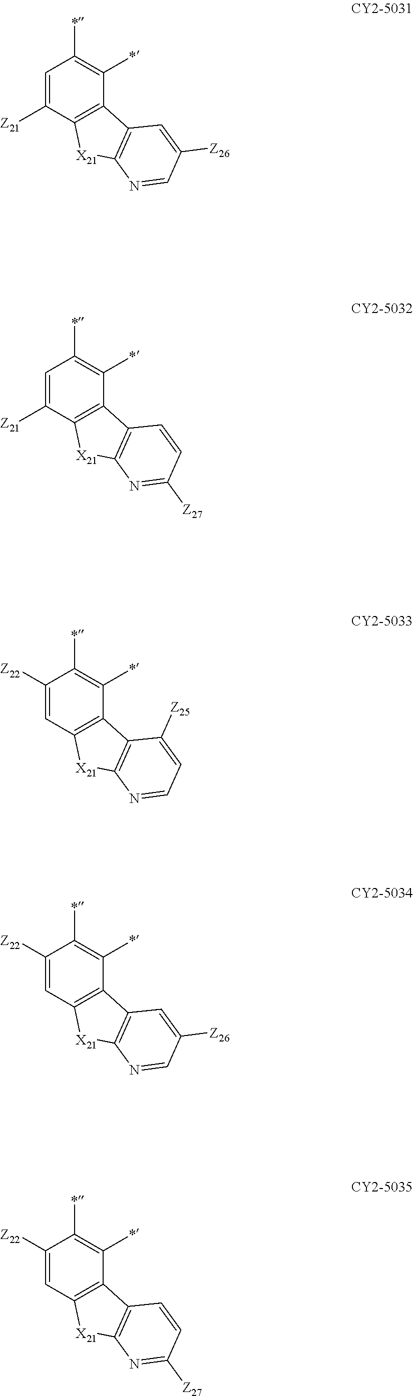

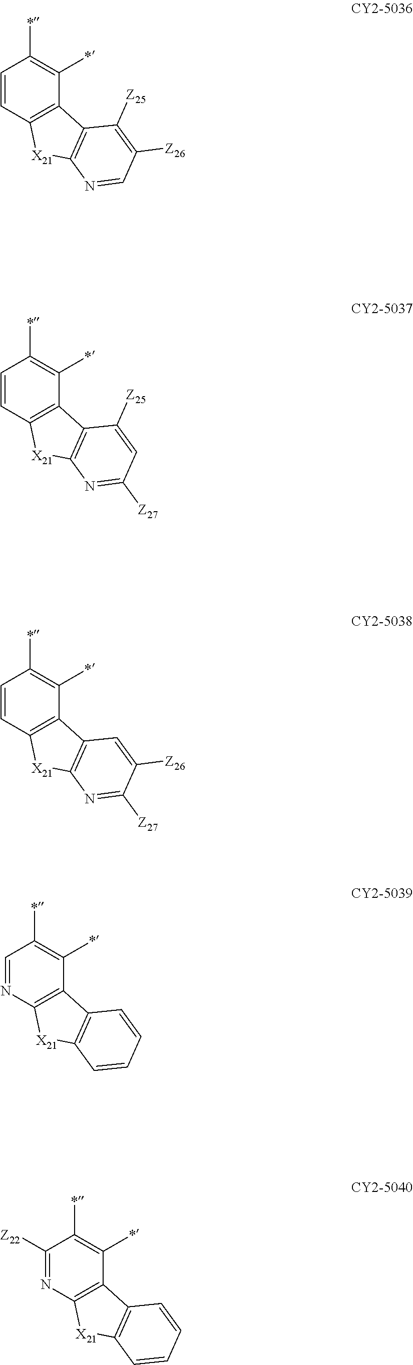

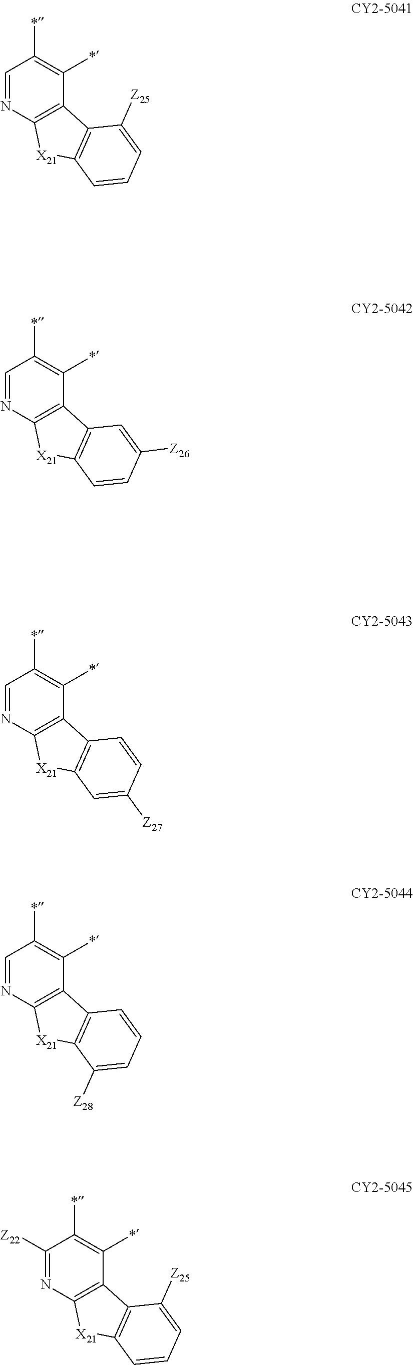

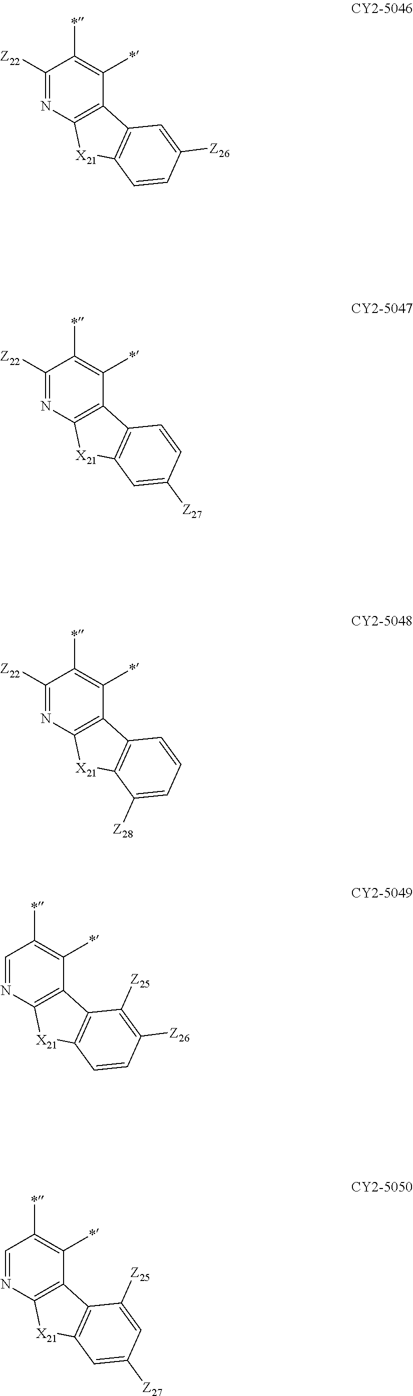

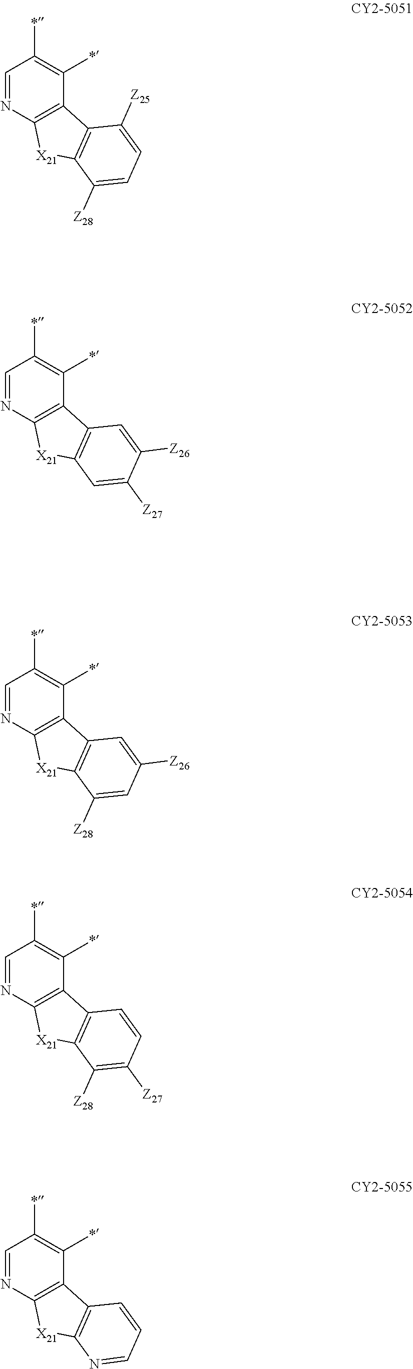

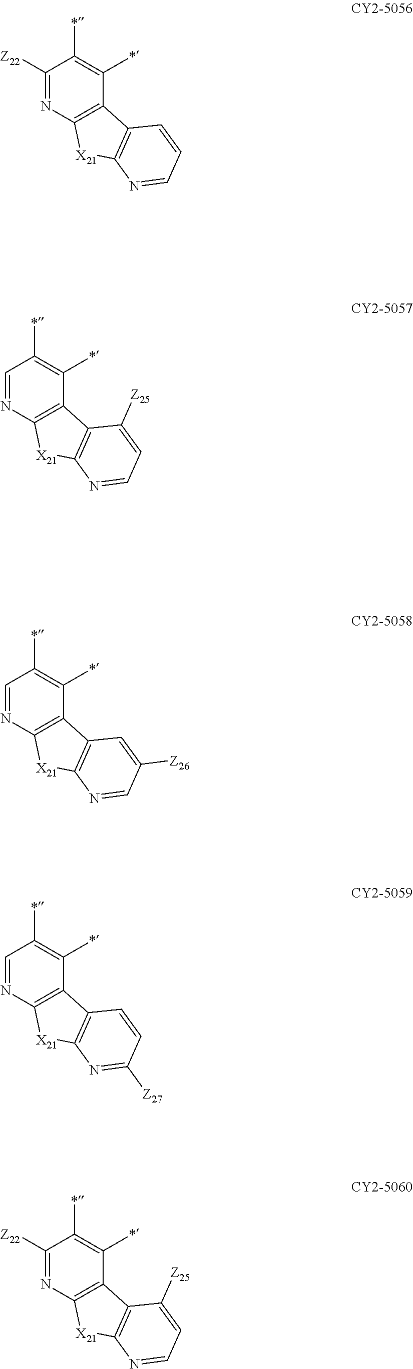

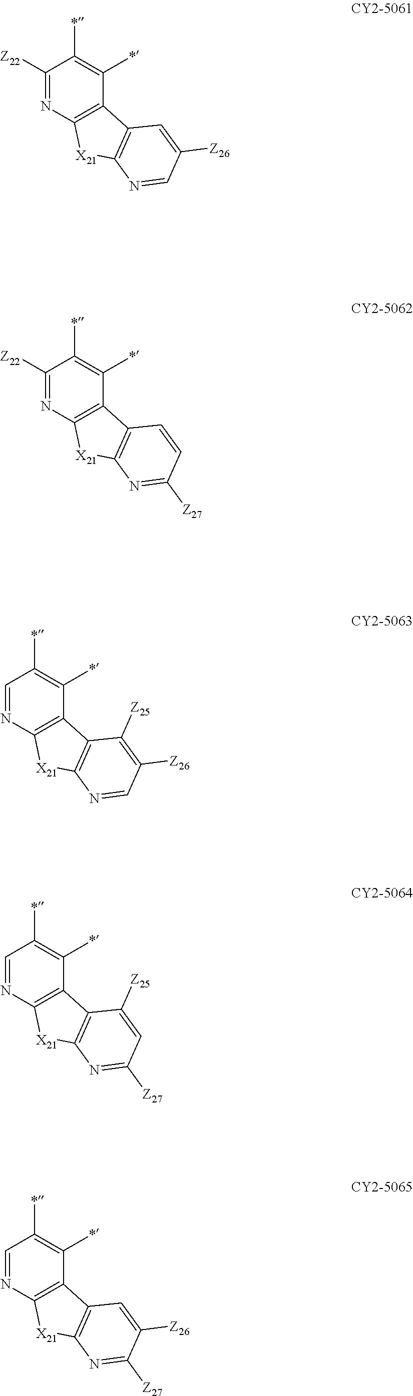

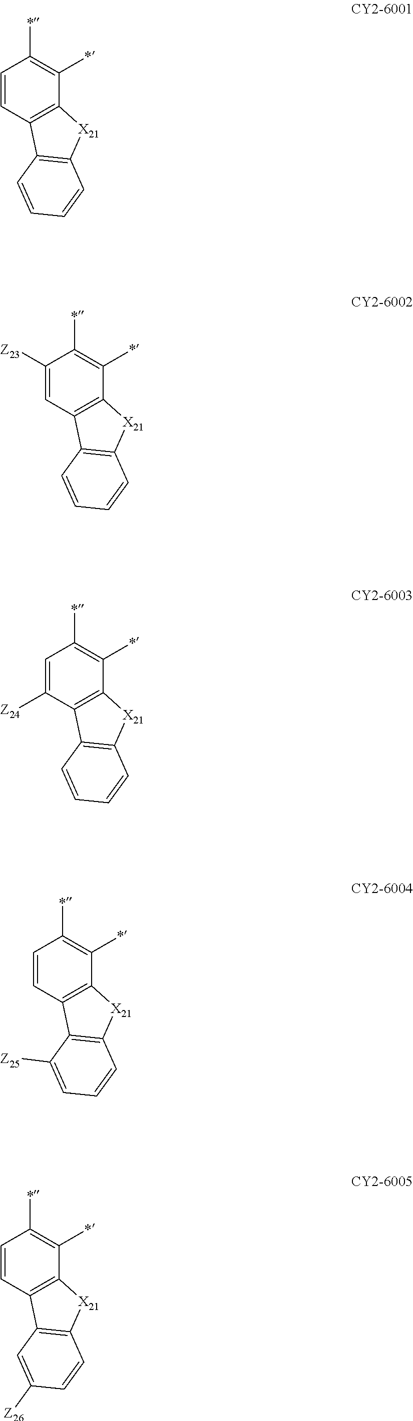

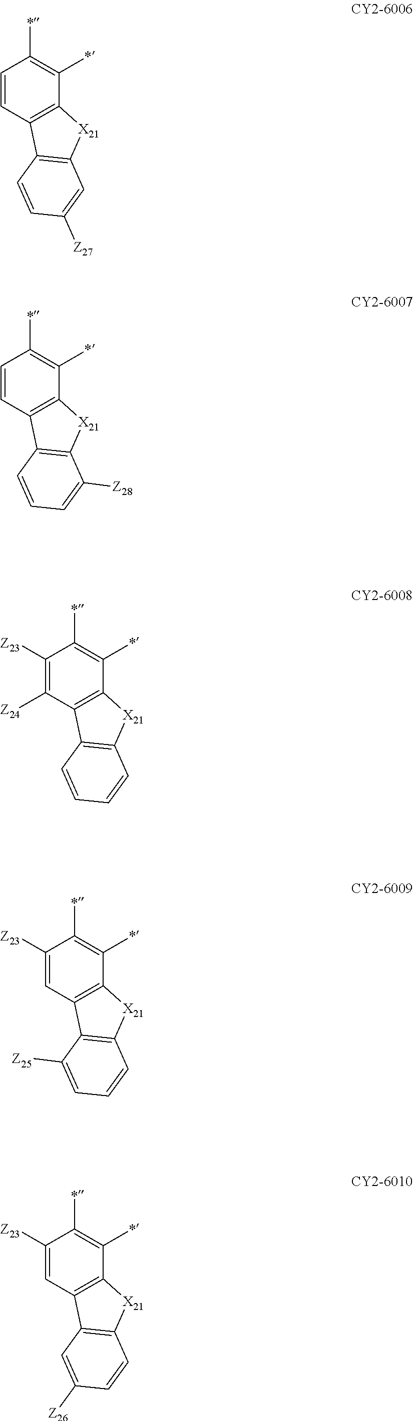

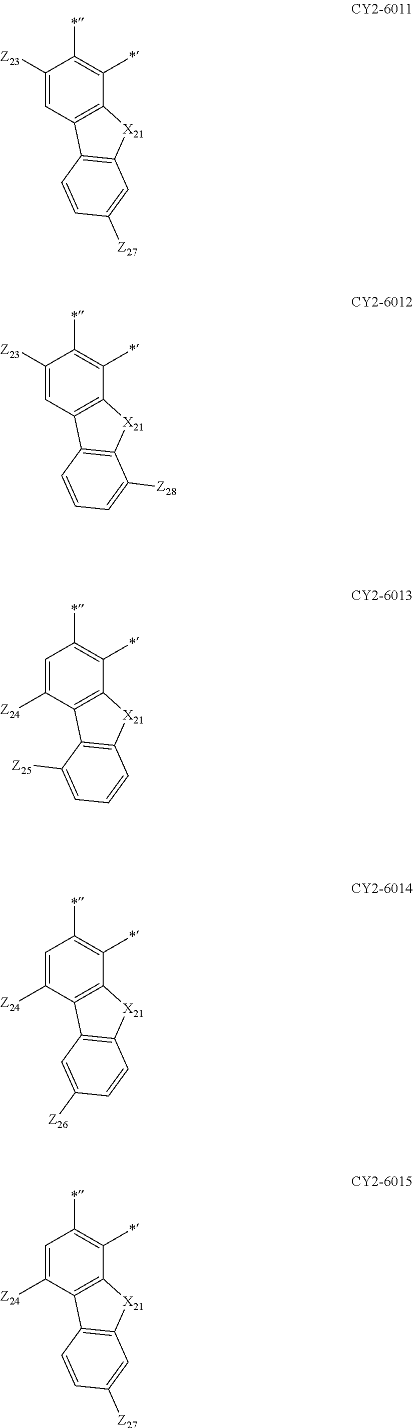

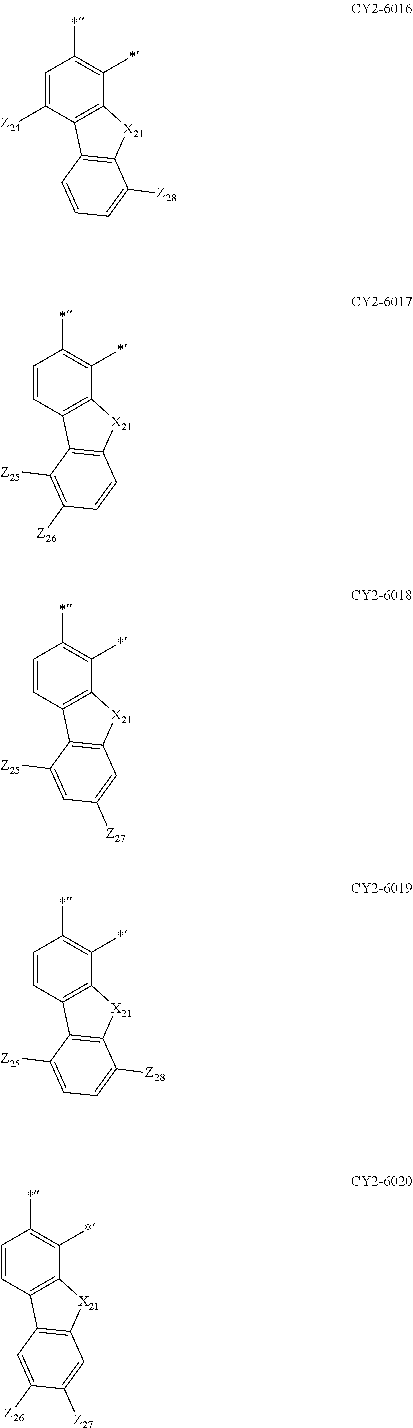

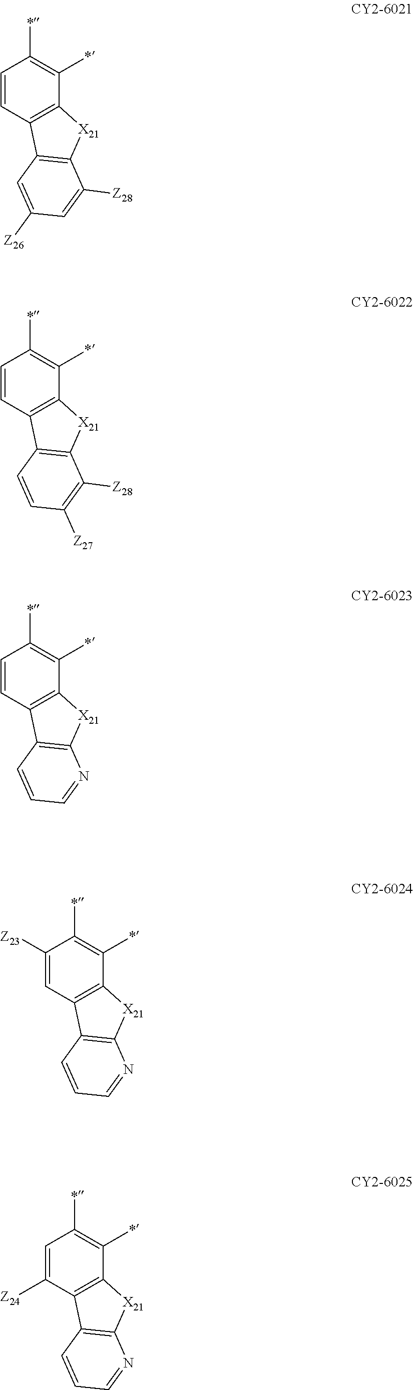

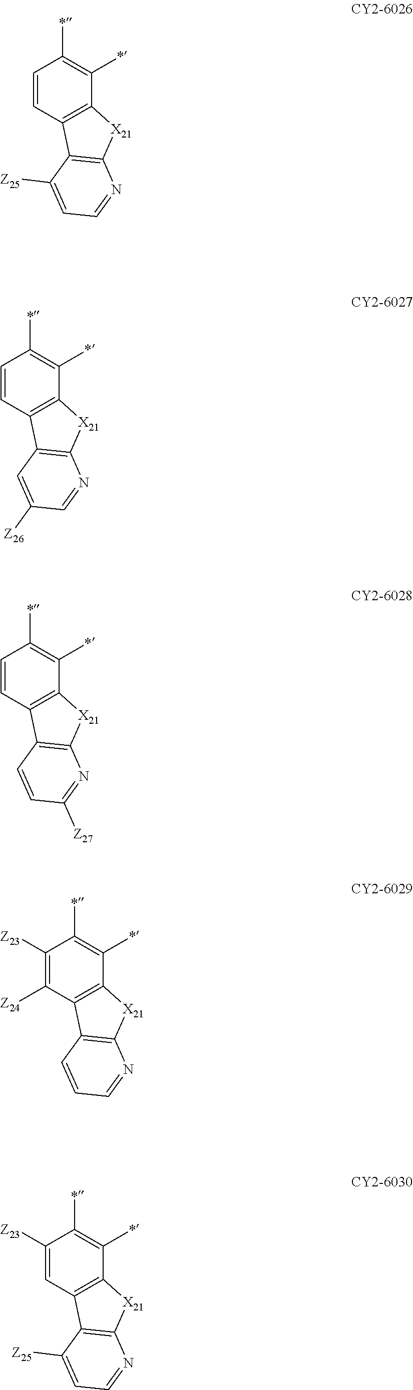

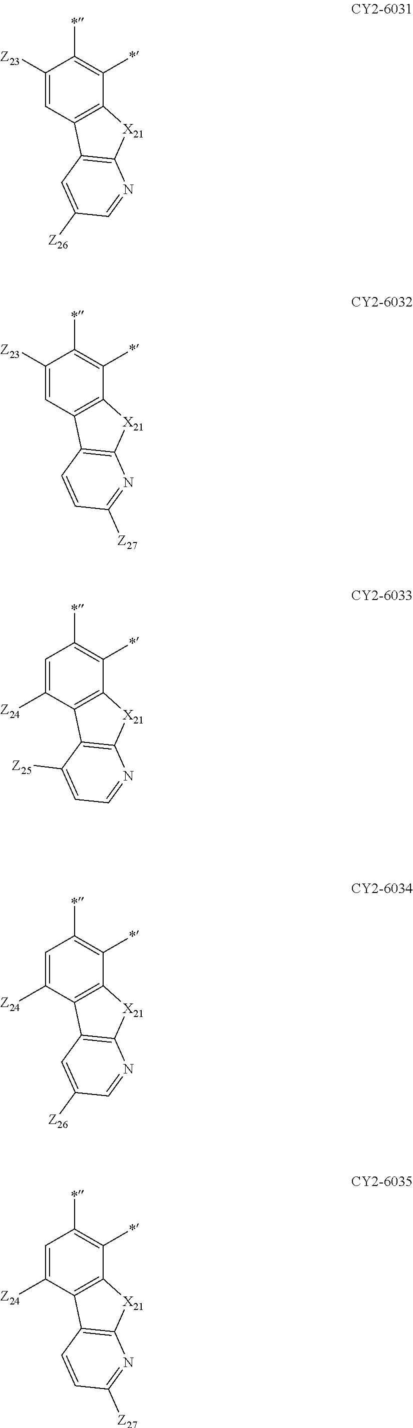

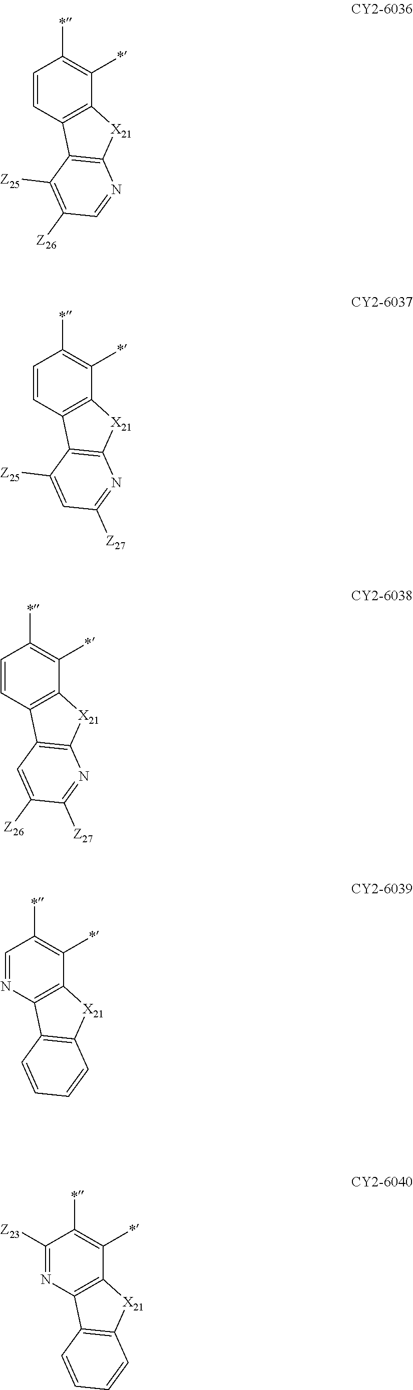

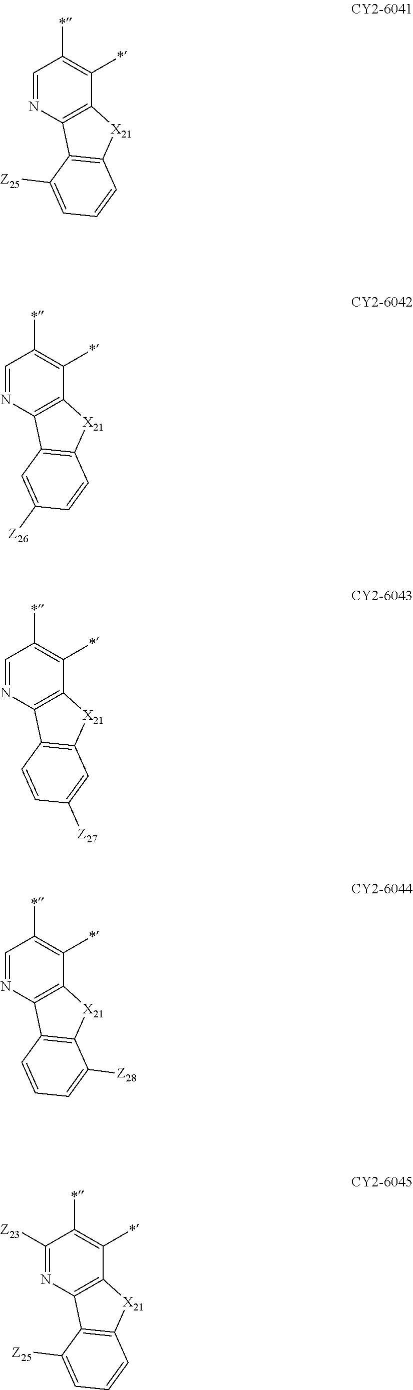

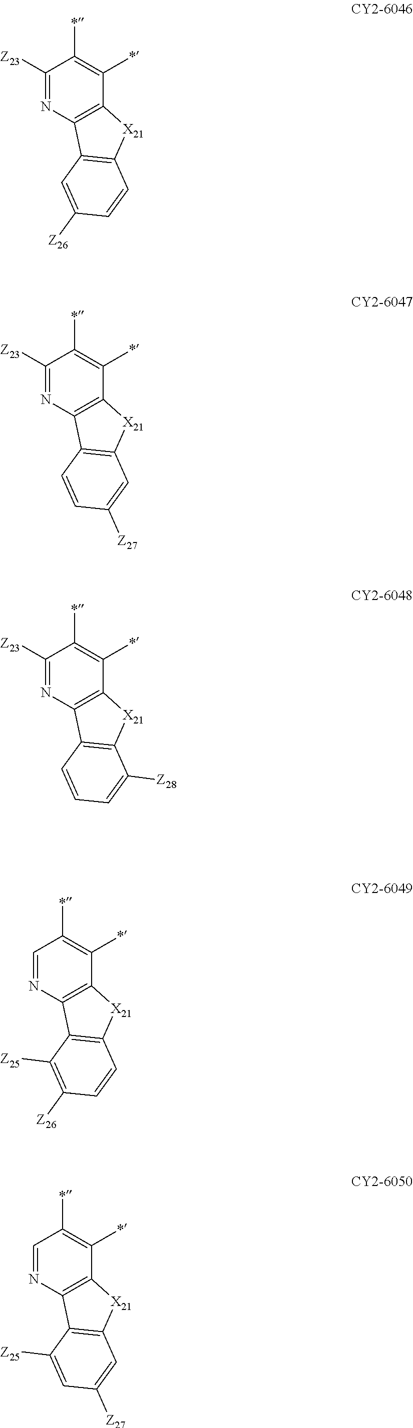

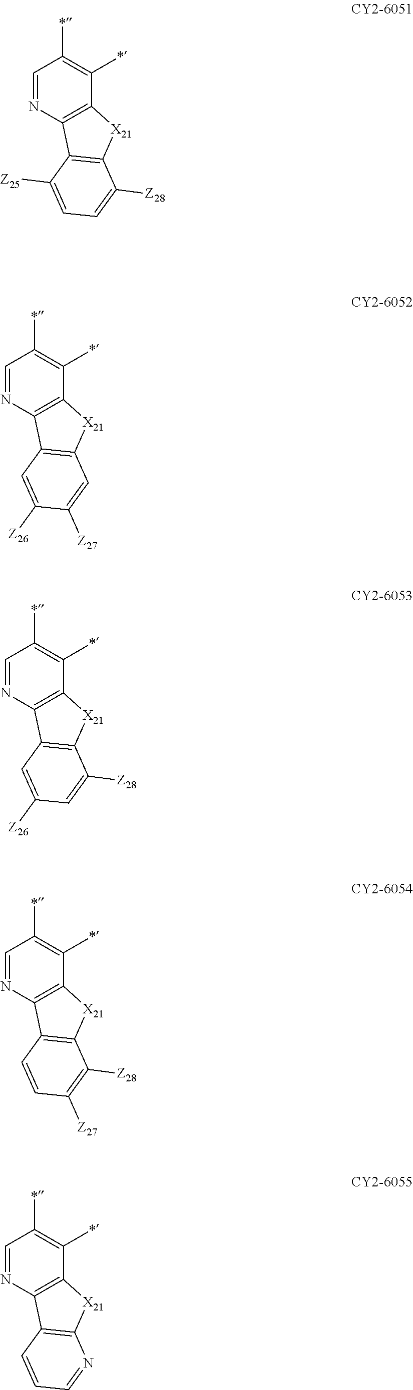

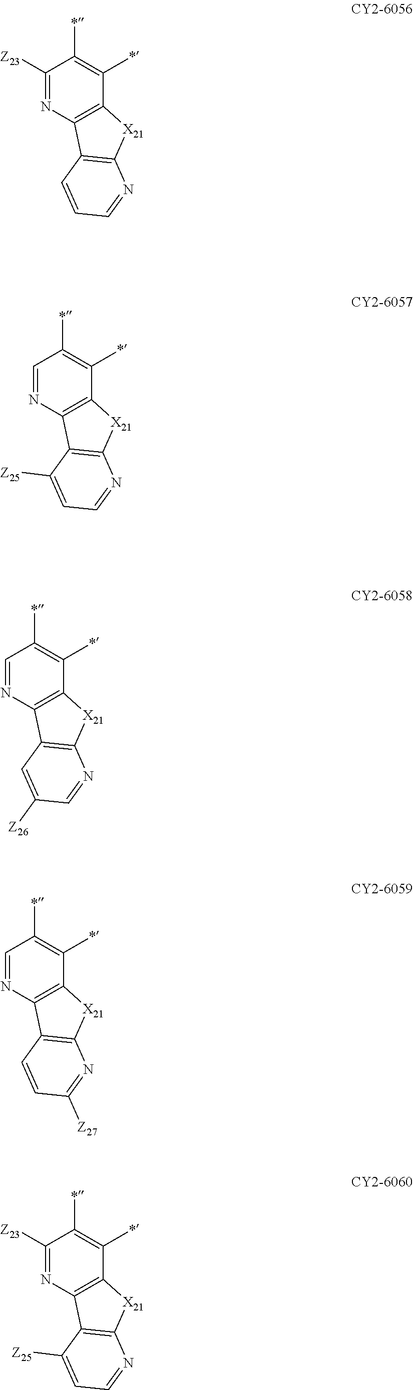

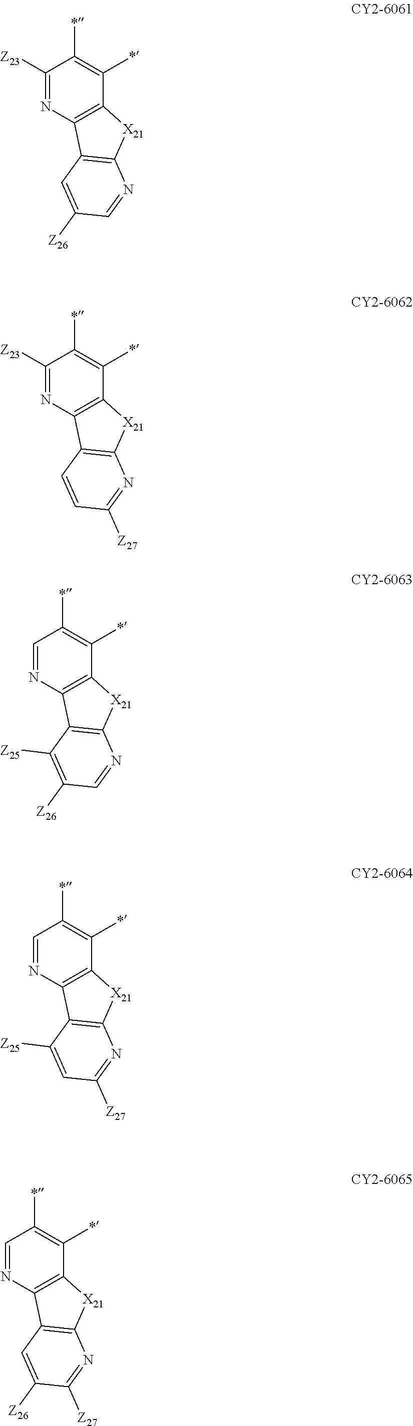

wherein, in Formulae CY2-1001 to CY2-1141, CY2-2001 to CY2-2092, CY2-3001 to CY2-3092, CY2-4001 to CY2-4092, CY2-5001 to CY2-5065, and CY2-6001 to CY2-6065,
X₂₁ are the same as described above,
Z₂₁ to R₂₈ are the same as described in connection with Z₂, and each of Z₂₁ to Z₂₈ is not hydrogen,
*″ is a binding site to ring CY₁ in Formula 2A, and
*′ is a binding site to M in Formula 1.

In one or more embodiments, a group represented by

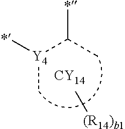

in Formula 2B may be a group represented by one of Formulae CY14-1 to CY14-64:

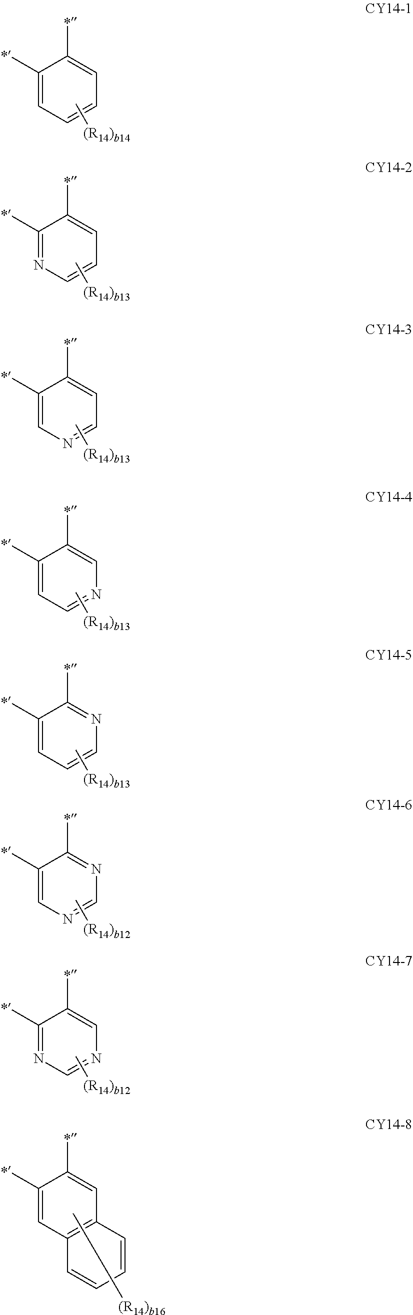

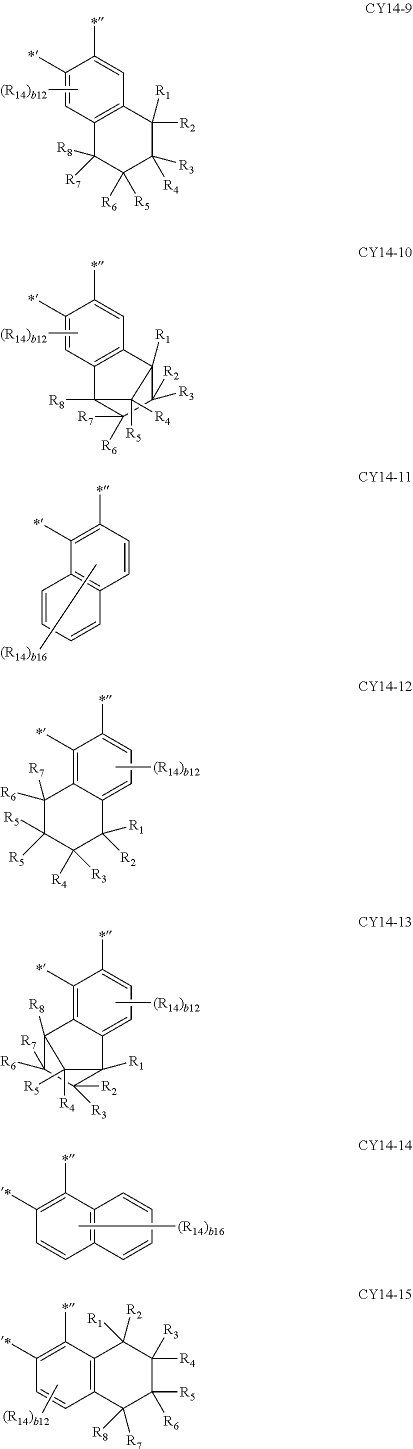

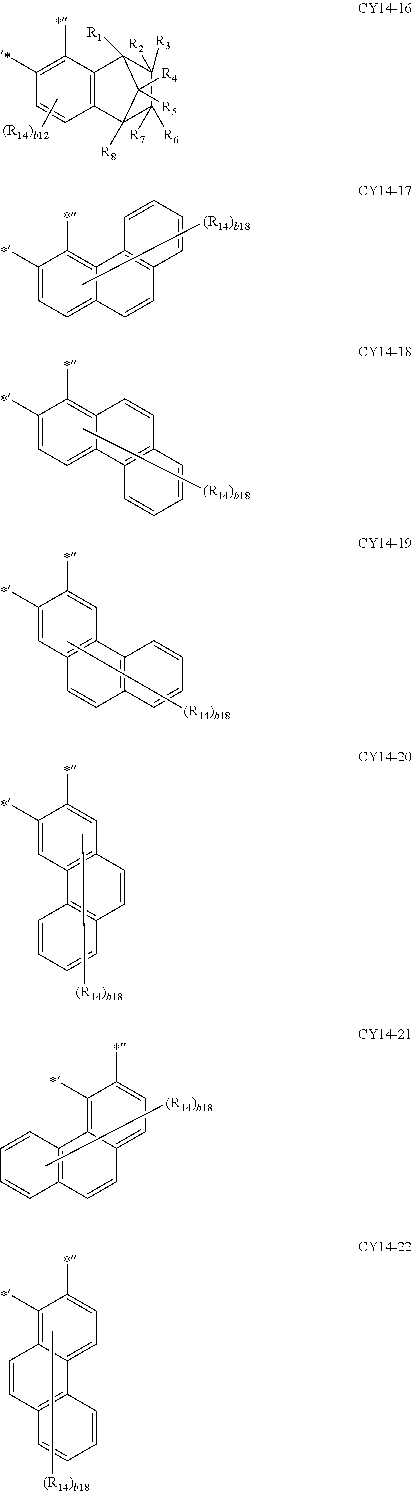

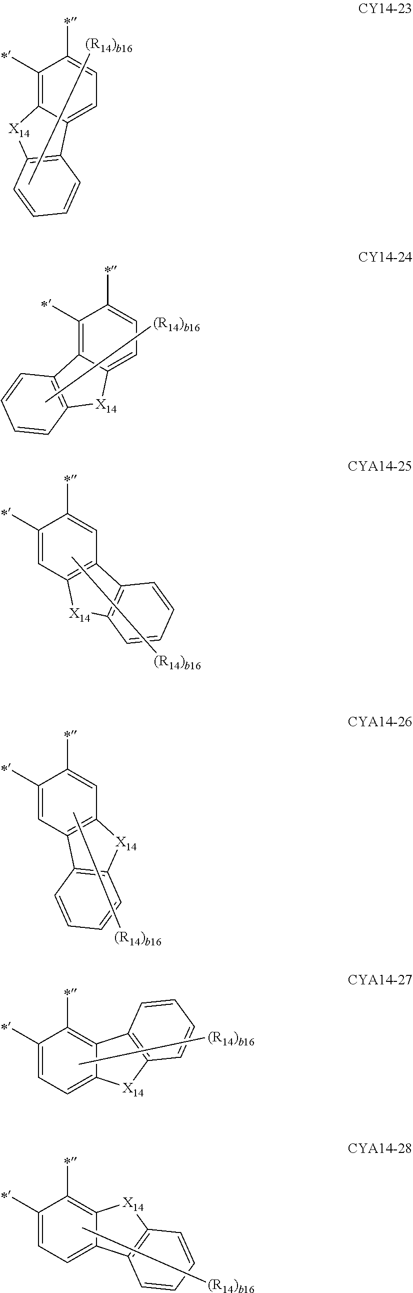

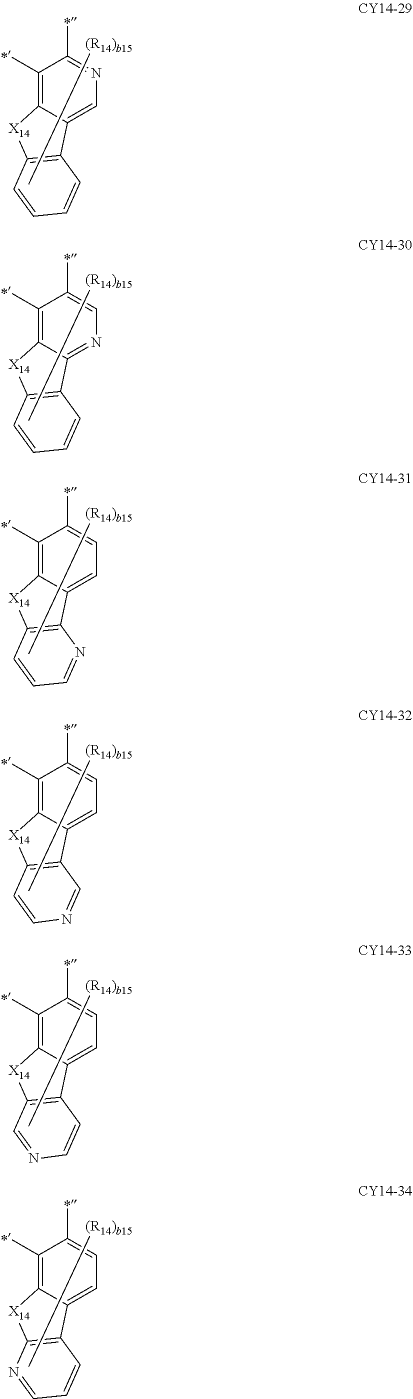

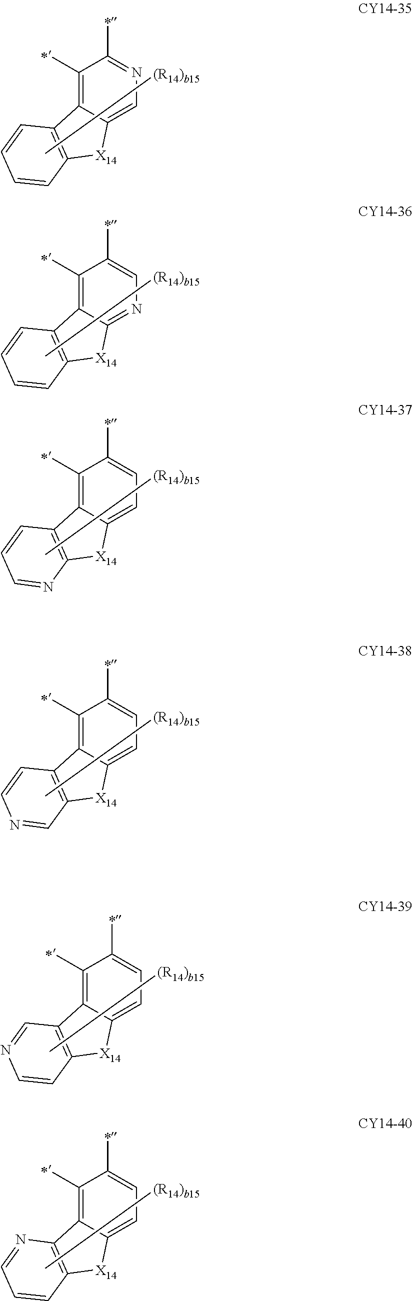

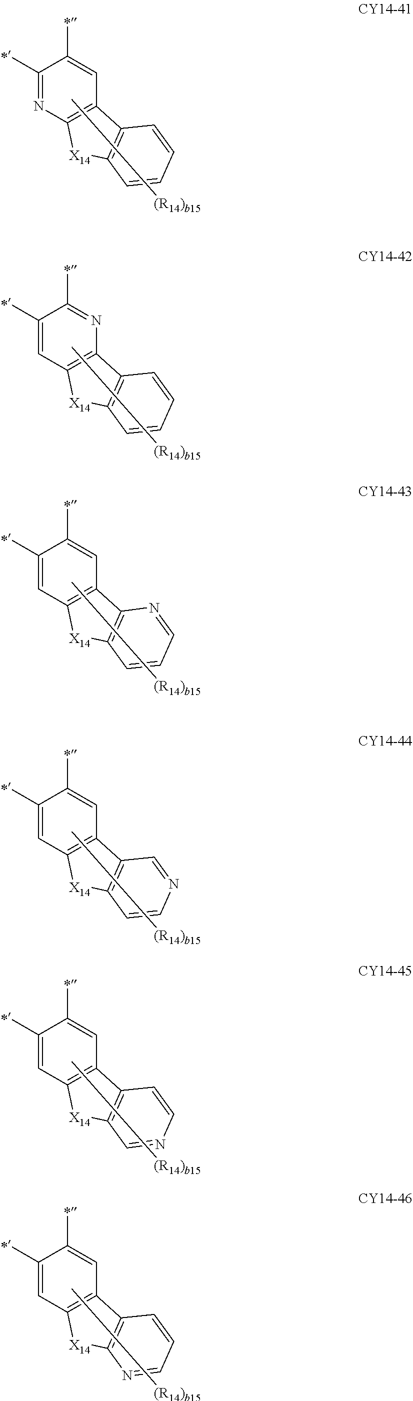

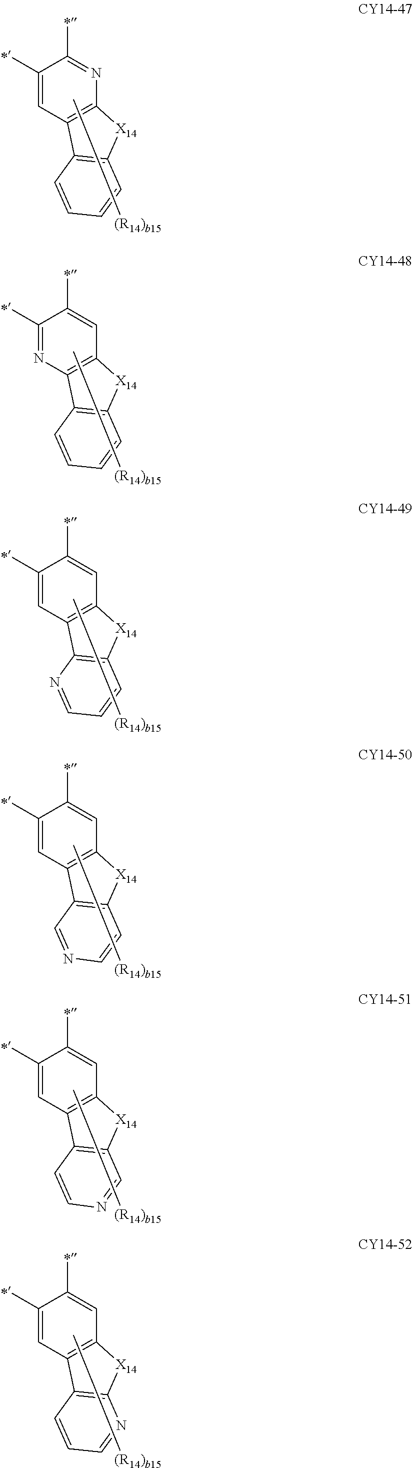

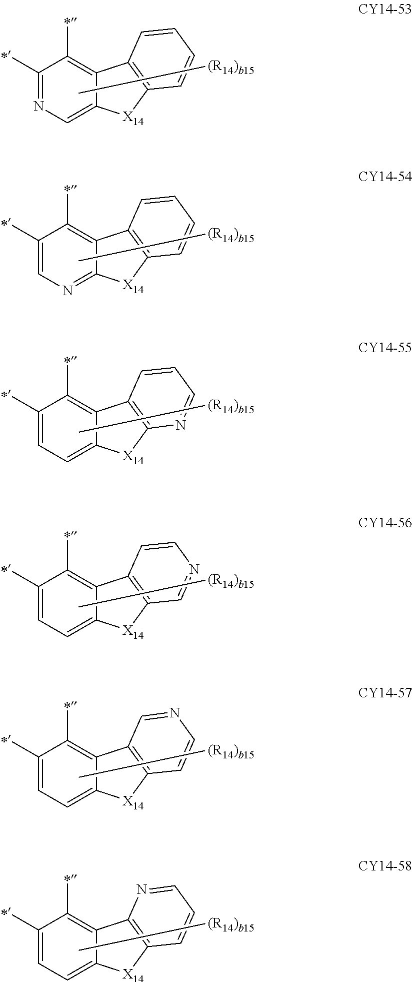

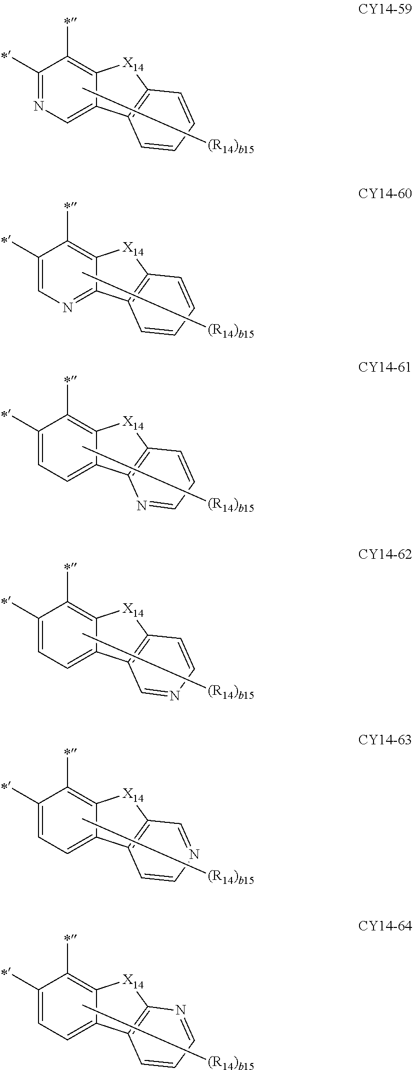

b14 may be an integer from 0 to 4,
b13 may be an integer from 0 to 3,
b12 may be an integer from 0 to 2,
*″ is a binding site to a carbon atom of a neighboring pyridine ring in Formula 2B, and
*′ is a binding site to M in Formula 1.

In one or more embodiments, a group represented by

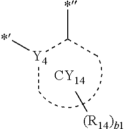

in Formula 2B may be a group represented by one of Formulae CY14(1) to CY14(63):

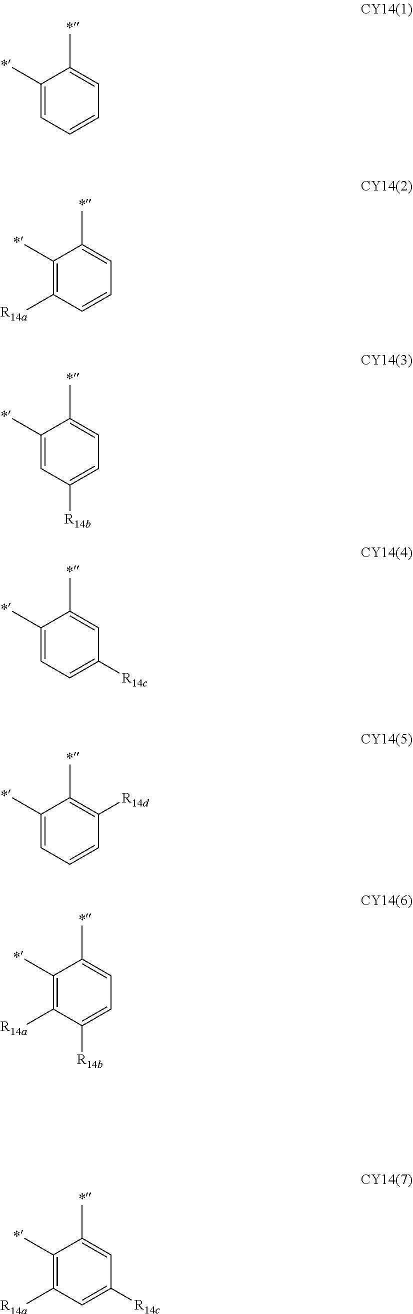

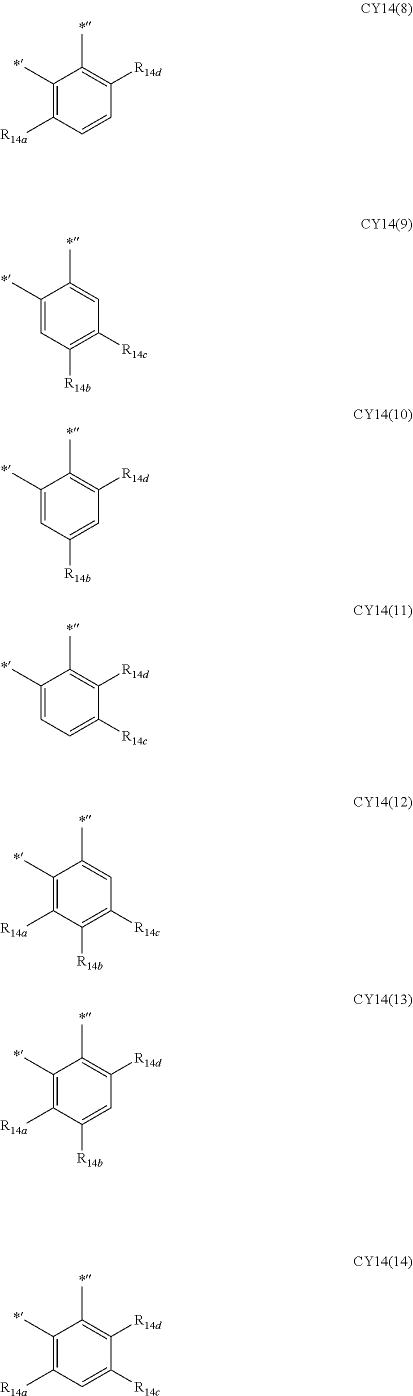

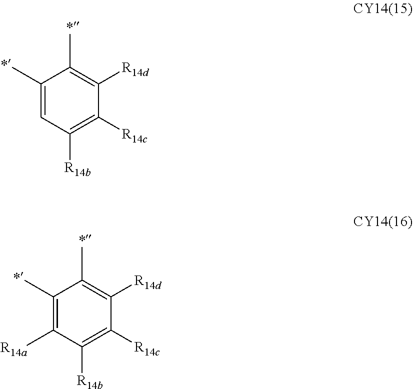

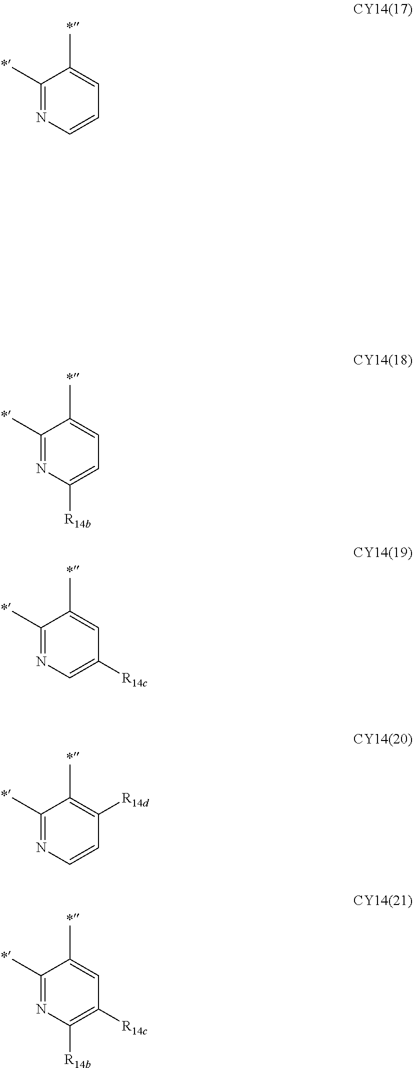

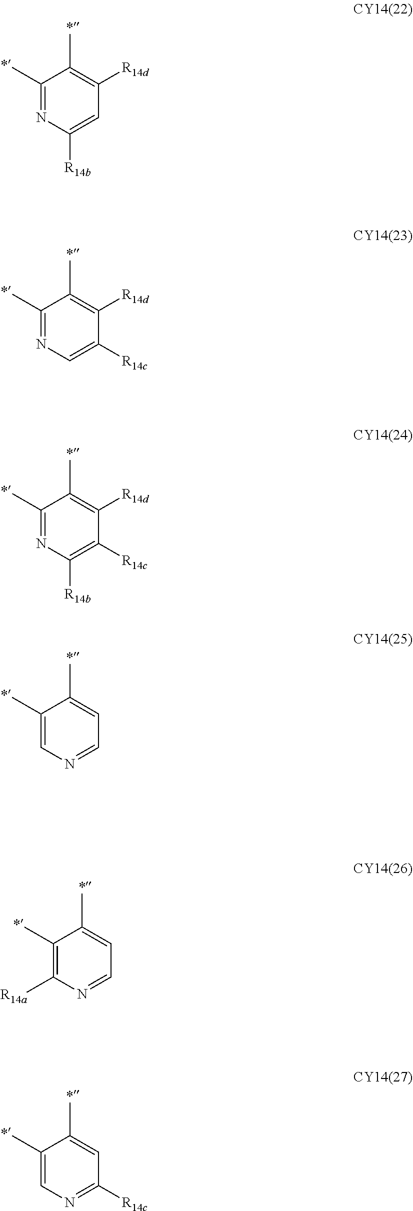

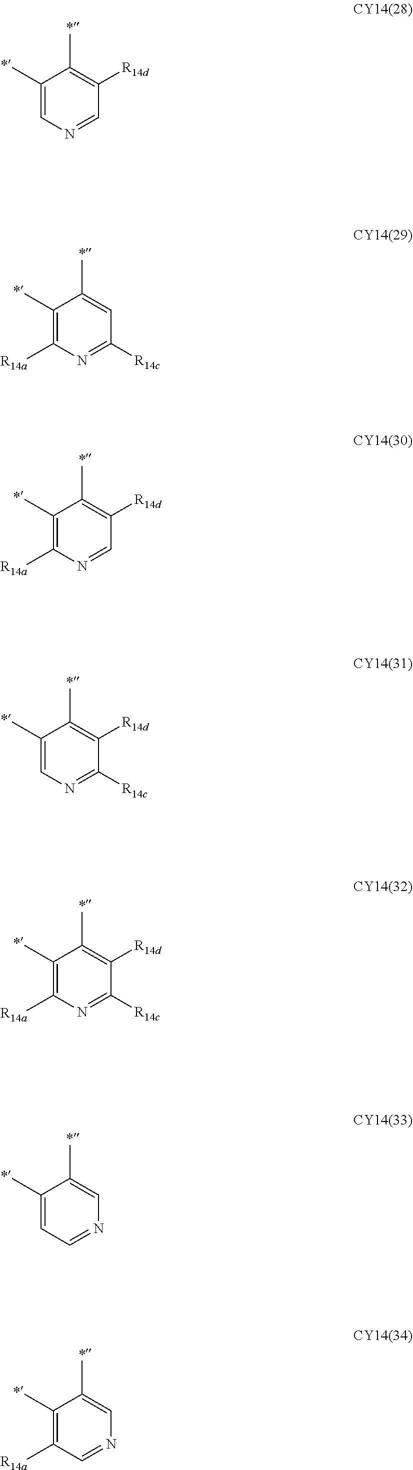

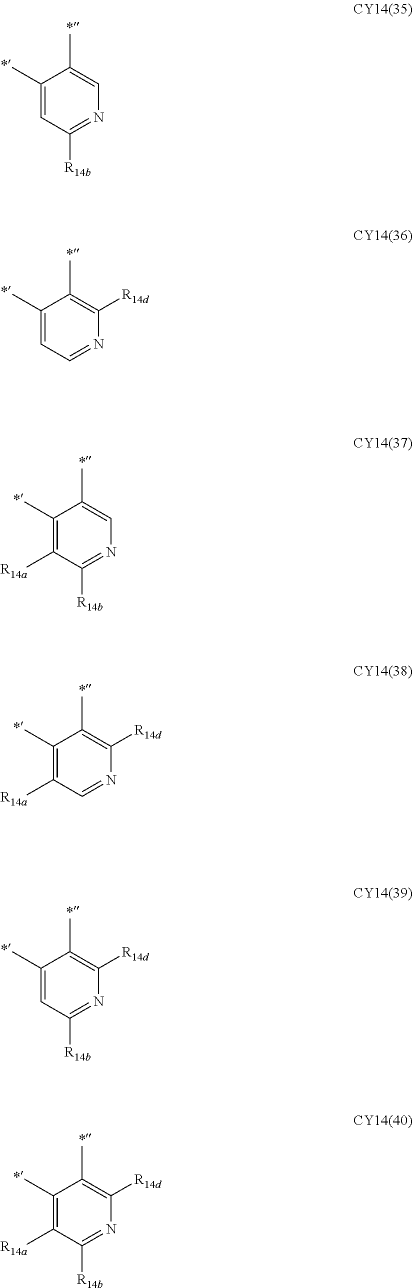

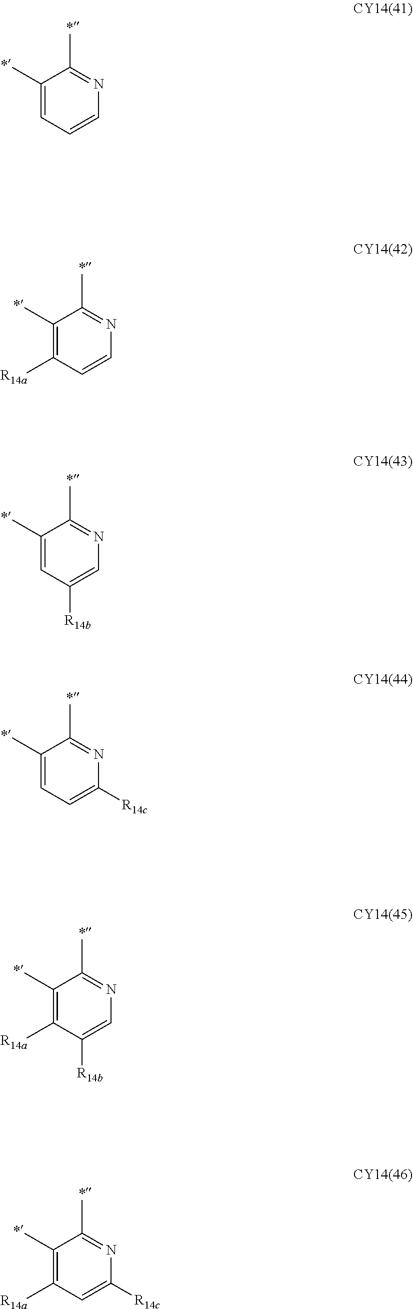

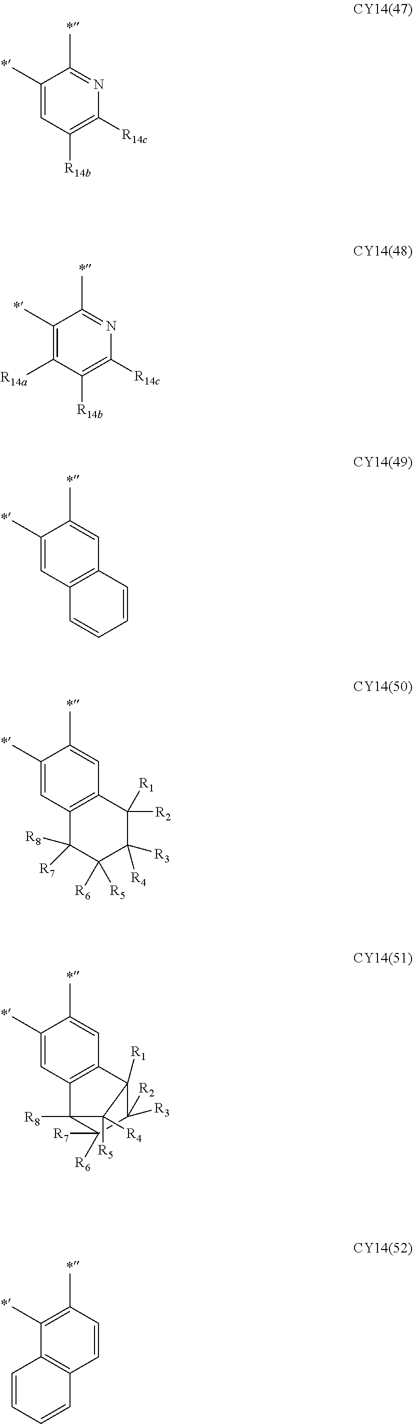

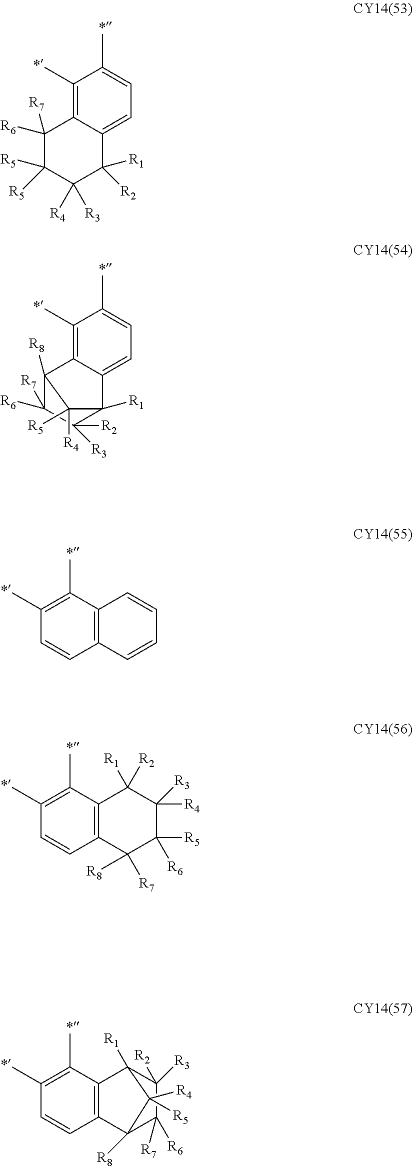

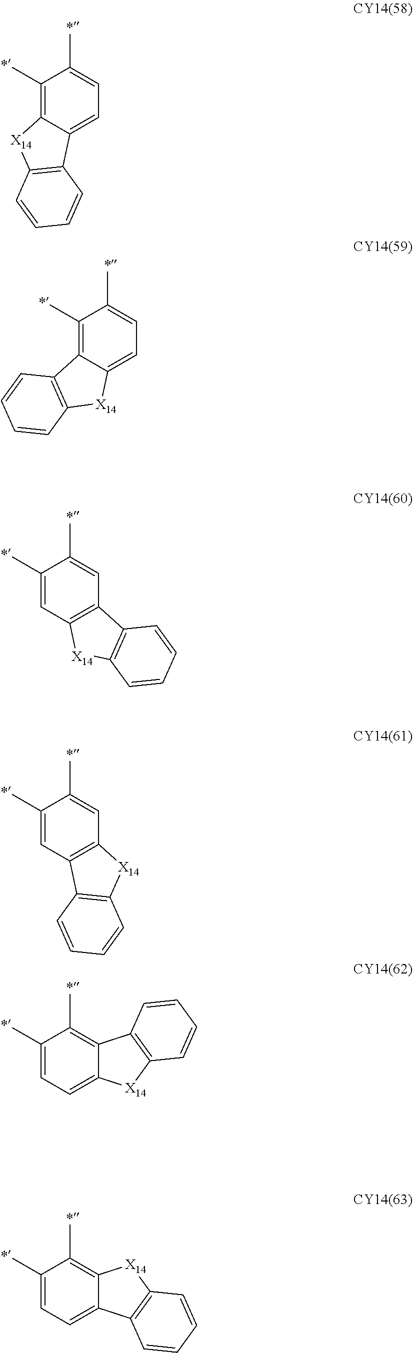

wherein, in Formulae CY14(1) to CY14(63),
R₁₄ₐ to R_{14d} are each the same as described in connection with R₁₄, and each of R₁₄ₐ to R_{14d} is not hydrogen,
X₁₄ may be C(R₁)(R₂), N(R₁), O, S, or Si(R₁)(R₂),
R₁ to R₈ are each the same as described in connection with R₁₄,
*″ is a binding site to a carbon atom of a neighboring pyridine ring in Formula 2B, and
*′ is a binding site to M in Formula 1.

In one or more embodiments, the organometallic compound may be represented by Formula 1A or 1B:

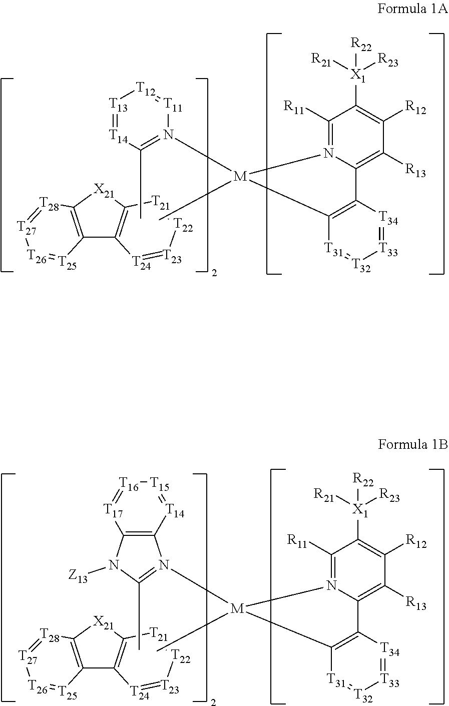

wherein, in Formulae 1A and 1B,
M, X₁, X₂₁, R₂₁ to R₂₃, and R₁₁ to R₁₃ are each the same as described in the present specification,
T₁₁ may be N or C(Z₁₁), T₁₂ may be N or C(Z₁₂), T₁₃ may be N or C(Z₁₃), T₁₄ may be N or C(Z₁₄), T₁₅ may be N or C(Z₁₅), T₁₆ may be N or C(Z₁₆), T₁₇ may be N or C(Z₁₇), and Z₁₁ to Z₁₇ are the same as described in connection with Z₁,
T₂₁ may be N, C(Z₂₁), carbon bonded to a neighboring 6-membered ring, or carbon bonded to M in Formula 1, T₂₂ may be N, C(Z₂₂), a carbon bonded to a neighboring 6-membered ring, or carbon bonded to M in Formula 1, T₂₃ may be N, C(Z₂₃), carbon bonded to a neighboring 6-membered ring, or carbon bonded to M in Formula 1, T₂₄ may be N, C(Z₂₄), a carbon bonded to a neighboring 6-membered ring, or carbon bonded to M in Formula 1, T₂₅ may be N or C(Z₂₅), T₂₆ may be N or C(Z₂₆), T₂₇ may be N or C(Z₂₇), and T₂₈ may be N or C(Z₂₈), wherein one of T₂₁ to T₂₄ may be carbon bonded to M in Formula 1, or one of the others of T₂₁ to T₂₄ which are not bonded to M, may be carbon bonded to a neighboring 6-membered ring, and Z₂₁ to Z₂₄ are the same as described in connection with Z₂,
T₃₁ may be N or C(R₁₄ₐ), T₃₂ may be N or C(R_{14b}), T₃₃ may be N or C(R_{14c}), T₃₄ may be N or C(R_{14d}), and R₁₄ₐ to R_{14d} are the same as described in connection with R₁₄,
two or more of Z₁₁ to Z₁₇ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of Z₂₁ to Z₂₈ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
R₁₂ and R₁₃ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of R₁₄ₐ to R_{14d} may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
R₁₀ₐ is the same as described in connection with R₁₄.

Further description of Formulae 1A and 1B are the same as described in connection with Formula 1.

For example, in Formula 1A, T₁₃ may be C(Z₁₃), and Z₁₃ may not be hydrogen.

In one or more embodiments, Z₁₃ in Formula 1B may not be hydrogen.

In one or more embodiments, each of Z₁, Z₂, Z₂₉, Z₃₀, and R₁₁ to R₁₄ in Formulae 2A and 2B may not include Si.

In one or more embodiments, a group represented by

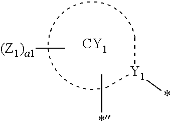

### in Formula 2A may be one of Groups B1 to B56:

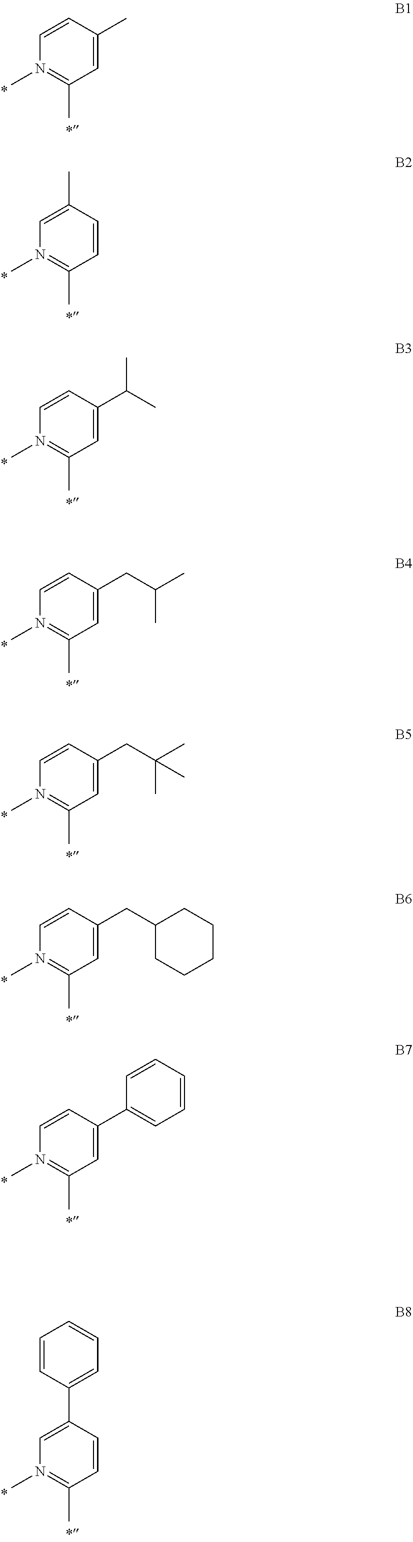 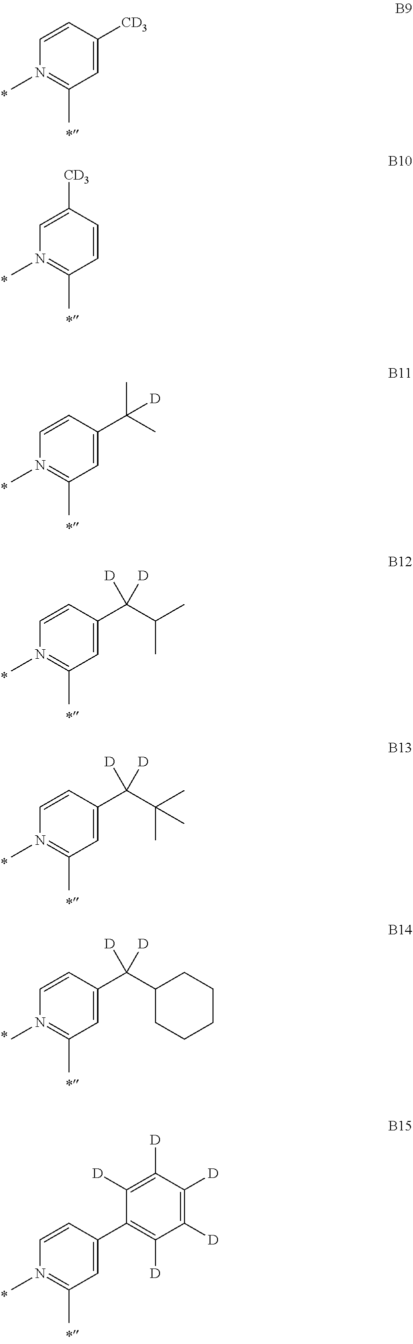 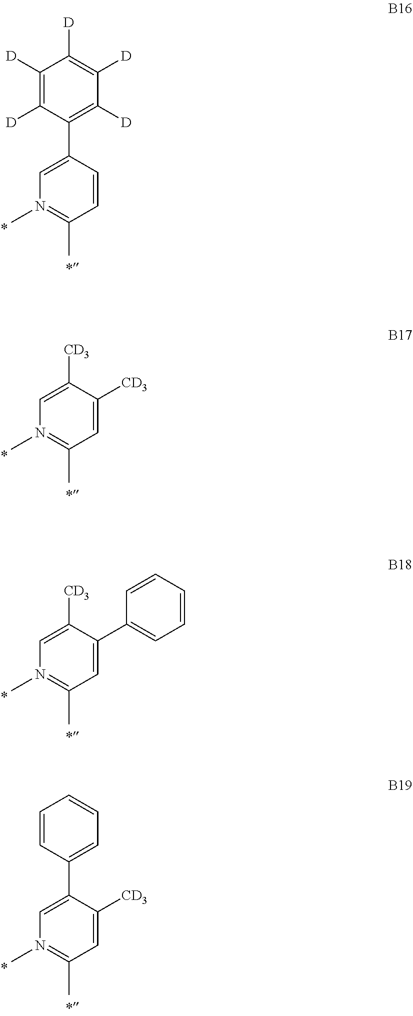 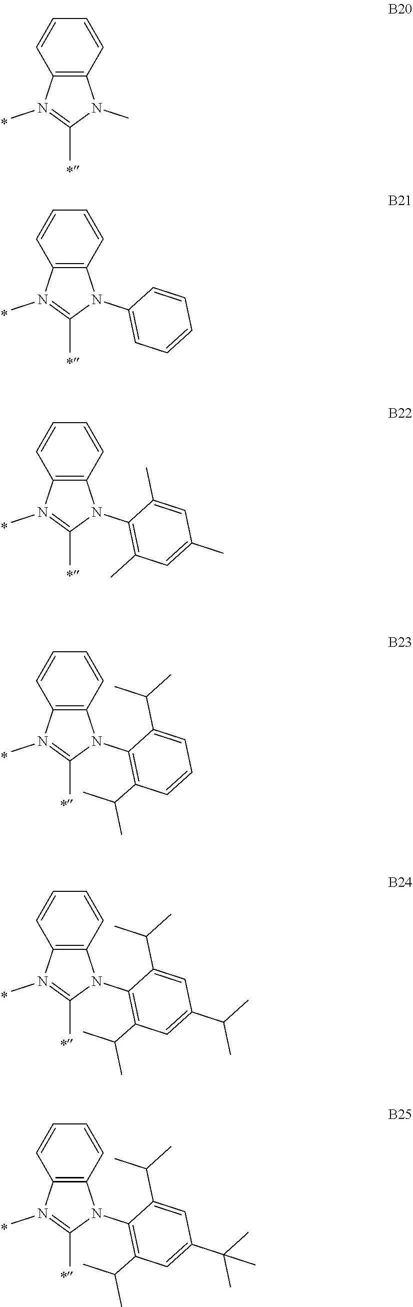 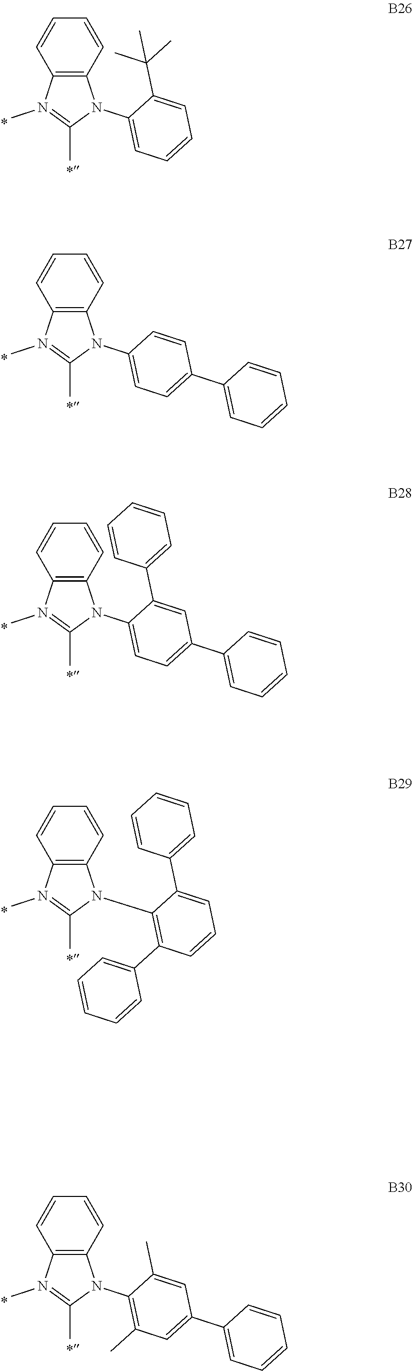 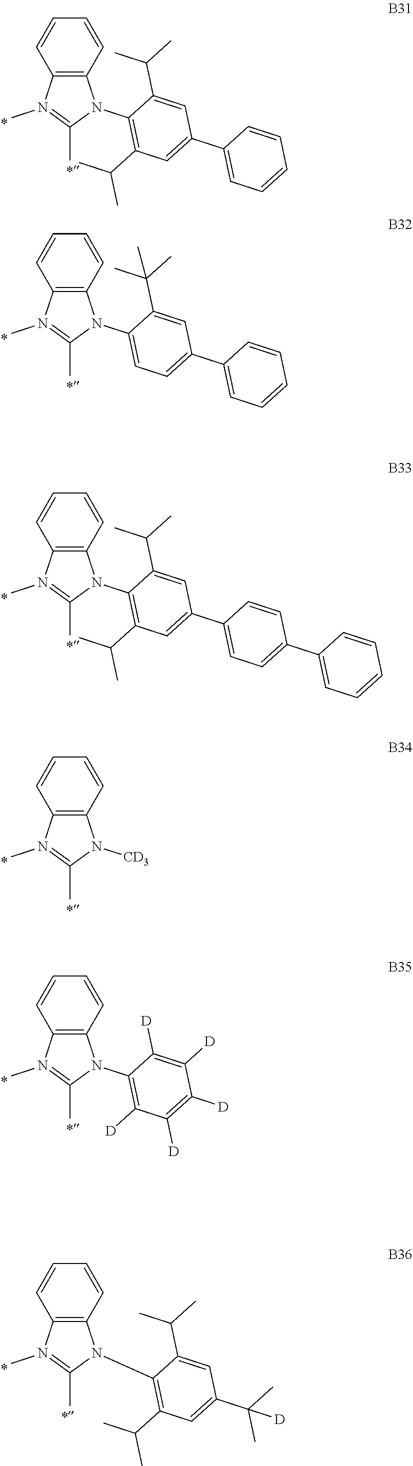 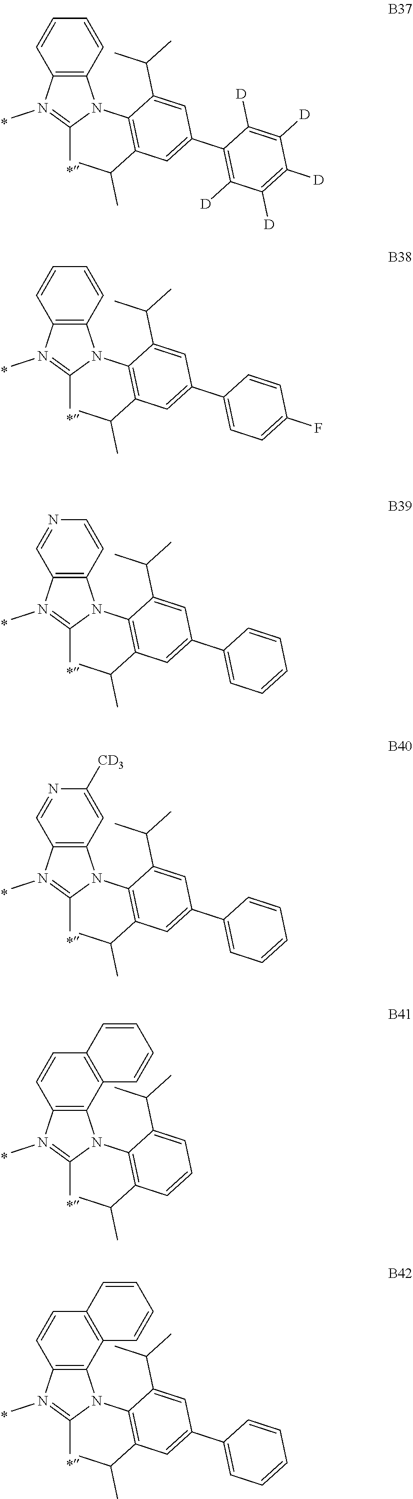 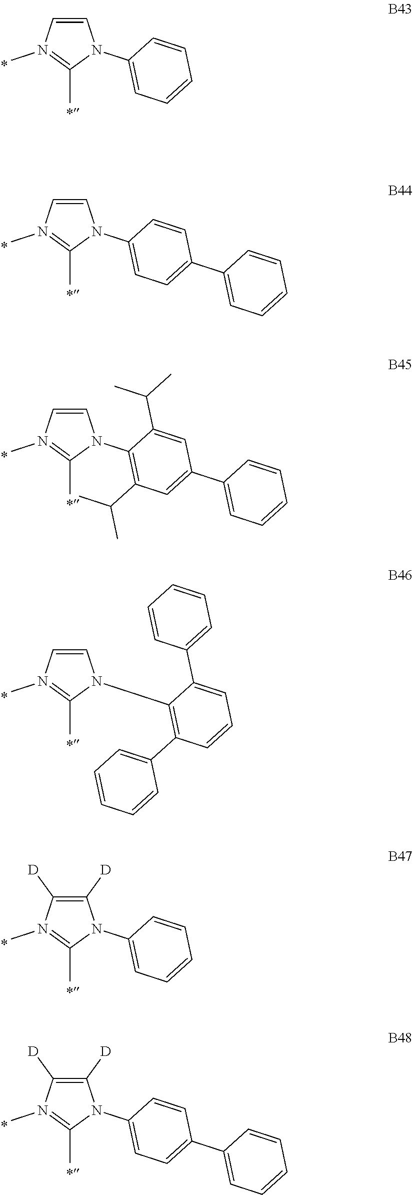 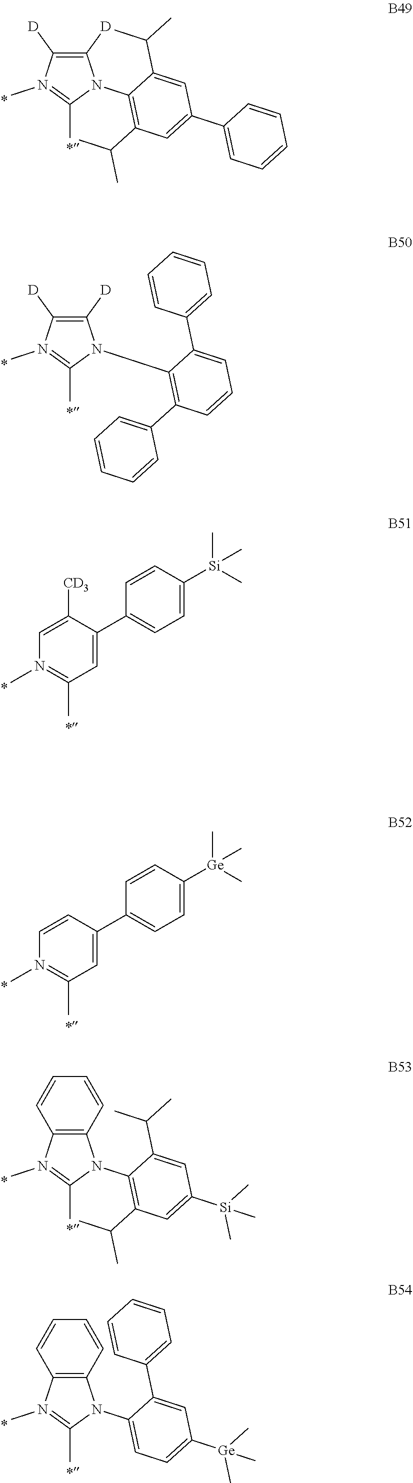 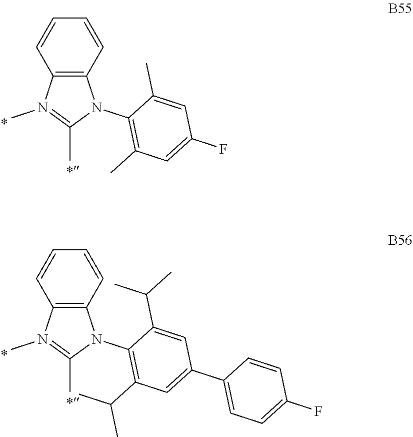 [0209] wherein, in Groups B1 to B56,
* is a binding site to M in Formula 1, and
*″ is a binding site to one of T₁ to T₄ of Formula 2A.

In one or more embodiments, a group represented by

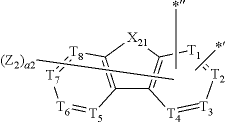

### in Formula 2A may be one of Groups C1 to C100:

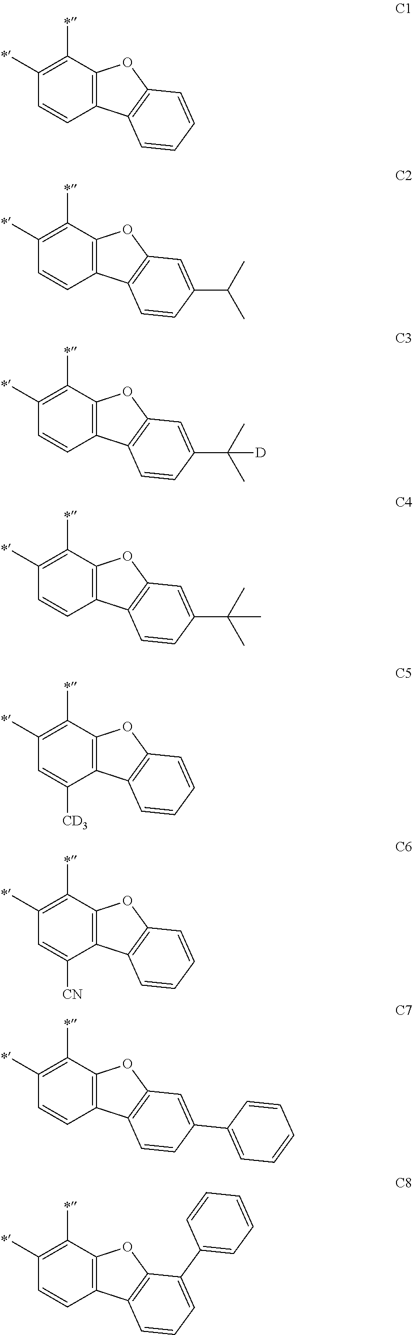 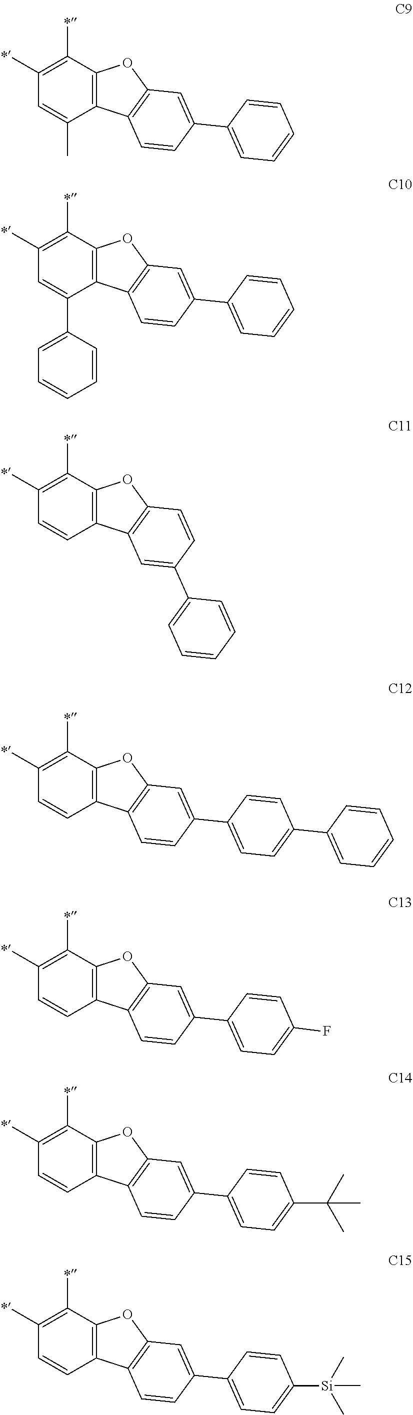 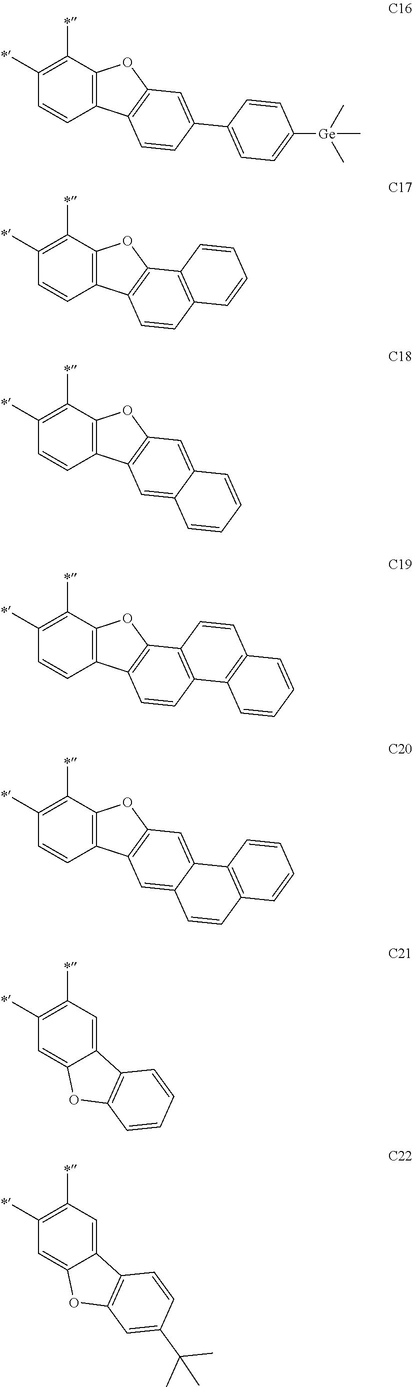 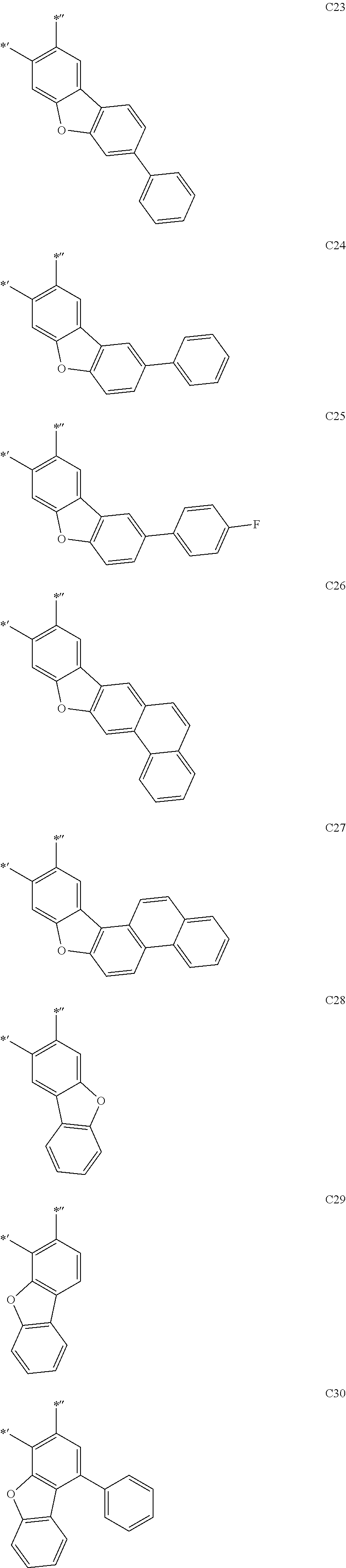 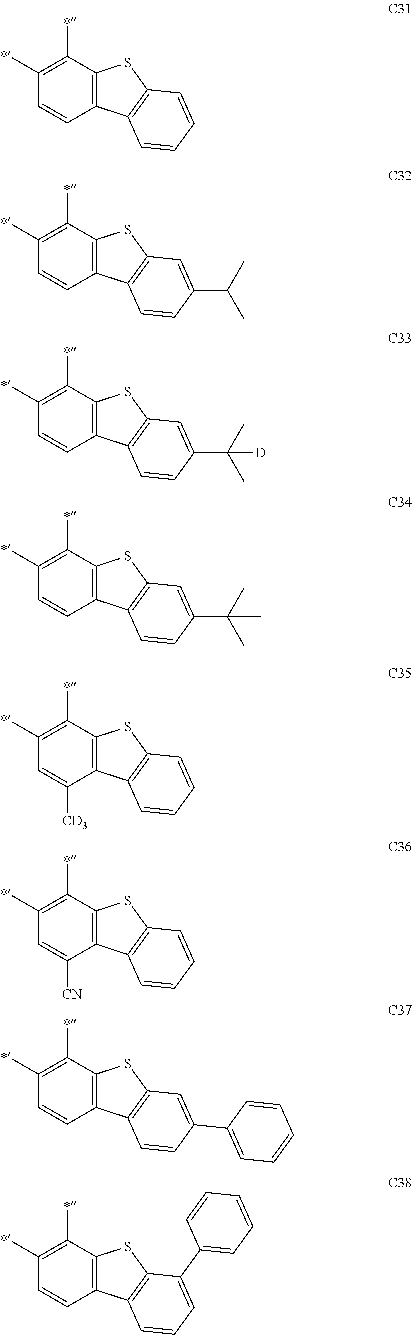 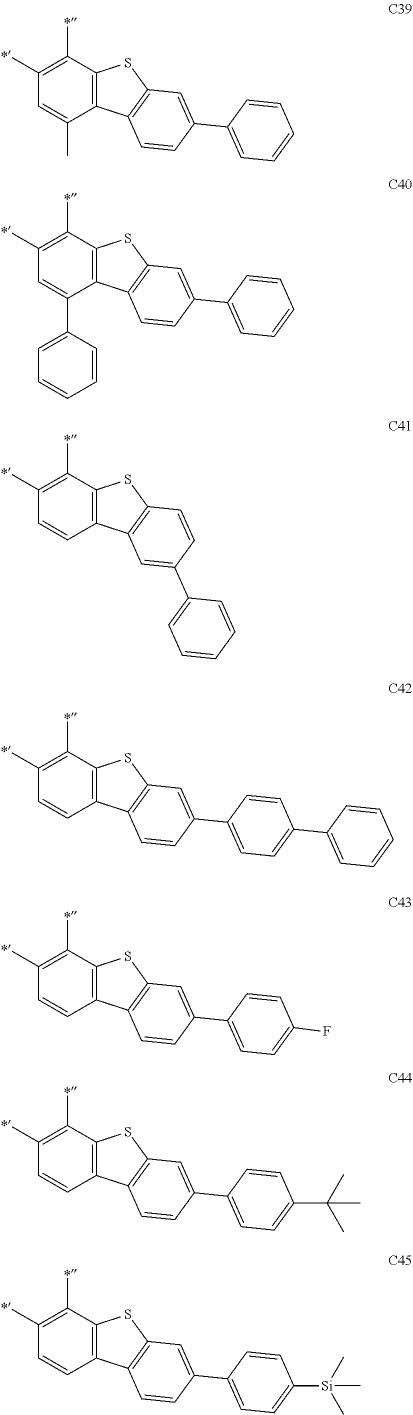 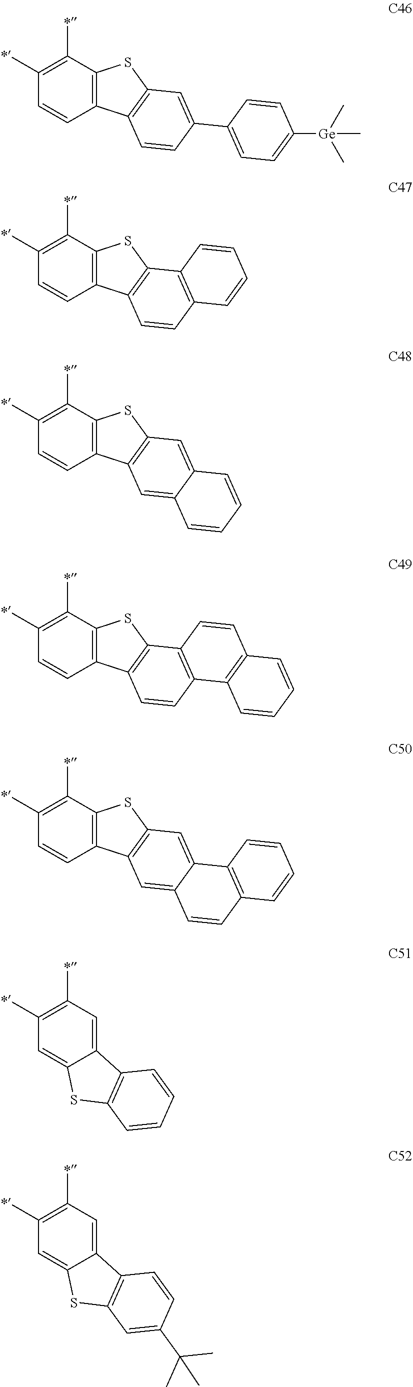 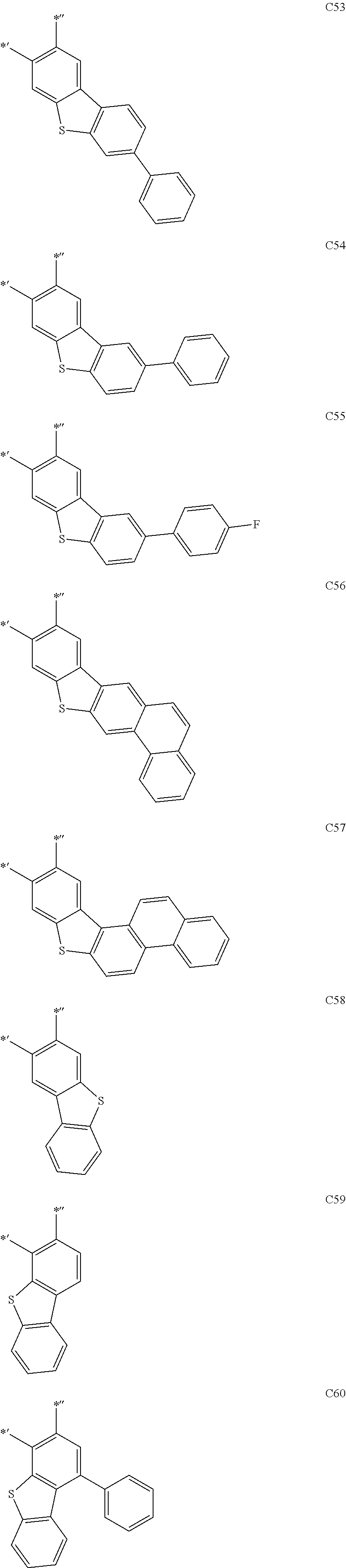 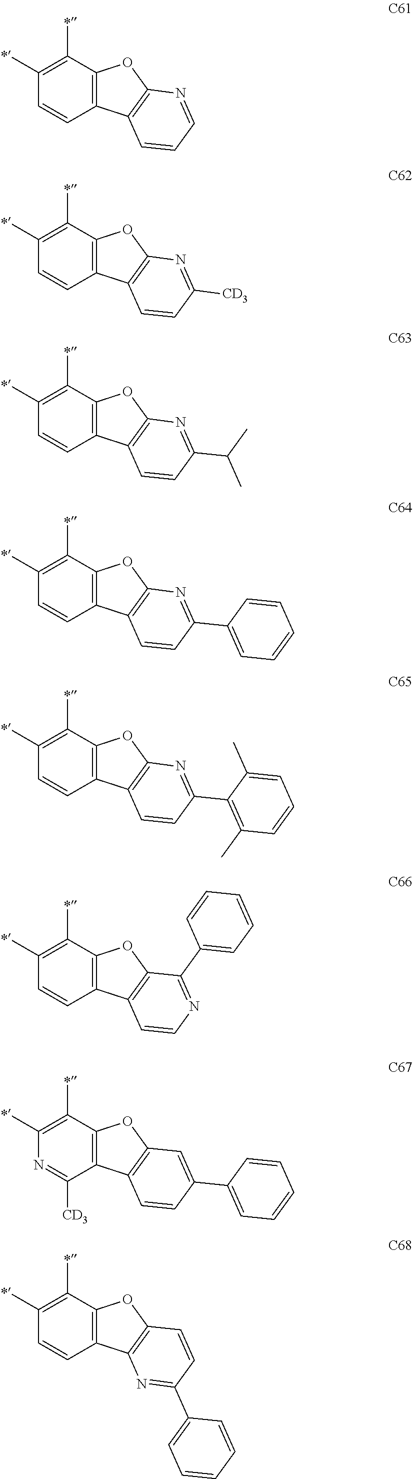 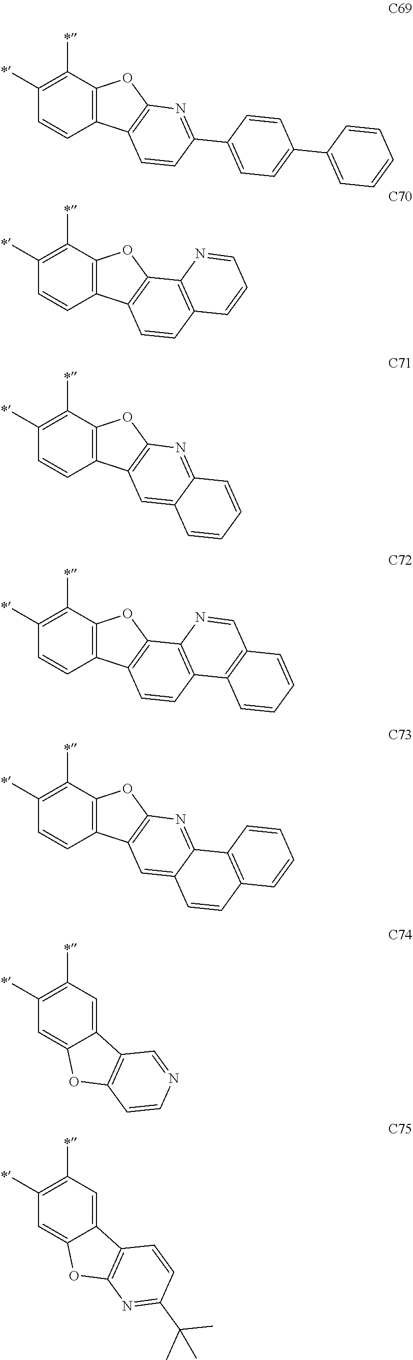 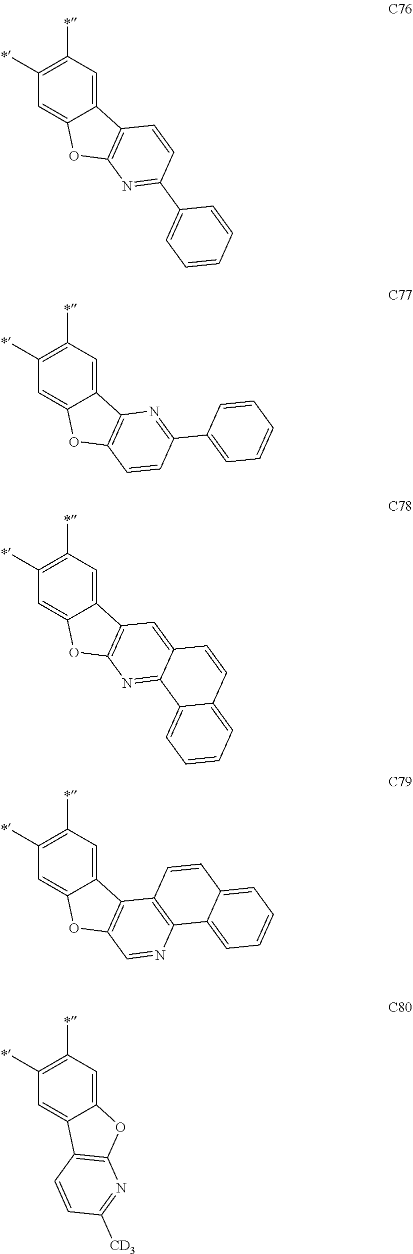 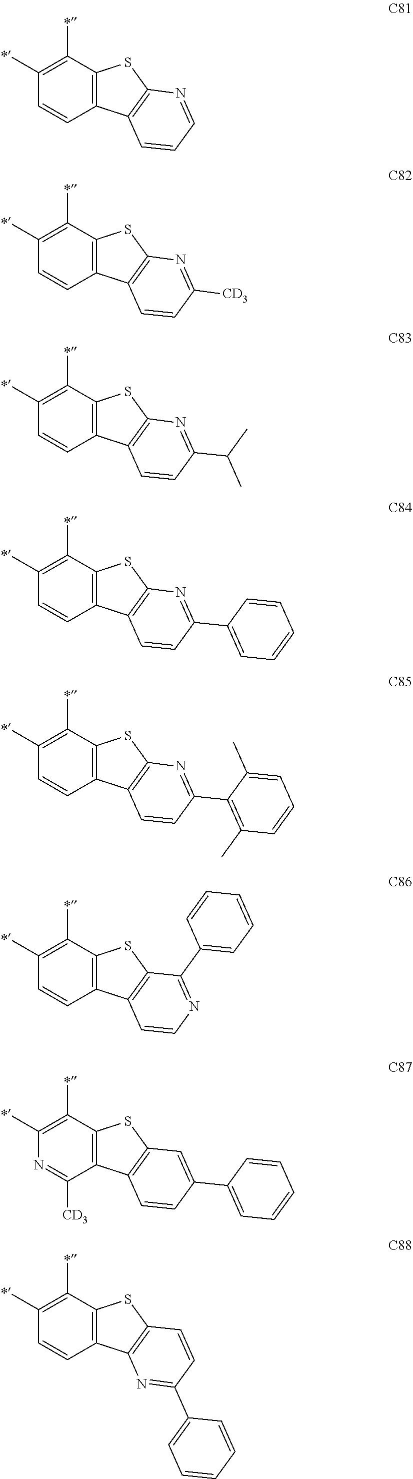 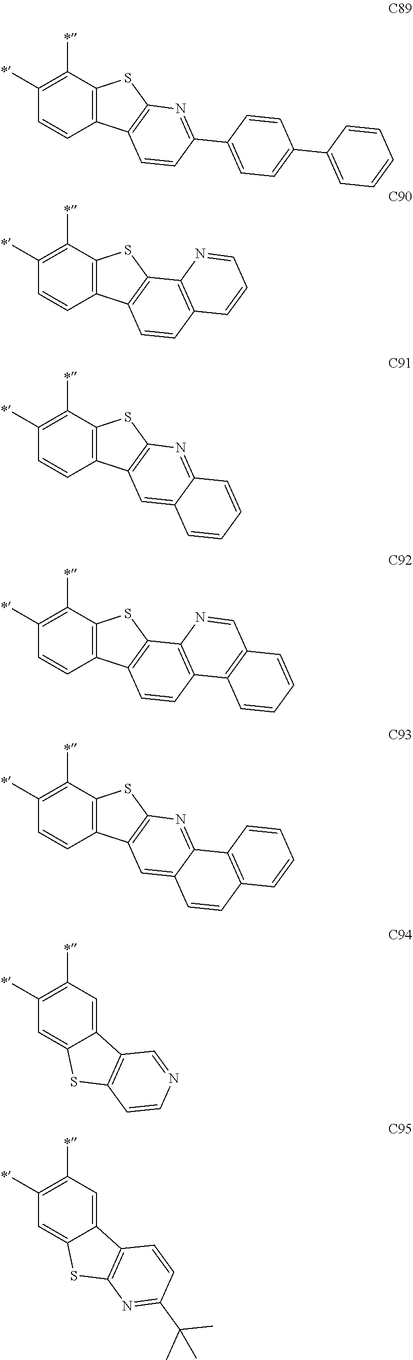 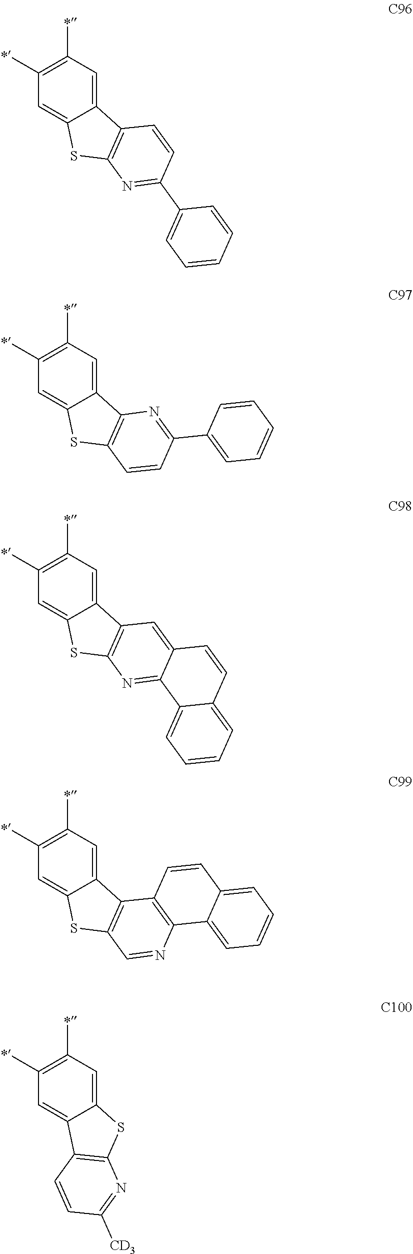 [0214] wherein, in Groups C1 to C100,
*″ is a binding site to ring CY1 in Formula 2A, and
*′ is a binding site to M in Formula 1.

In one or more embodiments, a ligand L₂ represented by Formula 2B in Formula 1 may be one of ligands A1 to A280:

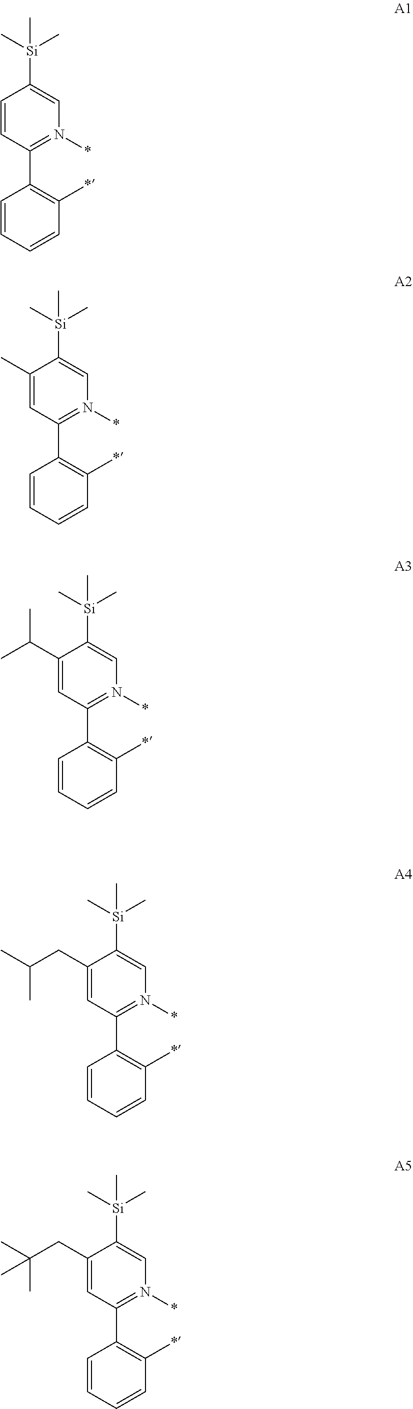

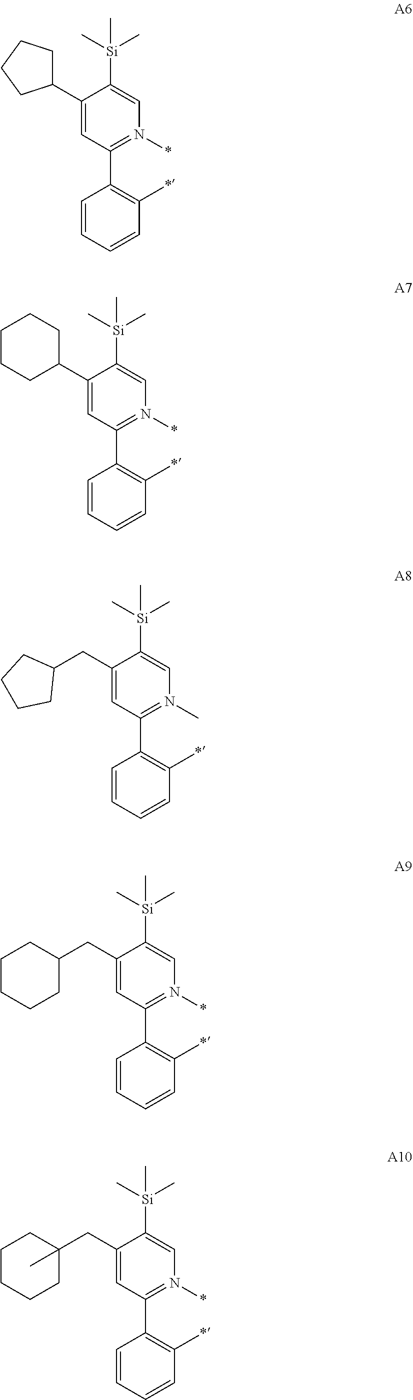

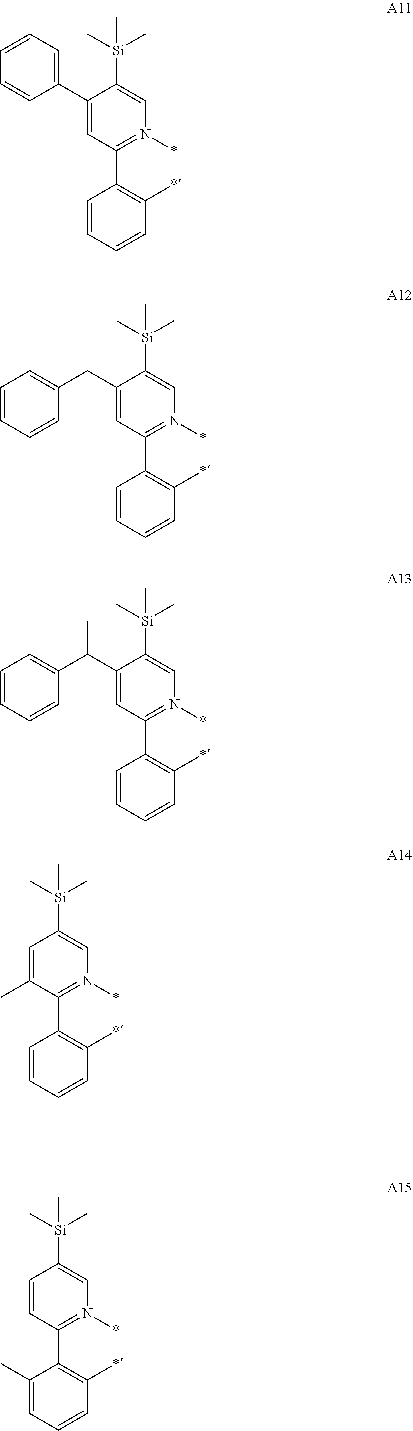

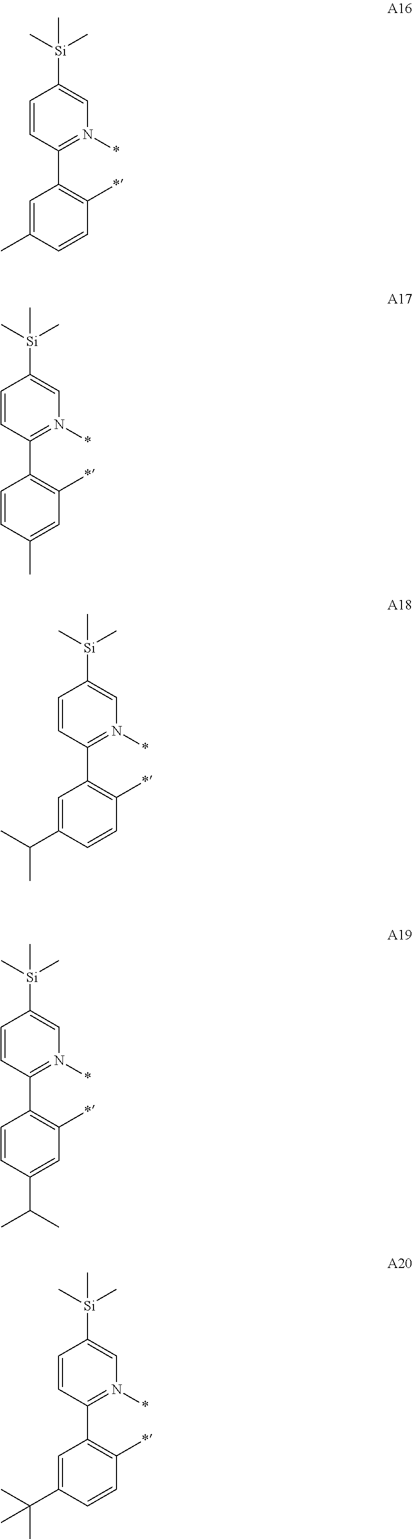

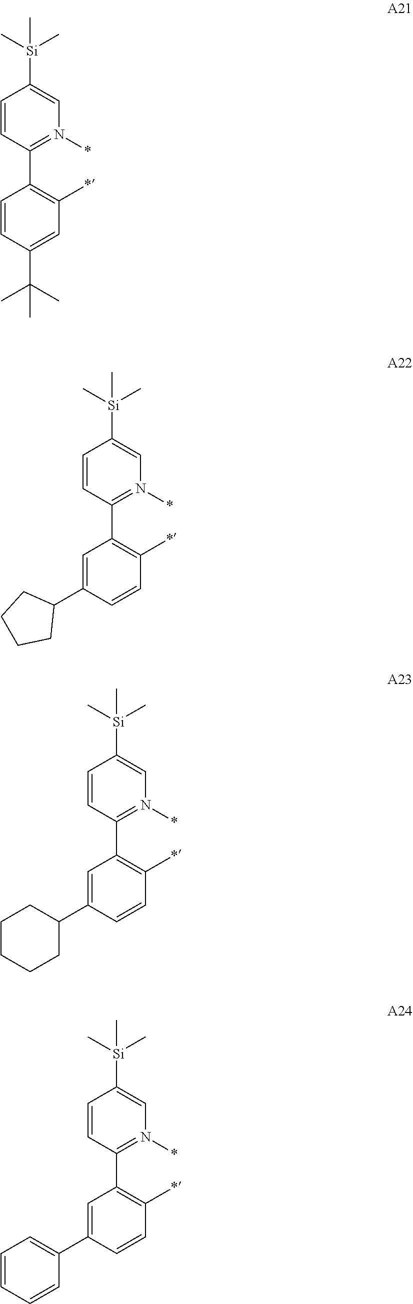

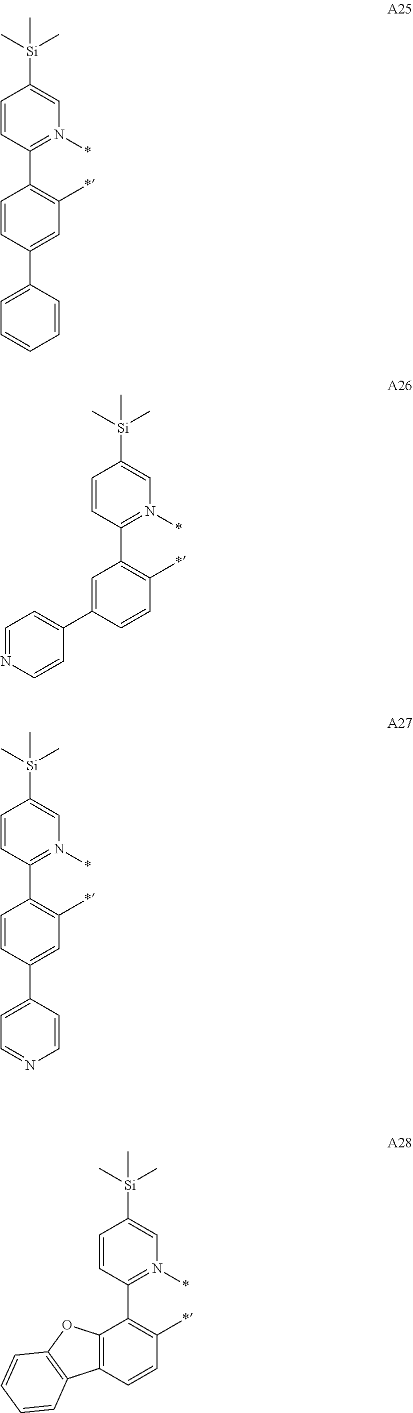

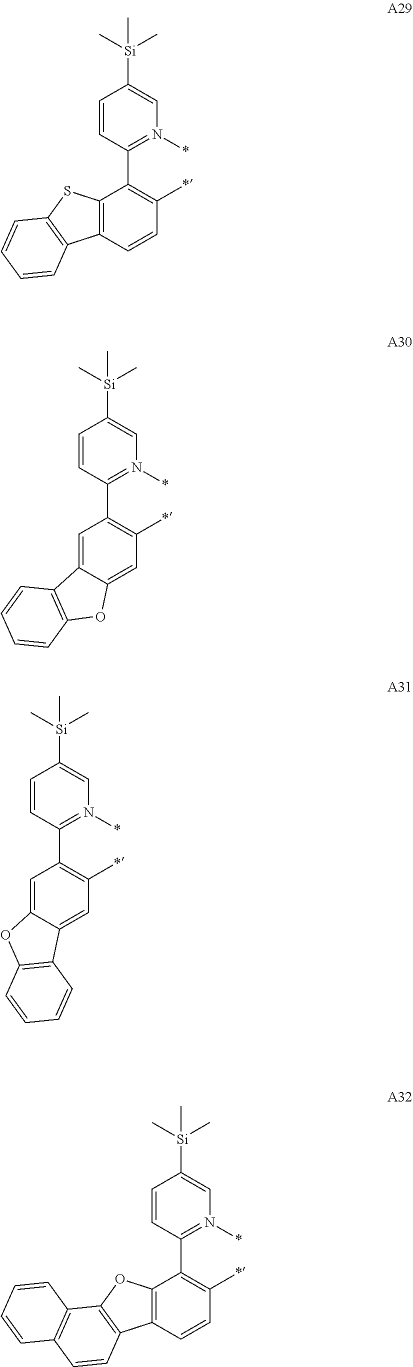

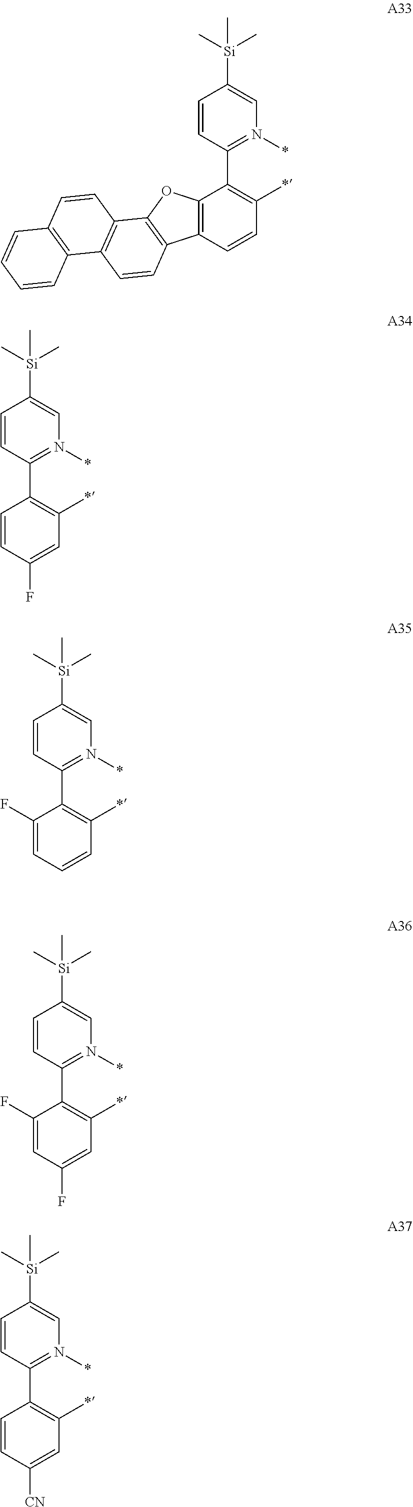

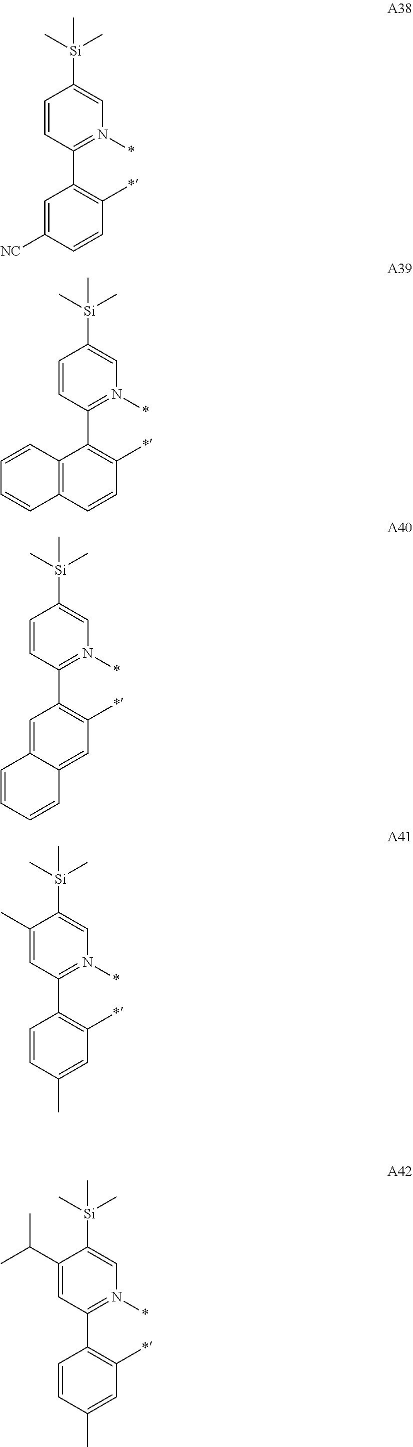

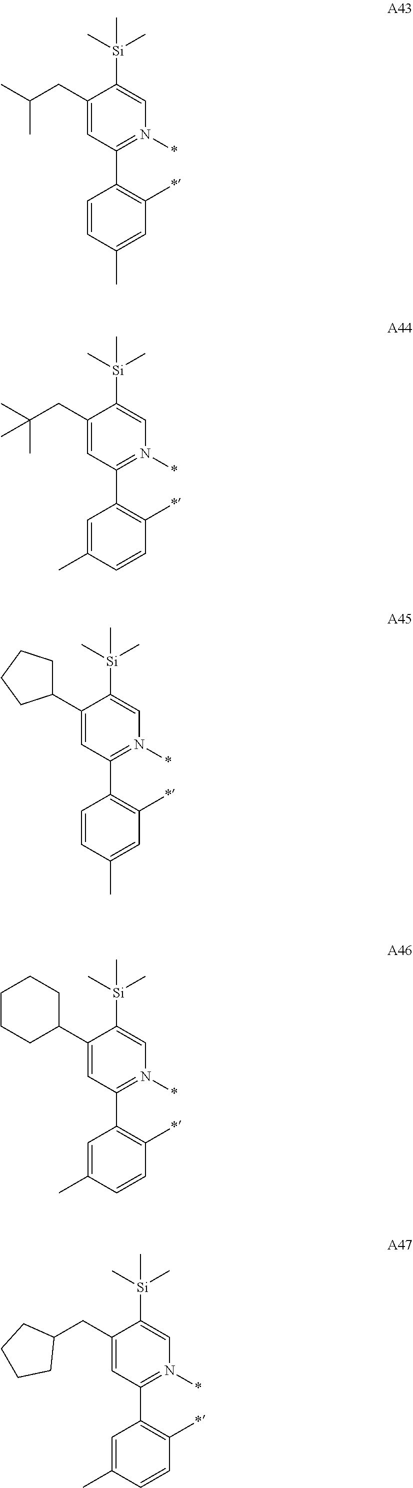

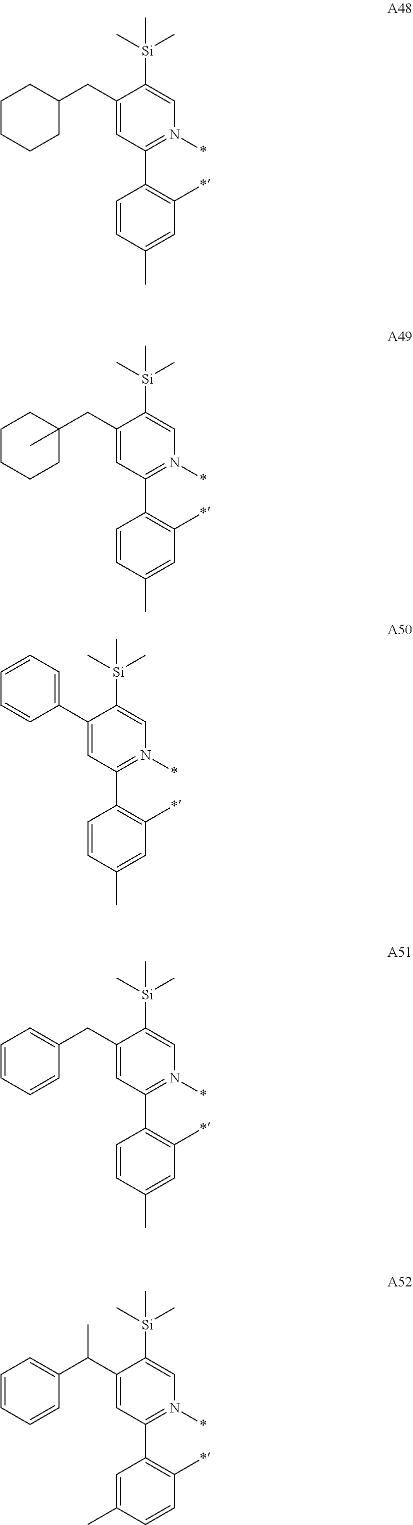

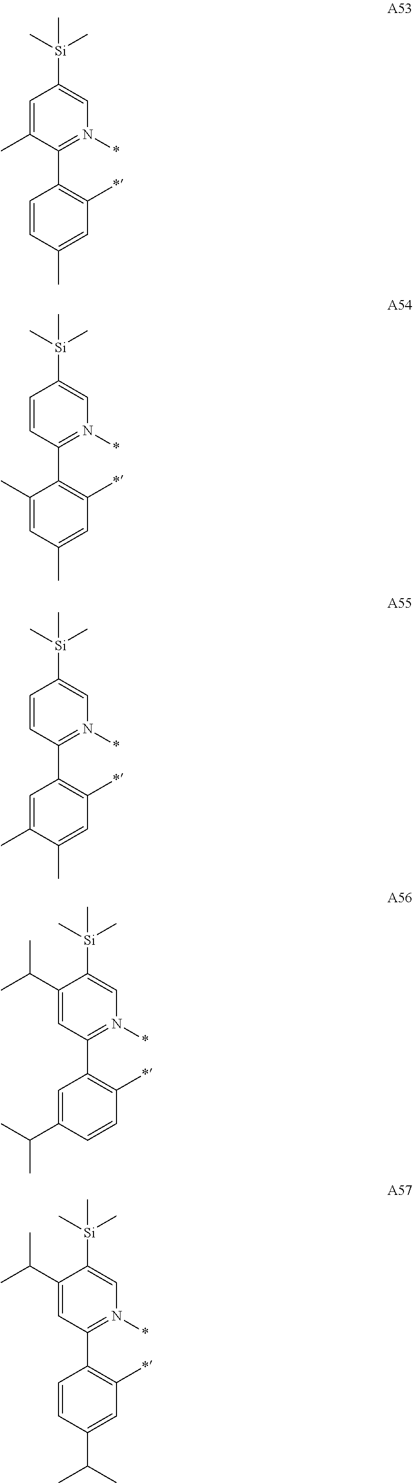

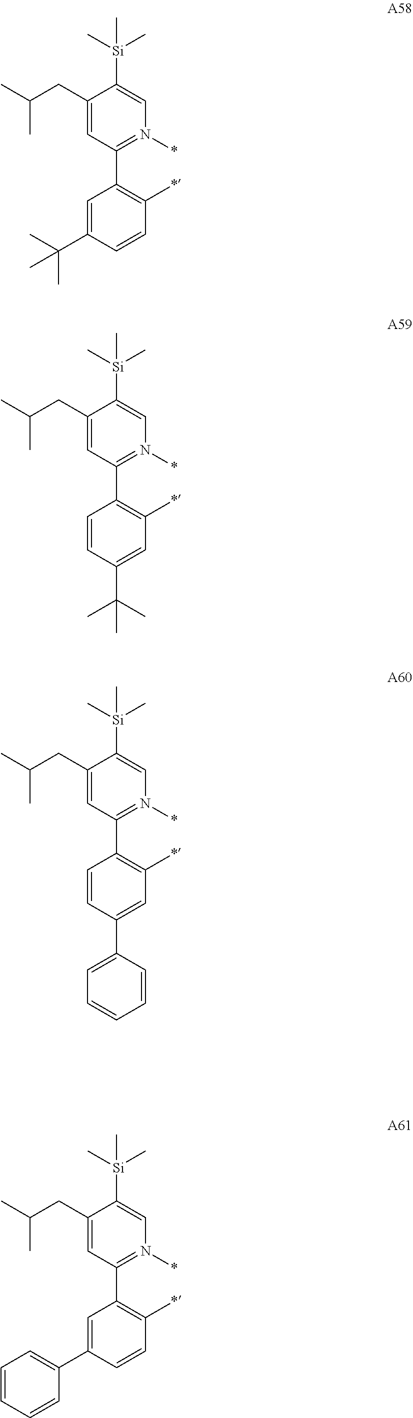

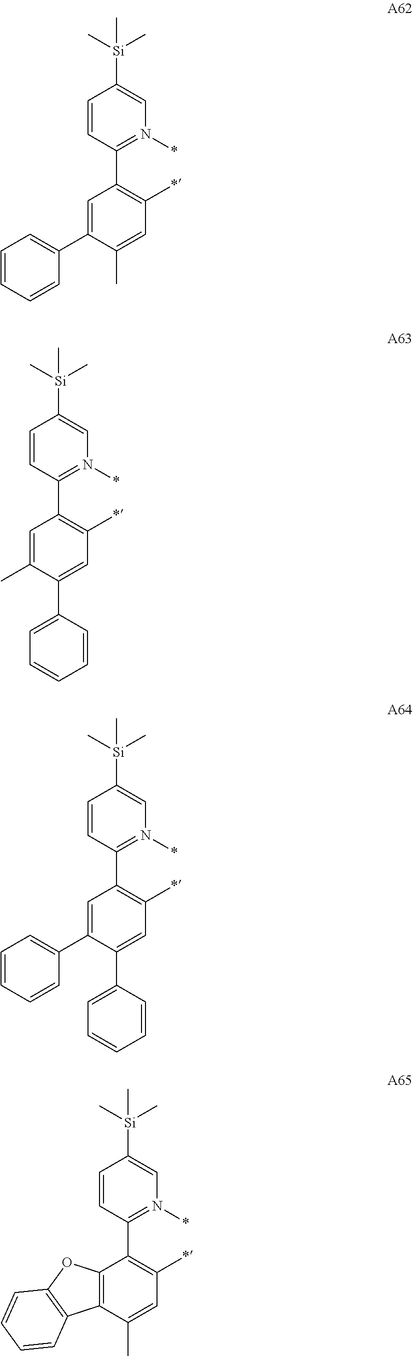

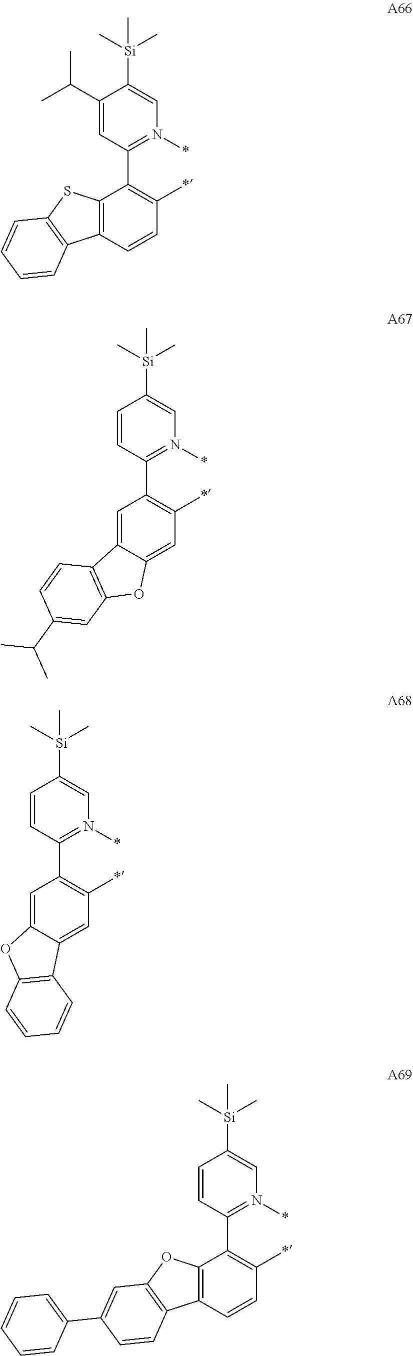

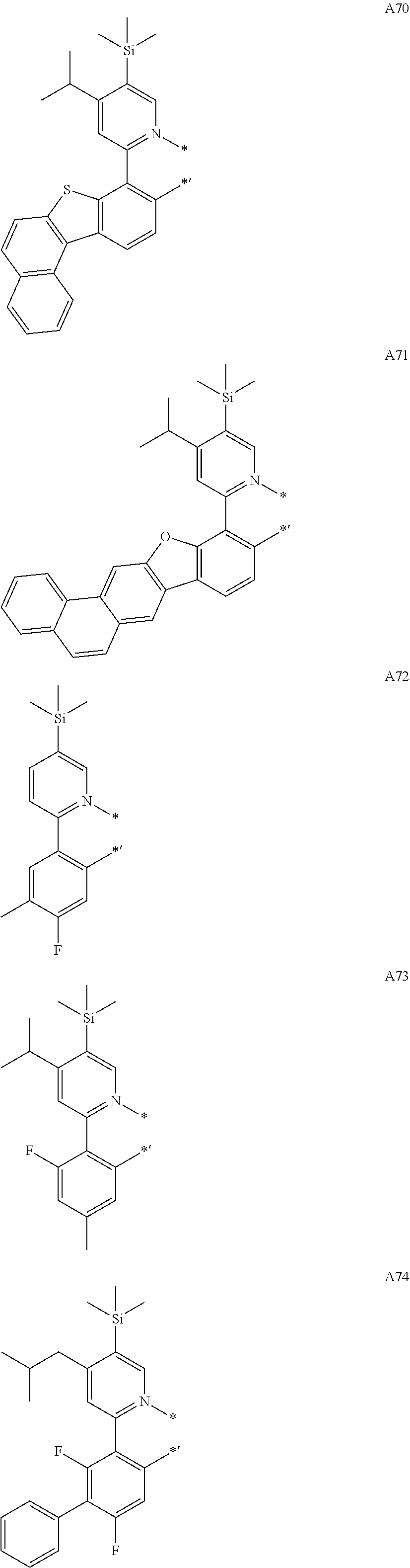

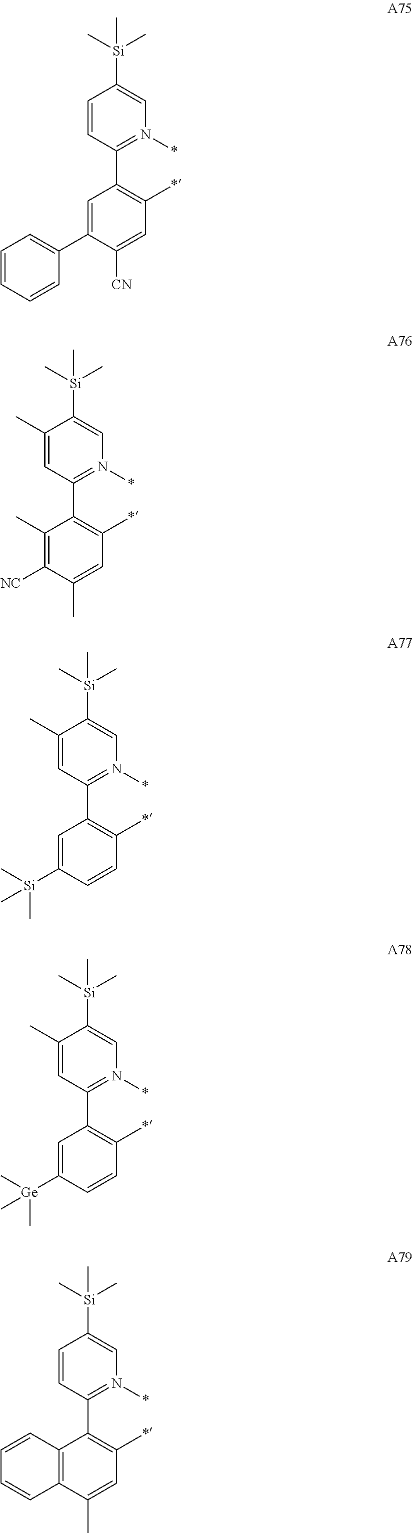

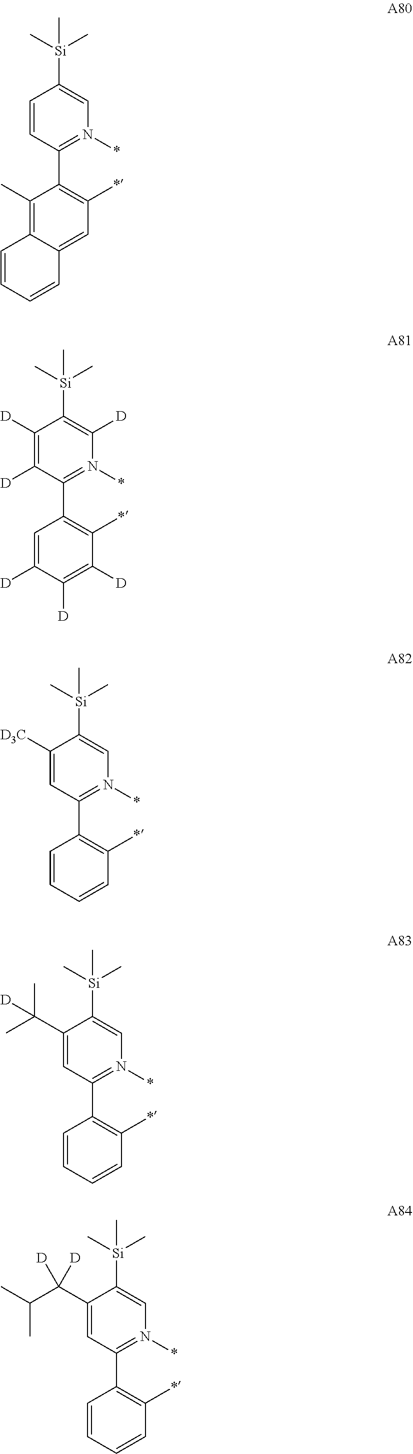

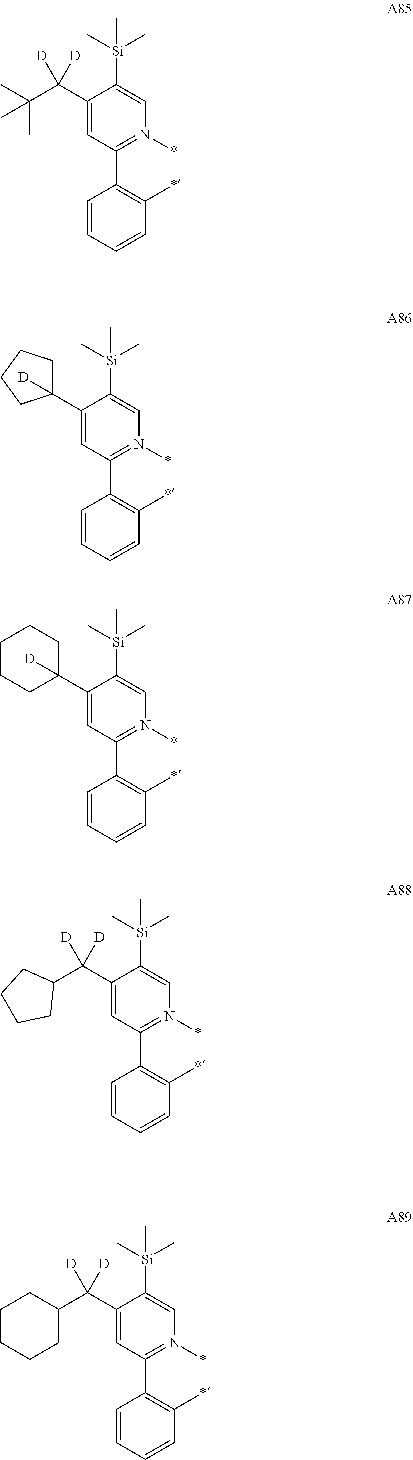

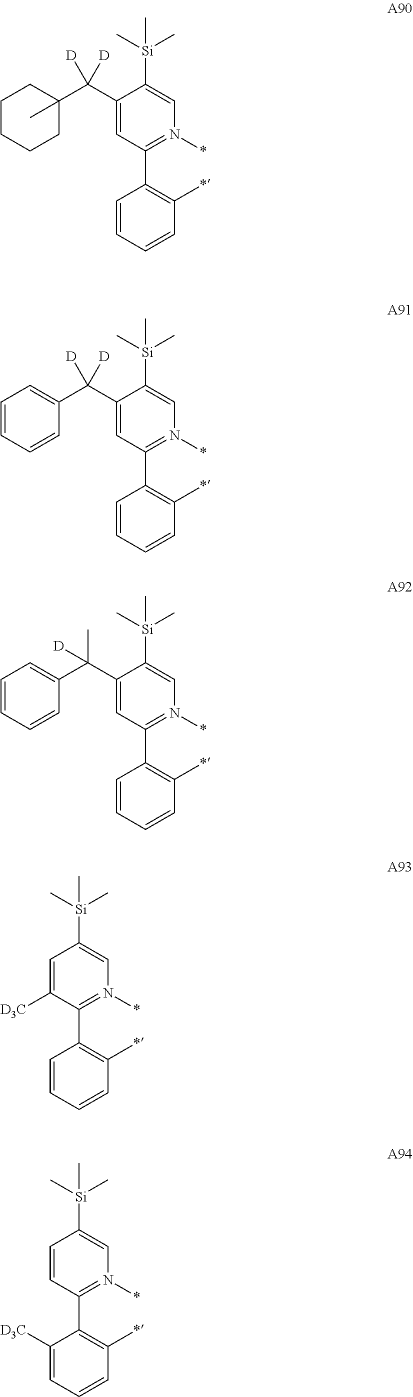

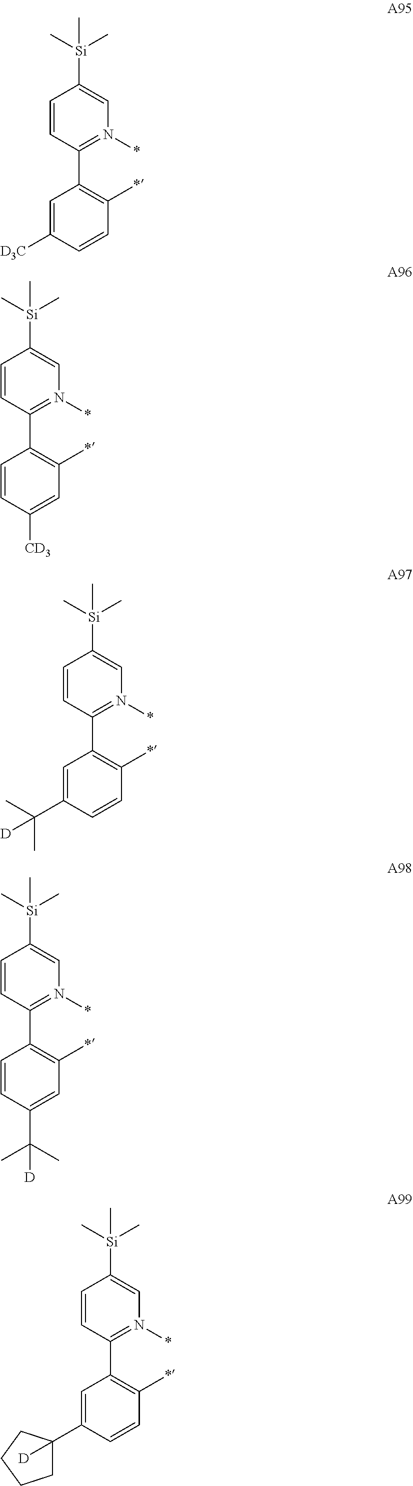

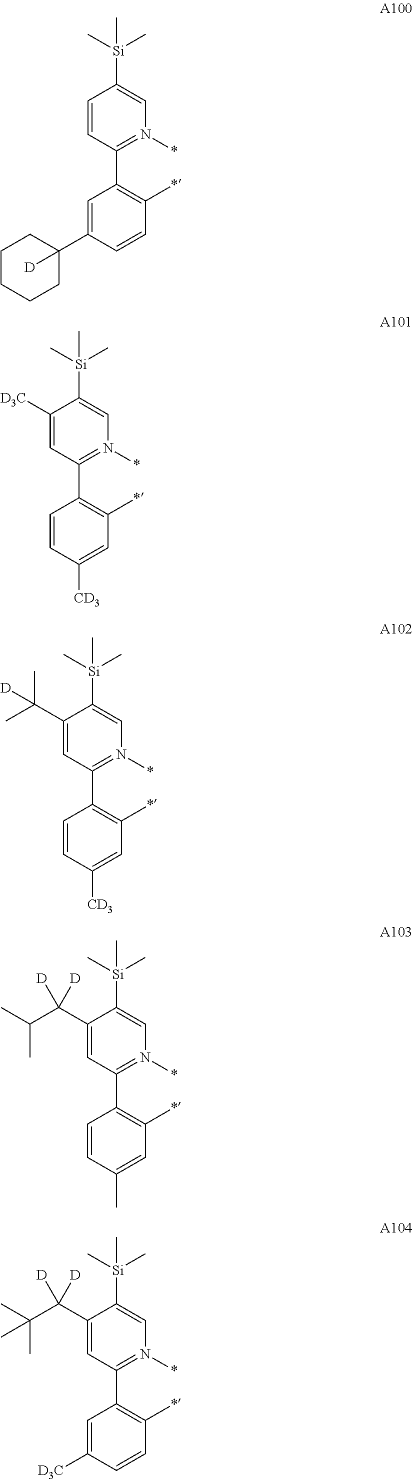

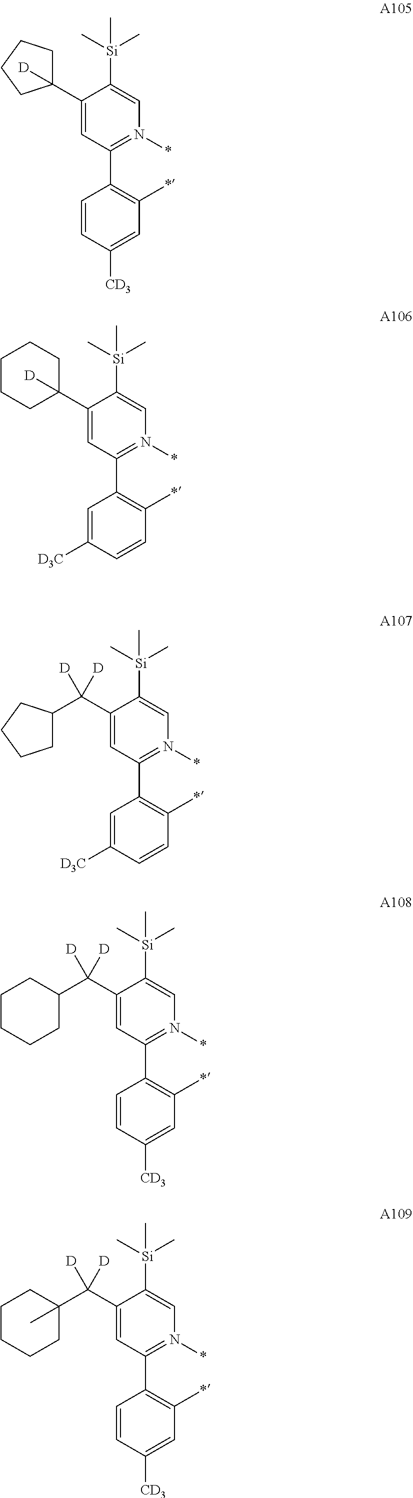

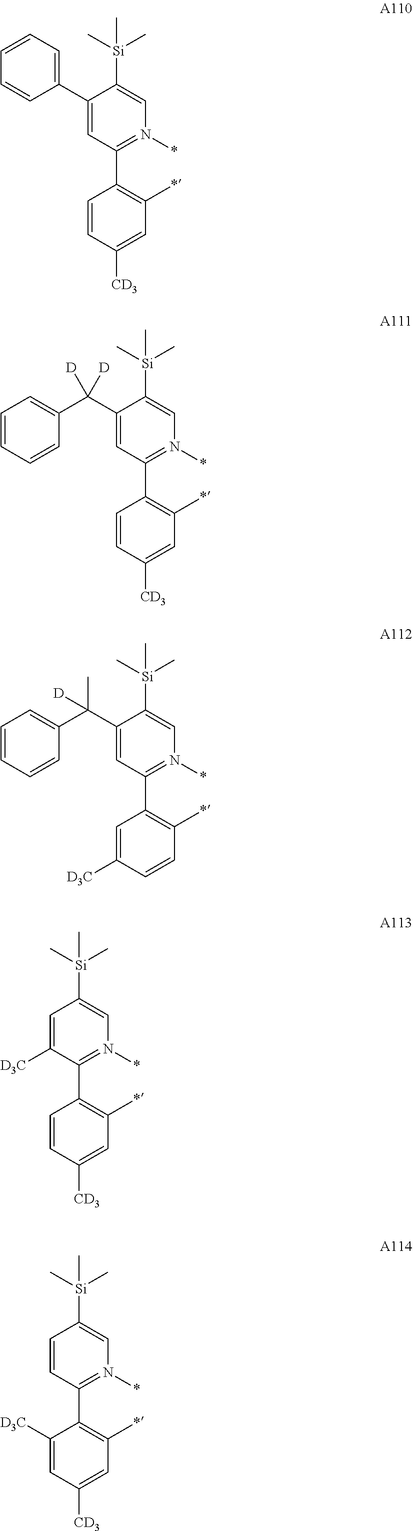

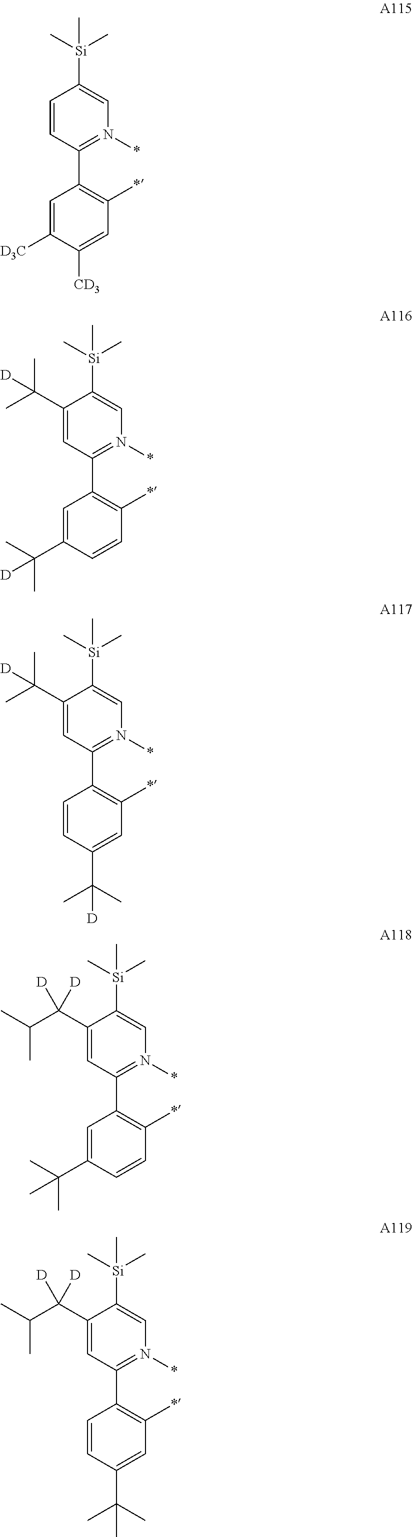

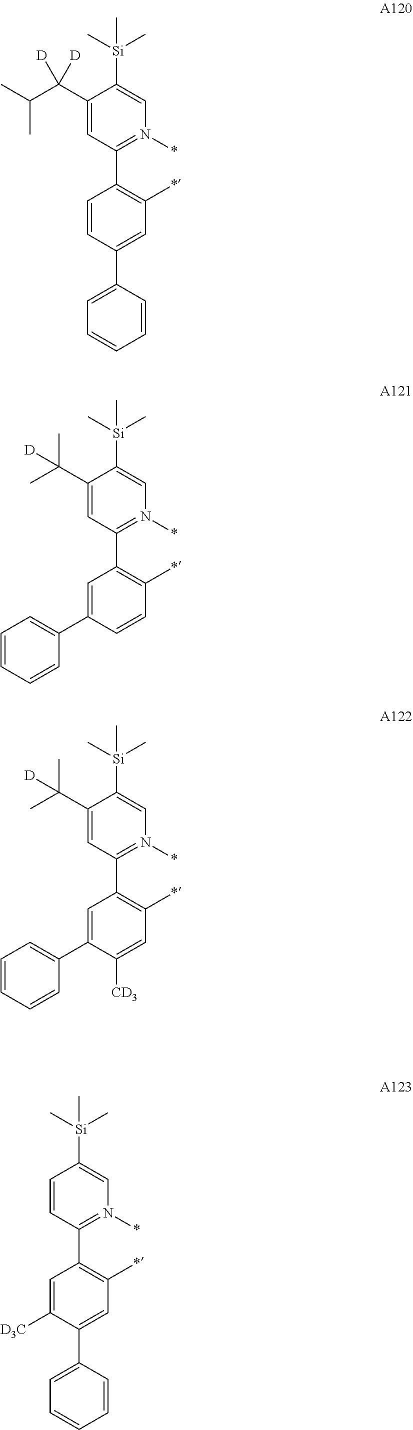

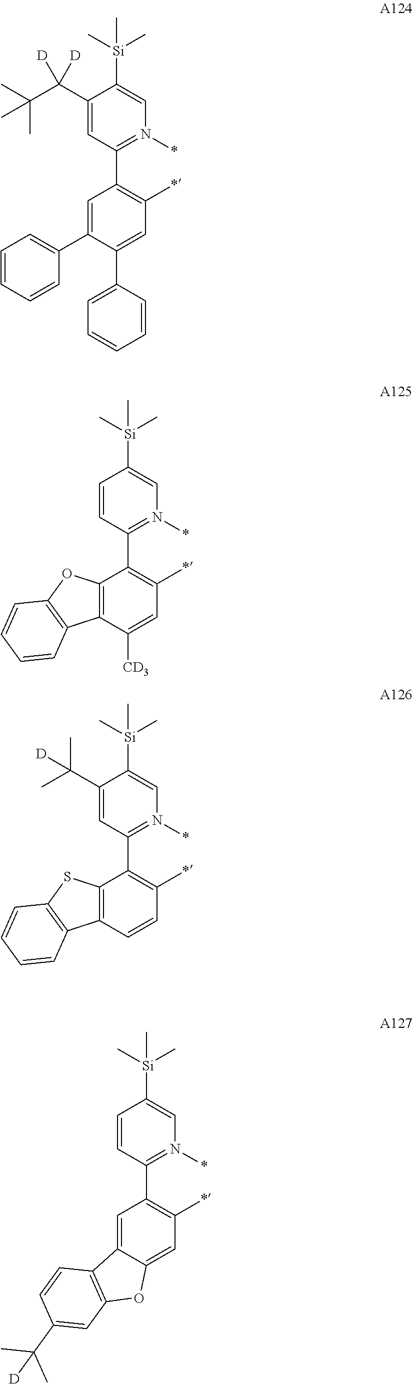

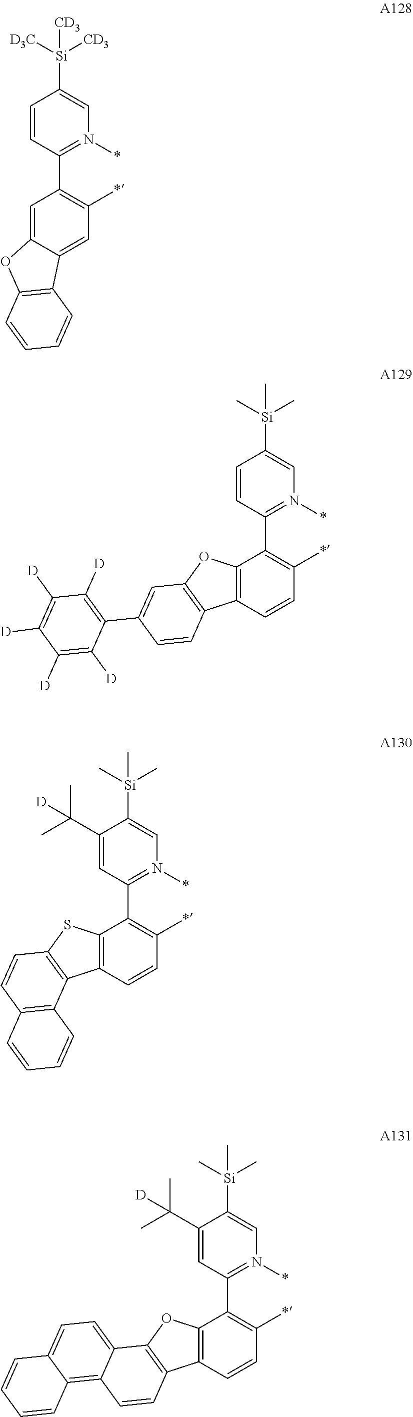

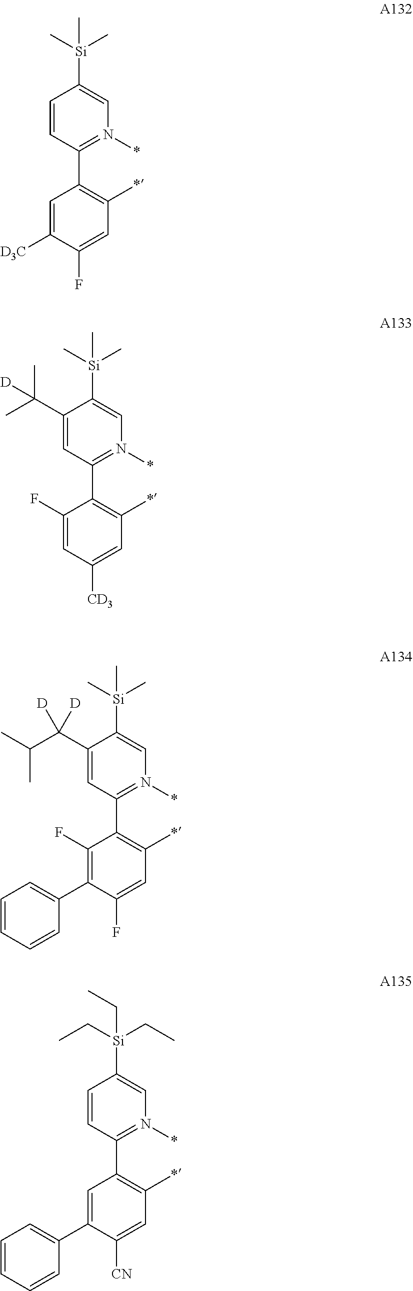

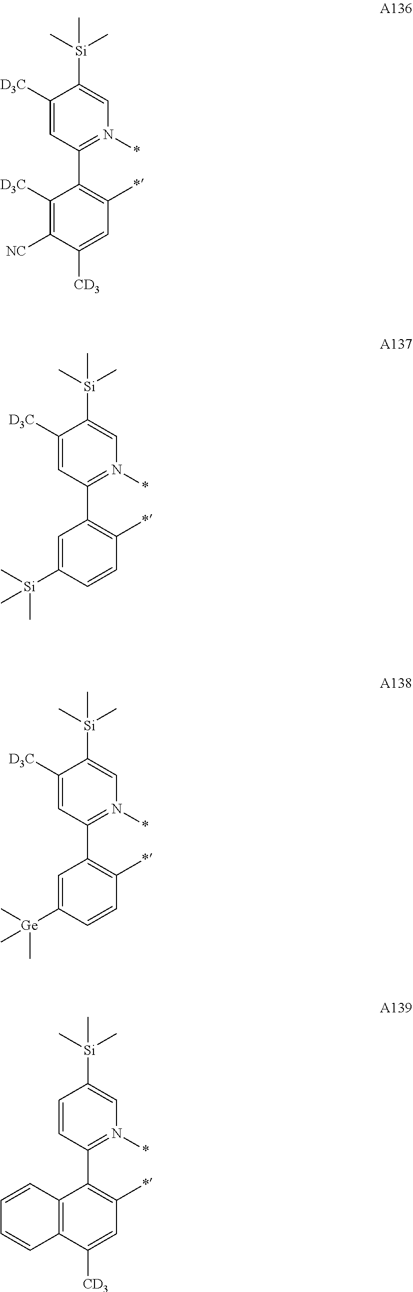

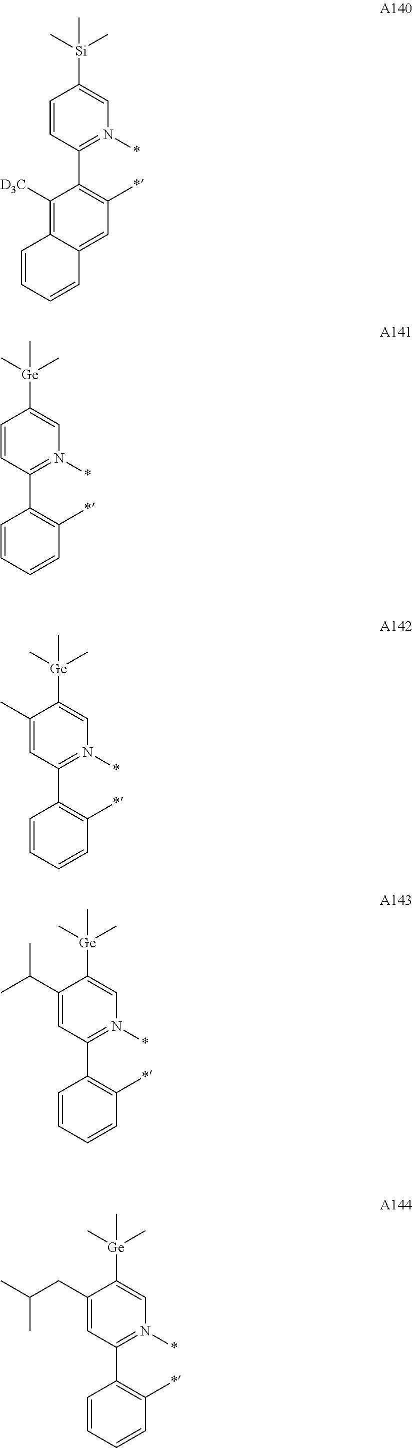

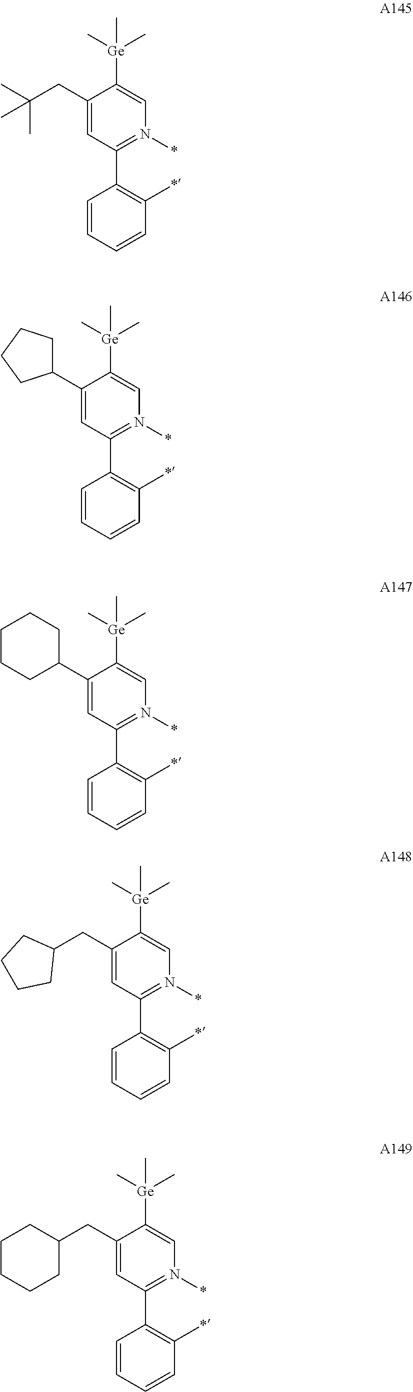

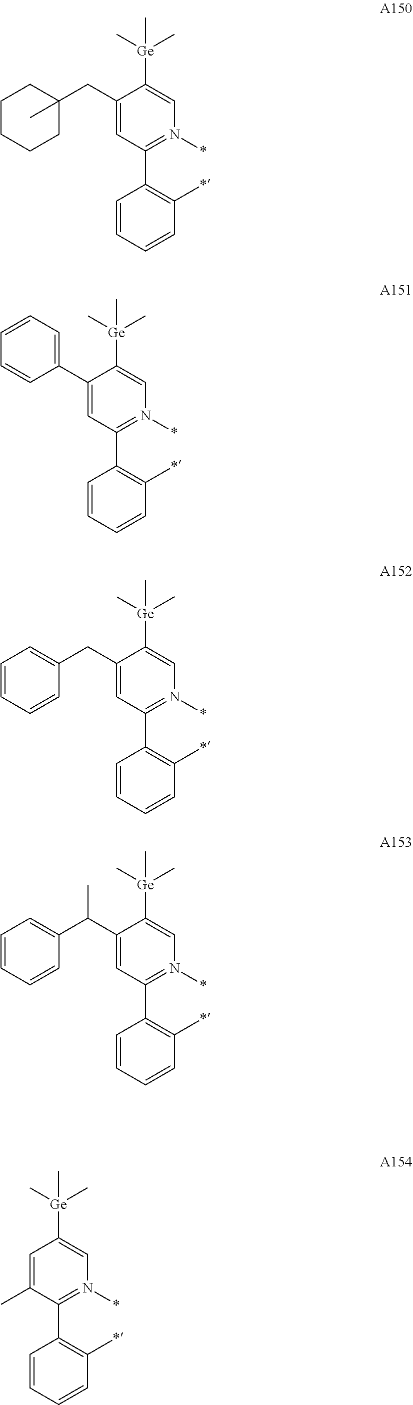

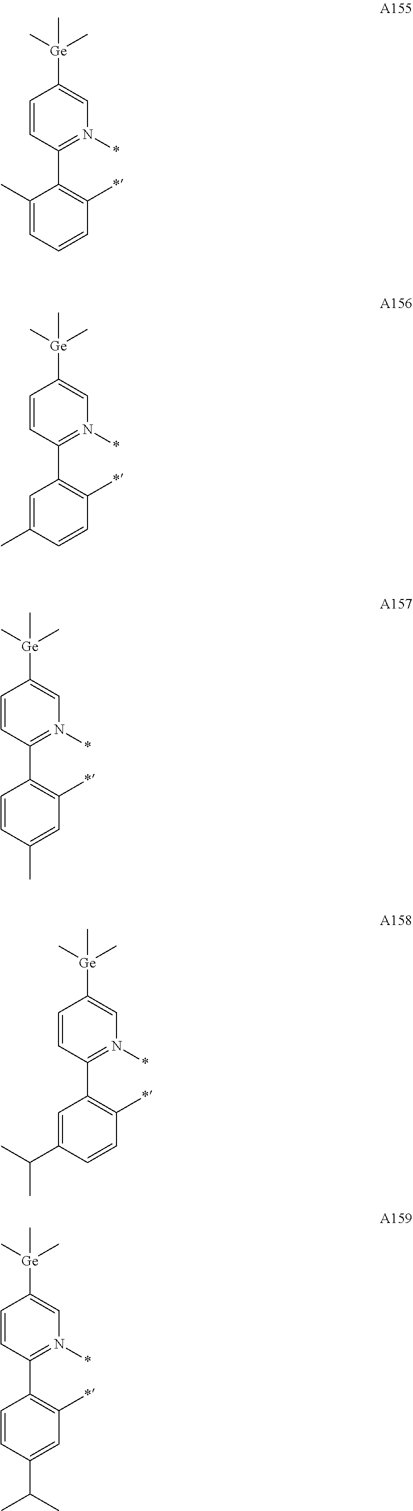

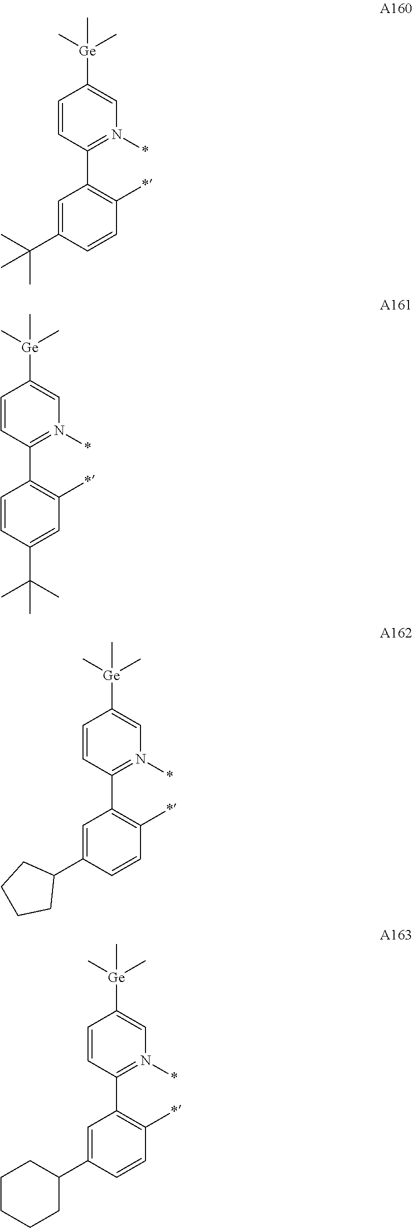

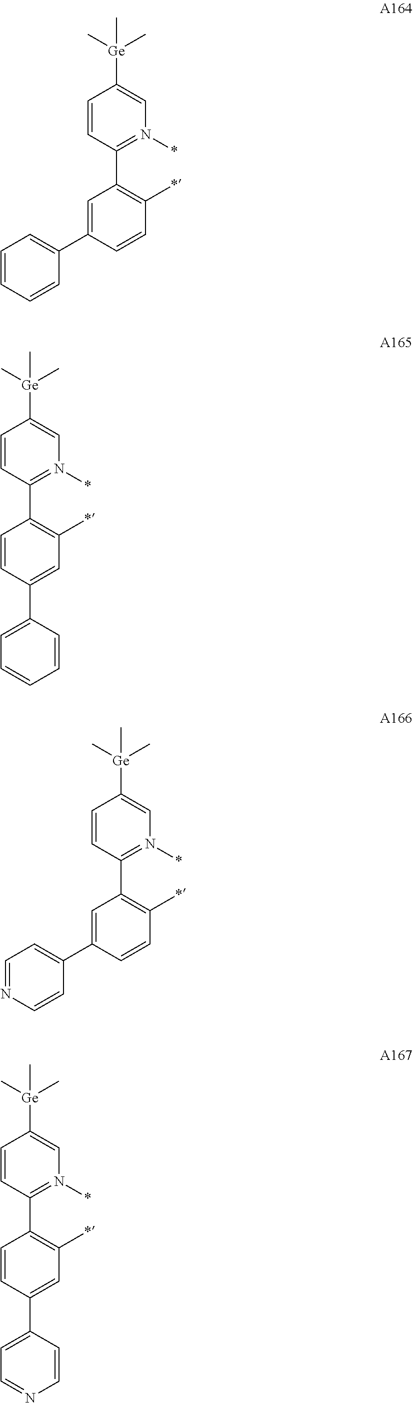

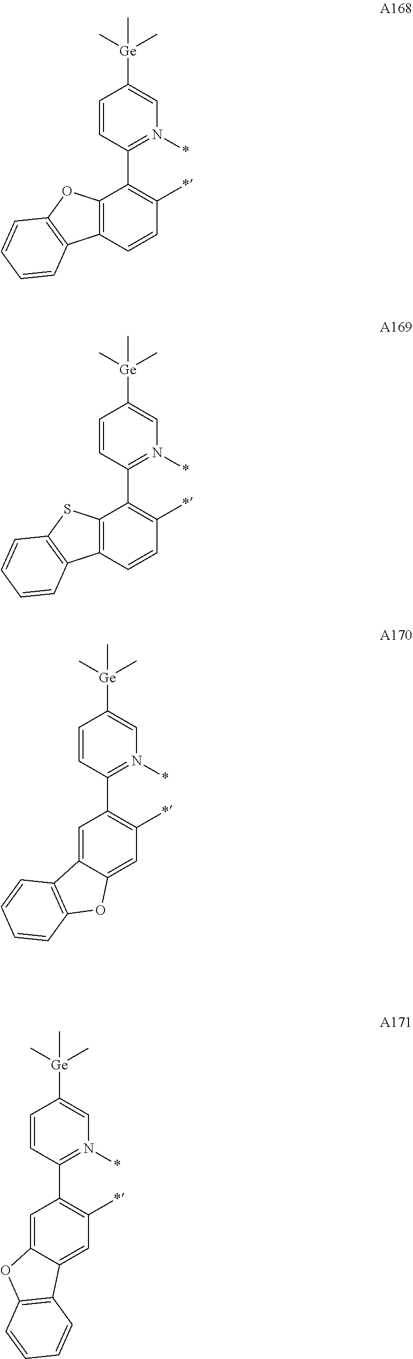

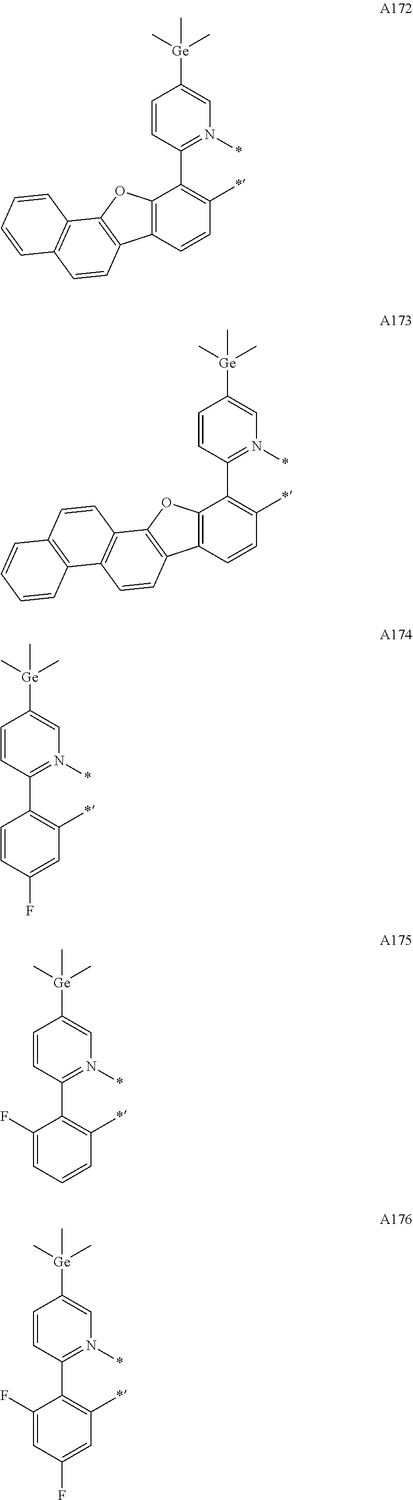

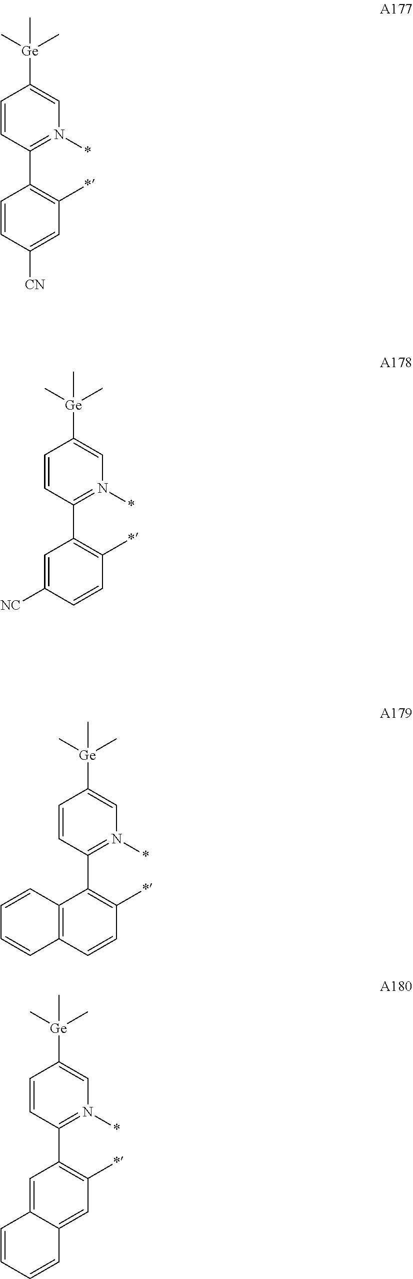

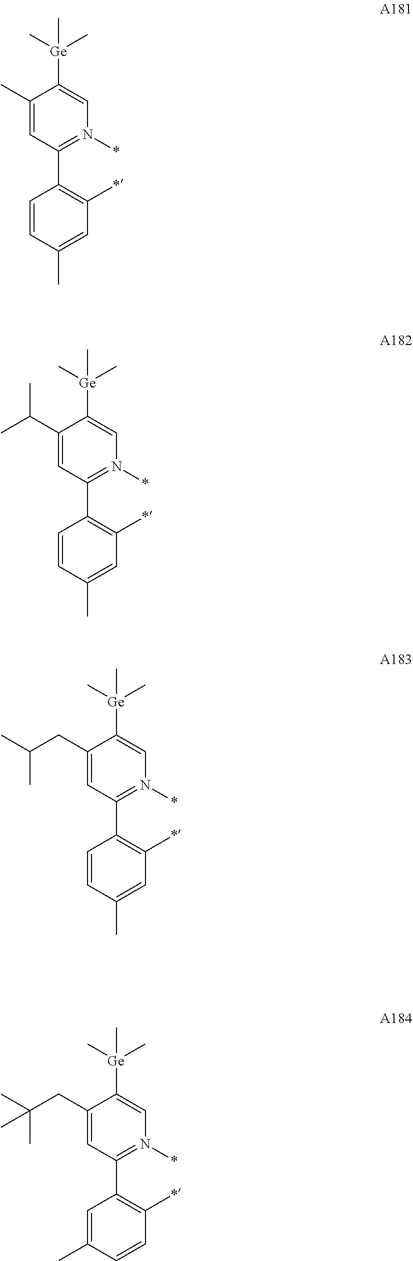

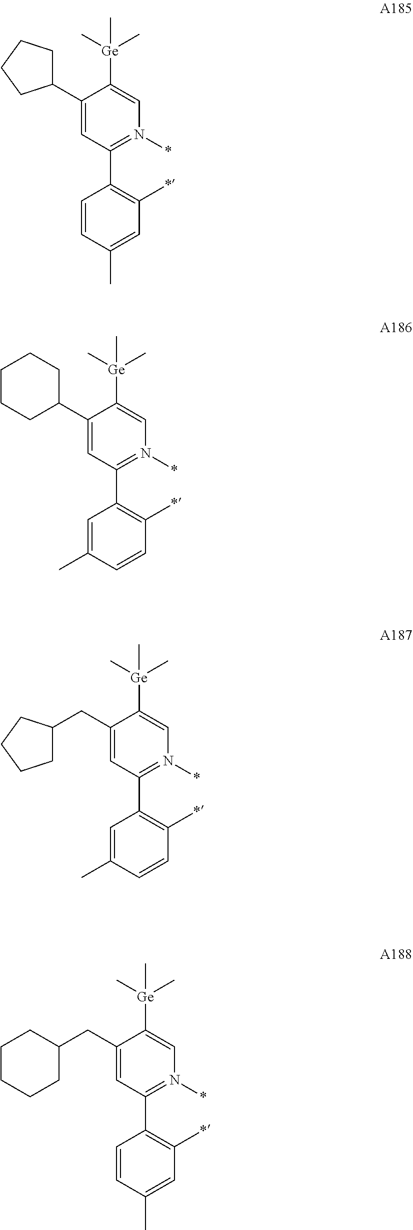

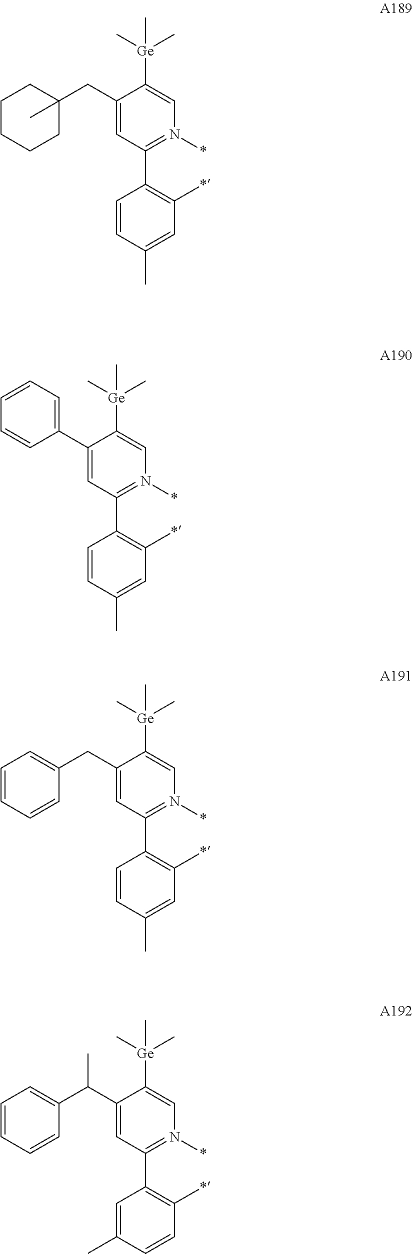

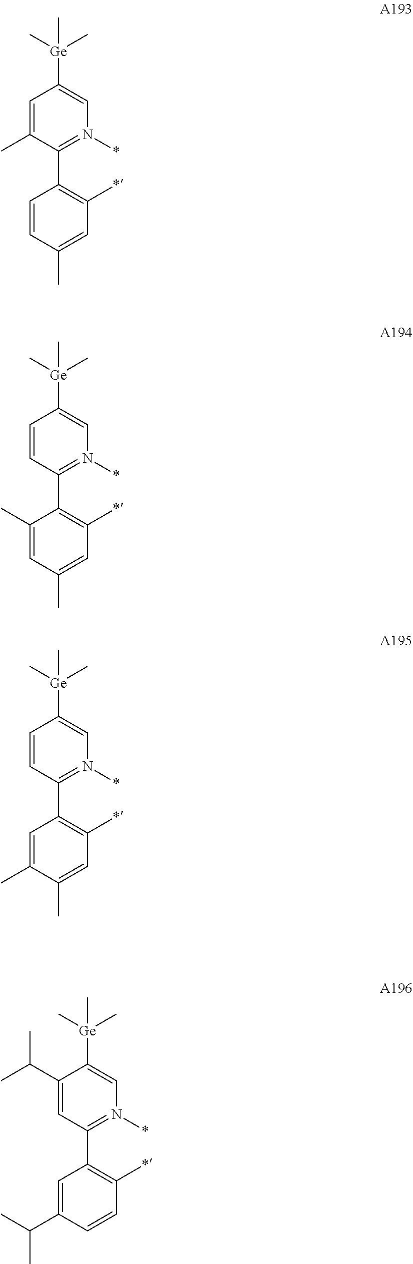

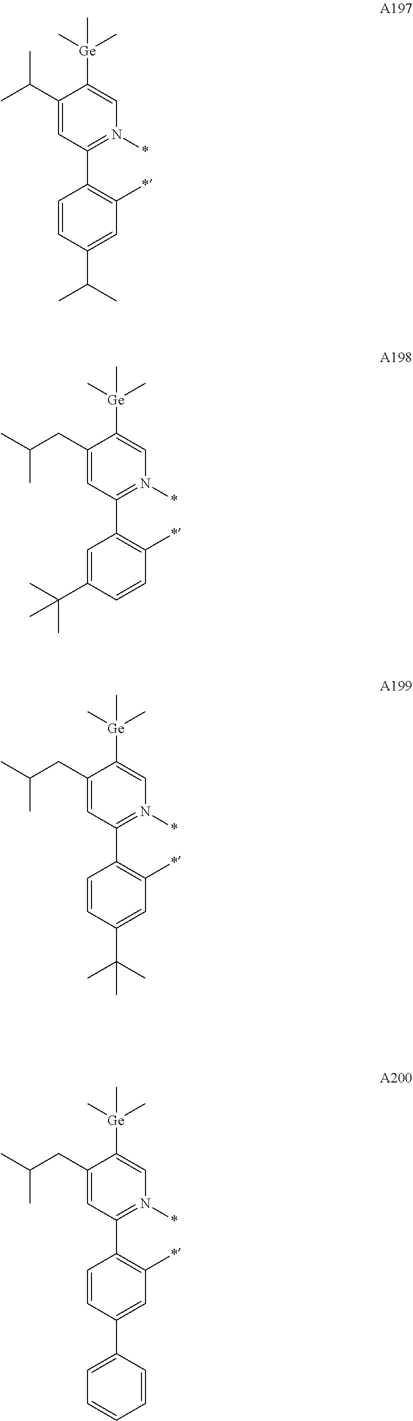

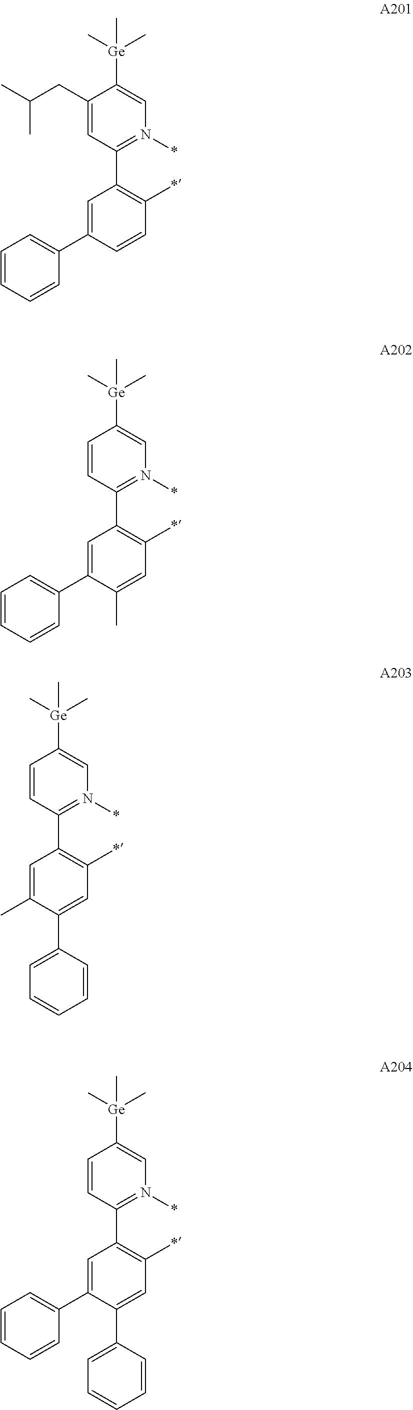

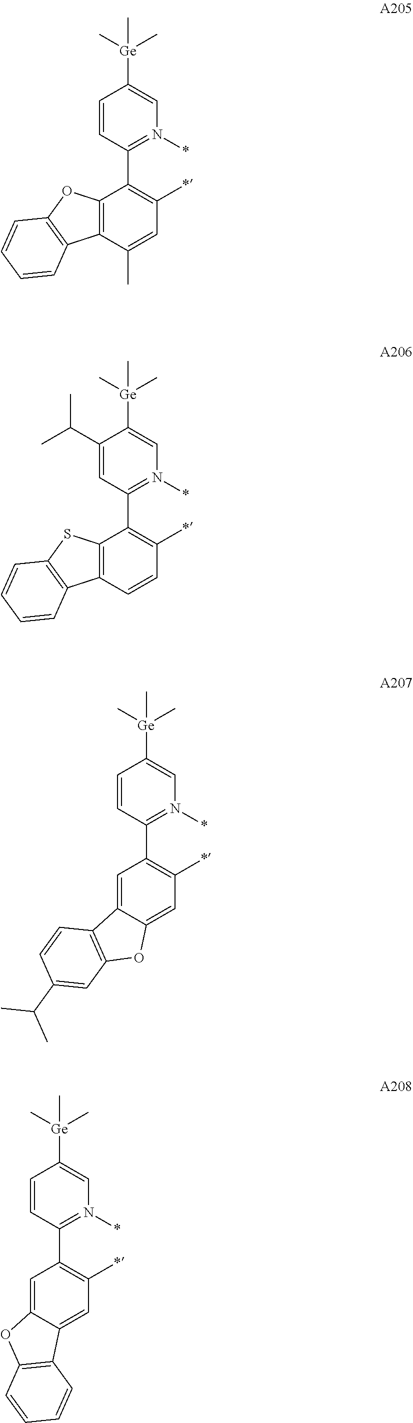

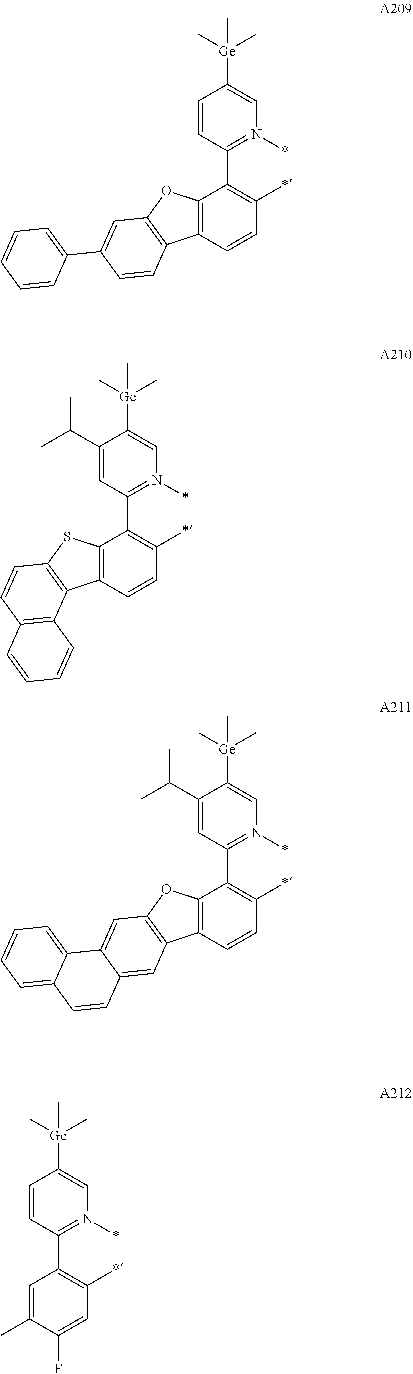

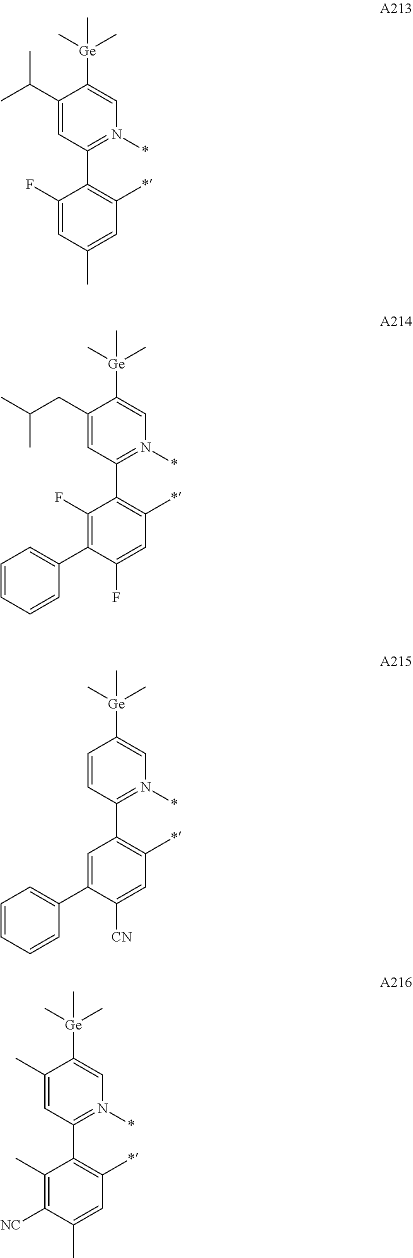

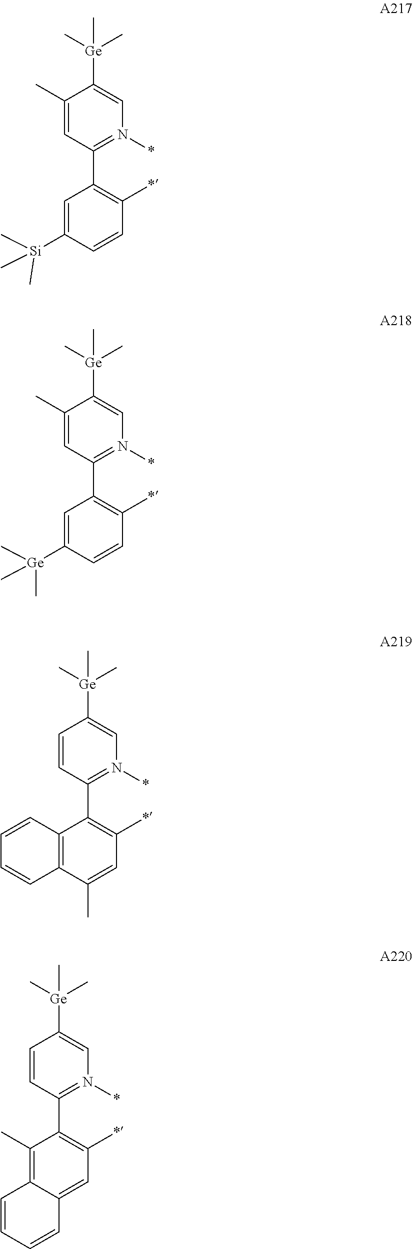

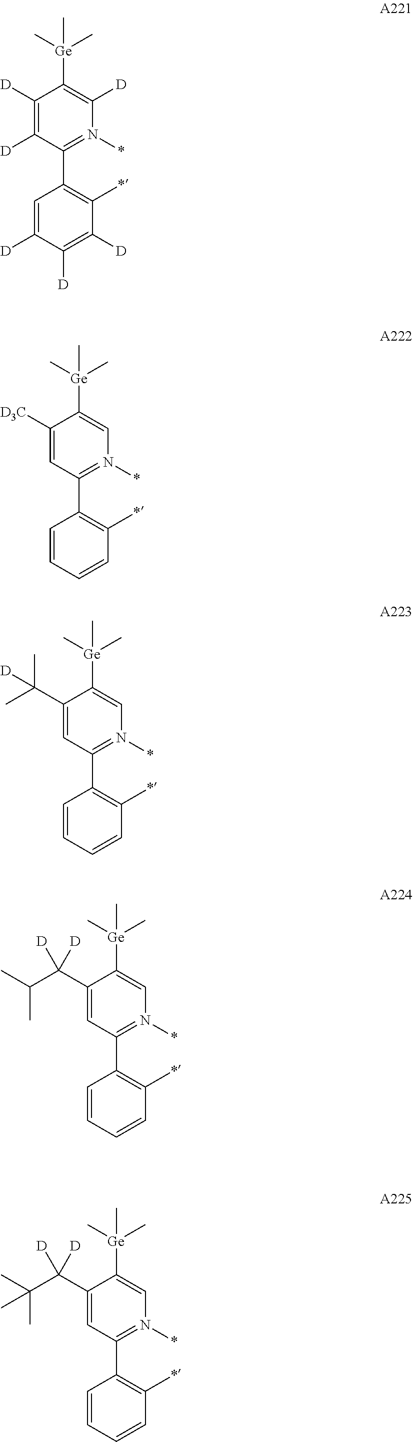

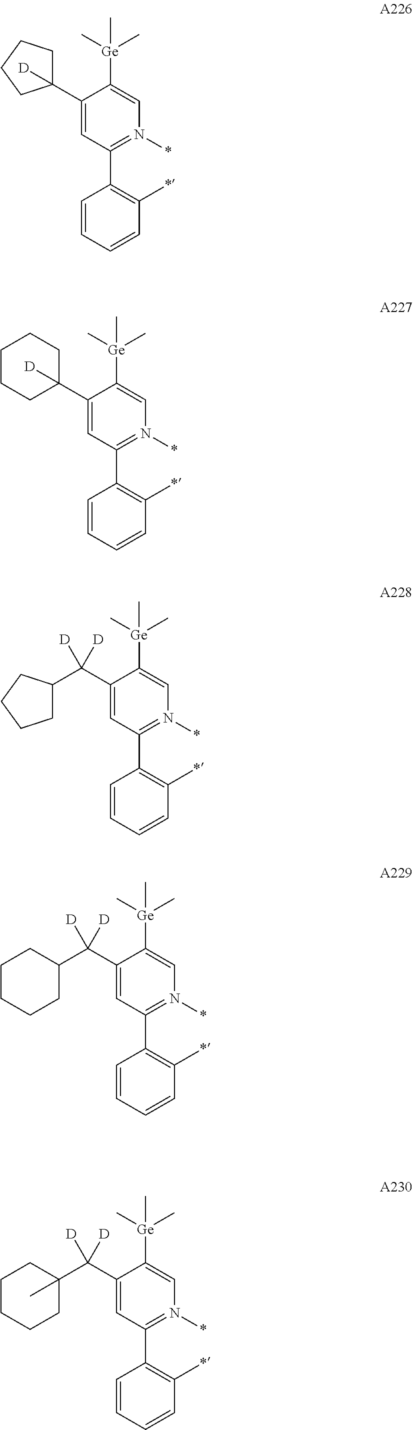

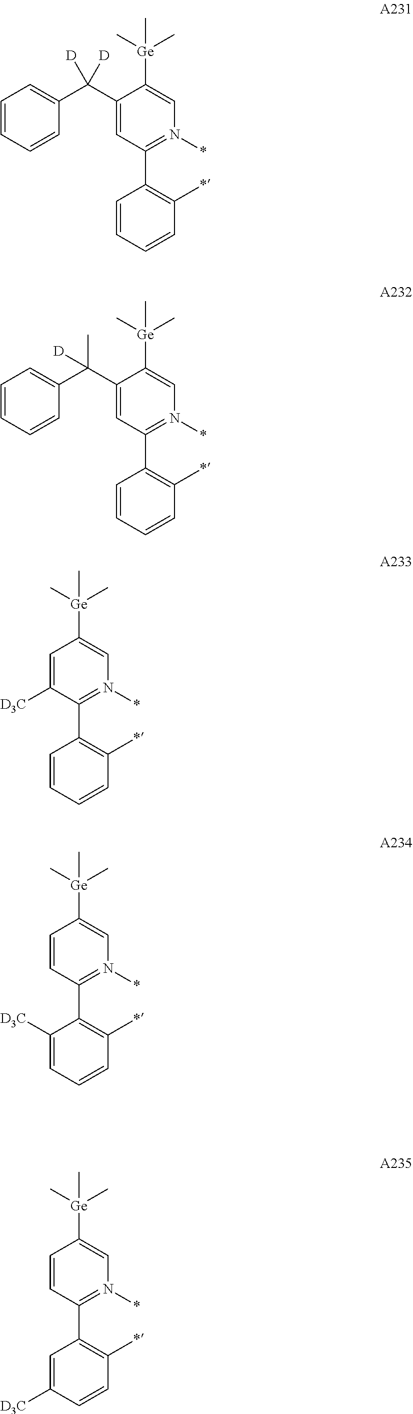

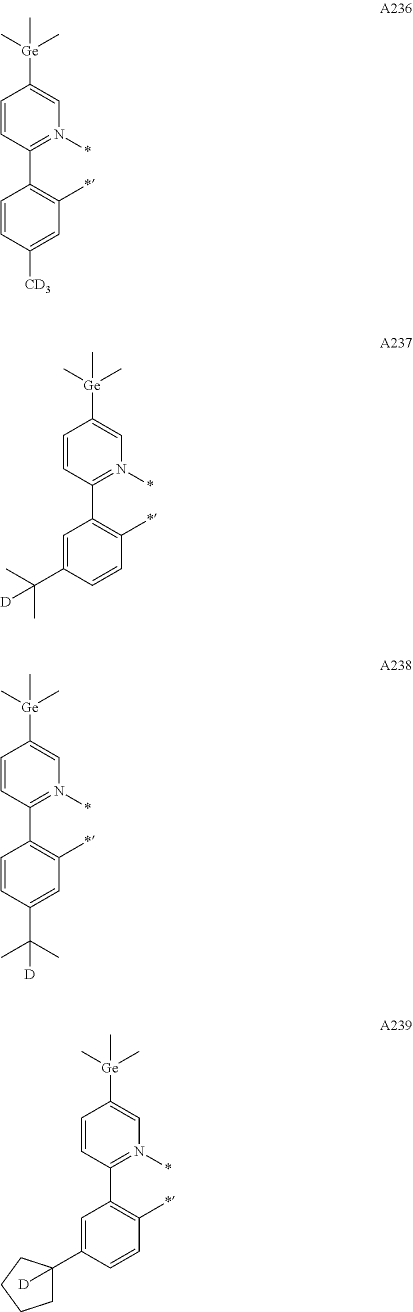

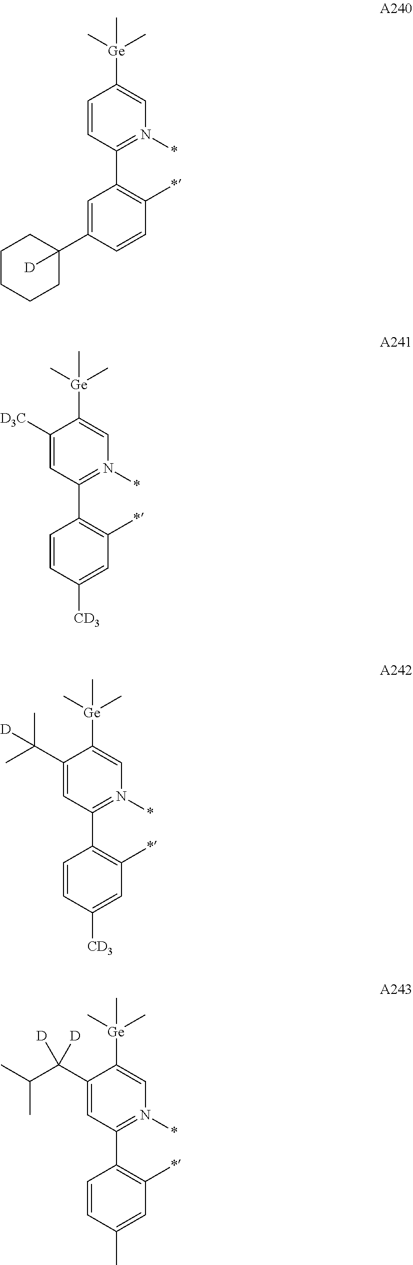

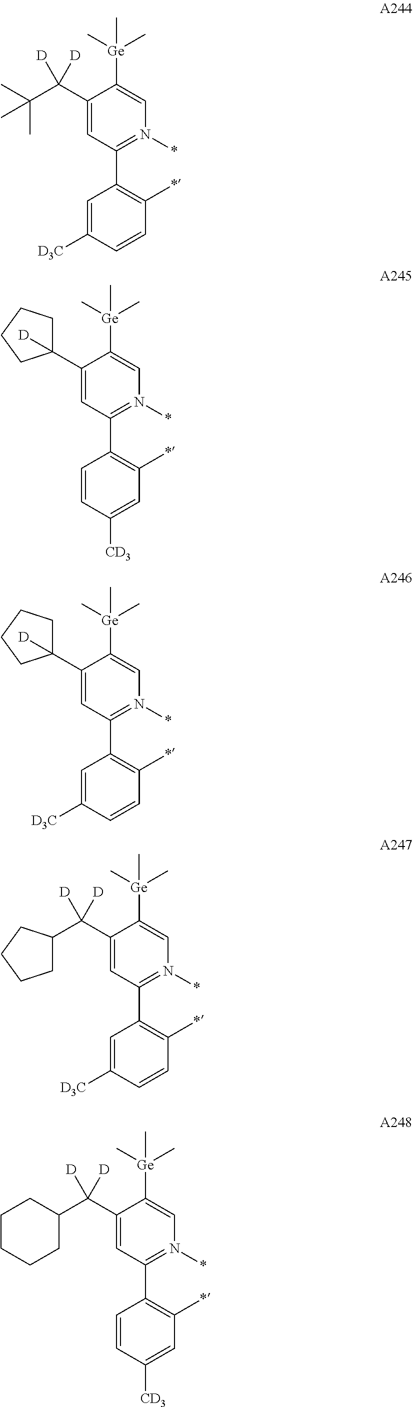

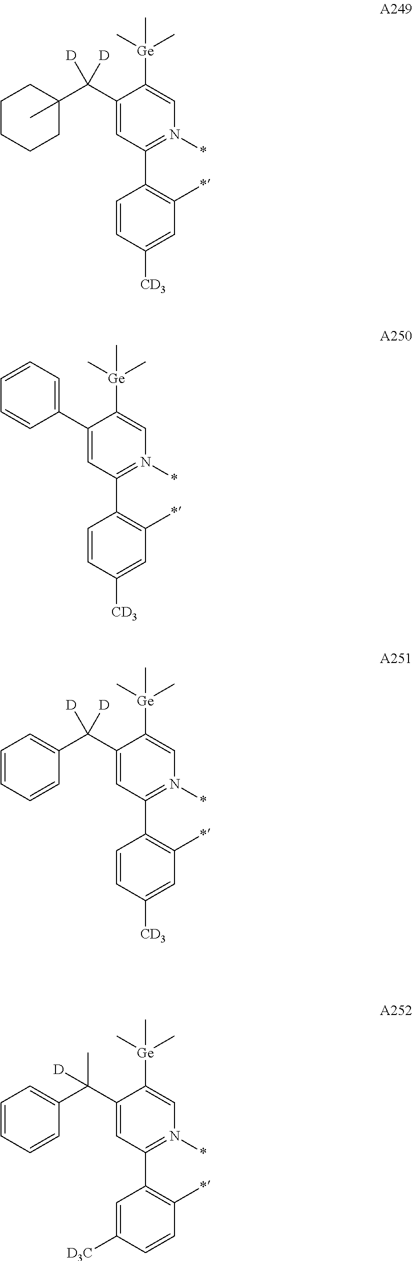

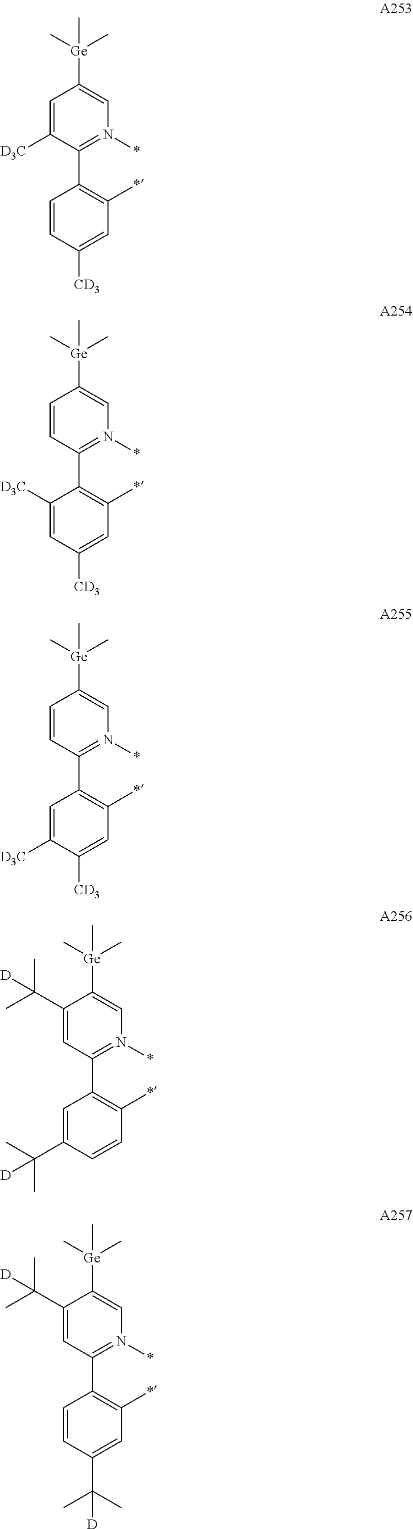

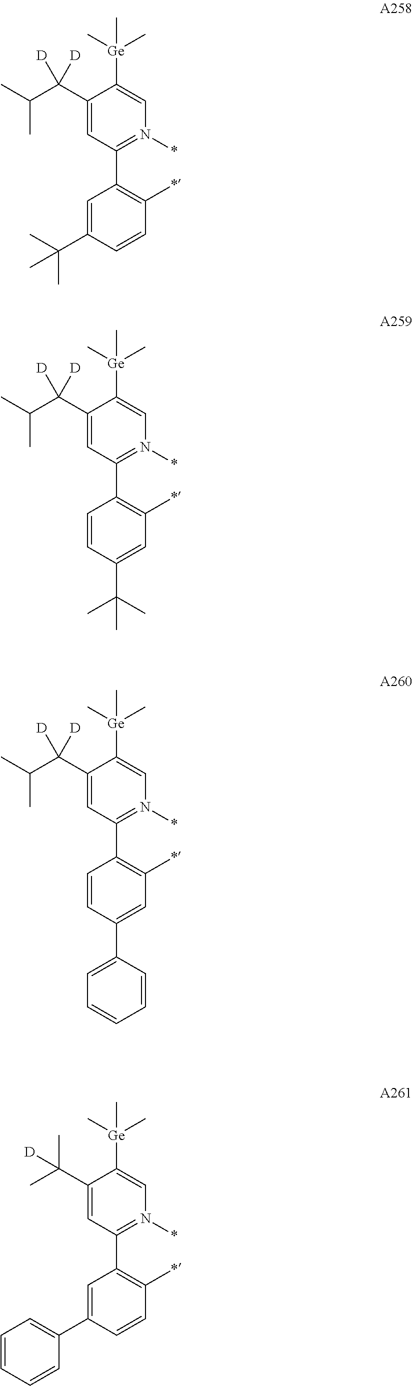

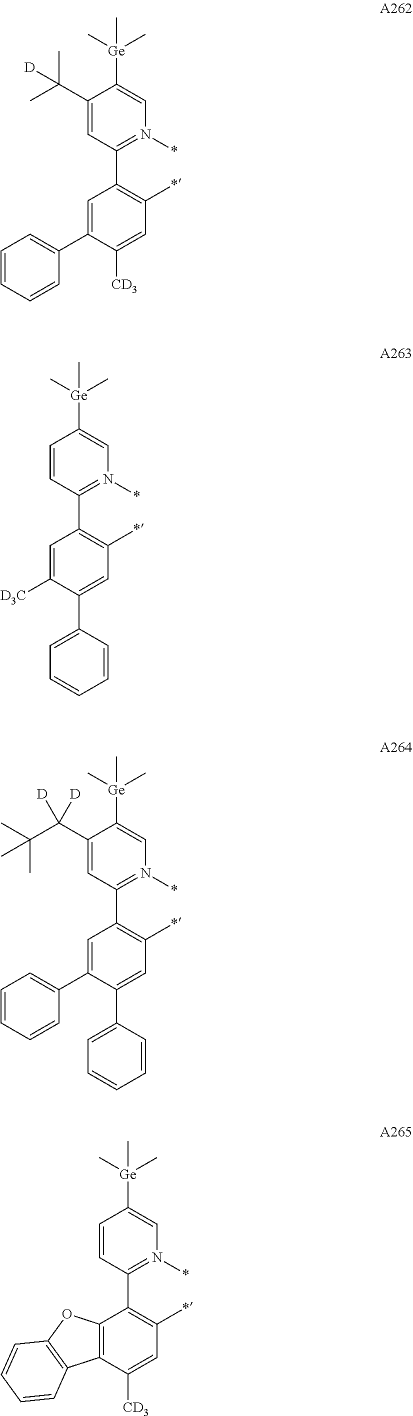

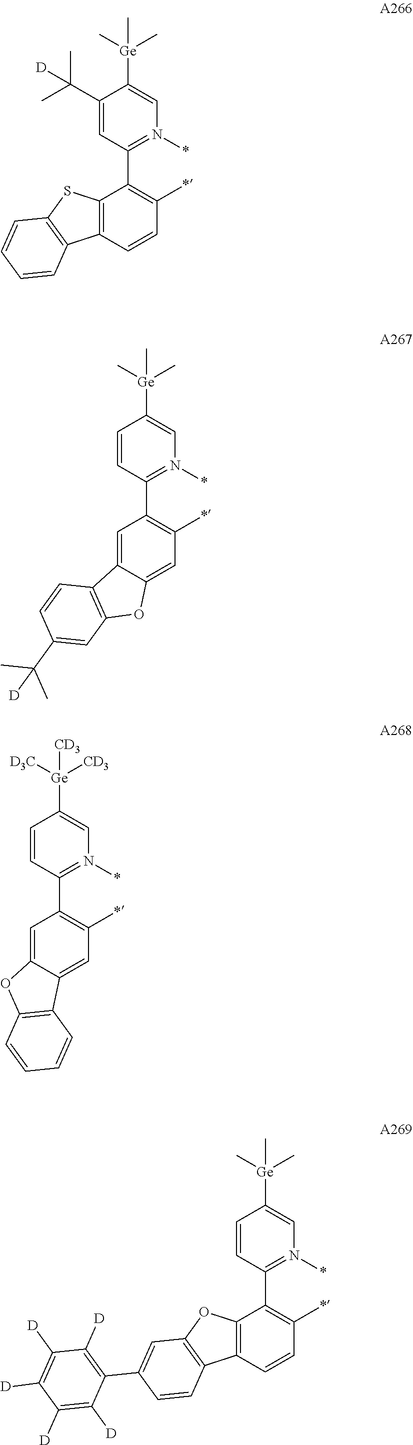

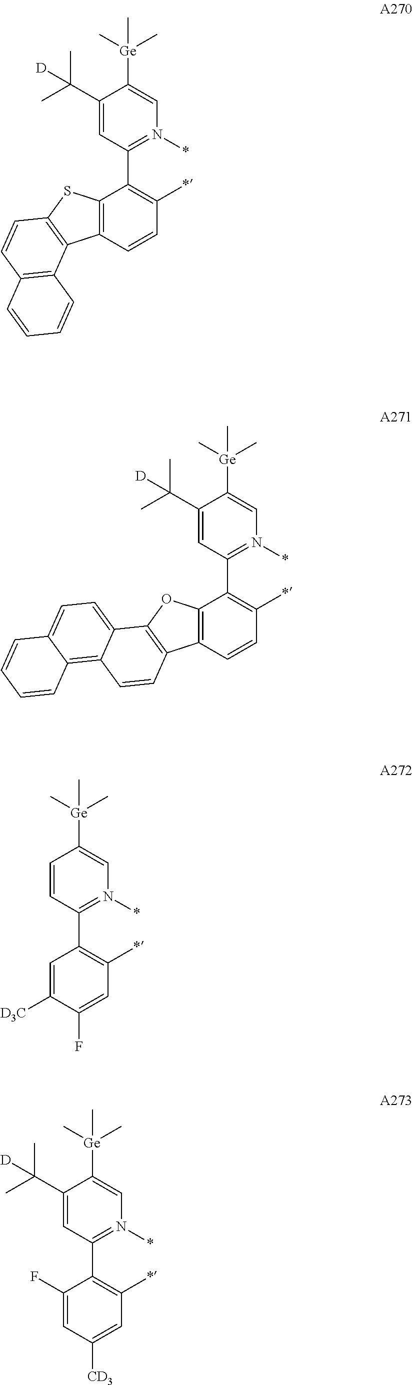

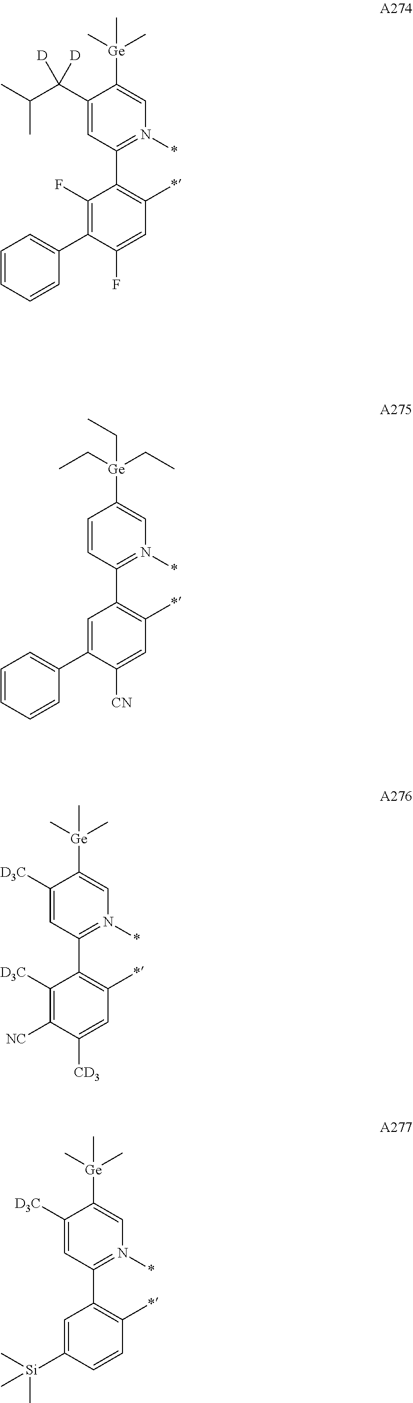

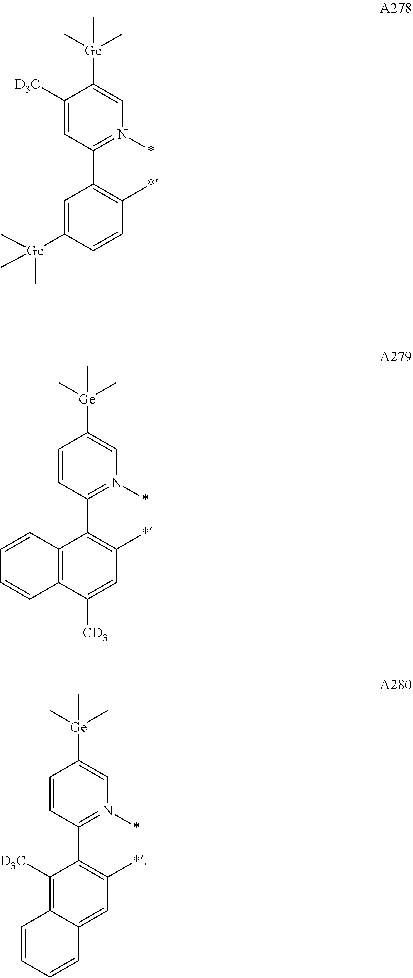

* and *′ in ligands A1 to A280 may each be a binding site M of Formula 1.

In one or more embodiments, the organometallic compound represented by Formula 1 may be one of the compounds listed in Tables 1 to 30.

Each compound listed in Tables 1 to 30 has the corresponding structure listed to the right thereof. <structure> shown in Tables 1 to 30 sequentially includes 1) a ligand L₂ represented by Formula 2B in Formula 1, 2) a group represented by

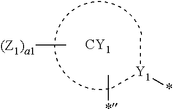

in Formula 2A, and 3) a group represented by

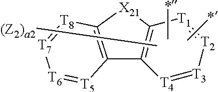

in Formula 2A, thereby defining the structure of a corresponding compound.

For example, referring to Table 2, the <structure> of Compound 141 is A141-B31-C7. That is, Compound 141 include
1) “ligand A141” as the ligand L₂ represented by Formula 2B in Formula 1,

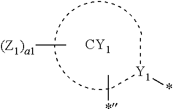

2) “Group B31” as the group represented by in Formula 2A, and
3) “Group C7” as the group represented by

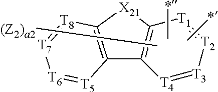

in Formula 2A, and accordingly, may be represented as follows:

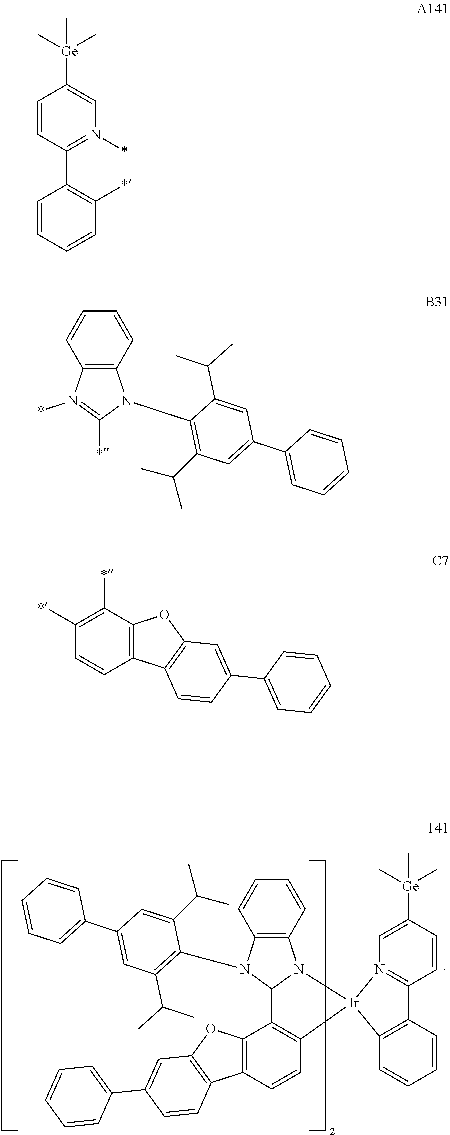

The structures of the other compounds in Tables 1 to 30 may also be understood in the same manner as described above.

TABLE 1

| Compound | <Structure> |
|---|---|
| 1 | A1-B31-C7 |
| 2 | A2-B31-C7 |
| 3 | A3-B31-C7 |
| 4 | A4-B31-C7 |
| 5 | A5-B31-C7 |
| 6 | A6-B31-C7 |
| 7 | A7-B31-C7 |
| 8 | A8-B31-C7 |
| 9 | A9-B31-C7 |
| 10 | A10-B31-C7 |
| 11 | A11-B31-C7 |
| 12 | A12-B31-C7 |
| 13 | A13-B31-C7 |
| 14 | A14-B31-C7 |
| 15 | A15-B31-C7 |
| 16 | A16-B31-C7 |
| 17 | A17-B31-C7 |
| 18 | A18-B31-C7 |
| 19 | A19-B31-C7 |
| 20 | A20-B31-C7 |
| 21 | A21-B31-C7 |
| 22 | A22-B31-C7 |
| 23 | A23-B31-C7 |
| 24 | A24-B31-C7 |
| 25 | A25-B31-C7 |
| 26 | A26-B31-C7 |
| 27 | A27-B31-C7 |
| 28 | A28-B31-C7 |
| 29 | A29-B31-C7 |
| 30 | A30-B31-C7 |
| 31 | A31-B31-C7 |
| 32 | A32-B31-C7 |
| 33 | A33-B31-C7 |
| 34 | A34-B31-C7 |
| 35 | A35-B31-C7 |
| 36 | A36-B31-C7 |
| 37 | A37-B31-C7 |
| 38 | A38-B31-C7 |
| 39 | A39-B31-C7 |
| 40 | A40-B31-C7 |
| 41 | A41-B31-C7 |
| 42 | A42-B31-C7 |
| 43 | A43-B31-C7 |
| 44 | A44-B31-C7 |
| 45 | A45-B31-C7 |
| 46 | A46-B31-C7 |
| 47 | A47-B31-C7 |
| 48 | A48-B31-C7 |
| 49 | A49-B31-C7 |
| 50 | A50-B31-C7 |
| 51 | A51-B31-C7 |
| 52 | A52-B31-C7 |
| 53 | A53-B31-C7 |
| 54 | A54-B31-C7 |
| 55 | A55-B31-C7 |
| 56 | A56-B31-C7 |
| 57 | A57-B31-C7 |
| 58 | A58-B31-C7 |
| 59 | A59-B31-C7 |
| 60 | A60-B31-C7 |
| 61 | A61-B31-C7 |
| 62 | A62-B31-C7 |
| 63 | A63-B31-C7 |
| 64 | A64-B31-C7 |
| 65 | A65-B31-C7 |
| 66 | A66-B31-C7 |
| 67 | A67-B31-C7 |
| 68 | A68-B31-C7 |
| 69 | A69-B31-C7 |
| 70 | A70-B31-C7 |
| 71 | A71-B31-C7 |
| 72 | A72-B31-C7 |
| 73 | A73-B31-C7 |
| 74 | A74-B31-C7 |
| 75 | A75-B31-C7 |
| 76 | A76-B31-C7 |
| 77 | A77-B31-C7 |
| 78 | A78-B31-C7 |
| 79 | A79-B31-C7 |
| 80 | A80-B31-C7 |
| 81 | A81-B31-C7 |
| 82 | A82-B31-C7 |
| 83 | A83-B31-C7 |
| 84 | A84-B31-C7 |
| 85 | A85-B31-C7 |
| 86 | A86-B31-C7 |
| 87 | A87-B31-C7 |
| 88 | A88-B31-C7 |
| 89 | A89-B31-C7 |
| 90 | A90-B31-C7 |
| 91 | A91-B31-C7 |
| 92 | A92-B31-C7 |
| 93 | A93-B31-C7 |
| 94 | A94-B31-C7 |
| 95 | A95-B31-C7 |
| 96 | A96-B31-C7 |
| 97 | A97-B31-C7 |
| 98 | A98-B31-C7 |
| 99 | A99-B31-C7 |
| 100 | A100-B31-C7 |

TABLE 2

| Compound | <Structure> |
|---|---|
| 101 | A101-B31-C7 |
| 102 | A102-B31-C7 |
| 103 | A103-B31-C7 |
| 104 | A104-B31-C7 |
| 105 | A105-B31-C7 |
| 106 | A106-B31-C7 |
| 107 | A107-B31-C7 |
| 108 | A108-B31-C7 |
| 109 | A109-B31-C7 |
| 110 | A110-B31-C7 |
| 111 | A111-B31-C7 |
| 112 | A112-B31-C7 |
| 113 | A113-B31-C7 |
| 114 | A114-B31-C7 |
| 115 | A115-B31-C7 |
| 116 | A116-B31-C7 |
| 117 | A117-B31-C7 |
| 118 | A118-B31-C7 |
| 119 | A119-B31-C7 |
| 120 | A120-B31-C7 |
| 121 | A121-B31-C7 |
| 122 | A122-B31-C7 |
| 123 | A123-B31-C7 |
| 124 | A124-B31-C7 |
| 125 | A125-B31-C7 |
| 126 | A126-B31-C7 |
| 127 | A127-B31-C7 |
| 128 | A128-B31-C7 |
| 129 | A129-B31-C7 |
| 130 | A130-B31-C7 |
| 131 | A131-B31-C7 |
| 132 | A132-B31-C7 |
| 133 | A133-B31-C7 |
| 134 | A134-B31-C7 |
| 135 | A135-B31-C7 |
| 136 | A136-B31-C7 |
| 137 | A137-B31-C7 |
| 138 | A138-B31-C7 |
| 139 | A139-B31-C7 |
| 140 | A140-B31-C7 |
| 141 | A141-B31-C7 |
| 142 | A142-B31-C7 |
| 143 | A143-B31-C7 |
| 144 | A144-B31-C7 |
| 145 | A145-B31-C7 |
| 146 | A146-B31-C7 |
| 147 | A147-B31-C7 |
| 148 | A148-B31-C7 |
| 149 | A149-B31-C7 |
| 150 | A150-B31-C7 |
| 151 | A151-B31-C7 |
| 152 | A152-B31-C7 |
| 153 | A153-B31-C7 |
| 154 | A154-B31-C7 |
| 155 | A155-B31-C7 |
| 156 | A156-B31-C7 |
| 157 | A157-B31-C7 |
| 158 | A158-B31-C7 |
| 159 | A159-B31-C7 |
| 160 | A160-B31-C7 |
| 161 | A161-B31-C7 |
| 162 | A162-B31-C7 |
| 163 | A163-B31-C7 |
| 164 | A164-B31-C7 |
| 165 | A165-B31-C7 |
| 166 | A166-B31-C7 |
| 167 | A167-B31-C7 |
| 168 | A168-B31-C7 |
| 169 | A169-B31-C7 |
| 170 | A170-B31-C7 |
| 171 | A171-B31-C7 |
| 172 | A172-B31-C7 |
| 173 | A173-B31-C7 |
| 174 | A174-B31-C7 |
| 175 | A175-B31-C7 |
| 176 | A176-B31-C7 |
| 177 | A177-B31-C7 |
| 178 | A178-B31-C7 |
| 179 | A179-B31-C7 |
| 180 | A180-B31-C7 |
| 181 | A181-B31-C7 |
| 182 | A182-B31-C7 |
| 183 | A183-B31-C7 |
| 184 | A184-B31-C7 |
| 185 | A185-B31-C7 |
| 186 | A186-B31-C7 |
| 187 | A187-B31-C7 |
| 188 | A188-B31-C7 |
| 189 | A189-B31-C7 |
| 190 | A190-B31-C7 |
| 191 | A191-B31-C7 |
| 192 | A192-B31-C7 |
| 193 | A193-B31-C7 |
| 194 | A194-B31-C7 |
| 195 | A195-B31-C7 |
| 196 | A196-B31-C7 |
| 197 | A197-B31-C7 |
| 198 | A198-B31-C7 |
| 199 | A199-B31-C7 |
| 200 | A200-B31-C7 |

TABLE 3

| Compound | <Structure> |
|---|---|
| 201 | A201-B31-C7 |
| 202 | A202-B31-C7 |
| 203 | A203-B31-C7 |
| 204 | A204-B31-C7 |
| 205 | A205-B31-C7 |
| 206 | A206-B31-C7 |
| 207 | A207-B31-C7 |
| 208 | A208-B31-C7 |
| 209 | A209-B31-C7 |
| 210 | A210-B31-C7 |
| 211 | A211-B31-C7 |
| 212 | A212-B31-C7 |
| 213 | A213-B31-C7 |
| 214 | A214-B31-C7 |
| 215 | A215-B31-C7 |
| 216 | A216-B31-C7 |
| 217 | A217-B31-C7 |
| 218 | A218-B31-C7 |
| 219 | A219-B31-C7 |
| 220 | A220-B31-C7 |
| 221 | A221-B31-C7 |
| 222 | A222-B31-C7 |
| 223 | A223-B31-C7 |
| 224 | A224-B31-C7 |
| 225 | A225-B31-C7 |
| 226 | A226-B31-C7 |
| 227 | A227-B31-C7 |
| 228 | A228-B31-C7 |
| 229 | A229-B31-C7 |
| 230 | A230-B31-C7 |
| 231 | A231-B31-C7 |
| 232 | A232-B31-C7 |
| 233 | A233-B31-C7 |
| 234 | A234-B31-C7 |
| 235 | A235-B31-C7 |
| 236 | A236-B31-C7 |
| 237 | A237-B31-C7 |
| 238 | A238-B31-C7 |
| 239 | A239-B31-C7 |
| 240 | A240-B31-C7 |
| 241 | A241-B31-C7 |
| 242 | A242-B31-C7 |
| 243 | A243-B31-C7 |
| 244 | A244-B31-C7 |
| 245 | A245-B31-C7 |
| 246 | A246-B31-C7 |
| 247 | A247-B31-C7 |
| 248 | A248-B31-C7 |
| 249 | A249-B31-C7 |
| 250 | A250-B31-C7 |
| 251 | A251-B31-C7 |
| 252 | A252-B31-C7 |
| 253 | A253-B31-C7 |
| 254 | A254-B31-C7 |
| 255 | A255-B31-C7 |
| 256 | A256-B31-C7 |
| 257 | A257-B31-C7 |
| 258 | A258-B31-C7 |
| 259 | A259-B31-C7 |
| 260 | A260-B31-C7 |
| 261 | A261-B31-C7 |
| 262 | A262-B31-C7 |
| 263 | A263-B31-C7 |
| 264 | A264-B31-C7 |
| 265 | A265-B31-C7 |
| 266 | A266-B31-C7 |
| 267 | A267-B31-C7 |
| 268 | A268-B31-C7 |
| 269 | A269-B31-C7 |
| 270 | A270-B31-C7 |
| 271 | A271-B31-C7 |
| 272 | A272-B31-C7 |
| 273 | A273-B31-C7 |
| 274 | A274-B31-C7 |
| 275 | A275-B31-C7 |
| 276 | A276-B31-C7 |
| 277 | A277-B31-C7 |
| 278 | A278-B31-C7 |
| 279 | A279-B31-C7 |
| 280 | A280-B31-C7 |
| 281 | A1-B11-C4 |
| 282 | A2-B11-C4 |
| 283 | A3-B11-C4 |
| 284 | A4-B11-C4 |
| 285 | A5-B11-C4 |
| 286 | A6-B11-C4 |
| 287 | A7-B11-C4 |
| 288 | A8-B11-C4 |
| 289 | A9-B11-C4 |
| 290 | A10-B11-C4 |
| 291 | A11-B11-C4 |
| 292 | A12-B11-C4 |
| 293 | A13-B11-C4 |
| 294 | A14-B11-C4 |
| 295 | A15-B11-C4 |
| 296 | A16-B11-C4 |
| 297 | A17-B11-C4 |
| 298 | A18-B11-C4 |
| 299 | A19-B11-C4 |
| 300 | A20-B11-C4 |

TABLE 4

| Compound | <Structure> |
|---|---|
| 301 | A21-B11-C4 |
| 302 | A22-B11-C4 |
| 303 | A23-B11-C4 |
| 304 | A24-B11-C4 |
| 305 | A25-B11-C4 |
| 306 | A26-B11-C4 |
| 307 | A27-B11-C4 |
| 308 | A28-B11-C4 |
| 309 | A29-B11-C4 |
| 310 | A30-B11-C4 |
| 311 | A31-B11-C4 |
| 312 | A32-B11-C4 |
| 313 | A33-B11-C4 |
| 314 | A34-B11-C4 |
| 315 | A35-B11-C4 |
| 316 | A36-B11-C4 |
| 317 | A37-B11-C4 |
| 318 | A38-B11-C4 |
| 319 | A39-B11-C4 |
| 320 | A40-B11-C4 |
| 321 | A41-B11-C4 |
| 322 | A42-B11-C4 |
| 323 | A43-B11-C4 |
| 324 | A44-B11-C4 |
| 325 | A45-B11-C4 |
| 326 | A46-B11-C4 |
| 327 | A47-B11-C4 |
| 328 | A48-B11-C4 |
| 329 | A49-B11-C4 |
| 330 | A50-B11-C4 |
| 331 | A51-B11-C4 |
| 332 | A52-B11-C4 |
| 333 | A53-B11-C4 |
| 334 | A54-B11-C4 |
| 335 | A55-B11-C4 |
| 336 | A56-B11-C4 |
| 337 | A57-B11-C4 |
| 338 | A58-B11-C4 |
| 339 | A59-B11-C4 |
| 340 | A60-B11-C4 |
| 341 | A61-B11-C4 |
| 342 | A62-B11-C4 |
| 343 | A63-B11-C4 |
| 344 | A64-B11-C4 |
| 345 | A65-B11-C4 |
| 346 | A66-B11-C4 |
| 347 | A67-B11-C4 |
| 348 | A68-B11-C4 |
| 349 | A69-B11-C4 |
| 350 | A70-B11-C4 |
| 351 | A71-B11-C4 |
| 352 | A72-B11-C4 |
| 353 | A73-B11-C4 |
| 354 | A74-B11-C4 |
| 355 | A75-B11-C4 |
| 356 | A76-B11-C4 |
| 357 | A77-B11-C4 |
| 358 | A78-B11-C4 |
| 359 | A79-B11-C4 |
| 360 | A80-B11-C4 |
| 361 | A81-B11-C4 |
| 362 | A82-B11-C4 |
| 363 | A83-B11-C4 |
| 364 | A84-B11-C4 |
| 365 | A85-B11-C4 |
| 366 | A86-B11-C4 |
| 367 | A87-B11-C4 |
| 368 | A88-B11-C4 |
| 369 | A89-B11-C4 |
| 370 | A90-B11-C4 |
| 371 | A91-B11-C4 |
| 372 | A92-B11-C4 |
| 373 | A93-B11-C4 |
| 374 | A94-B11-C4 |
| 375 | A95-B11-C4 |
| 376 | A96-B11-C4 |
| 377 | A97-B11-C4 |
| 378 | A98-B11-C4 |
| 379 | A99-B11-C4 |
| 380 | A100-B11-C4 |
| 381 | A101-B11-C4 |
| 382 | A102-B11-C4 |
| 383 | A103-B11-C4 |
| 384 | A104-B11-C4 |
| 385 | A105-B11-C4 |
| 386 | A106-B11-C4 |
| 387 | A107-B11-C4 |
| 388 | A108-B11-C4 |
| 389 | A109-B11-C4 |
| 390 | A110-B11-C4 |
| 391 | A111-B11-C4 |
| 392 | A112-B11-C4 |
| 393 | A113-B11-C4 |
| 394 | A114-B11-C4 |
| 395 | A115-B11-C4 |
| 396 | A116-B11-C4 |
| 397 | A117-B11-C4 |
| 398 | A118-B11-C4 |
| 399 | A119-B11-C4 |
| 400 | A120-B11-C4 |

TABLE 5

| Compound | <Structure> |
|---|---|
| 401 | A121-B11-C4 |
| 402 | A122-B11-C4 |
| 403 | A123-B11-C4 |
| 404 | A124-B11-C4 |
| 405 | A125-B11-C4 |
| 406 | A126-B11-C4 |
| 407 | A127-B11-C4 |
| 408 | A128-B11-C4 |
| 409 | A129-B11-C4 |
| 410 | A130-B11-C4 |
| 411 | A131-B11-C4 |
| 412 | A132-B11-C4 |
| 413 | A133-B11-C4 |
| 414 | A134-B11-C4 |
| 415 | A135-B11-C4 |
| 416 | A136-B11-C4 |
| 417 | A137-B11-C4 |
| 418 | A138-B11-C4 |
| 419 | A139-B11-C4 |
| 420 | A140-B11-C4 |
| 421 | A141-B11-C4 |
| 422 | A142-B11-C4 |
| 423 | A143-B11-C4 |
| 424 | A144-B11-C4 |
| 425 | A145-B11-C4 |
| 426 | A146-B11-C4 |
| 427 | A147-B11-C4 |
| 428 | A148-B11-C4 |
| 429 | A149-B11-C4 |
| 430 | A150-B11-C4 |
| 431 | A151-B11-C4 |
| 432 | A152-B11-C4 |
| 433 | A153-B11-C4 |
| 434 | A154-B11-C4 |
| 435 | A155-B11-C4 |
| 436 | A156-B11-C4 |
| 437 | A157-B11-C4 |
| 438 | A158-B11-C4 |
| 439 | A159-B11-C4 |
| 440 | A160-B11-C4 |
| 441 | A161-B11-C4 |
| 442 | A162-B11-C4 |
| 443 | A163-B11-C4 |
| 444 | A164-B11-C4 |
| 445 | A165-B11-C4 |
| 446 | A166-B11-C4 |
| 447 | A167-B11-C4 |
| 448 | A168-B11-C4 |
| 449 | A169-B11-C4 |
| 450 | A170-B11-C4 |
| 451 | A171-B11-C4 |
| 452 | A172-B11-C4 |
| 453 | A173-B11-C4 |
| 454 | A174-B11-C4 |
| 455 | A175-B11-C4 |
| 456 | A176-B11-C4 |
| 457 | A177-B11-C4 |
| 458 | A178-B11-C4 |
| 459 | A179-B11-C4 |
| 460 | A180-B11-C4 |
| 461 | A181-B11-C4 |
| 462 | A182-B11-C4 |
| 463 | A183-B11-C4 |
| 464 | A184-B11-C4 |
| 465 | A185-B11-C4 |
| 466 | A186-B11-C4 |
| 467 | A187-B11-C4 |
| 468 | A188-B11-C4 |
| 469 | A189-B11-C4 |
| 470 | A190-B11-C4 |
| 471 | A191-B11-C4 |
| 472 | A192-B11-C4 |
| 473 | A193-B11-C4 |
| 474 | A194-B11-C4 |
| 475 | A195-B11-C4 |
| 476 | A196-B11-C4 |
| 477 | A197-B11-C4 |
| 478 | A198-B11-C4 |
| 479 | A199-B11-C4 |
| 480 | A200-B11-C4 |
| 481 | A201-B11-C4 |
| 482 | A202-B11-C4 |
| 483 | A203-B11-C4 |
| 484 | A204-B11-C4 |
| 485 | A205-B11-C4 |
| 486 | A206-B11-C4 |
| 487 | A207-B11-C4 |
| 488 | A208-B11-C4 |
| 489 | A209-B11-C4 |
| 490 | A210-B11-C4 |
| 491 | A211-B11-C4 |
| 492 | A212-B11-C4 |
| 493 | A213-B11-C4 |
| 494 | A214-B11-C4 |
| 495 | A215-B11-C4 |
| 496 | A216-B11-C4 |
| 497 | A217-B11-C4 |
| 498 | A218-B11-C4 |
| 499 | A219-B11-C4 |
| 500 | A220-B11-C4 |

TABLE 6

| Compound | <Structure> |
|---|---|
| 501 | A221-B11-C4 |
| 502 | A222-B11-C4 |
| 503 | A223-B11-C4 |
| 504 | A224-B11-C4 |
| 505 | A225-B11-C4 |
| 506 | A226-B11-C4 |
| 507 | A227-B11-C4 |
| 508 | A228-B11-C4 |
| 509 | A229-B11-C4 |
| 510 | A230-B11-C4 |
| 511 | A231-B11-C4 |
| 512 | A232-B11-C4 |
| 513 | A233-B11-C4 |
| 514 | A234-B11-C4 |
| 515 | A235-B11-C4 |
| 516 | A236-B11-C4 |
| 517 | A237-B11-C4 |
| 518 | A238-B11-C4 |
| 519 | A239-B11-C4 |
| 520 | A240-B11-C4 |
| 521 | A241-B11-C4 |
| 522 | A242-B11-C4 |
| 523 | A243-B11-C4 |
| 524 | A244-B11-C4 |
| 525 | A245-B11-C4 |
| 526 | A246-B11-C4 |
| 527 | A247-B11-C4 |
| 528 | A248-B11-C4 |
| 529 | A249-B11-C4 |
| 530 | A250-B11-C4 |
| 531 | A251-B11-C4 |
| 532 | A252-B11-C4 |
| 533 | A253-B11-C4 |
| 534 | A254-B11-C4 |
| 535 | A255-B11-C4 |
| 536 | A256-B11-C4 |
| 537 | A257-B11-C4 |
| 538 | A258-B11-C4 |
| 539 | A259-B11-C4 |
| 540 | A260-B11-C4 |
| 541 | A261-B11-C4 |
| 542 | A262-B11-C4 |
| 543 | A263-B11-C4 |
| 544 | A264-B11-C4 |
| 545 | A265-B11-C4 |
| 546 | A266-B11-C4 |
| 547 | A267-B11-C4 |
| 548 | A268-B11-C4 |
| 549 | A269-B11-C4 |
| 550 | A270-B11-C4 |
| 551 | A271-B11-C4 |
| 552 | A272-B11-C4 |
| 553 | A273-B11-C4 |
| 554 | A274-B11-C4 |
| 555 | A275-B11-C4 |
| 556 | A276-B11-C4 |
| 557 | A277-B11-C4 |
| 558 | A278-B11-C4 |
| 559 | A279-B11-C4 |
| 560 | A280-B11-C4 |
| 561 | A1-B23-C20 |
| 562 | A2-B23-C20 |
| 563 | A3-B23-C20 |
| 564 | A4-B23-C20 |
| 565 | A5-B23-C20 |
| 566 | A6-B23-C20 |
| 567 | A7-B23-C20 |
| 568 | A8-B23-C20 |
| 569 | A9-B23-C20 |
| 570 | A10-B23-C20 |
| 571 | A11-B23-C20 |
| 572 | A12-B23-C20 |
| 573 | A13-B23-C20 |
| 574 | A14-B23-C20 |
| 575 | A15-B23-C20 |
| 576 | A16-B23-C20 |
| 577 | A17-B23-C20 |
| 578 | A18-B23-C20 |
| 579 | A19-B23-C20 |
| 580 | A20-B23-C20 |
| 581 | A21-B23-C20 |
| 582 | A22-B23-C20 |
| 583 | A23-B23-C20 |
| 584 | A24-B23-C20 |
| 585 | A25-B23-C20 |
| 586 | A26-B23-C20 |
| 587 | A27-B23-C20 |
| 588 | A28-B23-C20 |
| 589 | A29-B23-C20 |
| 590 | A30-B23-C20 |
| 591 | A31-B23-C20 |
| 592 | A32-B23-C20 |
| 593 | A33-B23-C20 |
| 594 | A34-B23-C20 |
| 595 | A35-B23-C20 |
| 596 | A36-B23-C20 |
| 597 | A37-B23-C20 |
| 598 | A38-B23-C20 |
| 599 | A39-B23-C20 |
| 600 | A40-B23-C20 |

TABLE 7

| Compound | <Structure> |
|---|---|
| 601 | A41-B23-C20 |
| 602 | A42-B23-C20 |
| 603 | A43-B23-C20 |
| 604 | A44-B23-C20 |
| 605 | A45-B23-C20 |
| 606 | A46-B23-C20 |
| 607 | A47-B23-C20 |
| 608 | A48-B23-C20 |
| 609 | A49-B23-C20 |
| 610 | A50-B23-C20 |
| 611 | A51-B23-C20 |
| 612 | A52-B23-C20 |
| 613 | A53-B23-C20 |
| 614 | A54-B23-C20 |
| 615 | A55-B23-C20 |
| 616 | A56-B23-C20 |
| 617 | A57-B23-C20 |
| 618 | A58-B23-C20 |
| 619 | A59-B23-C20 |
| 620 | A60-B23-C20 |
| 621 | A61-B23-C20 |
| 622 | A62-B23-C20 |
| 623 | A63-B23-C20 |
| 624 | A64-B23-C20 |
| 625 | A65-B23-C20 |
| 626 | A66-B23-C20 |
| 627 | A67-B23-C20 |
| 628 | A68-B23-C20 |
| 629 | A69-B23-C20 |
| 630 | A70-B23-C20 |
| 631 | A71-B23-C20 |
| 632 | A72-B23-C20 |
| 633 | A73-B23-C20 |
| 634 | A74-B23-C20 |
| 635 | A75-B23-C20 |
| 636 | A76-B23-C20 |
| 637 | A77-B23-C20 |
| 638 | A78-B23-C20 |
| 639 | A79-B23-C20 |
| 640 | A80-B23-C20 |
| 641 | A81-B23-C20 |
| 642 | A82-B23-C20 |
| 643 | A83-B23-C20 |
| 644 | A84-B23-C20 |
| 645 | A85-B23-C20 |
| 646 | A86-B23-C20 |
| 647 | A87-B23-C20 |
| 648 | A88-B23-C20 |
| 649 | A89-B23-C20 |
| 650 | A90-B23-C20 |
| 651 | A91-B23-C20 |
| 652 | A92-B23-C20 |
| 653 | A93-B23-C20 |
| 654 | A94-B23-C20 |
| 655 | A95-B23-C20 |
| 656 | A96-B23-C20 |
| 657 | A97-B23-C20 |
| 658 | A98-B23-C20 |
| 659 | A99-B23-C20 |
| 660 | A100-B23-C20 |
| 661 | A101-B23-C20 |
| 662 | A102-B23-C20 |
| 663 | A103-B23-C20 |
| 664 | A104-B23-C20 |
| 665 | A105-B23-C20 |
| 666 | A106-B23-C20 |
| 667 | A107-B23-C20 |
| 668 | A108-B23-C20 |
| 669 | A109-B23-C20 |
| 670 | A110-B23-C20 |
| 671 | A111-B23-C20 |
| 672 | A112-B23-C20 |
| 673 | A113-B23-C20 |
| 674 | A114-B23-C20 |
| 675 | A115-B23-C20 |
| 676 | A116-B23-C20 |
| 677 | A117-B23-C20 |
| 678 | A118-B23-C20 |
| 679 | A119-B23-C20 |
| 680 | A120-B23-C20 |
| 681 | A121-B23-C20 |
| 682 | A122-B23-C20 |
| 683 | A123-B23-C20 |
| 684 | A124-B23-C20 |
| 685 | A125-B23-C20 |
| 686 | A126-B23-C20 |
| 687 | A127-B23-C20 |
| 688 | A128-B23-C20 |
| 689 | A129-B23-C20 |
| 690 | A130-B23-C20 |
| 691 | A131-B23-C20 |
| 692 | A132-B23-C20 |
| 693 | A133-B23-C20 |
| 694 | A134-B23-C20 |
| 695 | A135-B23-C20 |
| 696 | A136-B23-C20 |
| 697 | A137-B23-C20 |
| 698 | A138-B23-C20 |
| 699 | A139-B23-C20 |
| 700 | A140-B23-C20 |

TABLE 8

| Compound | <Structure> |
|---|---|
| 701 | A141-B23-C20 |
| 702 | A142-B23-C20 |
| 703 | A143-B23-C20 |
| 704 | A144-B23-C20 |
| 705 | A145-B23-C20 |
| 706 | A146-B23-C20 |
| 707 | A147-B23-C20 |
| 708 | A148-B23-C20 |
| 709 | A149-B23-C20 |
| 710 | A150-B23-C20 |
| 711 | A151-B23-C20 |
| 712 | A152-B23-C20 |
| 713 | A153-B23-C20 |
| 714 | A154-B23-C20 |
| 715 | A155-B23-C20 |
| 716 | A156-B23-C20 |
| 717 | A157-B23-C20 |
| 718 | A158-B23-C20 |
| 719 | A159-B23-C20 |
| 720 | A160-B23-C20 |
| 721 | A161-B23-C20 |
| 722 | A162-B23-C20 |
| 723 | A163-B23-C20 |
| 724 | A164-B23-C20 |
| 725 | A165-B23-C20 |
| 726 | A166-B23-C20 |
| 727 | A167-B23-C20 |
| 728 | A168-B23-C20 |
| 729 | A169-B23-C20 |
| 730 | A170-B23-C20 |
| 731 | A171-B23-C20 |
| 732 | A172-B23-C20 |
| 733 | A173-B23-C20 |
| 734 | A174-B23-C20 |
| 735 | A175-B23-C20 |
| 736 | A176-B23-C20 |
| 737 | A177-B23-C20 |
| 738 | A178-B23-C20 |
| 739 | A179-B23-C20 |
| 740 | A180-B23-C20 |
| 741 | A181-B23-C20 |
| 742 | A182-B23-C20 |
| 743 | A183-B23-C20 |
| 744 | A184-B23-C20 |
| 745 | A185-B23-C20 |
| 746 | A186-B23-C20 |
| 747 | A187-B23-C20 |
| 748 | A188-B23-C20 |
| 749 | A189-B23-C20 |
| 750 | A190-B23-C20 |
| 751 | A191-B23-C20 |
| 752 | A192-B23-C20 |
| 753 | A193-B23-C20 |
| 754 | A194-B23-C20 |
| 755 | A195-B23-C20 |
| 756 | A196-B23-C20 |
| 757 | A197-B23-C20 |
| 758 | A198-B23-C20 |
| 759 | A199-B23-C20 |
| 760 | A200-B23-C20 |
| 761 | A201-B23-C20 |
| 762 | A202-B23-C20 |
| 763 | A203-B23-C20 |
| 764 | A204-B23-C20 |
| 765 | A205-B23-C20 |
| 766 | A206-B23-C20 |
| 767 | A207-B23-C20 |
| 768 | A208-B23-C20 |
| 769 | A209-B23-C20 |
| 770 | A210-B23-C20 |
| 771 | A211-B23-C20 |
| 772 | A212-B23-C20 |
| 773 | A213-B23-C20 |
| 774 | A214-B23-C20 |
| 775 | A215-B23-C20 |
| 776 | A216-B23-C20 |
| 777 | A217-B23-C20 |
| 778 | A218-B23-C20 |
| 779 | A219-B23-C20 |
| 780 | A220-B23-C20 |
| 781 | A221-B23-C20 |
| 782 | A222-B23-C20 |
| 783 | A223-B23-C20 |
| 784 | A224-B23-C20 |
| 785 | A225-B23-C20 |
| 786 | A226-B23-C20 |
| 787 | A227-B23-C20 |
| 788 | A228-B23-C20 |
| 789 | A229-B23-C20 |
| 790 | A230-B23-C20 |
| 791 | A231-B23-C20 |
| 792 | A232-B23-C20 |
| 793 | A233-B23-C20 |
| 794 | A234-B23-C20 |
| 795 | A235-B23-C20 |
| 796 | A236-B23-C20 |
| 797 | A237-B23-C20 |
| 798 | A238-B23-C20 |
| 799 | A239-B23-C20 |
| 800 | A240-B23-C20 |

TABLE 9

| Compound | <Structure> |
|---|---|
| 801 | A241-B23-C20 |
| 802 | A242-B23-C20 |
| 803 | A243-B23-C20 |
| 804 | A244-B23-C20 |
| 805 | A245-B23-C20 |
| 806 | A246-B23-C20 |
| 807 | A247-B23-C20 |
| 808 | A248-B23-C20 |
| 809 | A249-B23-C20 |
| 810 | A250-B23-C20 |
| 811 | A251-B23-C20 |
| 812 | A252-B23-C20 |
| 813 | A253-B23-C20 |
| 814 | A254-B23-C20 |
| 815 | A255-B23-C20 |
| 816 | A256-B23-C20 |
| 817 | A257-B23-C20 |
| 818 | A258-B23-C20 |
| 819 | A259-B23-C20 |
| 820 | A260-B23-C20 |
| 821 | A261-B23-C20 |
| 822 | A262-B23-C20 |
| 823 | A263-B23-C20 |
| 824 | A264-B23-C20 |
| 825 | A265-B23-C20 |
| 826 | A266-B23-C20 |
| 827 | A267-B23-C20 |
| 828 | A268-B23-C20 |
| 829 | A269-B23-C20 |
| 830 | A270-B23-C20 |
| 831 | A271-B23-C20 |
| 832 | A272-B23-C20 |
| 833 | A273-B23-C20 |
| 834 | A274-B23-C20 |
| 835 | A275-B23-C20 |
| 836 | A276-B23-C20 |
| 837 | A277-B23-C20 |
| 838 | A278-B23-C20 |
| 839 | A279-B23-C20 |
| 840 | A280-B23-C20 |
| 841 | A1-B5-C19 |
| 842 | A2-B5-C19 |
| 843 | A3-B5-C19 |
| 844 | A4-B5-C19 |
| 845 | A5-B5-C19 |
| 846 | A6-B5-C19 |
| 847 | A7-B5-C19 |
| 848 | A8-B5-C19 |
| 849 | A9-B5-C19 |
| 850 | A10-B5-C19 |
| 851 | A11-B5-C19 |
| 852 | A12-B5-C19 |
| 853 | A13-B5-C19 |
| 854 | A14-B5-C19 |
| 855 | A15-B5-C19 |
| 856 | A16-B5-C19 |
| 857 | A17-B5-C19 |
| 858 | A18-B5-C19 |
| 859 | A19-B5-C19 |
| 860 | A20-B5-C19 |
| 861 | A21-B5-C19 |
| 862 | A22-B5-C19 |
| 863 | A23-B5-C19 |
| 864 | A24-B5-C19 |
| 865 | A25-B5-C19 |
| 866 | A26-B5-C19 |
| 867 | A27-B5-C19 |
| 868 | A28-B5-C19 |
| 869 | A29-B5-C19 |
| 870 | A30-B5-C19 |
| 871 | A31-B5-C19 |
| 872 | A32-B5-C19 |
| 873 | A33-B5-C19 |
| 874 | A34-B5-C19 |
| 875 | A35-B5-C19 |
| 876 | A36-B5-C19 |
| 877 | A37-B5-C19 |
| 878 | A38-B5-C19 |
| 879 | A39-B5-C19 |
| 880 | A40-B5-C19 |
| 881 | A41-B5-C19 |
| 882 | A42-B5-C19 |
| 883 | A43-B5-C19 |
| 884 | A44-B5-C19 |
| 885 | A45-B5-C19 |
| 886 | A46-B5-C19 |
| 887 | A47-B5-C19 |
| 888 | A48-B5-C19 |
| 889 | A49-B5-C19 |
| 890 | A50-B5-C19 |
| 891 | A51-B5-C19 |
| 892 | A52-B5-C19 |
| 893 | A53-B5-C19 |
| 894 | A54-B5-C19 |
| 895 | A55-B5-C19 |
| 896 | A56-B5-C19 |
| 897 | A57-B5-C19 |
| 898 | A58-B5-C19 |
| 899 | A59-B5-C19 |
| 900 | A60-B5-C19 |

TABLE 10

| Compound | <Structure> |
|---|---|
| 901 | A61-B5-C19 |
| 902 | A62-B5-C19 |
| 903 | A63-B5-C19 |
| 904 | A64-B5-C19 |
| 905 | A65-B5-C19 |
| 906 | A66-B5-C19 |
| 907 | A67-B5-C19 |
| 908 | A68-B5-C19 |
| 909 | A69-B5-C19 |
| 910 | A70-B5-C19 |
| 911 | A71-B5-C19 |
| 912 | A72-B5-C19 |
| 913 | A73-B5-C19 |
| 914 | A74-B5-C19 |
| 915 | A75-B5-C19 |
| 916 | A76-B5-C19 |
| 917 | A77-B5-C19 |
| 918 | A78-B5-C19 |
| 919 | A79-B5-C19 |
| 920 | A80-B5-C19 |
| 921 | A81-B5-C19 |
| 922 | A82-B5-C19 |
| 923 | A83-B5-C19 |
| 924 | A84-B5-C19 |
| 925 | A85-B5-C19 |
| 926 | A86-B5-C19 |
| 927 | A87-B5-C19 |
| 928 | A88-B5-C19 |
| 929 | A89-B5-C19 |
| 930 | A90-B5-C19 |
| 931 | A91-B5-C19 |
| 932 | A92-B5-C19 |
| 933 | A93-B5-C19 |
| 934 | A94-B5-C19 |
| 935 | A95-B5-C19 |
| 936 | A96-B5-C19 |
| 937 | A97-B5-C19 |
| 938 | A98-B5-C19 |
| 939 | A99-B5-C19 |
| 940 | A100-B5-C19 |
| 941 | A101-B5-C19 |
| 942 | A102-B5-C19 |
| 943 | A103-B5-C19 |
| 944 | A104-B5-C19 |
| 945 | A105-B5-C19 |
| 946 | A106-B5-C19 |
| 947 | A107-B5-C19 |
| 948 | A108-B5-C19 |
| 949 | A109-B5-C19 |
| 950 | A110-B5-C19 |
| 951 | A111-B5-C19 |
| 952 | A112-B5-C19 |
| 953 | A113-B5-C19 |
| 954 | A114-B5-C19 |
| 955 | A115-B5-C19 |
| 956 | A116-B5-C19 |
| 957 | A117-B5-C19 |
| 958 | A118-B5-C19 |
| 959 | A119-B5-C19 |
| 960 | A120-B5-C19 |
| 961 | A121-B5-C19 |
| 962 | A122-B5-C19 |
| 963 | A123-B5-C19 |
| 964 | A124-B5-C19 |
| 965 | A125-B5-C19 |
| 966 | A126-B5-C19 |
| 967 | A127-B5-C19 |
| 968 | A128-B5-C19 |
| 969 | A129-B5-C19 |
| 970 | A130-B5-C19 |
| 971 | A131-B5-C19 |
| 972 | A132-B5-C19 |
| 973 | A133-B5-C19 |
| 974 | A134-B5-C19 |
| 975 | A135-B5-C19 |
| 976 | A136-B5-C19 |
| 977 | A137-B5-C19 |
| 978 | A138-B5-C19 |
| 979 | A139-B5-C19 |
| 980 | A140-B5-C19 |
| 981 | A141-B5-C19 |
| 982 | A142-B5-C19 |
| 983 | A143-B5-C19 |
| 984 | A144-B5-C19 |
| 985 | A145-B5-C19 |
| 986 | A146-B5-C19 |
| 987 | A147-B5-C19 |
| 988 | A148-B5-C19 |
| 989 | A149-B5-C19 |
| 990 | A150-B5-C19 |
| 991 | A151-B5-C19 |
| 992 | A152-B5-C19 |
| 993 | A153-B5-C19 |
| 994 | A154-B5-C19 |
| 995 | A155-B5-C19 |
| 996 | A156-B5-C19 |
| 997 | A157-B5-C19 |
| 998 | A158-B5-C19 |
| 999 | A159-B5-C19 |
| 1000 | A160-B5-C19 |

TABLE 11

| Compound | <Structure> |
|---|---|
| 1001 | A161-B5-C19 |
| 1002 | A162-B5-C19 |
| 1003 | A163-B5-C19 |
| 1004 | A164-B5-C19 |
| 1005 | A165-B5-C19 |
| 1006 | A166-B5-C19 |
| 1007 | A167-B5-C19 |
| 1008 | A168-B5-C19 |
| 1009 | A169-B5-C19 |
| 1010 | A170-B5-C19 |
| 1011 | A171-B5-C19 |
| 1012 | A172-B5-C19 |
| 1013 | A173-B5-C19 |
| 1014 | A174-B5-C19 |
| 1015 | A175-B5-C19 |
| 1016 | A176-B5-C19 |
| 1017 | A177-B5-C19 |
| 1018 | A178-B5-C19 |
| 1019 | A179-B5-C19 |
| 1020 | A180-B5-C19 |
| 1021 | A181-B5-C19 |
| 1022 | A182-B5-C19 |
| 1023 | A183-B5-C19 |
| 1024 | A184-B5-C19 |
| 1025 | A185-B5-C19 |
| 1026 | A186-B5-C19 |
| 1027 | A187-B5-C19 |
| 1028 | A188-B5-C19 |
| 1029 | A189-B5-C19 |
| 1030 | A190-B5-C19 |
| 1031 | A191-B5-C19 |
| 1032 | A192-B5-C19 |
| 1033 | A193-B5-C19 |
| 1034 | A194-B5-C19 |
| 1035 | A195-B5-C19 |
| 1036 | A196-B5-C19 |
| 1037 | A197-B5-C19 |
| 1038 | A198-B5-C19 |
| 1039 | A199-B5-C19 |
| 1040 | A200-B5-C19 |
| 1041 | A201-B5-C19 |
| 1042 | A202-B5-C19 |
| 1043 | A203-B5-C19 |
| 1044 | A204-B5-C19 |
| 1045 | A205-B5-C19 |
| 1046 | A206-B5-C19 |
| 1047 | A207-B5-C19 |
| 1048 | A208-B5-C19 |
| 1049 | A209-B5-C19 |
| 1050 | A210-B5-C19 |
| 1051 | A211-B5-C19 |
| 1052 | A212-B5-C19 |
| 1053 | A213-B5-C19 |
| 1054 | A214-B5-C19 |
| 1055 | A215-B5-C19 |
| 1056 | A216-B5-C19 |
| 1057 | A217-B5-C19 |
| 1058 | A218-B5-C19 |
| 1059 | A219-B5-C19 |
| 1060 | A220-B5-C19 |
| 1061 | A221-B5-C19 |
| 1062 | A222-B5-C19 |
| 1063 | A223-B5-C19 |
| 1064 | A224-B5-C19 |
| 1065 | A225-B5-C19 |
| 1066 | A226-B5-C19 |
| 1067 | A227-B5-C19 |
| 1068 | A228-B5-C19 |
| 1069 | A229-B5-C19 |
| 1070 | A230-B5-C19 |
| 1071 | A231-B5-C19 |
| 1072 | A232-B5-C19 |
| 1073 | A233-B5-C19 |
| 1074 | A234-B5-C19 |
| 1075 | A235-B5-C19 |
| 1076 | A236-B5-C19 |
| 1077 | A237-B5-C19 |
| 1078 | A238-B5-C19 |
| 1079 | A239-B5-C19 |
| 1080 | A240-B5-C19 |
| 1081 | A241-B5-C19 |
| 1082 | A242-B5-C19 |
| 1083 | A243-B5-C19 |
| 1084 | A244-B5-C19 |
| 1085 | A245-B5-C19 |
| 1086 | A246-B5-C19 |
| 1087 | A247-B5-C19 |
| 1088 | A248-B5-C19 |
| 1089 | A249-B5-C19 |
| 1090 | A250-B5-C19 |
| 1091 | A251-B5-C19 |
| 1092 | A252-B5-C19 |
| 1093 | A253-B5-C19 |
| 1094 | A254-B5-C19 |
| 1095 | A255-B5-C19 |
| 1096 | A256-B5-C19 |
| 1097 | A257-B5-C19 |
| 1098 | A258-B5-C19 |
| 1099 | A259-B5-C19 |
| 1100 | A260-B5-C19 |

TABLE 12

| Compound | <Structure> |
|---|---|
| 1101 | A261-B5-C19 |
| 1102 | A262-B5-C19 |
| 1103 | A263-B5-C19 |
| 1104 | A264-B5-C19 |
| 1105 | A265-B5-C19 |
| 1106 | A266-B5-C19 |
| 1107 | A267-B5-C19 |
| 1108 | A268-B5-C19 |
| 1109 | A269-B5-C19 |
| 1110 | A270-B5-C19 |
| 1111 | A271-B5-C19 |
| 1112 | A272-B5-C19 |
| 1113 | A273-B5-C19 |
| 1114 | A274-B5-C19 |
| 1115 | A275-B5-C19 |
| 1116 | A276-B5-C19 |
| 1117 | A277-B5-C19 |
| 1118 | A278-B5-C19 |
| 1119 | A279-B5-C19 |
| 1120 | A280-B5-C19 |
| 1121 | A1-B3-C1 |
| 1122 | A1-B3-C2 |
| 1123 | A1-B3-C3 |
| 1124 | A1-B3-C4 |
| 1125 | A1-B3-C5 |
| 1126 | A1-B3-C6 |
| 1127 | A1-B3-C7 |
| 1128 | A1-B3-C8 |
| 1129 | A1-B3-C9 |
| 1130 | A1-B3-C10 |
| 1131 | A1-B3-C11 |
| 1132 | A1-B3-C12 |
| 1133 | A1-B3-C13 |
| 1134 | A1-B3-C14 |
| 1135 | A1-B3-C15 |
| 1136 | A1-B3-C16 |
| 1137 | A1-B3-C17 |
| 1138 | A1-B3-C18 |
| 1139 | A1-B3-C19 |
| 1140 | A1-B3-C20 |
| 1141 | A1-B3-C21 |
| 1142 | A1-B3-C22 |
| 1143 | A1-B3-C23 |
| 1144 | A1-B3-C24 |
| 1145 | A1-B3-C25 |
| 1146 | A1-B3-C26 |
| 1147 | A1-B3-C27 |
| 1148 | A1-B3-C28 |
| 1149 | A1-B3-C29 |
| 1150 | A1-B3-C30 |
| 1151 | A1-B3-C31 |
| 1152 | A1-B3-C32 |
| 1153 | A1-B3-C33 |
| 1154 | A1-B3-C34 |
| 1155 | A1-B3-C35 |
| 1156 | A1-B3-C36 |
| 1157 | A1-B3-C37 |
| 1158 | A1-B3-C38 |
| 1159 | A1-B3-C39 |
| 1160 | A1-B3-C40 |
| 1161 | A1-B3-C41 |
| 1162 | A1-B3-C42 |
| 1163 | A1-B3-C43 |
| 1164 | A1-B3-C44 |
| 1165 | A1-B3-C45 |
| 1166 | A1-B3-C46 |
| 1167 | A1-B3-C47 |
| 1168 | A1-B3-C48 |
| 1169 | A1-B3-C49 |
| 1170 | A1-B3-C50 |
| 1171 | A1-B3-C51 |
| 1172 | A1-B3-C52 |
| 1173 | A1-B3-C53 |
| 1174 | A1-B3-C54 |
| 1175 | A1-B3-C55 |
| 1176 | A1-B3-C56 |
| 1177 | A1-B3-C57 |
| 1178 | A1-B3-C58 |
| 1179 | A1-B3-C59 |
| 1180 | A1-B3-C60 |
| 1181 | A1-B3-C61 |
| 1182 | A1-B3-C62 |
| 1183 | A1-B3-C63 |
| 1184 | A1-B3-C64 |
| 1185 | A1-B3-C65 |
| 1186 | A1-B3-C66 |
| 1187 | A1-B3-C67 |
| 1188 | A1-B3-C68 |
| 1189 | A1-B3-C69 |
| 1190 | A1-B3-C70 |
| 1191 | A1-B3-C71 |
| 1192 | A1-B3-C72 |
| 1193 | A1-B3-C73 |
| 1194 | A1-B3-C74 |
| 1195 | A1-B3-C75 |
| 1196 | A1-B3-C76 |
| 1197 | A1-B3-C77 |
| 1198 | A1-B3-C78 |
| 1199 | A1-B3-C79 |
| 1200 | A1-B3-C80 |

TABLE 13

| Compound | <Structure> |
|---|---|
| 1201 | A1-B3-C81 |
| 1202 | A1-B3-C82 |
| 1203 | A1-B3-C83 |
| 1204 | A1-B3-C84 |
| 1205 | A1-B3-C85 |
| 1206 | A1-B3-C86 |
| 1207 | A1-B3-C87 |
| 1208 | A1-B3-C88 |
| 1209 | A1-B3-C89 |
| 1210 | A1-B3-C90 |
| 1211 | A1-B3-C91 |
| 1212 | A1-B3-C92 |
| 1213 | A1-B3-C93 |
| 1214 | A1-B3-C94 |
| 1215 | A1-B3-C95 |
| 1216 | A1-B3-C96 |
| 1217 | A1-B3-C97 |
| 1218 | A1-B3-C98 |
| 1219 | A1-B3-C99 |
| 1220 | A1-B3-C100 |
| 1221 | A4-B12-C1 |
| 1222 | A4-B12-C2 |
| 1223 | A4-B12-C3 |
| 1224 | A4-B12-C4 |
| 1225 | A4-B12-C5 |
| 1226 | A4-B12-C6 |
| 1227 | A4-B12-C7 |
| 1228 | A4-B12-C8 |
| 1229 | A4-B12-C9 |
| 1230 | A4-B12-C10 |
| 1231 | A4-B12-C11 |
| 1232 | A4-B12-C12 |
| 1233 | A4-B12-C13 |
| 1234 | A4-B12-C14 |
| 1235 | A4-B12-C15 |
| 1236 | A4-B12-C16 |
| 1237 | A4-B12-C17 |
| 1238 | A4-B12-C18 |
| 1239 | A4-B12-C19 |
| 1240 | A4-B12-C20 |
| 1241 | A4-B12-C21 |
| 1242 | A4-B12-C22 |
| 1243 | A4-B12-C23 |
| 1244 | A4-B12-C24 |
| 1245 | A4-B12-C25 |
| 1246 | A4-B12-C26 |
| 1247 | A4-B12-C27 |
| 1248 | A4-B12-C28 |
| 1249 | A4-B12-C29 |
| 1250 | A4-B12-C30 |
| 1251 | A4-B12-C31 |
| 1252 | A4-B12-C32 |
| 1253 | A4-B12-C33 |
| 1254 | A4-B12-C34 |
| 1255 | A4-B12-C35 |
| 1256 | A4-B12-C36 |
| 1257 | A4-B12-C37 |
| 1258 | A4-B12-C38 |
| 1259 | A4-B12-C39 |
| 1260 | A4-B12-C40 |
| 1261 | A4-B12-C41 |
| 1262 | A4-B12-C42 |
| 1263 | A4-B12-C43 |
| 1264 | A4-B12-C44 |
| 1265 | A4-B12-C45 |
| 1266 | A4-B12-C46 |
| 1267 | A4-B12-C47 |
| 1268 | A4-B12-C48 |
| 1269 | A4-B12-C49 |
| 1270 | A4-B12-C50 |
| 1271 | A4-B12-C51 |
| 1272 | A4-B12-C52 |
| 1273 | A4-B12-C53 |
| 1274 | A4-B12-C54 |
| 1275 | A4-B12-C55 |
| 1276 | A4-B12-C56 |
| 1277 | A4-B12-C57 |
| 1278 | A4-B12-C58 |
| 1279 | A4-B12-C59 |
| 1280 | A4-B12-C60 |
| 1281 | A4-B12-C61 |
| 1282 | A4-B12-C62 |
| 1283 | A4-B12-C63 |
| 1284 | A4-B12-C64 |
| 1285 | A4-B12-C65 |
| 1286 | A4-B12-C66 |
| 1287 | A4-B12-C67 |
| 1288 | A4-B12-C68 |
| 1289 | A4-B12-C69 |
| 1290 | A4-B12-C70 |
| 1291 | A4-B12-C71 |
| 1292 | A4-B12-C72 |
| 1293 | A4-B12-C73 |
| 1294 | A4-B12-C74 |
| 1295 | A4-B12-C75 |
| 1296 | A4-B12-C76 |
| 1297 | A4-B12-C77 |
| 1298 | A4-B12-C78 |
| 1299 | A4-B12-C79 |
| 1300 | A4-B12-C80 |

TABLE 14

| Compound | <Structure> |
|---|---|
| 1301 | A4-B12-C81 |
| 1302 | A4-B12-C82 |
| 1303 | A4-B12-C83 |
| 1304 | A4-B12-C84 |
| 1305 | A4-B12-C85 |
| 1306 | A4-B12-C86 |
| 1307 | A4-B12-C87 |
| 1308 | A4-B12-C88 |
| 1309 | A4-B12-C89 |
| 1310 | A4-B12-C90 |
| 1311 | A4-B12-C91 |
| 1312 | A4-B12-C92 |
| 1313 | A4-B12-C93 |
| 1314 | A4-B12-C94 |
| 1315 | A4-B12-C95 |
| 1316 | A4-B12-C96 |
| 1317 | A4-B12-C97 |
| 1318 | A4-B12-C98 |
| 1319 | A4-B12-C99 |
| 1320 | A4-B12-C100 |
| 1321 | A102-B3-C1 |
| 1322 | A102-B3-C2 |
| 1323 | A102-B3-C3 |
| 1324 | A102-B3-C4 |
| 1325 | A102-B3-C5 |
| 1326 | A102-B3-C6 |
| 1327 | A102-B3-C7 |
| 1328 | A102-B3-C8 |
| 1329 | A102-B3-C9 |
| 1330 | A102-B3-C10 |
| 1331 | A102-B3-C11 |
| 1332 | A102-B3-C12 |
| 1333 | A102-B3-C13 |
| 1334 | A102-B3-C14 |
| 1335 | A102-B3-C15 |
| 1336 | A102-B3-C16 |
| 1337 | A102-B3-C17 |
| 1338 | A102-B3-C18 |
| 1339 | A102-B3-C19 |
| 1340 | A102-B3-C20 |
| 1341 | A102-B3-C21 |
| 1342 | A102-B3-C22 |
| 1343 | A102-B3-C23 |
| 1344 | A102-B3-C24 |
| 1345 | A102-B3-C25 |
| 1346 | A102-B3-C26 |
| 1347 | A102-B3-C27 |
| 1348 | A102-B3-C28 |
| 1349 | A102-B3-C29 |
| 1350 | A102-B3-C30 |
| 1351 | A102-B3-C31 |
| 1352 | A102-B3-C32 |
| 1353 | A102-B3-C33 |
| 1354 | A102-B3-C34 |
| 1355 | A102-B3-C35 |
| 1356 | A102-B3-C36 |
| 1357 | A102-B3-C37 |
| 1358 | A102-B3-C38 |
| 1359 | A102-B3-C39 |
| 1360 | A102-B3-C40 |
| 1361 | A102-B3-C41 |
| 1362 | A102-B3-C42 |
| 1363 | A102-B3-C43 |
| 1364 | A102-B3-C44 |
| 1365 | A102-B3-C45 |
| 1366 | A102-B3-C46 |
| 1367 | A102-B3-C47 |
| 1368 | A102-B3-C48 |
| 1369 | A102-B3-C49 |
| 1370 | A102-B3-C50 |
| 1371 | A102-B3-C51 |
| 1372 | A102-B3-C52 |
| 1373 | A102-B3-C53 |
| 1374 | A102-B3-C54 |
| 1375 | A102-B3-C55 |
| 1376 | A102-B3-C56 |
| 1377 | A102-B3-C57 |
| 1378 | A102-B3-C58 |
| 1379 | A102-B3-C59 |
| 1380 | A102-B3-C60 |
| 1381 | A102-B3-C61 |
| 1382 | A102-B3-C62 |
| 1383 | A102-B3-C63 |
| 1384 | A102-B3-C64 |
| 1385 | A102-B3-C65 |
| 1386 | A102-B3-C66 |
| 1387 | A102-B3-C67 |
| 1388 | A102-B3-C68 |
| 1389 | A102-B3-C69 |
| 1390 | A102-B3-C70 |
| 1391 | A102-B3-C71 |
| 1392 | A102-B3-C72 |
| 1393 | A102-B3-C73 |
| 1394 | A102-B3-C74 |
| 1395 | A102-B3-C75 |
| 1396 | A102-B3-C76 |
| 1397 | A102-B3-C77 |
| 1398 | A102-B3-C78 |
| 1399 | A102-B3-C79 |
| 1400 | A102-B3-C80 |

TABLE 15

| Compound | <Structure> |
|---|---|
| 1401 | A102-B3-C81 |
| 1402 | A102-B3-C82 |
| 1403 | A102-B3-C83 |
| 1404 | A102-B3-C84 |
| 1405 | A102-B3-C85 |
| 1406 | A102-B3-C86 |
| 1407 | A102-B3-C87 |
| 1408 | A102-B3-C88 |
| 1409 | A102-B3-C89 |
| 1410 | A102-B3-C90 |
| 1411 | A102-B3-C91 |
| 1412 | A102-B3-C92 |
| 1413 | A102-B3-C93 |
| 1414 | A102-B3-C94 |
| 1415 | A102-B3-C95 |
| 1416 | A102-B3-C96 |
| 1417 | A102-B3-C97 |
| 1418 | A102-B3-C98 |
| 1419 | A102-B3-C99 |
| 1420 | A102-B3-C100 |
| 1421 | A122-B13-C1 |
| 1422 | A122-B13-C2 |
| 1423 | A122-B13-C3 |
| 1424 | A122-B13-C4 |
| 1425 | A122-B13-C5 |
| 1426 | A122-B13-C6 |
| 1427 | A122-B13-C7 |
| 1428 | A122-B13-C8 |
| 1429 | A122-B13-C9 |
| 1430 | A122-B13-C10 |
| 1431 | A122-B13-C11 |
| 1432 | A122-B13-C12 |
| 1433 | A122-B13-C13 |
| 1434 | A122-B13-C14 |
| 1435 | A122-B13-C15 |
| 1436 | A122-B13-C16 |
| 1437 | A122-B13-C17 |
| 1438 | A122-B13-C18 |
| 1439 | A122-B13-C19 |
| 1440 | A122-B13-C20 |
| 1441 | A122-B13-C21 |
| 1442 | A122-B13-C22 |
| 1443 | A122-B13-C23 |
| 1444 | A122-B13-C24 |
| 1445 | A122-B13-C25 |
| 1446 | A122-B13-C26 |
| 1447 | A122-B13-C27 |
| 1448 | A122-B13-C28 |
| 1449 | A122-B13-C29 |
| 1450 | A122-B13-C30 |
| 1451 | A122-B13-C31 |
| 1452 | A122-B13-C32 |
| 1453 | A122-B13-C33 |
| 1454 | A122-B13-C34 |
| 1455 | A122-B13-C35 |
| 1456 | A122-B13-C36 |
| 1457 | A122-B13-C37 |
| 1458 | A122-B13-C38 |
| 1459 | A122-B13-C39 |
| 1460 | A122-B13-C40 |
| 1461 | A122-B13-C41 |
| 1462 | A122-B13-C42 |
| 1463 | A122-B13-C43 |
| 1464 | A122-B13-C44 |
| 1465 | A122-B13-C45 |
| 1466 | A122-B13-C46 |
| 1467 | A122-B13-C47 |
| 1468 | A122-B13-C48 |
| 1469 | A122-B13-C49 |
| 1470 | A122-B13-C50 |
| 1471 | A122-B13-C51 |
| 1472 | A122-B13-C52 |
| 1473 | A122-B13-C53 |
| 1474 | A122-B13-C54 |
| 1475 | A122-B13-C55 |
| 1476 | A122-B13-C56 |
| 1477 | A122-B13-C57 |
| 1478 | A122-B13-C58 |
| 1479 | A122-B13-C59 |
| 1480 | A122-B13-C60 |
| 1481 | A122-B13-C61 |
| 1482 | A122-B13-C62 |
| 1483 | A122-B13-C63 |
| 1484 | A122-B13-C64 |
| 1485 | A122-B13-C65 |
| 1486 | A122-B13-C66 |
| 1487 | A122-B13-C67 |
| 1488 | A122-B13-C68 |
| 1489 | A122-B13-C69 |
| 1490 | A122-B13-C70 |
| 1491 | A122-B13-C71 |
| 1492 | A122-B13-C72 |
| 1493 | A122-B13-C73 |
| 1494 | A122-B13-C74 |
| 1495 | A122-B13-C75 |
| 1496 | A122-B13-C76 |
| 1497 | A122-B13-C77 |
| 1498 | A122-B13-C78 |
| 1499 | A122-B13-C79 |
| 1500 | A122-B13-C80 |

TABLE 16

| Compound | <Structure> |
|---|---|
| 1501 | A122-B13-C81 |
| 1502 | A122-B13-C82 |
| 1503 | A122-B13-C83 |
| 1504 | A122-B13-C84 |
| 1505 | A122-B13-C85 |
| 1506 | A122-B13-C86 |
| 1507 | A122-B13-C87 |
| 1508 | A122-B13-C88 |
| 1509 | A122-B13-C89 |
| 1510 | A122-B13-C90 |
| 1511 | A122-B13-C91 |
| 1512 | A122-B13-C92 |
| 1513 | A122-B13-C93 |
| 1514 | A122-B13-C94 |
| 1515 | A122-B13-C95 |
| 1516 | A122-B13-C96 |
| 1517 | A122-B13-C97 |
| 1518 | A122-B13-C98 |
| 1519 | A122-B13-C99 |
| 1520 | A122-B13-C100 |
| 1521 | A141-B11-C1 |
| 1522 | A141-B11-C2 |
| 1523 | A141-B11-C3 |
| 1524 | |
| 1525 | A141-B11-C5 |
| 1526 | A141-B11-C6 |
| 1527 | A141-B11-C7 |
| 1528 | A141-B11-C8 |
| 1529 | A141-B11-C9 |
| 1530 | A141-B11-C10 |
| 1531 | A141-B11-C11 |
| 1532 | A141-B11-C12 |
| 1533 | A141-B11-C13 |
| 1534 | A141-B11-C14 |
| 1535 | A141-B11-C15 |
| 1536 | A141-B11-C16 |
| 1537 | A141-B11-C17 |
| 1538 | A141-B11-C18 |
| 1539 | A141-B11-C19 |
| 1540 | A141-B11-C20 |
| 1541 | A141-B11-C21 |
| 1542 | A141-B11-C22 |
| 1543 | A141-B11-C23 |
| 1544 | A141-B11-C24 |
| 1545 | A141-B11-C25 |
| 1546 | A141-B11-C26 |
| 1547 | A141-B11-C27 |
| 1548 | A141-B11-C28 |
| 1549 | A141-B11-C29 |
| 1550 | A141-B11-C30 |
| 1551 | A141-B11-C31 |
| 1552 | A141-B11-C32 |
| 1553 | A141-B11-C33 |
| 1554 | A141-B11-C34 |
| 1555 | A141-B11-C35 |
| 1556 | A141-B11-C36 |
| 1557 | A141-B11-C37 |
| 1558 | A141-B11-C38 |
| 1559 | A141-B11-C39 |
| 1560 | A141-B11-C40 |
| 1561 | A141-B11-C41 |
| 1562 | A141-B11-C42 |
| 1563 | A141-B11-C43 |
| 1564 | A141-B11-C44 |
| 1565 | A141-B11-C45 |
| 1566 | A141-B11-C46 |
| 1567 | A141-B11-C47 |
| 1568 | A141-B11-C48 |
| 1569 | A141-B11-C49 |
| 1570 | A141-B11-C50 |
| 1571 | A141-B11-C51 |
| 1572 | A141-B11-C52 |
| 1573 | A141-B11-C53 |
| 1574 | A141-B11-C54 |
| 1575 | A141-B11-C55 |
| 1576 | A141-B11-C56 |
| 1577 | A141-B11-C57 |
| 1578 | A141-B11-C58 |
| 1579 | A141-B11-C59 |
| 1580 | A141-B11-C60 |
| 1581 | A141-B11-C61 |
| 1582 | A141-B11-C62 |
| 1583 | A141-B11-C63 |
| 1584 | A141-B11-C64 |
| 1585 | A141-B11-C65 |
| 1586 | A141-B11-C66 |
| 1587 | A141-B11-C67 |
| 1588 | A141-B11-C68 |
| 1589 | A141-B11-C69 |
| 1590 | A141-B11-C70 |
| 1591 | A141-B11-C71 |
| 1592 | A141-B11-C72 |
| 1593 | A141-B11-C73 |
| 1594 | A141-B11-C74 |
| 1595 | A141-B11-C75 |
| 1596 | A141-B11-C76 |
| 1597 | A141-B11-C77 |
| 1598 | A141-B11-C78 |
| 1599 | A141-B11-C79 |
| 1600 | A141-B11-C80 |

TABLE 17

| Compound | <Structure> |
|---|---|
| 1601 | A141-B11-C81 |
| 1602 | A141-B11-C82 |
| 1603 | A141-B11-C83 |
| 1604 | A141-B11-C84 |
| 1605 | A141-B11-C85 |
| 1606 | A141-B11-C86 |
| 1607 | A141-B11-C87 |
| 1608 | A141-B11-C88 |
| 1609 | A141-B11-C89 |
| 1610 | A141-B11-C90 |
| 1611 | A141-B11-C91 |
| 1612 | A141-B11-C92 |
| 1613 | A141-B11-C93 |
| 1614 | A141-B11-C94 |
| 1615 | A141-B11-C95 |
| 1616 | A141-B11-C96 |
| 1617 | A141-B11-C97 |
| 1618 | A141-B11-C98 |
| 1619 | A141-B11-C99 |
| 1620 | A141-B11-C100 |
| 1621 | A236-B4-C1 |
| 1622 | A236-B4-C2 |
| 1623 | A236-B4-C3 |
| 1624 | A236-B4-C4 |
| 1625 | A236-B4-C5 |
| 1626 | A236-B4-C6 |
| 1627 | A236-B4-C7 |
| 1628 | A236-B4-C8 |
| 1629 | A236-B4-C9 |
| 1630 | A236-B4-C10 |
| 1631 | A236-B4-C11 |
| 1632 | A236-B4-C12 |
| 1633 | A236-B4-C13 |
| 1634 | A236-B4-C14 |
| 1635 | A236-B4-C15 |
| 1636 | A236-B4-C16 |
| 1637 | A236-B4-C17 |
| 1638 | A236-B4-C18 |
| 1639 | A236-B4-C19 |
| 1640 | A236-B4-C20 |
| 1641 | A236-B4-C21 |
| 1642 | A236-B4-C22 |
| 1643 | A236-B4-C23 |
| 1644 | A236-B4-C24 |
| 1645 | A236-B4-C25 |
| 1646 | A236-B4-C26 |
| 1647 | A236-B4-C27 |
| 1648 | A236-B4-C28 |
| 1649 | A236-B4-C29 |
| 1650 | A236-B4-C30 |
| 1651 | A236-B4-C31 |
| 1652 | A236-B4-C32 |
| 1653 | A236-B4-C33 |
| 1654 | A236-B4-C34 |
| 1655 | A236-B4-C35 |
| 1656 | A236-B4-C36 |
| 1657 | A236-B4-C37 |
| 1658 | A236-B4-C38 |
| 1659 | A236-B4-C39 |
| 1660 | A236-B4-C40 |
| 1661 | A236-B4-C41 |
| 1662 | A236-B4-C42 |
| 1663 | A236-B4-C43 |
| 1664 | A236-B4-C44 |
| 1665 | A236-B4-C45 |
| 1666 | A236-B4-C46 |
| 1667 | A236-B4-C47 |
| 1668 | A236-B4-C48 |
| 1669 | A236-B4-C49 |
| 1670 | A236-B4-C50 |
| 1671 | A236-B4-C51 |
| 1672 | A236-B4-C52 |
| 1673 | A236-B4-C53 |
| 1674 | A236-B4-C54 |
| 1675 | A236-B4-C55 |
| 1676 | A236-B4-C56 |
| 1677 | A236-B4-C57 |
| 1678 | A236-B4-C58 |
| 1679 | A236-B4-C59 |
| 1680 | A236-B4-C60 |
| 1681 | A236-B4-C61 |
| 1682 | A236-B4-C62 |
| 1683 | A236-B4-C63 |
| 1684 | A236-B4-C64 |
| 1685 | A236-B4-C65 |
| 1686 | A236-B4-C66 |
| 1687 | A236-B4-C67 |
| 1688 | A236-B4-C68 |
| 1689 | A236-B4-C69 |
| 1690 | A236-B4-C70 |
| 1691 | A236-B4-C71 |
| 1692 | A236-B4-C72 |
| 1693 | A236-B4-C73 |
| 1694 | A236-B4-C74 |
| 1695 | A236-B4-C75 |
| 1696 | A236-B4-C76 |
| 1697 | A236-B4-C77 |
| 1698 | A236-B4-C78 |
| 1699 | A236-B4-C79 |
| 1700 | A236-B4-C80 |

TABLE 18

| Compound | <Structure> |
|---|---|
| 1701 | A236-B4-C81 |
| 1702 | A236-B4-C82 |
| 1703 | A236-B4-C83 |
| 1704 | A236-B4-C84 |
| 1705 | A236-B4-C85 |
| 1706 | A236-B4-C86 |
| 1707 | A236-B4-C87 |
| 1708 | A236-B4-C88 |
| 1709 | A236-B4-C89 |
| 1710 | A236-B4-C90 |
| 1711 | A236-B4-C91 |
| 1712 | A236-B4-C92 |
| 1713 | A236-B4-C93 |
| 1714 | A236-B4-C94 |
| 1715 | A236-B4-C95 |
| 1716 | A236-B4-C96 |
| 1717 | A236-B4-C97 |
| 1718 | A236-B4-C98 |
| 1719 | A236-B4-C99 |
| 1720 | A236-B4-C100 |
| 1721 | A1-B31-C1 |
| 1722 | A1-B31-C2 |
| 1723 | A1-B31-C3 |
| 1724 | A1-B31-C4 |
| 1725 | A1-B31-C5 |
| 1726 | A1-B31-C6 |
| 1727 | |
| 1728 | A1-B31-C8 |
| 1729 | A1-B31-C9 |
| 1730 | A1-B31-C10 |
| 1731 | A1-B31-C11 |
| 1732 | A1-B31-C12 |
| 1733 | A1-B31-C13 |
| 1734 | A1-B31-C14 |
| 1735 | A1-B31-C15 |
| 1736 | A1-B31-C16 |
| 1737 | A1-B31-C17 |
| 1738 | A1-B31-C18 |
| 1739 | A1-B31-C19 |
| 1740 | A1-B31-C20 |
| 1741 | A1-B31-C21 |
| 1742 | A1-B31-C22 |
| 1743 | A1-B31-C23 |
| 1744 | A1-B31-C24 |
| 1745 | A1-B31-C25 |
| 1746 | A1-B31-C26 |
| 1747 | A1-B31-C27 |
| 1748 | A1-B31-C28 |
| 1749 | A1-B31-C29 |
| 1750 | A1-B31-C30 |
| 1751 | A1-B31-C31 |
| 1752 | A1-B31-C32 |
| 1753 | A1-B31-C33 |
| 1754 | A1-B31-C34 |
| 1755 | A1-B31-C35 |
| 1756 | A1-B31-C36 |
| 1757 | A1-B31-C37 |
| 1758 | A1-B31-C38 |
| 1759 | A1-B31-C39 |
| 1760 | A1-B31-C40 |
| 1761 | A1-B31-C41 |
| 1762 | A1-B31-C42 |
| 1763 | A1-B31-C43 |
| 1764 | A1-B31-C44 |
| 1765 | A1-B31-C45 |
| 1766 | A1-B31-C46 |
| 1767 | A1-B31-C47 |
| 1768 | A1-B31-C48 |
| 1769 | A1-B31-C49 |
| 1770 | A1-B31-C50 |
| 1771 | A1-B31-C51 |
| 1772 | A1-B31-C52 |
| 1773 | A1-B31-C53 |
| 1774 | A1-B31-C54 |
| 1775 | A1-B31-C55 |
| 1776 | A1-B31-C56 |
| 1777 | A1-B31-C57 |
| 1778 | A1-B31-C58 |
| 1779 | A1-B31-C59 |
| 1780 | A1-B31-C60 |
| 1781 | A1-B31-C61 |
| 1782 | A1-B31-C62 |
| 1783 | A1-B31-C63 |
| 1784 | A1-B31-C64 |
| 1785 | A1-B31-C65 |
| 1786 | A1-B31-C66 |
| 1787 | A1-B31-C67 |
| 1788 | A1-B31-C68 |
| 1789 | A1-B31-C69 |
| 1790 | A1-B31-C70 |
| 1791 | A1-B31-C71 |
| 1792 | A1-B31-C72 |
| 1793 | A1-B31-C73 |
| 1794 | A1-B31-C74 |
| 1795 | A1-B31-C75 |
| 1796 | A1-B31-C76 |
| 1797 | A1-B31-C77 |
| 1798 | A1-B31-C78 |
| 1799 | A1-B31-C79 |
| 1800 | A1-B31-C80 |

TABLE 19

| Compound | <Structure> |
|---|---|
| 1801 | A1-B31-C81 |
| 1802 | A1-B31-C82 |
| 1803 | A1-B31-C83 |
| 1804 | A1-B31-C84 |
| 1805 | A1-B31-C85 |
| 1806 | A1-B31-C86 |
| 1807 | A1-B31-C87 |
| 1808 | A1-B31-C88 |
| 1809 | A1-B31-C89 |
| 1810 | A1-B31-C90 |
| 1811 | A1-B31-C91 |
| 1812 | A1-B31-C92 |
| 1813 | A1-B31-C93 |
| 1814 | A1-B31-C94 |
| 1815 | A1-B31-C95 |
| 1816 | A1-B31-C96 |
| 1817 | A1-B31-C97 |
| 1818 | A1-B31-C98 |
| 1819 | A1-B31-C99 |
| 1820 | A1-B31-C100 |
| 1821 | A83-B29-C1 |
| 1822 | A83-B29-C2 |
| 1823 | A83-B29-C3 |
| 1824 | A83-B29-C4 |
| 1825 | A83-B29-C5 |
| 1826 | A83-B29-C6 |
| 1827 | A83-B29-C7 |
| 1828 | A83-B29-C8 |
| 1829 | A83-B29-C9 |
| 1830 | A83-B29-C10 |
| 1831 | A83-B29-C11 |
| 1832 | A83-B29-C12 |
| 1833 | A83-B29-C13 |
| 1834 | A83-B29-C14 |
| 1835 | A83-B29-C15 |
| 1836 | A83-B29-C16 |
| 1837 | A83-B29-C17 |
| 1838 | A83-B29-C18 |
| 1839 | A83-B29-C19 |
| 1840 | A83-B29-C20 |
| 1841 | A83-B29-C21 |
| 1842 | A83-B29-C22 |
| 1843 | A83-B29-C23 |
| 1844 | A83-B29-C24 |
| 1845 | A83-B29-C25 |
| 1846 | A83-B29-C26 |
| 1847 | A83-B29-C27 |
| 1848 | A83-B29-C28 |
| 1849 | A83-B29-C29 |
| 1850 | A83-B29-C30 |
| 1851 | A83-B29-C31 |
| 1852 | A83-B29-C32 |
| 1853 | A83-B29-C33 |
| 1854 | A83-B29-C34 |
| 1855 | A83-B29-C35 |
| 1856 | A83-B29-C36 |
| 1857 | A83-B29-C37 |
| 1858 | A83-B29-C38 |
| 1859 | A83-B29-C39 |
| 1860 | A83-B29-C40 |
| 1861 | A83-B29-C41 |
| 1862 | A83-B29-C42 |
| 1863 | A83-B29-C43 |
| 1864 | A83-B29-C44 |
| 1865 | A83-B29-C45 |
| 1866 | A83-B29-C46 |
| 1867 | A83-B29-C47 |
| 1868 | A83-B29-C48 |
| 1869 | A83-B29-C49 |
| 1870 | A83-B29-C50 |
| 1871 | A83-B29-C51 |
| 1872 | A83-B29-C52 |
| 1873 | A83-B29-C53 |
| 1874 | A83-B29-C54 |
| 1875 | A83-B29-C55 |
| 1876 | A83-B29-C56 |
| 1877 | A83-B29-C57 |
| 1878 | A83-B29-C58 |
| 1879 | A83-B29-C59 |
| 1880 | A83-B29-C60 |
| 1881 | A83-B29-C61 |
| 1882 | A83-B29-C62 |
| 1883 | A83-B29-C63 |
| 1884 | A83-B29-C64 |
| 1885 | A83-B29-C65 |
| 1886 | A83-B29-C66 |
| 1887 | A83-B29-C67 |
| 1888 | A83-B29-C68 |
| 1889 | A83-B29-C69 |
| 1890 | A83-B29-C70 |
| 1891 | A83-B29-C71 |
| 1892 | A83-B29-C72 |
| 1893 | A83-B29-C73 |
| 1894 | A83-B29-C74 |
| 1895 | A83-B29-C75 |
| 1896 | A83-B29-C76 |
| 1897 | A83-B29-C77 |
| 1898 | A83-B29-C78 |
| 1899 | A83-B29-C79 |
| 1900 | A83-B29-C80 |

TABLE 20

| Compound | <Structure> |
|---|---|
| 1901 | A83-B29-C81 |
| 1902 | A83-B29-C82 |
| 1903 | A83-B29-C83 |
| 1904 | A83-B29-C84 |
| 1905 | A83-B29-C85 |
| 1906 | A83-B29-C86 |
| 1907 | A83-B29-C87 |
| 1908 | A83-B29-C88 |
| 1909 | A83-B29-C89 |
| 1910 | A83-B29-C90 |
| 1911 | A83-B29-C91 |
| 1912 | A83-B29-C92 |
| 1913 | A83-B29-C93 |
| 1914 | A83-B29-C94 |
| 1915 | A83-B29-C95 |
| 1916 | A83-B29-C96 |
| 1917 | A83-B29-C97 |
| 1918 | A83-B29-C98 |
| 1919 | A83-B29-C99 |
| 1920 | A83-B29-C100 |
| 1921 | A121-B25-C1 |
| 1922 | A121-B25-C2 |
| 1923 | A121-B25-C3 |
| 1924 | A121-B25-C4 |
| 1925 | A121-B25-C5 |
| 1926 | A121-B25-C6 |
| 1927 | A121-B25-C7 |
| 1928 | A121-B25-C8 |
| 1929 | A121-B25-C9 |
| 1930 | A121-B25-C10 |
| 1931 | A121-B25-C11 |
| 1932 | A121-B25-C12 |
| 1933 | A121-B25-C13 |
| 1934 | A121-B25-C14 |
| 1935 | A121-B25-C15 |
| 1936 | A121-B25-C16 |
| 1937 | A121-B25-C17 |
| 1938 | A121-B25-C18 |
| 1939 | A121-B25-C19 |
| 1940 | A121-B25-C20 |
| 1941 | A121-B25-C21 |
| 1942 | A121-B25-C22 |
| 1943 | A121-B25-C23 |
| 1944 | A121-B25-C24 |
| 1945 | A121-B25-C25 |
| 1946 | A121-B25-C26 |
| 1947 | A121-B25-C27 |
| 1948 | A121-B25-C28 |
| 1949 | A121-B25-C29 |
| 1950 | A121-B25-C30 |
| 1951 | A121-B25-C31 |
| 1952 | A121-B25-C32 |
| 1953 | A121-B25-C33 |
| 1954 | A121-B25-C34 |
| 1955 | A121-B25-C35 |
| 1956 | A121-B25-C36 |
| 1957 | A121-B25-C37 |
| 1958 | A121-B25-C38 |
| 1959 | A121-B25-C39 |
| 1960 | A121-B25-C40 |
| 1961 | A121-B25-C41 |
| 1962 | A121-B25-C42 |
| 1963 | A121-B25-C43 |
| 1964 | A121-B25-C44 |
| 1965 | A121-B25-C45 |
| 1966 | A121-B25-C46 |
| 1967 | A121-B25-C47 |
| 1968 | A121-B25-C48 |
| 1969 | A121-B25-C49 |
| 1970 | A121-B25-C50 |
| 1971 | A121-B25-C51 |
| 1972 | A121-B25-C52 |
| 1973 | A121-B25-C53 |
| 1974 | A121-B25-C54 |
| 1975 | A121-B25-C55 |
| 1976 | A121-B25-C56 |
| 1977 | A121-B25-C57 |
| 1978 | A121-B25-C58 |
| 1979 | A121-B25-C59 |
| 1980 | A121-B25-C60 |
| 1981 | A121-B25-C61 |
| 1982 | A121-B25-C62 |
| 1983 | A121-B25-C63 |
| 1984 | A121-B25-C64 |
| 1985 | A121-B25-C65 |
| 1986 | A121-B25-C66 |
| 1987 | A121-B25-C67 |
| 1988 | A121-B25-C68 |
| 1989 | A121-B25-C69 |
| 1990 | A121-B25-C70 |
| 1991 | A121-B25-C71 |
| 1992 | A121-B25-C72 |
| 1993 | A121-B25-C73 |
| 1994 | A121-B25-C74 |
| 1995 | A121-B25-C75 |
| 1996 | A121-B25-C76 |
| 1997 | A121-B25-C77 |
| 1998 | A121-B25-C78 |
| 1999 | A121-B25-C79 |
| 2000 | A121-B25-C80 |

TABLE 21

| Compound | <Structure> |
|---|---|
| 2001 | A121-B25-C81 |
| 2002 | A121-B25-C82 |
| 2003 | A121-B25-C83 |
| 2004 | A121-B25-C84 |
| 2005 | A121-B25-C85 |
| 2006 | A121-B25-C86 |
| 2007 | A121-B25-C87 |
| 2008 | A121-B25-C88 |
| 2009 | A121-B25-C89 |
| 2010 | A121-B25-C90 |
| 2011 | A121-B25-C91 |
| 2012 | A121-B25-C92 |
| 2013 | A121-B25-C93 |
| 2014 | A121-B25-C94 |
| 2015 | A121-B25-C95 |
| 2016 | A121-B25-C96 |
| 2017 | A121-B25-C97 |
| 2018 | A121-B25-C98 |
| 2019 | A121-B25-C99 |
| 2020 | A121-B25-C100 |
| 2021 | A141-B42-C1 |
| 2022 | A141-B42-C2 |
| 2023 | A141-B42-C3 |
| 2024 | A141-B42-C4 |
| 2025 | A141-B42-C5 |
| 2026 | A141-B42-C6 |
| 2027 | A141-B42-C7 |
| 2028 | A141-B42-C8 |
| 2029 | A141-B42-C9 |
| 2030 | A141-B42-C10 |
| 2031 | A141-B42-C11 |
| 2032 | A141-B42-C12 |
| 2033 | A141-B42-C13 |
| 2034 | A141-B42-C14 |
| 2035 | A141-B42-C15 |
| 2036 | A141-B42-C16 |
| 2037 | A141-B42-C17 |
| 2038 | A141-B42-C18 |
| 2039 | A141-B42-C19 |
| 2040 | A141-B42-C20 |
| 2041 | A141-B42-C21 |
| 2042 | A141-B42-C22 |
| 2043 | A141-B42-C23 |
| 2044 | A141-B42-C24 |
| 2045 | A141-B42-C25 |
| 2046 | A141-B42-C26 |
| 2047 | A141-B42-C27 |
| 2048 | A141-B42-C28 |
| 2049 | A141-B42-C29 |
| 2050 | A141-B42-C30 |
| 2051 | A141-B42-C31 |
| 2052 | A141-B42-C32 |
| 2053 | A141-B42-C33 |
| 2054 | A141-B42-C34 |
| 2055 | A141-B42-C35 |
| 2056 | A141-B42-C36 |
| 2057 | A141-B42-C37 |
| 2058 | A141-B42-C38 |
| 2059 | A141-B42-C39 |
| 2060 | A141-B42-C40 |
| 2061 | A141-B42-C41 |
| 2062 | A141-B42-C42 |
| 2063 | A141-B42-C43 |
| 2064 | A141-B42-C44 |
| 2065 | A141-B42-C45 |
| 2066 | A141-B42-C46 |
| 2067 | A141-B42-C47 |
| 2068 | A141-B42-C48 |
| 2069 | A141-B42-C49 |
| 2070 | A141-B42-C50 |
| 2071 | A141-B42-C51 |
| 2072 | A141-B42-C52 |
| 2073 | A141-B42-C53 |
| 2074 | A141-B42-C54 |
| 2075 | A141-B42-C55 |
| 2076 | A141-B42-C56 |
| 2077 | A141-B42-C57 |
| 2078 | A141-B42-C58 |
| 2079 | A141-B42-C59 |
| 2080 | A141-B42-C60 |
| 2081 | A141-B42-C61 |
| 2082 | A141-B42-C62 |
| 2083 | A141-B42-C63 |
| 2084 | A141-B42-C64 |
| 2085 | A141-B42-C65 |
| 2086 | A141-B42-C66 |
| 2087 | A141-B42-C67 |
| 2088 | A141-B42-C68 |
| 2089 | A141-B42-C69 |
| 2090 | A141-B42-C70 |
| 2091 | A141-B42-C71 |
| 2092 | A141-B42-C72 |
| 2093 | A141-B42-C73 |
| 2094 | A141-B42-C74 |
| 2095 | A141-B42-C75 |
| 2096 | A141-B42-C76 |
| 2097 | A141-B42-C77 |
| 2098 | A141-B42-C78 |
| 2099 | A141-B42-C79 |
| 2100 | A141-B42-C80 |

TABLE 22

| Compound | <Structure> |
|---|---|
| 2101 | A141-B42-C81 |
| 2102 | A141-B42-C82 |
| 2103 | A141-B42-C83 |
| 2104 | A141-B42-C84 |
| 2105 | A141-B42-C85 |
| 2106 | A141-B42-C86 |
| 2107 | A141-B42-C87 |
| 2108 | A141-B42-C88 |
| 2109 | A141-B42-C89 |
| 2110 | A141-B42-C90 |
| 2111 | A141-B42-C91 |
| 2112 | A141-B42-C92 |
| 2113 | A141-B42-C93 |
| 2114 | A141-B42-C94 |
| 2115 | A141-B42-C95 |
| 2116 | A141-B42-C96 |
| 2117 | A141-B42-C97 |
| 2118 | A141-B42-C98 |
| 2119 | A141-B42-C99 |
| 2120 | A141-B42-C100 |
| 2121 | A174-B50-C1 |
| 2122 | A174-B50-C2 |
| 2123 | A174-B50-C3 |
| 2124 | A174-B50-C4 |
| 2125 | A174-B50-C5 |
| 2126 | A174-B50-C6 |
| 2127 | A174-B50-C7 |
| 2128 | A174-B50-C8 |
| 2129 | A174-B50-C9 |
| 2130 | A174-B50-C10 |
| 2131 | A174-B50-C11 |
| 2132 | A174-B50-C12 |
| 2133 | A174-B50-C13 |
| 2134 | A174-B50-C14 |
| 2135 | A174-B50-C15 |
| 2136 | A174-B50-C16 |
| 2137 | A174-B50-C17 |
| 2138 | A174-B50-C18 |
| 2139 | A174-B50-C19 |
| 2140 | A174-B50-C20 |
| 2141 | A174-B50-C21 |
| 2142 | A174-B50-C22 |
| 2143 | A174-B50-C23 |
| 2144 | A174-B50-C24 |
| 2145 | A174-B50-C25 |
| 2146 | A174-B50-C26 |
| 2147 | A174-B50-C27 |
| 2148 | A174-B50-C28 |
| 2149 | A174-B50-C29 |
| 2150 | A174-B50-C30 |
| 2151 | A174-B50-C31 |
| 2152 | A174-B50-C32 |
| 2153 | A174-B50-C33 |
| 2154 | A174-B50-C34 |
| 2155 | A174-B50-C35 |
| 2156 | A174-B50-C36 |
| 2157 | A174-B50-C37 |
| 2158 | A174-B50-C38 |
| 2159 | A174-B50-C39 |
| 2160 | A174-B50-C40 |
| 2161 | A174-B50-C41 |
| 2162 | A174-B50-C42 |
| 2163 | A174-B50-C43 |
| 2164 | A174-B50-C44 |
| 2165 | A174-B50-C45 |
| 2166 | A174-B50-C46 |
| 2167 | A174-B50-C47 |
| 2168 | A174-B50-C48 |
| 2169 | A174-B50-C49 |
| 2170 | A174-B50-C50 |
| 2171 | A174-B50-C51 |
| 2172 | A174-B50-C52 |
| 2173 | A174-B50-C53 |
| 2174 | A174-B50-C54 |
| 2175 | A174-B50-C55 |
| 2176 | A174-B50-C56 |
| 2177 | A174-B50-C57 |
| 2178 | A174-B50-C58 |
| 2179 | A174-B50-C59 |
| 2180 | A174-B50-C60 |
| 2181 | A174-B50-C61 |
| 2182 | A174-B50-C62 |
| 2183 | A174-B50-C63 |
| 2184 | A174-B50-C64 |
| 2185 | A174-B50-C65 |
| 2186 | A174-B50-C66 |
| 2187 | A174-B50-C67 |
| 2188 | A174-B50-C68 |
| 2189 | A174-B50-C69 |
| 2190 | A174-B50-C70 |
| 2191 | A174-B50-C71 |
| 2192 | A174-B50-C72 |
| 2193 | A174-B50-C73 |
| 2194 | A174-B50-C74 |
| 2195 | A174-B50-C75 |
| 2196 | A174-B50-C76 |
| 2197 | A174-B50-C77 |
| 2198 | A174-B50-C78 |
| 2199 | A174-B50-C79 |
| 2200 | A174-B50-C80 |

TABLE 23

| Compound | <Structure> |
|---|---|
| 2201 | A174-B50-C81 |
| 2202 | A174-B50-C82 |
| 2203 | A174-B50-C83 |
| 2204 | A174-B50-C84 |
| 2205 | A174-B50-C85 |
| 2206 | A174-B50-C86 |
| 2207 | A174-B50-C87 |
| 2208 | A174-B50-C88 |
| 2209 | A174-B50-C89 |
| 2210 | A174-B50-C90 |
| 2211 | A174-B50-C91 |
| 2212 | A174-B50-C92 |
| 2213 | A174-B50-C93 |
| 2214 | A174-B50-C94 |
| 2215 | A174-B50-C95 |
| 2216 | A174-B50-C96 |
| 2217 | A174-B50-C97 |
| 2218 | A174-B50-C98 |
| 2219 | A174-B50-C99 |
| 2220 | A174-B50-C100 |
| 2221 | A242-B38-C1 |
| 2222 | A242-B38-C2 |
| 2223 | A242-B38-C3 |
| 2224 | A242-B38-C4 |
| 2225 | A242-B38-C5 |
| 2226 | A242-B38-C6 |
| 2227 | A242-B38-C7 |
| 2228 | A242-B38-C8 |
| 2229 | A242-B38-C9 |
| 2230 | A242-B38-C10 |
| 2231 | A242-B38-C11 |
| 2232 | A242-B38-C12 |
| 2233 | A242-B38-C13 |
| 2234 | A242-B38-C14 |
| 2235 | A242-B38-C15 |
| 2236 | A242-B38-C16 |
| 2237 | A242-B38-C17 |
| 2238 | A242-B38-C18 |
| 2239 | A242-B38-C19 |
| 2240 | A242-B38-C20 |
| 2241 | A242-B38-C21 |
| 2242 | A242-B38-C22 |
| 2243 | A242-B38-C23 |
| 2244 | A242-B38-C24 |
| 2245 | A242-B38-C25 |
| 2246 | A242-B38-C26 |
| 2247 | A242-B38-C27 |
| 2248 | A242-B38-C28 |
| 2249 | A242-B38-C29 |
| 2250 | A242-B38-C30 |
| 2251 | A242-B38-C31 |
| 2252 | A242-B38-C32 |
| 2253 | A242-B38-C33 |
| 2254 | A242-B38-C34 |
| 2255 | A242-B38-C35 |
| 2256 | A242-B38-C36 |
| 2257 | A242-B38-C37 |
| 2258 | A242-B38-C38 |
| 2259 | A242-B38-C39 |
| 2260 | A242-B38-C40 |
| 2261 | A242-B38-C41 |
| 2262 | A242-B38-C42 |
| 2263 | A242-B38-C43 |
| 2264 | A242-B38-C44 |
| 2265 | A242-B38-C45 |
| 2266 | A242-B38-C46 |
| 2267 | A242-B38-C47 |
| 2268 | A242-B38-C48 |
| 2269 | A242-B38-C49 |
| 2270 | A242-B38-C50 |
| 2271 | A242-B38-C51 |
| 2272 | A242-B38-C52 |
| 2273 | A242-B38-C53 |
| 2274 | A242-B38-C54 |
| 2275 | A242-B38-C55 |
| 2276 | A242-B38-C56 |
| 2277 | A242-B38-C57 |
| 2278 | A242-B38-C58 |
| 2279 | A242-B38-C59 |
| 2280 | A242-B38-C60 |
| 2281 | A242-B38-C61 |
| 2282 | A242-B38-C62 |
| 2283 | A242-B38-C63 |
| 2284 | A242-B38-C64 |
| 2285 | A242-B38-C65 |
| 2286 | A242-B38-C66 |
| 2287 | A242-B38-C67 |
| 2288 | A242-B38-C68 |
| 2289 | A242-B38-C69 |
| 2290 | A242-B38-C70 |
| 2291 | A242-B38-C71 |
| 2292 | A242-B38-C72 |
| 2293 | A242-B38-C73 |
| 2294 | A242-B38-C74 |
| 2295 | A242-B38-C75 |
| 2296 | A242-B38-C76 |
| 2297 | A242-B38-C77 |
| 2298 | A242-B38-C78 |
| 2299 | A242-B38-C79 |
| 2300 | A242-B38-C80 |

TABLE 24

| Compound | <Structure> |
|---|---|
| 2301 | A242-B38-C81 |
| 2302 | A242-B38-C82 |
| 2303 | A242-B38-C83 |
| 2304 | A242-B38-C84 |
| 2305 | A242-B38-C85 |
| 2306 | A242-B38-C86 |
| 2307 | A242-B38-C87 |
| 2308 | A242-B38-C88 |
| 2309 | A242-B38-C89 |
| 2310 | A242-B38-C90 |
| 2311 | A242-B38-C91 |
| 2312 | A242-B38-C92 |
| 2313 | A242-B38-C93 |
| 2314 | A242-B38-C94 |
| 2315 | A242-B38-C95 |
| 2316 | A242-B38-C96 |
| 2317 | A242-B38-C97 |
| 2318 | A242-B38-C98 |
| 2319 | A242-B38-C99 |
| 2320 | A242-B38-C100 |
| 2321 | A1-B1-C1 |
| 2322 | A1-B2-C1 |
| 2323 | |
| 2324 | A1-B4-C1 |
| 2325 | A1-B5-C1 |
| 2326 | A1-B6-C1 |
| 2327 | A1-B7-C1 |
| 2328 | A1-B8-C1 |
| 2329 | A1-B9-C1 |
| 2330 | A1-B10-C1 |
| 2331 | A1-B11-C1 |
| 2332 | A1-B12-C1 |
| 2333 | A1-B13-C1 |
| 2334 | A1-B14-C1 |
| 2335 | A1-B15-C1 |
| 2336 | A1-B16-C1 |
| 2337 | A1-B17-C1 |
| 2338 | A1-B18-C1 |
| 2339 | A1-B19-C1 |
| 2340 | A1-B20-C1 |
| 2341 | A1-B21-C1 |
| 2342 | A1-B22-C1 |
| 2343 | A1-B23-C1 |
| 2344 | A1-B24-C1 |
| 2345 | A1-B25-C1 |
| 2346 | A1-B26-C1 |
| 2347 | A1-B27-C1 |
| 2348 | A1-B28-C1 |
| 2349 | A1-B29-C1 |
| 2350 | A1-B30-C1 |
| 2351 | |
| 2352 | A1-B32-C1 |
| 2353 | A1-B33-C1 |
| 2354 | A1-B34-C1 |
| 2355 | A1-B35-C1 |
| 2356 | A1-B36-C1 |
| 2357 | A1-B37-C1 |
| 2358 | A1-B38-C1 |
| 2359 | A1-B39-C1 |
| 2360 | A1-B40-C1 |
| 2361 | A1-B41-C1 |
| 2362 | A1-B42-C1 |
| 2363 | A1-B43-C1 |
| 2364 | A1-B44-C1 |
| 2365 | A1-B45-C1 |
| 2366 | A1-B46-C1 |
| 2367 | A1-B47-C1 |
| 2368 | A1-B48-C1 |
| 2369 | A1-B49-C1 |
| 2370 | A1-B50-C1 |
| 2371 | A5-B1-C12 |
| 2372 | A5-B2-C12 |
| 2373 | A5-B3-C12 |
| 2374 | A5-B4-C12 |
| 2375 | A5-B5-C12 |
| 2376 | A5-B6-C12 |
| 2377 | A5-B7-C12 |
| 2378 | A5-B8-C12 |
| 2379 | A5-B9-C12 |
| 2380 | A5-B10-C12 |
| 2381 | A5-B11-C12 |
| 2382 | A5-B12-C12 |
| 2383 | A5-B13-C12 |
| 2384 | A5-B14-C12 |
| 2385 | A5-B15-C12 |
| 2386 | A5-B16-C12 |
| 2387 | A5-B17-C12 |
| 2388 | A5-B18-C12 |
| 2389 | A5-B19-C12 |
| 2390 | A5-B20-C12 |
| 2391 | A5-B21-C12 |
| 2392 | A5-B22-C12 |
| 2393 | A5-B23-C12 |
| 2394 | A5-B24-C12 |
| 2395 | A5-B25-C12 |
| 2396 | A5-B26-C12 |
| 2397 | A5-B27-C12 |
| 2398 | A5-B28-C12 |
| 2399 | A5-B29-C12 |
| 2400 | A5-B30-C12 |

TABLE 25

| Compound | <Structure> |
|---|---|
| 2401 | A5-B31-C12 |
| 2402 | A5-B32-C12 |
| 2403 | A5-B33-C12 |
| 2404 | A5-B34-C12 |
| 2405 | A5-B35-C12 |
| 2406 | A5-B36-C12 |
| 2407 | A5-B37-C12 |
| 2408 | A5-B38-C12 |
| 2409 | A5-B39-C12 |
| 2410 | A5-B40-C12 |
| 2411 | A5-B41-C12 |
| 2412 | A5-B42-C12 |
| 2413 | A5-B43-C12 |
| 2414 | A5-B44-C12 |
| 2415 | A5-B45-C12 |
| 2416 | A5-B46-C12 |
| 2417 | A5-B47-C12 |
| 2418 | A5-B48-C12 |
| 2419 | A5-B49-C12 |
| 2420 | A5-B50-C12 |
| 2421 | A34-B1-C13 |
| 2422 | A34-B2-C13 |
| 2423 | A34-B3-C13 |
| 2424 | A34-B4-C13 |
| 2425 | A34-B5-C13 |
| 2426 | A34-B6-C13 |
| 2427 | A34-B7-C13 |
| 2428 | A34-B8-C13 |
| 2429 | A34-B9-C13 |
| 2430 | A34-B10-C13 |
| 2431 | A34-B11-C13 |
| 2432 | A34-B12-C13 |
| 2433 | A34-B13-C13 |
| 2434 | A34-B14-C13 |
| 2435 | A34-B15-C13 |
| 2436 | A34-B16-C13 |
| 2437 | A34-B17-C13 |
| 2438 | A34-B18-C13 |
| 2439 | A34-B19-C13 |
| 2440 | A34-B20-C13 |
| 2441 | A34-B21-C13 |
| 2442 | A34-B22-C13 |
| 2443 | A34-B23-C13 |
| 2444 | A34-B24-C13 |
| 2445 | A34-B25-C13 |
| 2446 | A34-B26-C13 |
| 2447 | A34-B27-C13 |
| 2448 | A34-B28-C13 |
| 2449 | A34-B29-C13 |
| 2450 | A34-B30-C13 |
| 2451 | A34-B31-C13 |
| 2452 | A34-B32-C13 |
| 2453 | A34-B33-C13 |
| 2454 | A34-B34-C13 |
| 2455 | A34-B35-C13 |
| 2456 | A34-B36-C13 |
| 2457 | A34-B37-C13 |
| 2458 | A34-B38-C13 |
| 2459 | A34-B39-C13 |
| 2460 | A34-B40-C13 |
| 2461 | A34-B41-C13 |
| 2462 | A34-B42-C13 |
| 2463 | A34-B43-C13 |
| 2464 | A34-B44-C13 |
| 2465 | A34-B45-C13 |
| 2466 | A34-B46-C13 |
| 2467 | A34-B47-C13 |
| 2468 | A34-B48-C13 |
| 2469 | A34-B49-C13 |
| 2470 | A34-B50-C13 |
| 2471 | A82-B1-C14 |
| 2472 | A82-B2-C14 |
| 2473 | A82-B3-C14 |
| 2474 | A82-B4-C14 |
| 2475 | A82-B5-C14 |
| 2476 | A82-B6-C14 |
| 2477 | A82-B7-C14 |
| 2478 | A82-B8-C14 |
| 2479 | A82-B9-C14 |
| 2480 | A82-B10-C14 |
| 2481 | A82-B11-C14 |
| 2482 | A82-B12-C14 |
| 2483 | A82-B13-C14 |
| 2484 | A82-B14-C14 |
| 2485 | A82-B15-C14 |
| 2486 | A82-B16-C14 |
| 2487 | A82-B17-C14 |
| 2488 | A82-B18-C14 |
| 2489 | A82-B19-C14 |
| 2490 | A82-B20-C14 |
| 2491 | A82-B21-C14 |
| 2492 | A82-B22-C14 |
| 2493 | A82-B23-C14 |
| 2494 | A82-B24-C14 |
| 2495 | A82-B25-C14 |
| 2496 | A82-B26-C14 |
| 2497 | A82-B27-C14 |
| 2498 | A82-B28-C14 |
| 2499 | A82-B29-C14 |
| 2500 | A82-B30-C14 |

TABLE 26

| Compound | <Structure> |
|---|---|
| 2501 | A82-B31-C14 |
| 2502 | A82-B32-C14 |
| 2503 | A82-B33-C14 |
| 2504 | A82-B34-C14 |
| 2505 | A82-B35-C14 |
| 2506 | A82-B36-C14 |
| 2507 | A82-B37-C14 |
| 2508 | A82-B38-C14 |
| 2509 | A82-B39-C14 |
| 2510 | A82-B40-C14 |
| 2511 | A82-B41-C14 |
| 2512 | A82-B42-C14 |
| 2513 | A82-B43-C14 |
| 2514 | A82-B44-C14 |
| 2515 | A82-B45-C14 |
| 2516 | A82-B46-C14 |
| 2517 | A82-B47-C14 |
| 2518 | A82-B48-C14 |
| 2519 | A82-B49-C14 |
| 2520 | A82-B50-C14 |
| 2521 | A110-B1-C17 |
| 2522 | A110-B2-C17 |
| 2523 | A110-B3-C17 |
| 2524 | A110-B4-C17 |
| 2525 | A110-B5-C17 |
| 2526 | A110-B6-C17 |
| 2527 | A110-B7-C17 |
| 2528 | A110-B8-C17 |
| 2529 | A110-B9-C17 |
| 2530 | A110-B10-C17 |
| 2531 | A110-B11-C17 |
| 2532 | A110-B12-C17 |
| 2533 | A110-B13-C17 |
| 2534 | A110-B14-C17 |
| 2535 | A110-B15-C17 |
| 2536 | A110-B16-C17 |
| 2537 | A110-B17-C17 |
| 2538 | A110-B18-C17 |
| 2539 | A110-B19-C17 |
| 2540 | A110-B20-C17 |
| 2541 | A110-B21-C17 |
| 2542 | A110-B22-C17 |
| 2543 | A110-B23-C17 |
| 2544 | A110-B24-C17 |
| 2545 | A110-B25-C17 |
| 2546 | A110-B26-C17 |
| 2547 | A110-B27-C17 |
| 2548 | A110-B28-C17 |
| 2549 | A110-B29-C17 |
| 2550 | A110-B30-C17 |
| 2551 | A110-B31-C17 |
| 2552 | A110-B32-C17 |
| 2553 | A110-B33-C17 |
| 2554 | A110-B34-C17 |
| 2555 | A110-B35-C17 |
| 2556 | A110-B36-C17 |
| 2557 | A110-B37-C17 |
| 2558 | A110-B38-C17 |
| 2559 | A110-B39-C17 |
| 2560 | A110-B40-C17 |
| 2561 | A110-B41-C17 |
| 2562 | A110-B42-C17 |
| 2563 | A110-B43-C17 |
| 2564 | A110-B44-C17 |
| 2565 | A110-B45-C17 |
| 2566 | A110-B46-C17 |
| 2567 | A110-B47-C17 |
| 2568 | A110-B48-C17 |
| 2569 | A110-B49-C17 |
| 2570 | A110-B50-C17 |
| 2571 | A118-B1-C21 |
| 2572 | A118-B2-C21 |
| 2573 | A118-B3-C21 |
| 2574 | A118-B4-C21 |
| 2575 | A118-B5-C21 |
| 2576 | A118-B6-C21 |
| 2577 | A118-B7-C21 |
| 2578 | A118-B8-C21 |
| 2579 | A118-B9-C21 |
| 2580 | A118-B10-C21 |
| 2581 | A118-B11-C21 |
| 2582 | A118-B12-C21 |
| 2583 | A118-B13-C21 |
| 2584 | A118-B14-C21 |
| 2585 | A118-B15-C21 |
| 2586 | A118-B16-C21 |
| 2587 | A118-B17-C21 |
| 2588 | A118-B18-C21 |
| 2589 | A118-B19-C21 |
| 2590 | A118-B20-C21 |
| 2591 | A118-B21-C21 |
| 2592 | A118-B22-C21 |
| 2593 | A118-B23-C21 |
| 2594 | A118-B24-C21 |
| 2595 | A118-B25-C21 |
| 2596 | A118-B26-C21 |
| 2597 | A118-B27-C21 |
| 2598 | A118-B28-C21 |
| 2599 | A118-B29-C21 |
| 2600 | A118-B30-C21 |

TABLE 27

| Compound | <Structure> |
|---|---|
| 2601 | A118-B31-C21 |
| 2602 | A118-B32-C21 |
| 2603 | A118-B33-C21 |
| 2604 | A118-B34-C21 |
| 2605 | A118-B35-C21 |
| 2606 | A118-B36-C21 |
| 2607 | A118-B37-C21 |
| 2608 | A118-B38-C21 |
| 2609 | A118-B39-C21 |
| 2610 | A118-B40-C21 |
| 2611 | A118-B41-C21 |
| 2612 | A118-B42-C21 |
| 2613 | A118-B43-C21 |
| 2614 | A118-B44-C21 |
| 2615 | A118-B45-C21 |
| 2616 | A118-B46-C21 |
| 2617 | A118-B47-C21 |
| 2618 | A118-B48-C21 |
| 2619 | A118-B49-C21 |
| 2620 | A118-B50-C21 |
| 2621 | A132-B1-C30 |
| 2622 | A132-B2-C30 |
| 2623 | A132-B3-C30 |
| 2624 | A132-B4-C30 |
| 2625 | A132-B5-C30 |
| 2626 | A132-B6-C30 |
| 2627 | A132-B7-C30 |
| 2628 | A132-B8-C30 |
| 2629 | A132-B9-C30 |
| 2630 | A132-B10-C30 |
| 2631 | A132-B11-C30 |
| 2632 | A132-B12-C30 |
| 2633 | A132-B13-C30 |
| 2634 | A132-B14-C30 |
| 2635 | A132-B15-C30 |
| 2636 | A132-B16-C30 |
| 2637 | A132-B17-C30 |
| 2638 | A132-B18-C30 |
| 2639 | A132-B19-C30 |
| 2640 | A132-B20-C30 |
| 2641 | A132-B21-C30 |
| 2642 | A132-B22-C30 |
| 2643 | A132-B23-C30 |
| 2644 | A132-B24-C30 |
| 2645 | A132-B25-C30 |
| 2646 | A132-B26-C30 |
| 2647 | A132-B27-C30 |
| 2648 | A132-B28-C30 |
| 2649 | A132-B29-C30 |
| 2650 | A132-B30-C30 |
| 2651 | A132-B31-C30 |
| 2652 | A132-B32-C30 |
| 2653 | A132-B33-C30 |
| 2654 | A132-B34-C30 |
| 2655 | A132-B35-C30 |
| 2656 | A132-B36-C30 |
| 2657 | A132-B37-C30 |
| 2658 | A132-B38-C30 |
| 2659 | A132-B39-C30 |
| 2660 | A132-B40-C30 |
| 2661 | A132-B41-C30 |
| 2662 | A132-B42-C30 |
| 2663 | A132-B43-C30 |
| 2664 | A132-B44-C30 |
| 2665 | A132-B45-C30 |
| 2666 | A132-B46-C30 |
| 2667 | A132-B47-C30 |
| 2668 | A132-B48-C30 |
| 2669 | A132-B49-C30 |
| 2670 | A132-B50-C30 |
| 2671 | A141-B1-C37 |
| 2672 | A141-B2-C37 |
| 2673 | A141-B3-C37 |
| 2674 | A141-B4-C37 |
| 2675 | A141-B5-C37 |
| 2676 | A141-B6-C37 |
| 2677 | A141-B7-C37 |
| 2678 | A141-B8-C37 |
| 2679 | A141-B9-C37 |
| 2680 | A141-B10-C37 |
| 2681 | |
| 2682 | A141-B12-C37 |
| 2683 | A141-B13-C37 |
| 2684 | A141-B14-C37 |
| 2685 | A141-B15-C37 |
| 2686 | A141-B16-C37 |
| 2687 | A141-B17-C37 |
| 2688 | A141-B18-C37 |
| 2689 | A141-B19-C37 |
| 2690 | A141-B20-C37 |
| 2691 | A141-B21-C37 |
| 2692 | A141-B22-C37 |
| 2693 | A141-B23-C37 |
| 2694 | A141-B24-C37 |
| 2695 | A141-B25-C37 |
| 2696 | A141-B26-C37 |
| 2697 | A141-B27-C37 |
| 2698 | A141-B28-C37 |
| 2699 | A141-B29-C37 |
| 2700 | A141-B30-C37 |

TABLE 28

| Compound | <Structure> |
|---|---|
| 2701 | |
| 2702 | A141-B32-C37 |
| 2703 | A141-B33-C37 |
| 2704 | A141-B34-C37 |
| 2705 | A141-B35-C37 |
| 2706 | A141-B36-C37 |
| 2707 | A141-B37-C37 |
| 2708 | A141-B38-C37 |
| 2709 | A141-B39-C37 |
| 2710 | A141-B40-C37 |
| 2711 | A141-B41-C37 |
| 2712 | A141-B42-C37 |
| 2713 | A141-B43-C37 |
| 2714 | A141-B44-C37 |
| 2715 | A141-B45-C37 |
| 2716 | A141-B46-C37 |
| 2717 | A141-B47-C37 |
| 2718 | A141-B48-C37 |
| 2719 | A141-B49-C37 |
| 2720 | A141-B50-C37 |
| 2721 | A215-B1-C63 |
| 2722 | A215-B2-C63 |
| 2723 | A215-B3-C63 |
| 2724 | A215-B4-C63 |
| 2725 | A215-B5-C63 |
| 2726 | A215-B6-C63 |
| 2727 | A215-B7-C63 |
| 2728 | A215-B8-C63 |
| 2729 | A215-B9-C63 |
| 2730 | A215-B10-C63 |
| 2731 | A215-B11-C63 |
| 2732 | A215-B12-C63 |
| 2733 | A215-B13-C63 |
| 2734 | A215-B14-C63 |
| 2735 | A215-B15-C63 |
| 2736 | A215-B16-C63 |
| 2737 | A215-B17-C63 |
| 2738 | A215-B18-C63 |
| 2739 | A215-B19-C63 |
| 2740 | A215-B20-C63 |
| 2741 | A215-B21-C63 |
| 2742 | A215-B22-C63 |
| 2743 | A215-B23-C63 |
| 2744 | A215-B24-C63 |
| 2745 | A215-B25-C63 |
| 2746 | A215-B26-C63 |
| 2747 | A215-B27-C63 |
| 2748 | A215-B28-C63 |
| 2749 | A215-B29-C63 |
| 2750 | A215-B30-C63 |
| 2751 | A215-B31-C63 |
| 2752 | A215-B32-C63 |
| 2753 | A215-B33-C63 |
| 2754 | A215-B34-C63 |
| 2755 | A215-B35-C63 |
| 2756 | A215-B36-C63 |
| 2757 | A215-B37-C63 |
| 2758 | A215-B38-C63 |
| 2759 | A215-B39-C63 |
| 2760 | A215-B40-C63 |
| 2761 | A215-B41-C63 |
| 2762 | A215-B42-C63 |
| 2763 | A215-B43-C63 |
| 2764 | A215-B44-C63 |
| 2765 | A215-B45-C63 |
| 2766 | A215-B46-C63 |
| 2767 | A215-B47-C63 |
| 2768 | A215-B48-C63 |
| 2769 | A215-B49-C63 |
| 2770 | A215-B50-C63 |
| 2771 | A223-B1-C65 |
| 2772 | A223-B2-C65 |
| 2773 | A223-B3-C65 |
| 2774 | A223-B4-C65 |
| 2775 | A223-B5-C65 |
| 2776 | A223-B6-C65 |
| 2777 | A223-B7-C65 |
| 2778 | A223-B8-C65 |
| 2779 | A223-B9-C65 |
| 2780 | A223-B10-C65 |
| 2781 | A223-B11-C65 |
| 2782 | A223-B12-C65 |
| 2783 | A223-B13-C65 |
| 2784 | A223-B14-C65 |
| 2785 | A223-B15-C65 |
| 2786 | A223-B16-C65 |
| 2787 | A223-B17-C65 |
| 2788 | A223-B18-C65 |
| 2789 | A223-B19-C65 |
| 2790 | A223-B20-C65 |
| 2791 | A223-B21-C65 |
| 2792 | A223-B22-C65 |
| 2793 | A223-B23-C65 |
| 2794 | A223-B24-C65 |
| 2795 | A223-B25-C65 |
| 2796 | A223-B26-C65 |
| 2797 | A223-B27-C65 |
| 2798 | A223-B28-C65 |
| 2799 | A223-B29-C65 |
| 2800 | A223-B30-C65 |

TABLE 29

| Compound | <Structure> |
|---|---|
| 2801 | A223-B31-C65 |
| 2802 | A223-B32-C65 |
| 2803 | A223-B33-C65 |
| 2804 | A223-B34-C65 |
| 2805 | A223-B35-C65 |
| 2806 | A223-B36-C65 |
| 2807 | A223-B37-C65 |
| 2808 | A223-B38-C65 |
| 2809 | A223-B39-C65 |
| 2810 | A223-B40-C65 |
| 2811 | A223-B41-C65 |
| 2812 | A223-B42-C65 |
| 2813 | A223-B43-C65 |
| 2814 | A223-B44-C65 |
| 2815 | A223-B45-C65 |
| 2816 | A223-B46-C65 |
| 2817 | A223-B47-C65 |
| 2818 | A223-B48-C65 |
| 2819 | A223-B49-C65 |
| 2820 | A223-B50-C65 |
| 2821 | A237-B1-C72 |
| 2822 | A237-B2-C72 |
| 2823 | A237-B3-C72 |
| 2824 | A237-B4-C72 |
| 2825 | A237-B5-C72 |
| 2826 | A237-B6-C72 |
| 2827 | A237-B7-C72 |
| 2828 | A237-B8-C72 |
| 2829 | A237-B9-C72 |
| 2830 | A237-B10-C72 |
| 2831 | A237-B11-C72 |
| 2832 | A237-B12-C72 |
| 2833 | A237-B13-C72 |
| 2834 | A237-B14-C72 |
| 2835 | A237-B15-C72 |
| 2836 | A237-B16-C72 |
| 2837 | A237-B17-C72 |
| 2838 | A237-B18-C72 |
| 2839 | A237-B19-C72 |
| 2840 | A237-B20-C72 |
| 2841 | A237-B21-C72 |
| 2842 | A237-B22-C72 |
| 2843 | A237-B23-C72 |
| 2844 | A237-B24-C72 |
| 2845 | A237-B25-C72 |
| 2846 | A237-B26-C72 |
| 2847 | A237-B27-C72 |
| 2848 | A237-B28-C72 |
| 2849 | A237-B29-C72 |
| 2850 | A237-B30-C72 |
| 2851 | A237-B31-C72 |
| 2852 | A237-B32-C72 |
| 2853 | A237-B33-C72 |
| 2854 | A237-B34-C72 |
| 2855 | A237-B35-C72 |
| 2856 | A237-B36-C72 |
| 2857 | A237-B37-C72 |
| 2858 | A237-B38-C72 |
| 2859 | A237-B39-C72 |
| 2860 | A237-B40-C72 |
| 2861 | A237-B41-C72 |
| 2862 | A237-B42-C72 |
| 2863 | A237-B43-C72 |
| 2864 | A237-B44-C72 |
| 2865 | A237-B45-C72 |
| 2866 | A237-B46-C72 |
| 2867 | A237-B47-C72 |
| 2868 | A237-B48-C72 |
| 2869 | A237-B49-C72 |
| 2870 | A237-B50-C72 |
| 2871 | A254-B1-C84 |
| 2872 | A254-B2-C84 |
| 2873 | A254-B3-C84 |
| 2874 | A254-B4-C84 |
| 2875 | A254-B5-C84 |
| 2876 | A254-B6-C84 |
| 2877 | A254-B7-C84 |
| 2878 | A254-B8-C84 |
| 2879 | A254-B9-C84 |
| 2880 | A254-B10-C84 |
| 2881 | A254-B11-C84 |
| 2882 | A254-B12-C84 |
| 2883 | A254-B13-C84 |
| 2884 | A254-B14-C84 |
| 2885 | A254-B15-C84 |
| 2886 | A254-B16-C84 |
| 2887 | A254-B17-C84 |
| 2888 | A254-B18-C84 |
| 2889 | A254-B19-C84 |
| 2890 | A254-B20-C84 |
| 2891 | A254-B21-C84 |
| 2892 | A254-B22-C84 |
| 2893 | A254-B23-C84 |
| 2894 | A254-B24-C84 |
| 2895 | A254-B25-C84 |
| 2896 | A254-B26-C84 |
| 2897 | A254-B27-C84 |
| 2898 | A254-B28-C84 |
| 2899 | A254-B29-C84 |
| 2900 | A254-B30-C84 |

TABLE 30

| Compound | <Structure> |
|---|---|
| 2901 | A254-B31-C84 |
| 2902 | A254-B32-C84 |
| 2903 | A254-B33-C84 |
| 2904 | A254-B34-C84 |
| 2905 | A254-B35-C84 |
| 2906 | A254-B36-C84 |
| 2907 | A254-B37-C84 |
| 2908 | A254-B38-C84 |
| 2909 | A254-B39-C84 |
| 2910 | A254-B40-C84 |
| 2911 | A254-B41-C84 |
| 2912 | A254-B42-C84 |
| 2913 | A254-B43-C84 |
| 2914 | A254-B44-C84 |
| 2915 | A254-B45-C84 |
| 2916 | A254-B46-C84 |
| 2917 | A254-B47-C84 |
| 2918 | A254-B48-C84 |
| 2919 | A254-B49-C84 |
| 2920 | A254-B50-C84 |
| 2921 | A265-B1-C95 |
| 2922 | A265-B2-C95 |
| 2923 | A265-B3-C95 |
| 2924 | A265-B4-C95 |
| 2925 | A265-B5-C95 |
| 2926 | A265-B6-C95 |
| 2927 | A265-B7-C95 |
| 2928 | A265-B8-C95 |
| 2929 | A265-B9-C95 |
| 2930 | A265-B10-C95 |
| 2931 | A265-B11-C95 |
| 2932 | A265-B12-C95 |
| 2933 | A265-B13-C95 |
| 2934 | A265-B14-C95 |
| 2935 | A265-B15-C95 |
| 2936 | A265-B16-C95 |
| 2937 | A265-B17-C95 |
| 2938 | A265-B18-C95 |
| 2939 | A265-B19-C95 |
| 2940 | A265-B20-C95 |
| 2941 | A265-B21-C95 |
| 2942 | A265-B22-C95 |
| 2943 | A265-B23-C95 |
| 2944 | A265-B24-C95 |
| 2945 | A265-B25-C95 |
| 2946 | A265-B26-C95 |
| 2947 | A265-B27-C95 |
| 2948 | A265-B28-C95 |
| 2949 | A265-B29-C95 |
| 2950 | A265-B30-C95 |
| 2951 | A265-B31-C95 |
| 2952 | A265-B32-C95 |
| 2953 | A265-B33-C95 |
| 2954 | A265-B34-C95 |
| 2955 | A265-B35-C95 |
| 2956 | A265-B36-C95 |
| 2957 | A265-B37-C95 |
| 2958 | A265-B38-C95 |
| 2959 | A265-B39-C95 |
| 2960 | A265-B40-C95 |
| 2961 | A265-B41-C95 |
| 2962 | A265-B42-C95 |
| 2963 | A265-B43-C95 |
| 2964 | A265-B44-C95 |
| 2965 | A265-B45-C95 |
| 2966 | A265-B46-C95 |
| 2967 | A265-B47-C95 |
| 2968 | A265-B48-C95 |
| 2969 | A265-B49-C95 |
| 2970 | A265-B50-C95 |
| 2971 | A1-B51-C7 |
| 2972 | A1-B52-C7 |
| 2973 | A1-B53-C7 |
| 2974 | A1-B54-C7 |
| 2975 | A1-B55-C7 |
| 2976 | A1-B56-C7 |
| 2977 | A82-B51-C20 |
| 2978 | A82-B52-C20 |
| 2979 | A82-B53-C20 |
| 2980 | A82-B54-C20 |
| 2981 | A82-B55-C20 |
| 2982 | A82-B56-C20 |
| 2983 | A164-B51-C85 |
| 2984 | A164-B52-C85 |
| 2985 | A164-B53-C85 |
| 2986 | A164-B54-C85 |
| 2987 | A164-B55-C85 |
| 2988 | A164-B56-C85 |
| 2989 | A236-B51-C13 |
| 2990 | A236-B52-C13 |
| 2991 | A236-B53-C13 |
| 2992 | A236-B54-C13 |
| 2993 | A236-B55-C13 |
| 2994 | A236-B56-C13 |
| 2995 | A82-B51-C85 |
| 2996 | A82-B52-C85 |
| 2997 | A82-B53-C85 |
| 2998 | A82-B54-C85 |
| 2999 | A82-B55-C85 |
| 3000 | A82-B56-C85 |
| 3001 | A1-B53-C20 |
| 3002 | A1-B54-C20 |

L₁ in the organometallic compound represented by Formula 1 is a ligand represented by Formula 2A, n1, which is the number of L₁(s), may be 2, L₂ is a ligand represented by Formula 2B, n2, which is the number of L₂(s), may be 1, and L₁ and L₂ may be different from each other. Accordingly, the organometallic compound represented by Formula 1 may emit visible light (for example, green light) having a relatively small full width at half maximum (FWHM). In addition, the lifespan of the device is greatly improved due to improved stability.

At least one of Z₁(s) in the number of a1 in Formula 2A may not be hydrogen. Stability may be improved through the introduction of a substituent.

In one or more embodiments, each of Z₁, Z₂, Z₂₉, Z₃₀, and R₁₁ to R₁₄ in Formulae 2A and 2B may not include silicon. Orientation characteristics are improved and the efficiency of the device may be greatly improved.

The highest occupied molecular orbital (HOMO) energy level, lowest unoccupied molecular orbital (LUMO) energy level, Si energy level and T₁ energy level of some compounds of the organometallic compounds represented by Formula 1 are evaluated by using Gaussian 09 program having been subjected to molecular structure optimization performed by density functional theory (DFT) based on B3LYP. Results thereof are shown in Table 31.

TABLE 31

| Compound | HOMO | LUMO | S₁ | T₁ |
|---|---|---|---|---|
| No. | (eV) | (eV) | (eV) | (eV) |
| 121 | −4.751 | −1.224 | 2.857 | 2.519 |
| 1721 | −4.741 | −1.214 | 2.832 | 2.532 |

From Table 31, it can be confirmed that the organometallic compound represented by Formula 1 has electrical characteristics suitable for use as a dopant of an electronic device, for example, an organic light-emitting device.

Synthesis methods of the organometallic compound represented by Formula 1 may be understood by one of ordinary skill in the art by referring to Synthesis Examples provided below.

Accordingly, the organometallic compound represented by Formula 1 is suitable for use as a material for an organic layer of organic light-emitting device, for example, a dopant in an emission layer of the organic layer. Thus, another aspect provides an organic light-emitting device including: a first electrode; a second electrode; and an organic layer located between the first electrode and the second electrode and including an emission layer, and the organic layer includes at least one of the organometallic compounds represented by Formula 1.

The organic light-emitting device may have low driving voltage, high external quantum efficiency, and high lifespan characteristics by having the organic layer including the organometallic compound represented by Formula 1 as described above.

The organometallic compound of Formula 1 may be used between a pair of electrodes of an organic light-emitting device. For example, the organometallic compound represented by Formula 1 may be included in the emission layer. In this regard, the organometallic compound may act as a dopant, and the emission layer may further include a host (that is, an amount of the organometallic compound represented by Formula 1 is smaller than an amount of the host). The emission layer may emit, for example, green light or blue light.

The expression “(an organic layer) includes at least one of organometallic compounds” used herein may include a case in which “(an organic layer) includes identical organometallic compounds represented by Formula 1” and a case in which “(an organic layer) includes two or more different organometallic compounds represented by Formula 1.”

For example, the organic layer may include, as the organometallic compound, only Compound 1. In this embodiment, Compound 1 may be included in the emission layer of the organic light-emitting device. In one or more embodiments, the organic layer may include, as the organometallic compound, Compound 1 and Compound 2. In this regard, Compound 1 and Compound 2 may exist in an identical layer (for example, Compound 1 and Compound 2 all may exist in an emission layer).

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

In one or more embodiments, in the organic light-emitting device, the first electrode is an anode, and the second electrode is a cathode, and the organic layer may further include a hole transport region located between the first electrode and the emission layer and an electron transport region located between the emission layer and the second electrode, and the hole transport region may include a hole injection layer, a hole transport layer, an electron-blocking layer, a buffer layer, or a combination thereof, and the electron transport region may include a hole-blocking layer, an electron transport layer, an electron injection layer, or a combination thereof.

The term “organic layer” used herein refers to a single layer and/or a plurality of layers between the first electrode and the second electrode of the organic light-emitting device. The “organic layer” may include, in addition to an organic compound, an organometallic complex including metal.

FIGURE is a schematic cross-sectional view of an organic light-emitting device 10 according to an embodiment. Hereinafter, the structure and manufacturing method of the organic light-emitting device 10 according to an embodiment of the present disclosure will be described in connection with FIGURE. The organic light-emitting device 10 includes a first electrode 11, an organic layer 15, and a second electrode 19, which are sequentially stacked.

A substrate may be additionally disposed under the first electrode 11 or on the second electrode 19. The substrate may be a conventional substrate used in organic light-emitting devices, e.g., a glass substrate or a transparent plastic substrate, each having excellent mechanical strength, thermal stability, transparency, surface smoothness, ease of handling, and water repellency.

The first electrode 11 may be produced by depositing or sputtering, onto the substrate, a material for forming the first electrode 11. The first electrode 11 may be an anode. The material for forming the first electrode 11 may include materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), aluminum (A1), aluminum-lithium (Al—Li), calcium (Ca), magnesium-indium (Mg—In), or magnesium-silver (Mg—Ag).

The first electrode 11 may have a single-layered structure or a multi-layered structure including a plurality of layers. For example, the first electrode 11 may have a three-layered structure of ITO/Ag/ITO.

The organic layer 15 is located on the first electrode 11.

The organic layer 15 may include a hole transport region, an emission layer, and an electron transport region.

The hole transport region may be between the first electrode 11 and the emission layer.

The hole transport region may include a hole injection layer, a hole transport layer, an electron-blocking layer, a buffer layer, or any combination thereof.

The hole transport region may include only either a hole injection layer or a hole transport layer. In one or more embodiments, the hole transport region may have a hole injection layer/hole transport layer structure or a hole injection layer/hole transport layer/electron-blocking layer structure, wherein, for each structure, respective layers are sequentially stacked in this stated order from the first electrode 11.

When the hole transport region includes a hole injection layer, the hole injection layer may be formed on the first electrode 11 by using one or more suitable methods, for example, vacuum deposition, spin coating, casting, and/or Langmuir-Blodgett (LB) deposition.

When a hole injection layer is formed by vacuum deposition, the deposition conditions may vary depending on a material that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Å/sec to about 100 Å/sec. When the hole injection layer is formed by spin coating, the coating conditions may vary depending on a material for forming the hole injection layer, and the structure and thermal characteristics of the hole injection layer. For example, the coating conditions may include a coating speed in a range of about 2,000 rpm to about 5,000 rpm and a heat treatment temperature in a range of about 80° C. to about 200° C. for removing a solvent after coating.

The conditions for forming the hole transport layer and the electron-blocking layer may be the same as the conditions for forming the hole injection layer.

The hole transport region may be m-MTDATA, TDATA, 2-TNATA, NPB, β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201 below, a compound represented by Formula 202 below, or any combination thereof:

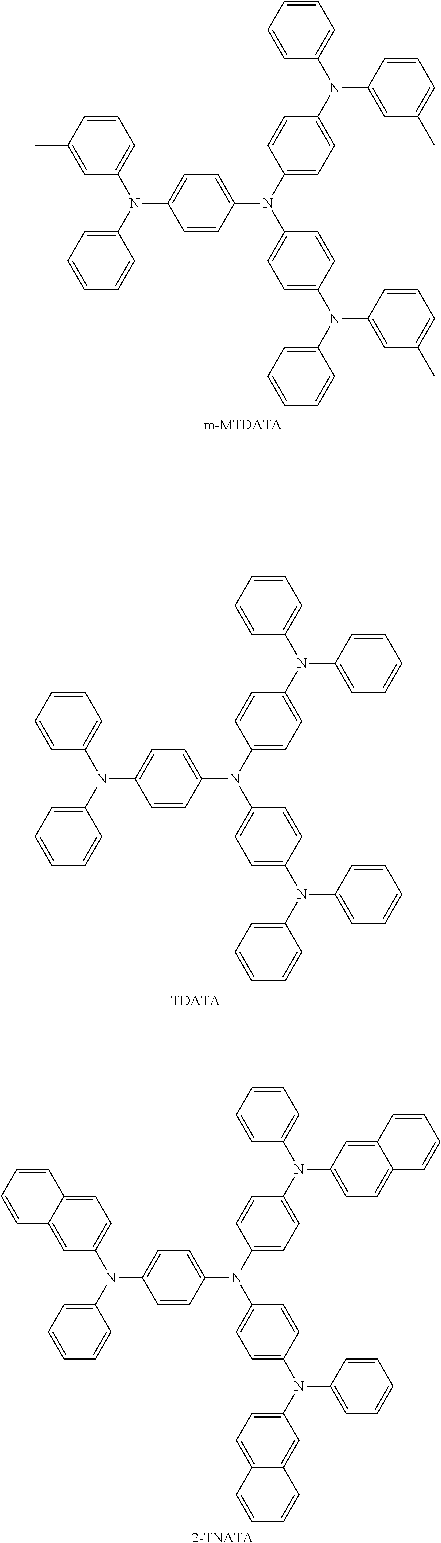

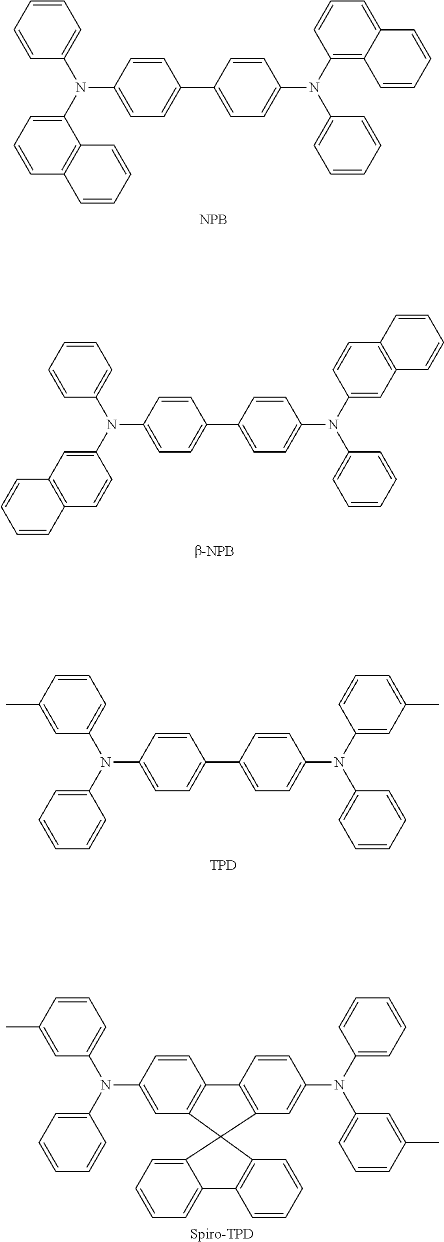

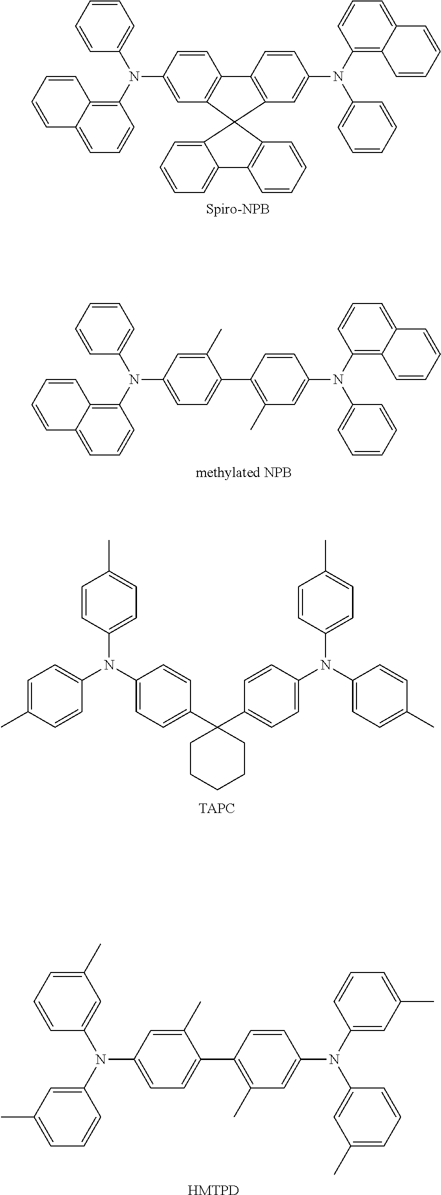

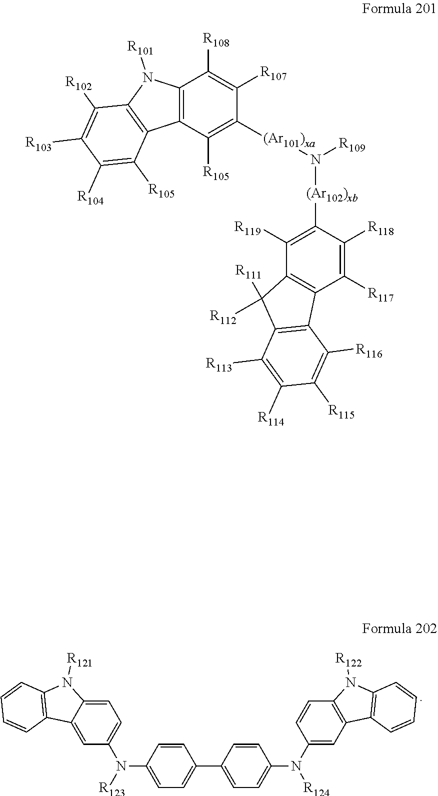

Ar₁₀₁ and Ar₁₀₂ in Formula 201 may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, or a pentacenylene group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or any combination thereof.

xa and xb in Formula 201 may each independently be an integer from 0 to 5, or 0, 1, or 2. For example, xa may be 1 and xb may be 0.

R₁₀₁ to R₁₀₈, R₁₁₁ to R₁₁₉ and R₁₂₁ to R₁₂₄ in Formulae 201 and 202 may each independently be:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, pentyl group, a hexyl group, etc.), or a C₁-C₁₀ alkoxy group (for example, a methoxy group, an ethoxy group, a propoxy group, a butoxy group, a pentoxy group, etc.);
a C₁-C₁₀ alkyl group or a C₁-C₁₀ alkoxy group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or any combination thereof; or
a C₁-C₁₀ alkyl group or a C₁-C₁₀ alkoxy group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or any combination thereof.

R₁₀₉ in Formula 201 may be a phenyl group, a naphthyl group, an anthracenyl group, or a pyridinyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyridinyl group, or any combination thereof.

In one embodiment, the compound represented by Formula 201 may be represented by Formula 201A:

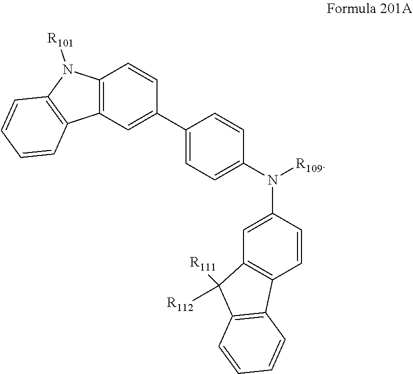

R₁₀₁, R₁₁₁, R₁₁₂, and R₁₀₉ in Formula 201A are each the same as described in the present specification.

For example, the hole transport region may include one of Compounds HT1 to HT20 or any combination thereof:

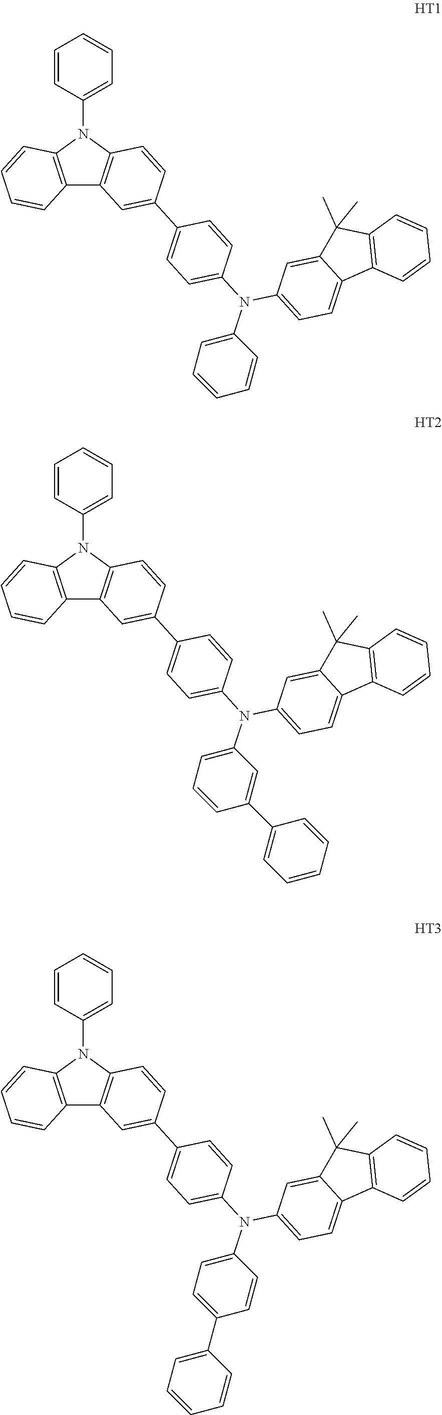 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

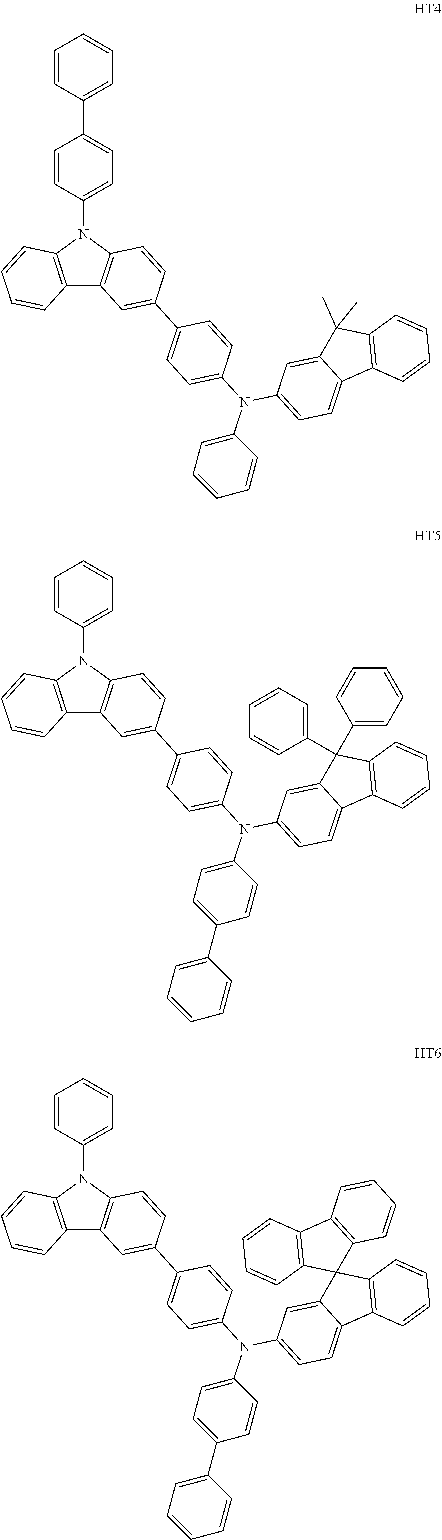 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

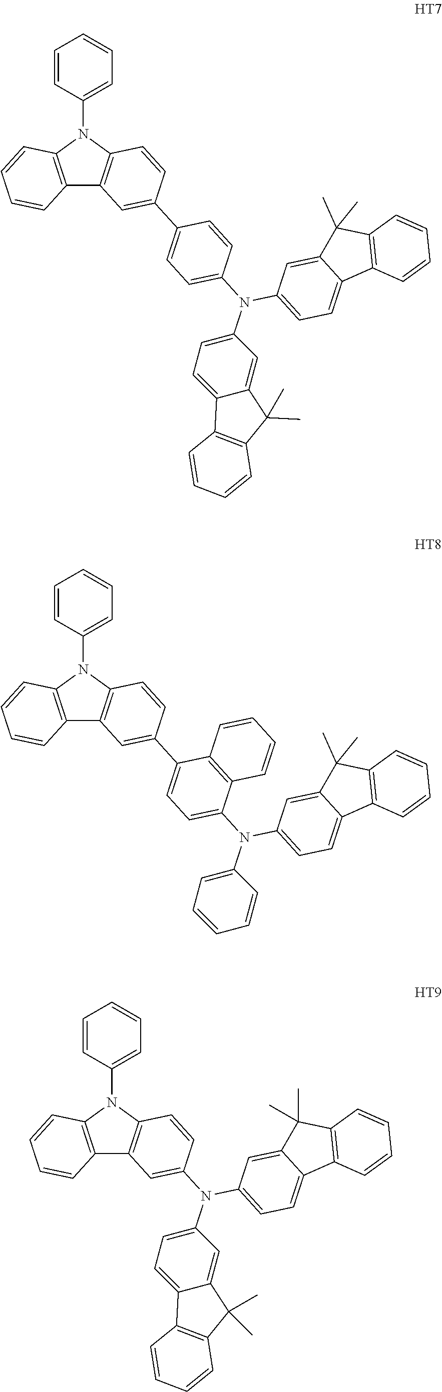 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

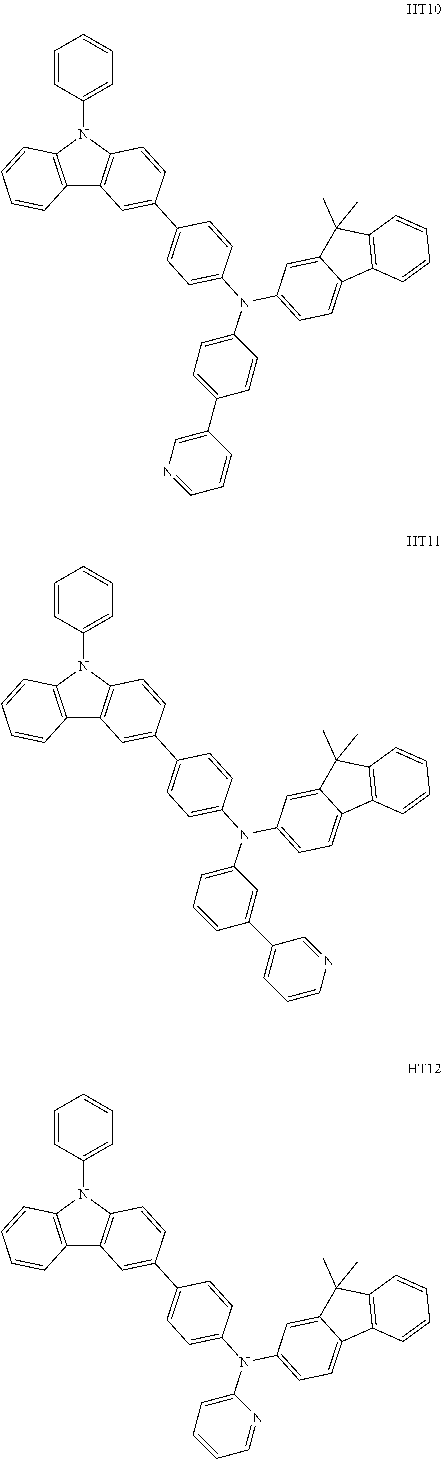 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

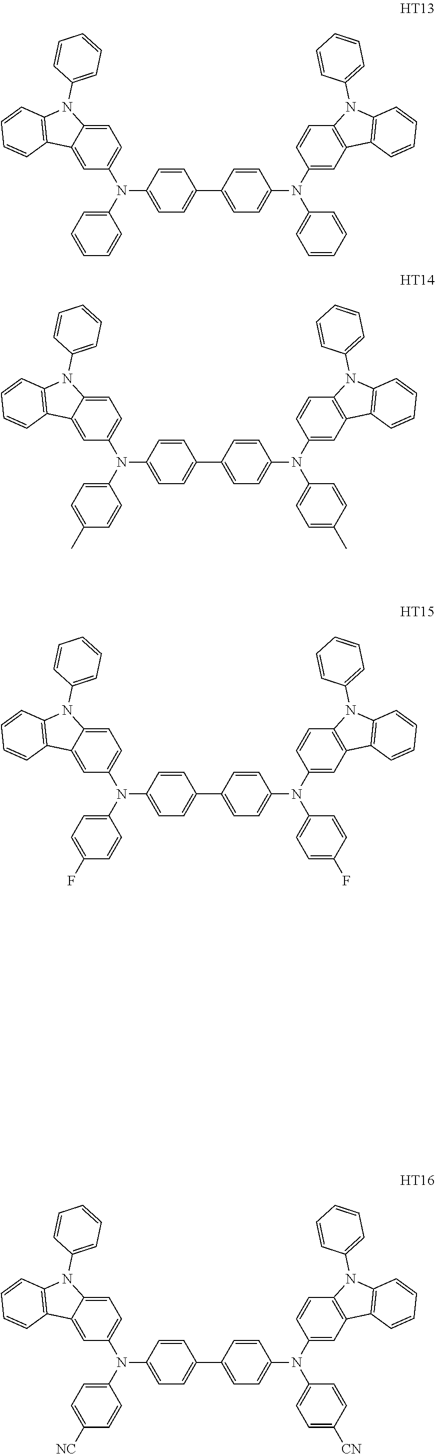 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

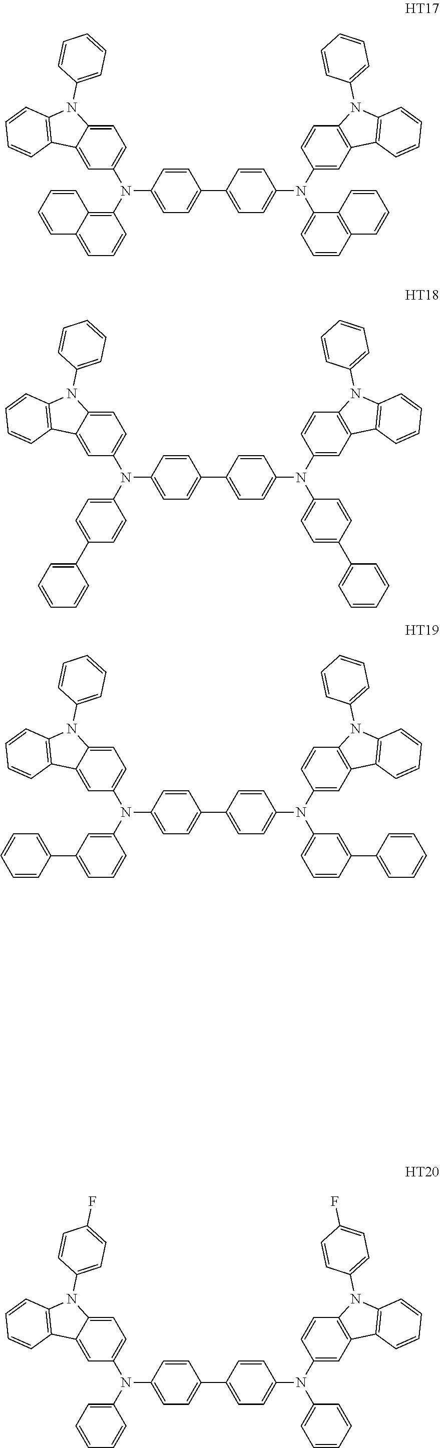 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in the range of about 100 Å to about 10,000 Å, for example, about 100 Å to about 1,000 Å. When the hole transport region includes at least one of a hole injection layer, a hole transport layer, an electron-blocking layer, or any combination thereof, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be a quinone derivative, a metal oxide, a cyano group-containing compound, or any combination thereof. For example, the p-dopant may be: a quinone derivative such as tetracyanoquinodimethane (TCNQ), 2,3,5,6-tetrafluoro-tetracyano-1,4-benzoquinonedimethane (F4-TCNQ), or F6-TCNNQ; metal oxide, such as tungsten oxide and molybdenum oxide; a cyano group-containing compound, such as Compound HT-D1; or any combination thereof.

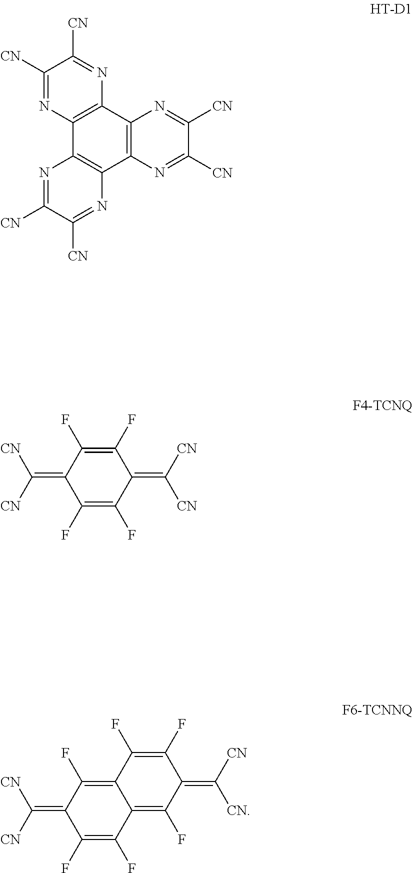

The hole transport region may include a buffer layer.

Also, the buffer layer may compensate for an optical resonance distance according to a wavelength of light emitted from the emission layer, and thus, efficiency of a formed organic light-emitting device may be improved.

Meanwhile, when the hole transport region includes an electron-blocking layer, a material for forming the electron-blocking layer may include a material that is used in the hole transport region as described above, a host material described below, or any combination thereof. In one or more embodiments, when the hole transport region includes an electron-blocking layer, as an electron-blocking layer material, mCP, which will be described later, or any combination thereof may be used.

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a material that is used to form the hole transport layer.

The emission layer may include a host and a dopant, and the dopant may include the organometallic compound represented by Formula 1 as described herein.

The host may include TBADN, ADN (also referred to as “DNA”), CBP, CDBP, TCP, mCP, Compound H50, Compound H51, Compound H52, Compound H-H1 (see Example 1 below), Compound H-E43 (Example below) 1), or any combination thereof:

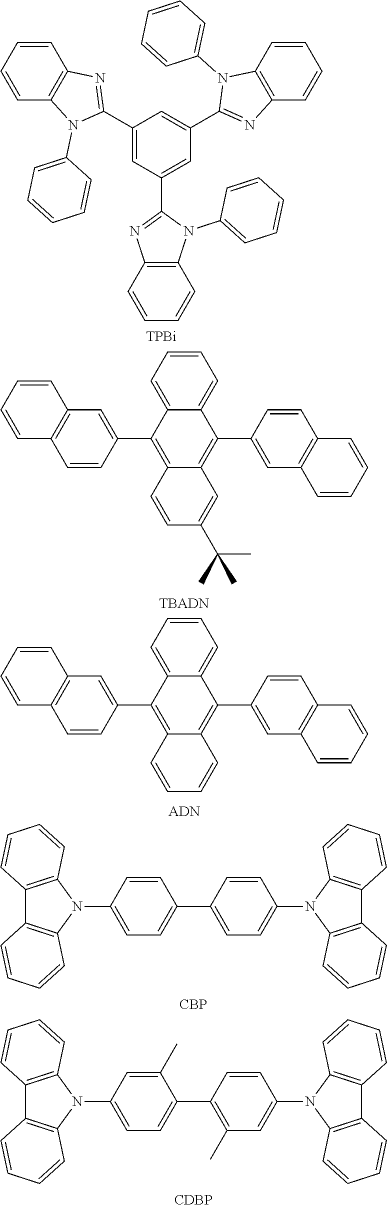

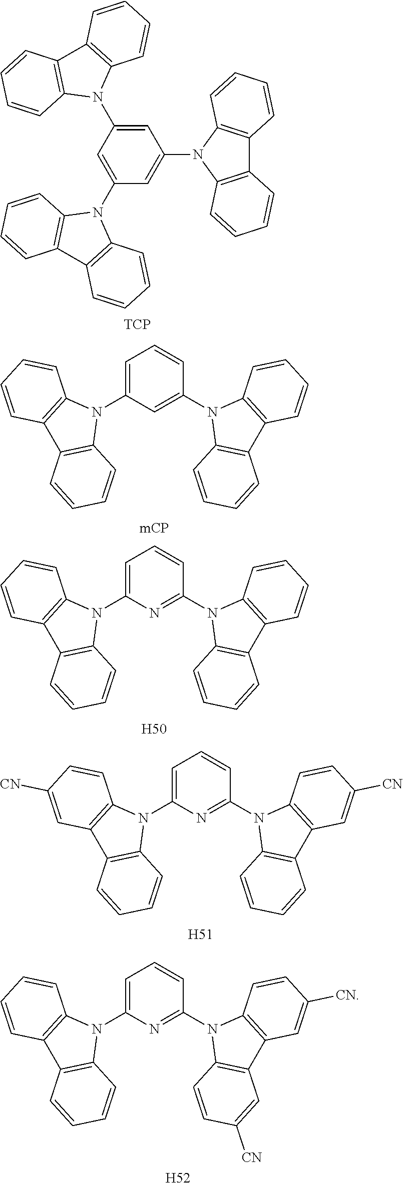

When the organic light-emitting device is a full-color organic light-emitting device, the emission layer may be patterned into a red emission layer, a green emission layer, and/or a blue emission layer. In one or more embodiments, due to a stacked structure including a red emission layer, a green emission layer, and/or a blue emission layer, the emission layer may emit white light.

When the emission layer includes a host and a dopant, an amount of the dopant may be in a range of about 0.01 part by weight to about 15 parts by weight based on 100 parts by weight of the host.

A thickness of the emission layer may be in a range of about 100 Å to about 1,000 Å, for example, about 200 Å to about 600 Å. When the thickness of the emission layer is within these ranges, excellent light-emission characteristics may be obtained without a substantial increase in driving voltage.

An electron transport region may be located on the emission layer.

The electron transport region may include a hole-blocking layer, an electron transport layer, an electron injection layer, or a combination thereof.

For example, the electron transport region may have a hole-blocking layer/electron transport layer/electron injection layer structure or an electron transport layer/electron injection layer structure. The electron transport layer may have a single-layered structure or a multi-layered structure including two or more different materials.

Conditions for forming the hole-blocking layer, the electron transport layer, and the electron injection layer which constitute the electron transport region may be understood by referring to the conditions for forming the hole injection layer.

When the electron transport region includes a hole-blocking layer, the hole-blocking layer may include, for example, BCP, Bphen, BAIq, or any combination thereof:

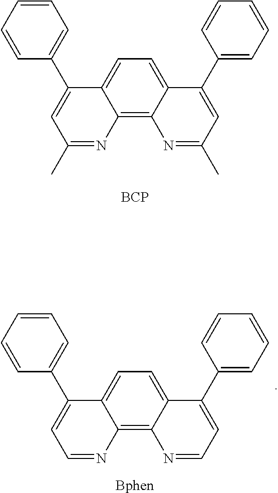

A thickness of the hole-blocking layer may be in a range of about 20 Å to about 1,000 Å, for example, about 30 Å to about 600 Å. When the thickness of the hole-blocking layer is within these ranges, excellent hole blocking characteristics may be obtained without a substantial increase in driving voltage.

The electron transport layer may include BCP, Bphen, TPBi, Alq₃, Balq, TAZ, NTAZ, or any combination thereof:

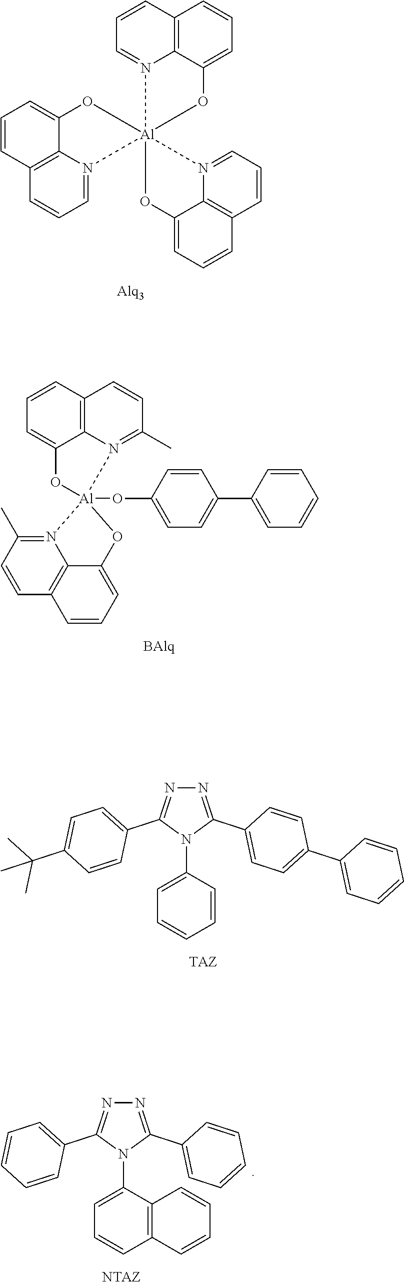

In one or more embodiments, the electron transport layer may include one of Compounds ET1 to ET25 or any combination thereof:

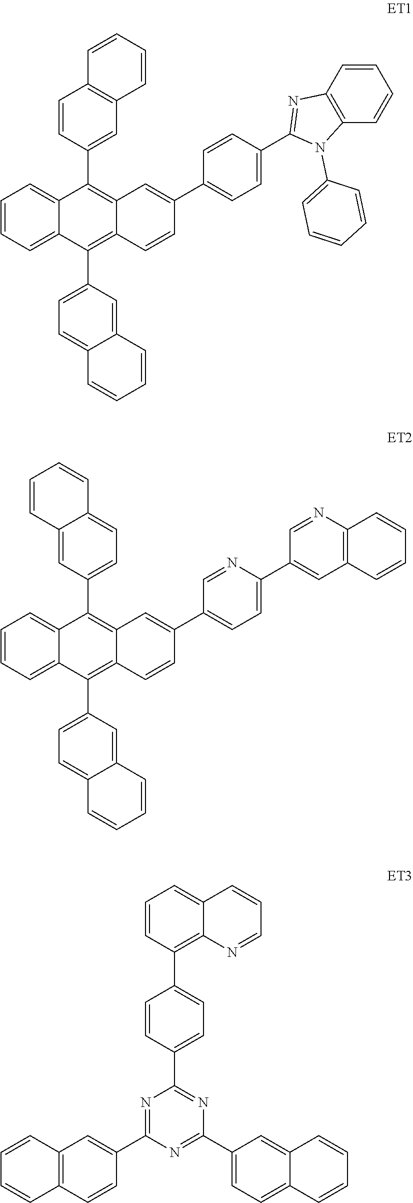 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

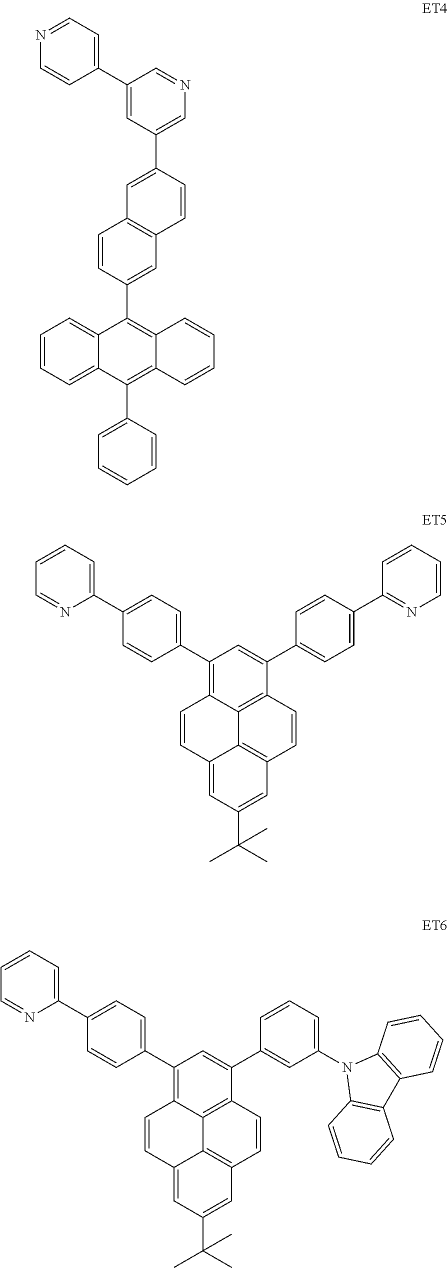 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

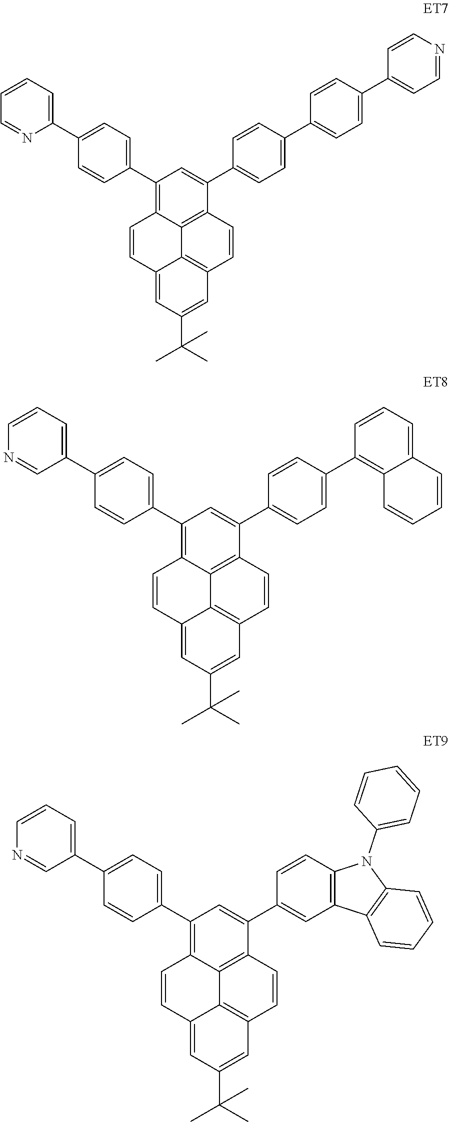 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

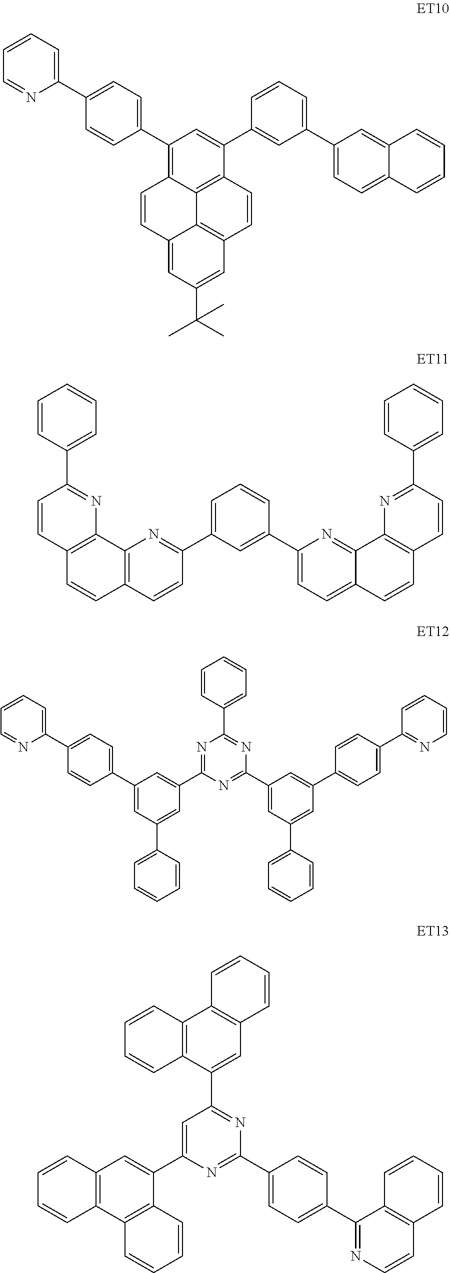 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1]

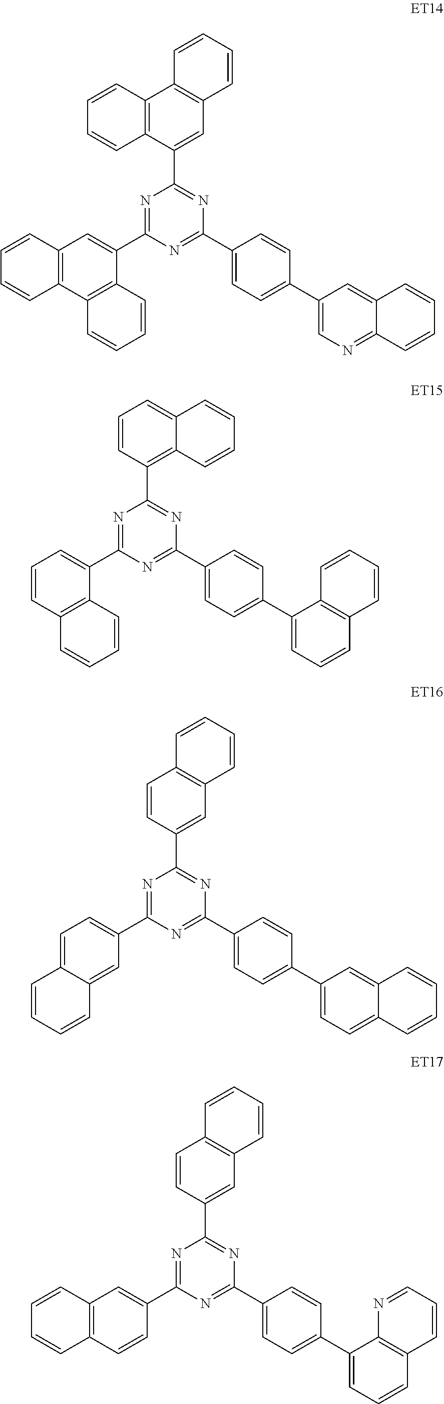 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1]

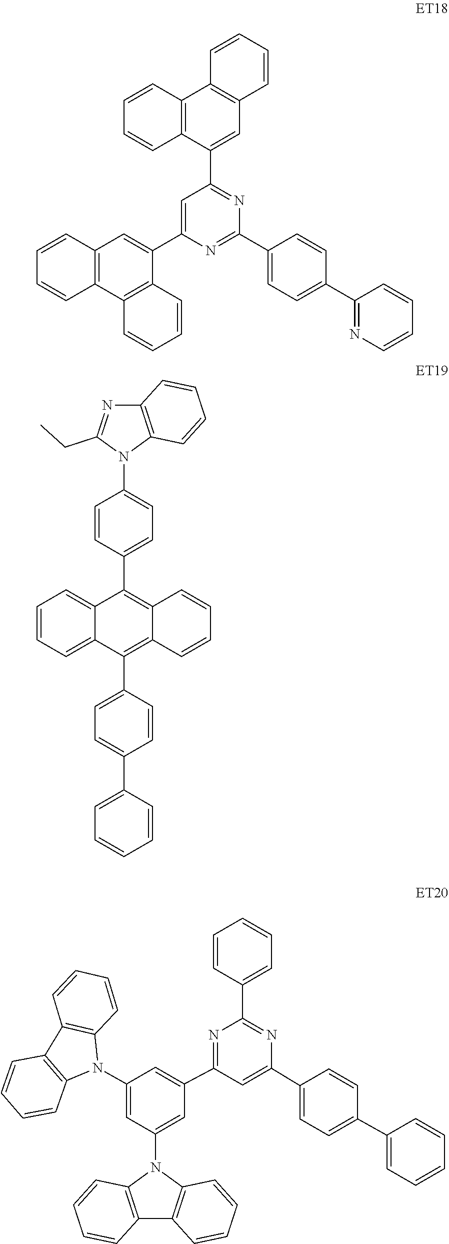

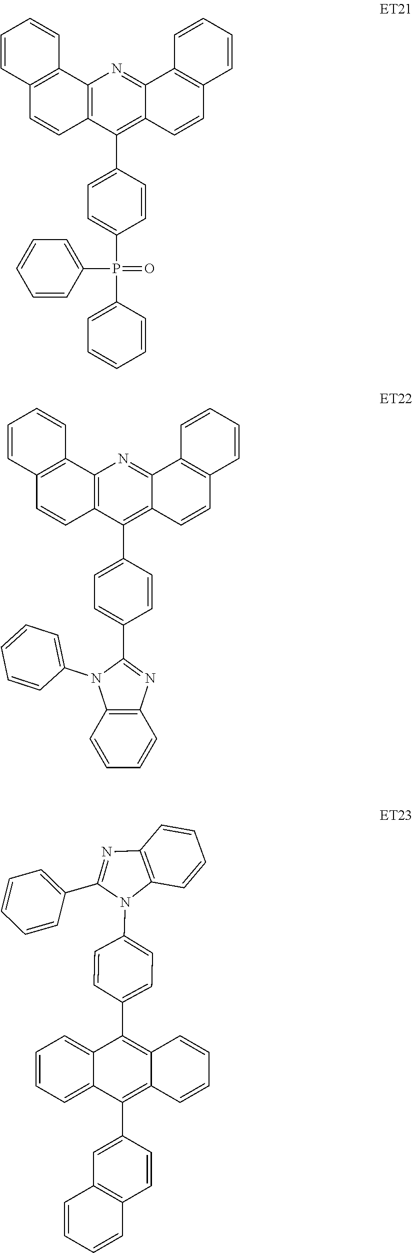 [SMILES: O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1]

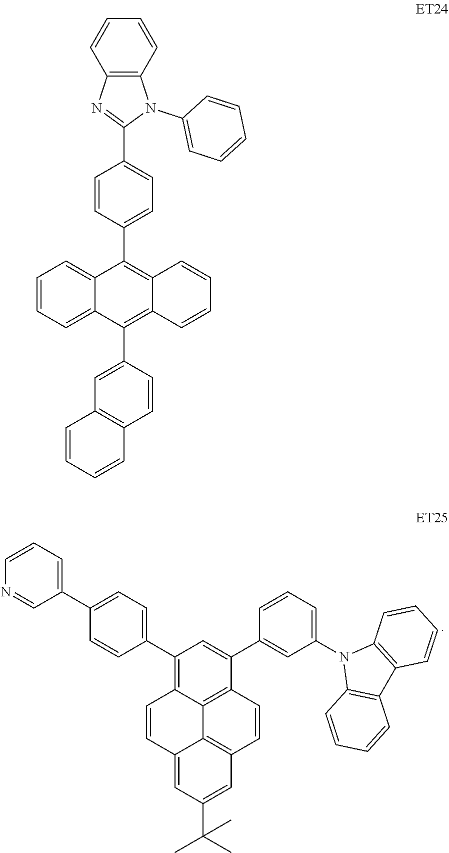 [SMILES: c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in the range of about 100 Å to about 1,000 Å, for example, about 150 Å to about 500 Å. When the thickness of the electron transport layer is within the range described above, the electron transport layer may have satisfactory electron transporting characteristics without a substantial increase in driving voltage.

The electron transport layer may include a metal-containing material in addition to the material as described above.

The metal-containing material may include a L₁ complex. The L₁ complex may include, for example, Compound ET-D1 or ET-D2:

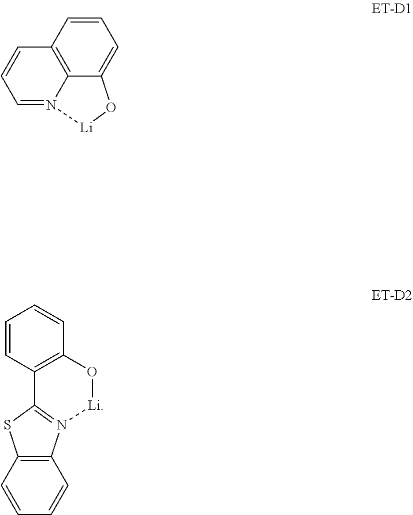

The electron transport region may include an electron injection layer that promotes the flow of electrons from the second electrode 19 thereinto.

The electron injection layer may include LiF, NaCl, CsF, Li₂O, BaO, or any combination thereof.

A thickness of the electron injection layer may be in a range of about 1 Å to about 100 Å, and, for example, about 3 Å to about 90 Å. When the thickness of the electron injection layer is within the ranges described above, satisfactory electron injection characteristics may be obtained without a substantial increase in driving voltage.

The second electrode 19 may be located on the organic layer 15. The second electrode 19 may be a cathode. A material for forming the second electrode 19 may be metal, an alloy, an electrically conductive compound, or a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as the material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIGURE, but embodiments of the present disclosure are not limited thereto.

According to another aspect, the organic light-emitting device may be included in an electronic apparatus. Thus, an electronic apparatus including the organic light-emitting device is provided. The electronic apparatus may include, for example, a display, an illumination, a sensor, and the like.

Another aspect provides a diagnostic composition including at least one organometallic compound represented by Formula 1.

The organometallic compound represented by Formula 1 provides high luminescence efficiency. Accordingly, a diagnostic composition including the organometallic compound may have high diagnostic efficiency.

The diagnostic composition may be used in various applications including a diagnosis kit, a diagnosis reagent, a biosensor, and a biomarker.

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used here refers to a divalent group having the same structure as the C₁-C₆₀ alkyl group.

Examples of the C₁-C₆₀ alkyl group, the C₁-C₂₀ alkyl group, and/or the C₁-C₁₀ alkyl group are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or any combination thereof. For example, Formula 9-33 is a branched C₆ alkyl group, for example, a tert-butyl group that is substituted with two methyl groups.

The term “C₁-C₆₀ alkoxy group” used herein refers to a monovalent group represented by —OA₁₀₁ (wherein A₁₀₁ is the C₁-C₆₀ alkyl group), and examples thereof are a methoxy group, an ethoxy group, a propoxy group, a butoxy group, and a pentoxy group.

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the C₃-C₁₀ cycloalkylene group is a divalent group having the same structure as the C₃-C₁₀ cycloalkyl group.

Examples of the C₃-C₁₀ cycloalkyl group are a cyclopropyl group, a cyclobutyl group, a cyclopentyl, cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group.

The term “C₁-C₁₀ heterocycloalkyl group” as used herein refers to a monocyclic group that includes at least one heteroatom selected from N, O, P, Si, S, Se, Ge, and B as a ring-forming atom and 1 to 10 carbon atoms, and the C₁-C₁₀ heterocycloalkylene group refers to a divalent group having the same structure as the C₁-C₁₀ heterocycloalkyl group.

Examples of the C₁-C₁₀ heterocycloalkyl group are a silolanyl group, a silinanyl group, tetrahydrofuranyl group, a tetrahydro-2H-pyranyl group, and a tetrahydrothiophenyl group.

The term “C₃-C₁₀ cycloalkenyl group” as used herein refers to a monovalent cyclic group that includes 3 to 10 carbon atoms and at least one carbon-carbon double bond in the ring thereof and has no aromaticity, and examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, S, Se, Ge, and B as a ring-forming atom, 1 to 10 carbon atoms, and at least one carbon-carbon double bond in its ring. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The C₇-C₆₀ alkylaryl group used herein refers to a C₆-C₆₀ aryl group substituted with at least one C₁-C₆₀ alkyl group.

The term “C₁-C₆₀ heteroaryl group” as used herein refers to a monovalent group having at least one heteroatom selected from N, O, P, Si, S, Se, Ge, and B as a ring-forming atom and a cyclic aromatic system having 1 to 60 carbon atoms, and the term “C₁-C₆₀ heteroarylene group” as used herein refers to a divalent group having at least one heteroatom selected from N, O, P, Si, S, Se, Ge, and B as a ring-forming atom and a carbocyclic aromatic system having 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₆-C₆₀ heteroaryl group and the C₆-C₆₀ heteroarylene group each include two or more rings, the rings may be fused to each other.

The C₂-C₆₀ alkylheteroaryl group used herein refers to a C₁-C₆₀ heteroaryl group substituted with at least one C₁-C₆₀ alkyl group.

The term “C₆-C₆₀ aryloxy group” as used herein indicates —OA₁₀₂ (wherein A₁₀₂ indicates the C₆-C₆₀ aryl group), the C₆-C₆₀ arylthio group indicates —SA₁₀₃ (wherein A₁₀₃ indicates the C₆-C₆₀ aryl group), and the C₁-C₆₀ alkylthio group indicates —SA₁₀₄ (wherein A₁₀₄ indicates the C₁-C₆₀ alkyl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, a heteroatom selected from N, O, P, Si, S, Se, Ge, and B, other than carbon atoms, as a ring-forming atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group described above.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group. Examples of the “C₅-C₃₀ carbocyclic group (unsubstituted or substituted with at least one R₁₀ₐ)” used herein are an adamantane group, a norbornene group, a bicyclo[1.1.1]pentane group, a bicyclo[2.1.1]hexane group, a bicyclo[2.2.1]heptane (norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, and a fluorene group (each unsubstituted or substituted with at least one R₁₀ₐ).

The term “C₁-C₃₀ heterocyclic group” as used herein refers to a saturated or unsaturated cyclic group having, as a ring-forming atom, at least one heteroatom selected from N, O, P, Si, S, Se, Ge, and B other than 1 to 30 carbon atoms. The C₁-C₃₀ heterocyclic group may be a monocyclic group or a polycyclic group. The “C₁-C₃₀ heterocyclic group (unsubstituted or substituted with at least one R₁₀ₐ)” may be, for example, a thiophene group, a furan group, a pyrrole group, a silole group, borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group (each unsubstituted or substituted with at least one R₁₀ₐ).

Examples of the “C₅-C₃₀ carbocyclic group” and “C₁-C₃₀ heterocyclic group” as used herein are i) a first ring, ii) a second ring, iii) a condensed ring in which two or more first rings are condensed with each other, iv) a condensed ring in which two or more second rings are condensed with each other, or v) a condensed ring in which at least one first ring is condensed with at least one second ring, wherein the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and the second ring may be an adamantane group, a norbornane group, a norbornene group, a cyclohexane group, a cyclohexene group, a benzene group, a pyridine group, a pyrimidine group, a pyrazine group, a pyridazine group, or a triazine group.

The terms “fluorinated C₁-C₆₀ alkyl group (or a fluorinated C₁-C₂₀ alkyl group or the like)”, “fluorinated C₃-C₁₀ cycloalkyl group”, “fluorinated C₁-C₁₀ heterocycloalkyl group,” and “fluorinated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one fluoro group (—F). For example, the term “fluorinated C₁ alkyl group (that is, a fluorinated methyl group)” includes —CF₃, —CF₂H, and —CFH₂. The “fluorinated C₁-C₆₀ alkyl group (or, a fluorinated C₁-C₂₀ alkyl group, or the like)”, “the fluorinated C₃-C₁₀ cycloalkyl group”, “the fluorinated C₁-C₁₀ heterocycloalkyl group”, or “the fluorinated a phenyl group” may be i) a fully fluorinated C₁-C₆₀ alkyl group (or, a fully fluorinated C₁-C₂₀ alkyl group, or the like), a fully fluorinated C₃-C₁₀ cycloalkyl group, a fully fluorinated C₁-C₁₀ heterocycloalkyl group, or a fully fluorinated phenyl group, wherein, in each group, all hydrogen included therein is substituted with a fluoro group, or ii) a partially fluorinated C₁-C₆₀ alkyl group (or, a partially fluorinated C₁-C₂₀ alkyl group, or the like), a partially fluorinated C₃-C₁₀ cycloalkyl group, a partially fluorinated C₁-C₁₀ heterocycloalkyl group, or partially fluorinated phenyl group, wherein, in each group, not all hydrogen included therein is substituted with a fluoro group.

The terms “deuterated C₁-C₆₀ alkyl group (or a deuterated C₁-C₂₀ alkyl group or the like)”, “deuterated C₃-C₁₀ cycloalkyl group”, “deuterated C₁-C₁₀ heterocycloalkyl group,” and “deuterated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one deuterium. For example, the “deuterated C₁ alkyl group (that is, the deuterated methyl group)” may include —CD₃, —CD₂H, and —CDH₂, and examples of the “deuterated C₃-C₁₀ cycloalkyl group” are, for example, Formula 10-501 and the like. The “deuterated C₁-C₆₀ alkyl group (or, the deuterated C₁-C₂₀ alkyl group or the like)”, “the deuterated C₃-C₁₀ cycloalkyl group”, “the deuterated C₁-C₁₀ heterocycloalkyl group”, or “the deuterated phenyl group” may be i) a fully deuterated C₁-C₆₀ alkyl group (or, a fully deuterated C₁-C₂₀ alkyl group or the like), a fully deuterated C₃-C₁₀ cycloalkyl group, a fully deuterated C₁-C₁₀ heterocycloalkyl group, or a fully deuterated phenyl group, in which, in each group, all hydrogen included therein are substituted with deuterium, or ii) a partially deuterated C₁-C₆₀ alkyl group (or, a partially deuterated C₁-C₂₀ alkyl group or the like), a partially deuterated C₃-C₁₀ cycloalkyl group, a partially deuterated C₁-C₁₀ heterocycloalkyl group, or a partially deuterated phenyl group, in which, in each group, not all hydrogen included therein are substituted with deuterium.

The term “(C₁-C₂₀ alkyl) ‘X’ group” as used herein refers to a ‘X’ group that is substituted with at least one C₁-C₂₀ alkyl group. For example, the term “(C₁-C₂₀ alkyl)C₃-C₁₀ cycloalkyl group” as used herein refers to a C₃-C₁₀ cycloalkyl group substituted with at least one C₁-C₂₀ alkyl group, and the term “(C₁-C₂₀ alkyl)phenyl group” as used herein refers to a phenyl group substituted with at least one C₁-C₂₀ alkyl group. An example of a (C₁ alkyl) phenyl group is a toluyl group.

The terms “an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, and an azadibenzothiophene 5,5-dioxide group” respectively refer to heterocyclic groups having the same backbones as “an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, and a dibenzothiophene 5,5-dioxide group,” in which, in each group, at least one carbon selected from ring-forming carbons is substituted with nitrogen.

At least one substituent of the substituted C₅-C₃₀ carbocyclic group, the substituted C₂-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkylaryl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted monovalent non-aromatic condensed polycyclic group, and the substituted monovalent non-aromatic condensed heteropolycyclic group may each independently be:
deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group,
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof.
Q₁ to Q₉, Q₁₁ to Q₁₉, Q₂₁ to Q₂₉, and Q₃₁ to Q₃₉ used herein may each independently be: hydrogen; deuterium; —F; —Cl; —Br; —I; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group which is unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group which is unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

For example, Q₁ to Q₉, Q₁₁ to Q₁₉, Q₂₁ to Q₂₉ and Q₃₁ to Q₃₉ described herein may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or any combination thereof.

As used herein, the number of carbons in each group that is substituted (e.g., C₁-C₆₀) excludes the number of carbons in the substituent. For example, a C₁-C₆₀ alkyl group can be substituted with a C₁-C₆₀ alkyl group. The total number of carbons included in the C₁-C₆₀ alkyl group substituted with the C₁-C₆₀ alkyl group is not limited to 60 carbons. In addition, more than one C₁-C₆₀ alkyl substituent may be present on the C₁-C₆₀ alkyl group. This definition is not limited to the C₁-C₆₀ alkyl group and applies to all substituted groups that recite a carbon range.

Hereinafter, a compound and an organic light-emitting device according to embodiments are described in detail with reference to Synthesis Example and Examples. However, the organic light-emitting device is not limited thereto. The wording “B was used instead of A” used in describing Synthesis Examples means that an amount of A used was identical to an amount of B used, in terms of a molar equivalent.

### EXAMPLES

### Synthesis Example 1 (Compound 141)

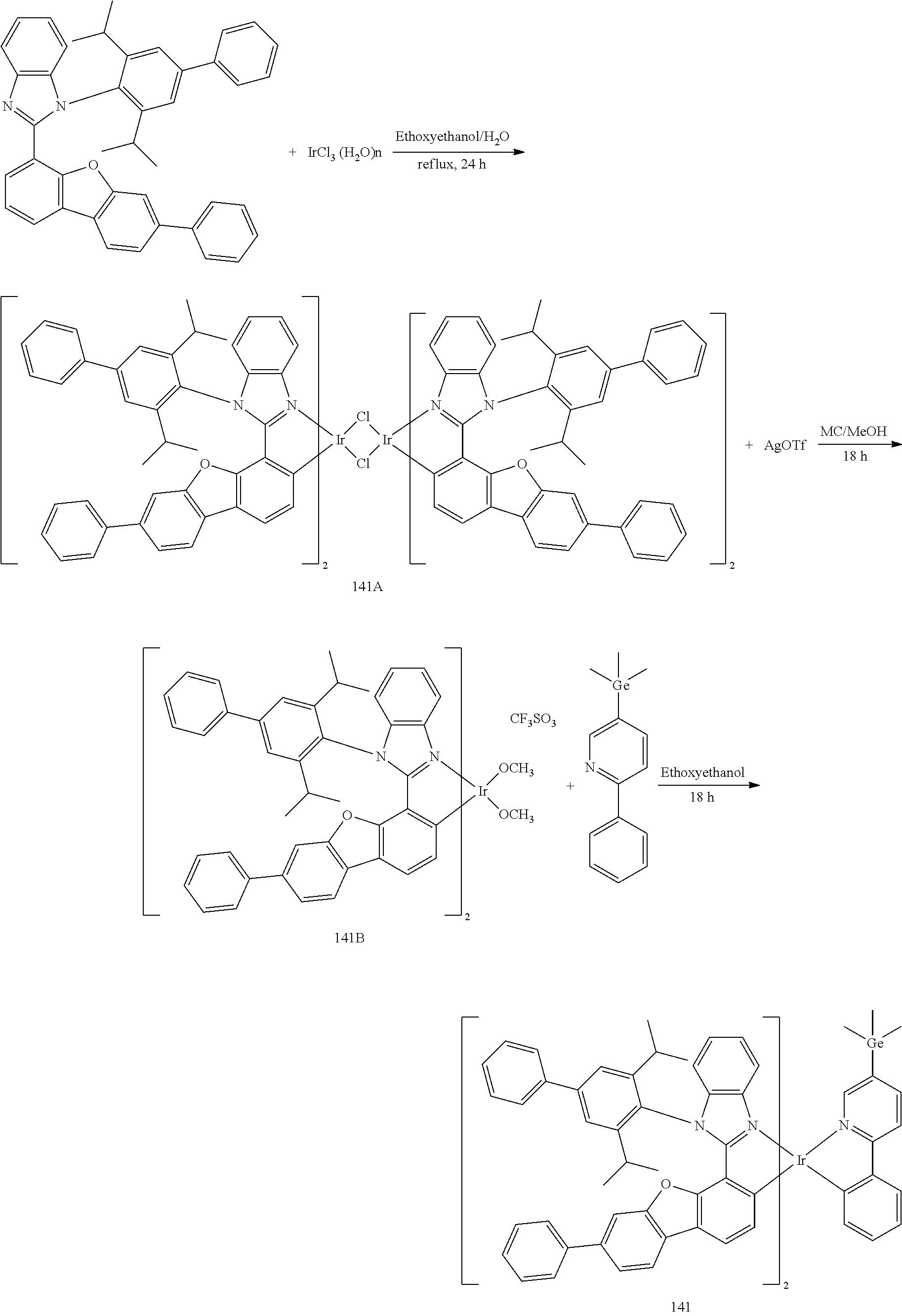

### Synthesis of Compound 141A

1-(3,5-diisopropyl-[1,1′-biphenyl]-4-yl)-2-(7-phenyldibenzo[b,d]furan-4-yl)-1H-benzo[d]imidazole (9.5 g, 15.9 mmol) and iridium chloride (2.5 g, 7.1 mmol) were mixed with 150 mL of ethoxyethanol and 50 mL of distilled water, and then stirred while refluxing for 24 hours. Then, the temperature was lowered to room temperature. The solid formed therefrom was separated by filtration, washed sufficiently in the order of water/methanol/hexane, and the obtained solid was dried in a vacuum oven to obtain 7.3 g (yield of 73%) of Compound 141A.

### Synthesis of Compound 141B

Compound 141A (5.3 g, 1.9 mmol) was mixed with 150 mL of methylene chloride, and then, AgOTf (1.0 g, 3.8 mmol) mixed with 50 mL of methanol, was added thereto. Then, the resultant mixture was stirred for 18 hours at room temperature while light was blocked by using aluminum foil, and then filtered through Celite to remove the generated solid and the filtrate was subjected to reduced pressure to obtain a solid (Compound 141B), which was used in the next reaction without an additional purification process.

### Synthesis of Compound 141

120 mL of 2-ethoxyethanol was mixed with Compound 141B (5.3 g, 3.3 mmol) and 2-phenyl-5-(trimethylgermyl)pyridine (0.9 g, 3.5 mmol), and then, stirred while refluxing for 18 hours and then, the temperature was lowered. The obtained mixture was subjected to reduced pressure to obtain a solid, and then, column chromatography was performed thereon (eluent: methylene chloride (MC) and hexane) to obtain 1.7 g (yield of 31%) of Compound 141. The obtained compound was identified by Mass and HPLC analysis.

HRMS (MALDI) calcd. for C₁₀₀H₈₆GeIrN₅O₂: m/z 1654.6680 Found: 1654.6670.

### Synthesis Example 2 (Compound 541)

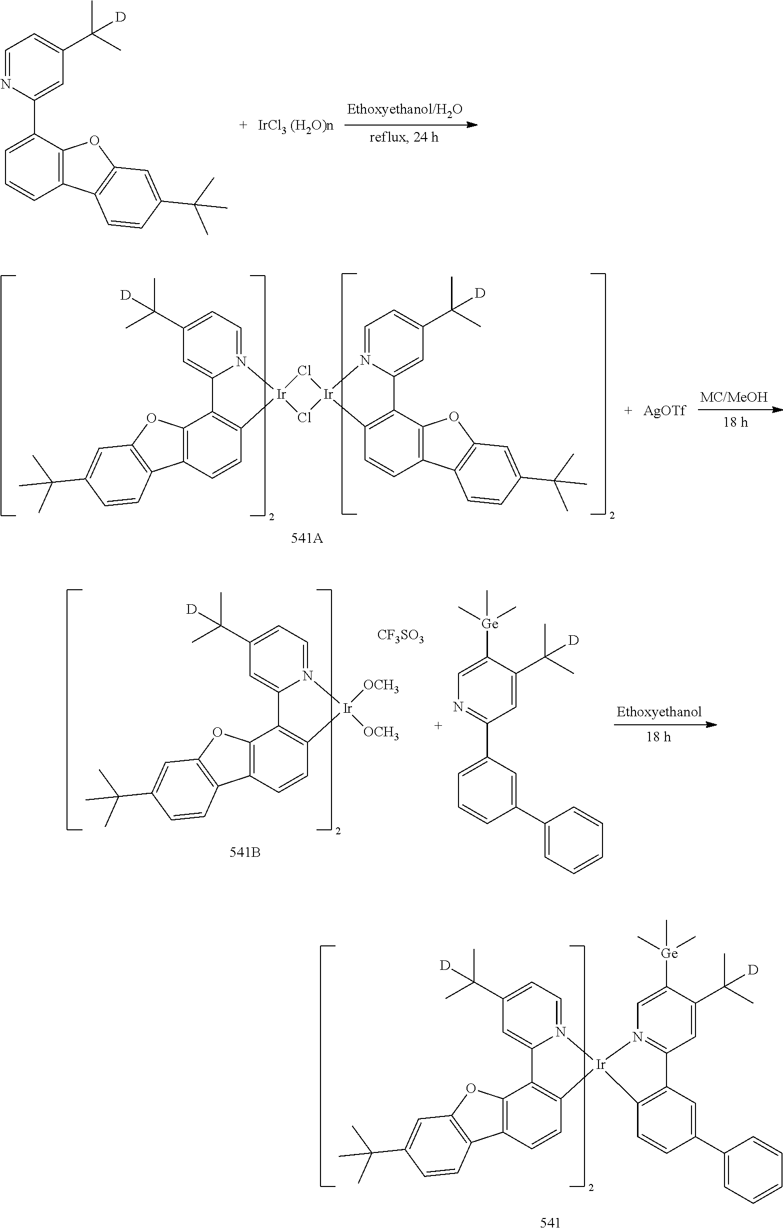

### Synthesis of Compound 541A

6.5 g (yield of 65%) of Compound 401A was obtained in the same manner as used to prepare Compound 141A of Synthesis Example 1, except that (2-(7-(tert-butyl)dibenzo[b,d]furan-4-yl)-4-(propan-2-yl-2-d)pyridine) was used instead of 1-(3,5-diisopropyl-[1,1′-biphenyl]-4-yl)-2-(7-phenyldibenzo[b,d]furan-4-yl)-1H-benzo[d]imidazole.

### Synthesis of Compound 541B

Compound 541B was obtained in the same manner as used to obtain Compound 141B of Synthesis Example 1, except that Compound 541A was used instead of Compound 141A. The obtained Compound 541B was used in the next reaction without further purification.

### Synthesis of Compound 541

1.3 g (yield of 28%) of Compound 541 was obtained in the same manner as used to obtain Compound 141 of Synthesis Example 1, except that Compound 541B was used instead of Compound 141B and 2-([1,1′-biphenyl]-3-yl)-4-(propan-2-yl-2-d)-5-(trimethylgermyl)pyridine was used instead of 2-phenyl-5-(trimethylgermyl)pyridine. The obtained compound was identified by Mass and HPLC analysis.

HRMS (MALDI) calcd for C₇₁H₇₁D₃GeIrN₃O₂: m/z 1270.4810 Found: 1270.4817.

### Synthesis Example 3 (Compound 656)

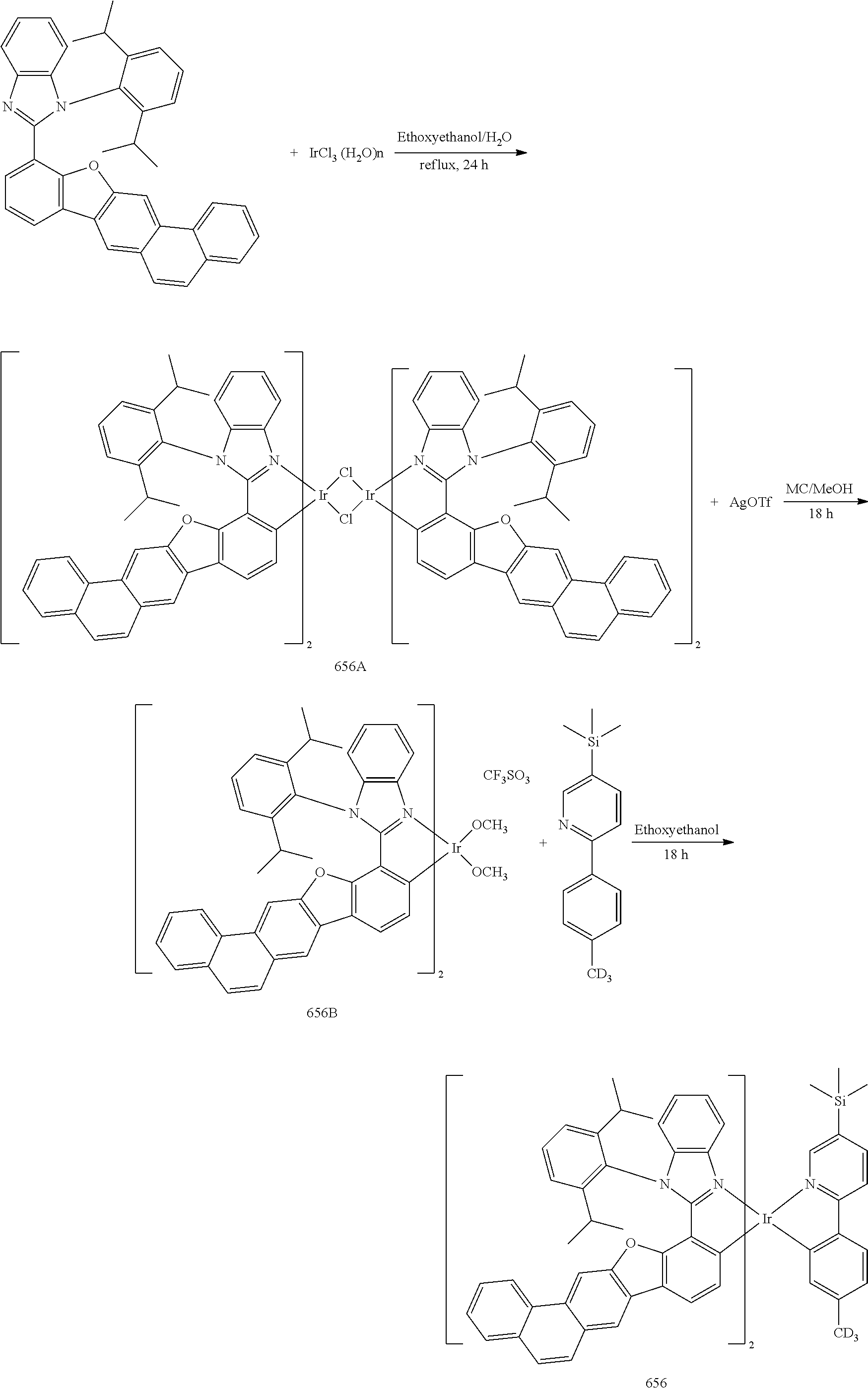

### Synthesis of Compound 656A

Compound 656A 7.7 g (yield of 77%) was obtained in the same manner as used to obtain Compound 141A of Synthesis Example 1, except that 1-(2,6-diisopropylphenyl)-2-(phenanthro[3,2-b]benzofuran-11-yl)-1H-benzo[d]imidazole was used instead of 1-(3,5-diisopropyl-[1,1′-biphenyl]-4-yl)-2-(7-phenyldibenzo[b,d]furan-4-yl)-1H-benzo[d]imidazole.

### Synthesis of Compound 656B

Compound 656B was obtained in the same manner as used to obtain Compound 141B of Synthesis Example 1, except that Compound 656A was used instead of Compound 141A. The obtained Compound 656B was used in the next reaction without further purification.

### Synthesis of Compound 656

0.9 g (yield of 32%) of Compound 656 was obtained in the same manner as used to obtain Compound 141 of Synthesis Example 1, except that Compound 656B was used instead of Compound 141B, and 2-(4-(methyl-d3)phenyl)-5-(trimethylsilyl)pyridine was used instead of 2-phenyl-5-(trimethylgermyl)pyridine. The obtained compound was identified by Mass and HPLC analysis.

HRMS (MALDI) calcd for C₉₃H₇₇D₃IrN₅O₂Si: m/z 1522.5899 Found: 1522.5891.

### Synthesis Example 4 (Compound 1239)

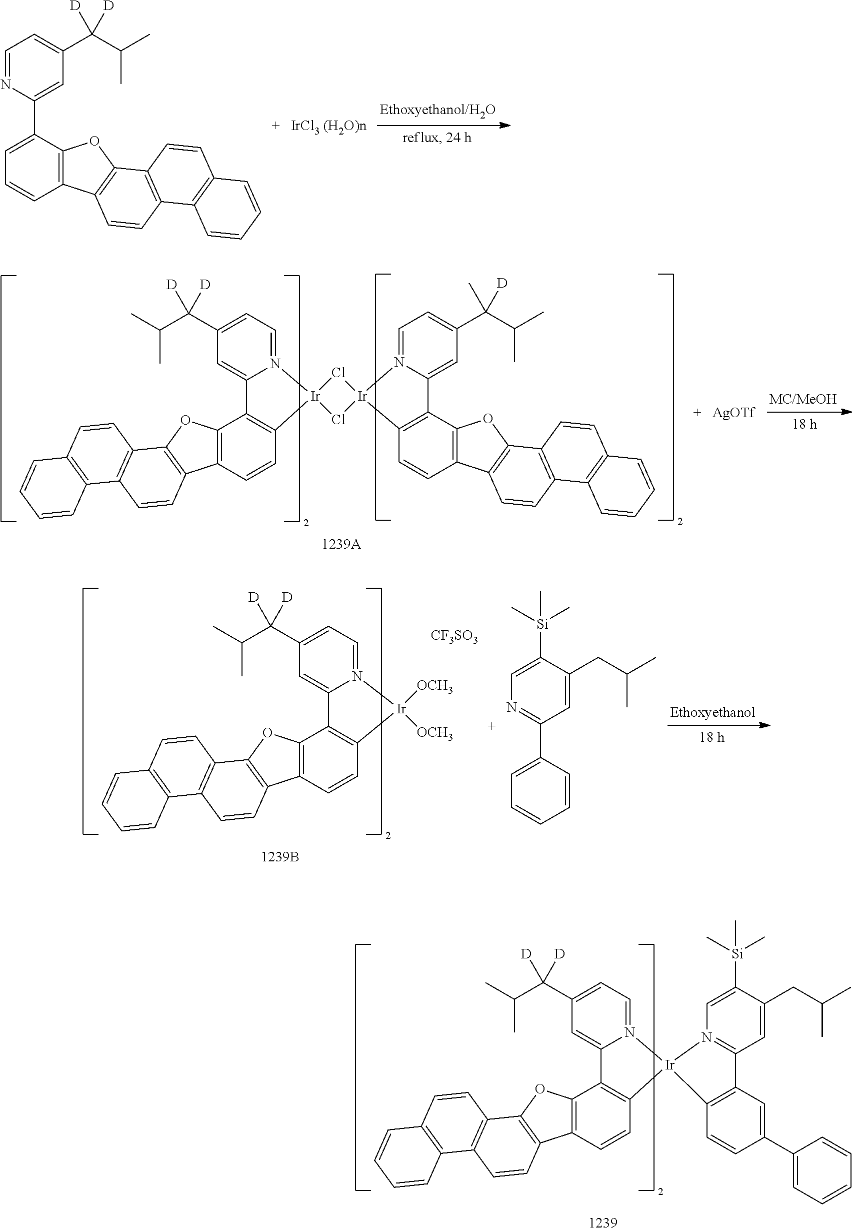

### Synthesis of Compound 1239A

6.2 g (yield of 62%) of Compound 1239A was obtained in the same manner as used to obtain Compound 141A of Synthesis Example 1, except that 4-(2-methylpropyl-1,1-d2)-2-(phenanthro[1,2-b]benzofuran-12-yl)pyridine was used instead of 1-(3,5-diisopropyl-[1,1′-biphenyl]-4-yl)-2-(7-phenyldibenzo[b,d]furan-4-yl)-1H-benzo[d]imidazole.

### Synthesis of Compound 1239B

Compound 1239B was obtained in the same manner as used to obtain Compound 141B of Synthesis Example 1, except that Compound 1239A was used instead of Compound 141A. The obtained Compound 1239B was used in the next reaction without further purification.

### Synthesis of Compound 1239

0.9 g (yield of 32%) of Compound 1239 was obtained in the same manner as used to obtain Compound 141 of Synthesis Example 1, except that Compound 1239B was used instead of Compound 141B and 4-isobutyl-2-phenyl-5-(trimethylsilyl)pyridine was used instead of 2-phenyl-5-(trimethylgermyl)pyridine. The obtained compound was identified by Mass and HPLC analysis.

HRMS (MALDI) calcd for C₇₆H₆₄D₄IrN₃O₂Si: m/z 1279.4961 Found: 1279.4955.

### Example 1

As an anode, an ITO-patterned glass substrate was cut to a size of 50 mm×50 mm×0.5 mm, sonicated with isopropyl alcohol and pure water, each for 5 minutes, and then cleaned by exposure to ultraviolet rays and ozone for 30 minutes. The resultant glass substrate was loaded onto a vacuum deposition apparatus.

Compound HT3 and F6-TCNNQ were vacuum-codeposited on the anode at the weight ratio of 98:2 to form a hole injection layer having a thickness of 100 Å, and Compound HT3 was vacuum-deposited on the hole injection layer to form a hole transport layer having a thickness of 1350 Å, and then, Compound H-H1 was deposited on the hole transport layer to form an electron-blocking layer having a thickness of 300 Å.

Then, Compound H-H1, Compound H-E43, and Compound 141 (dopant) were co-deposited on the electron-blocking layer at a weight ratio of 57:38:5 to form an emission layer having a thickness of 400 Å.

Then, ET3 and ET-D1 were co-deposited at the volume ratio of 50:50 on the emission layer to form an electron-transporting layer having a thickness of 350 Å, and ET-D1 was vacuum-deposited on the electron-transporting layer to form an electron injection layer having a thickness of 10 Å, and Al was vacuum-deposited on the electron injection layer to form a cathode having a thickness of 1000 Å, thereby completing the manufacture of an organic light-emitting device.

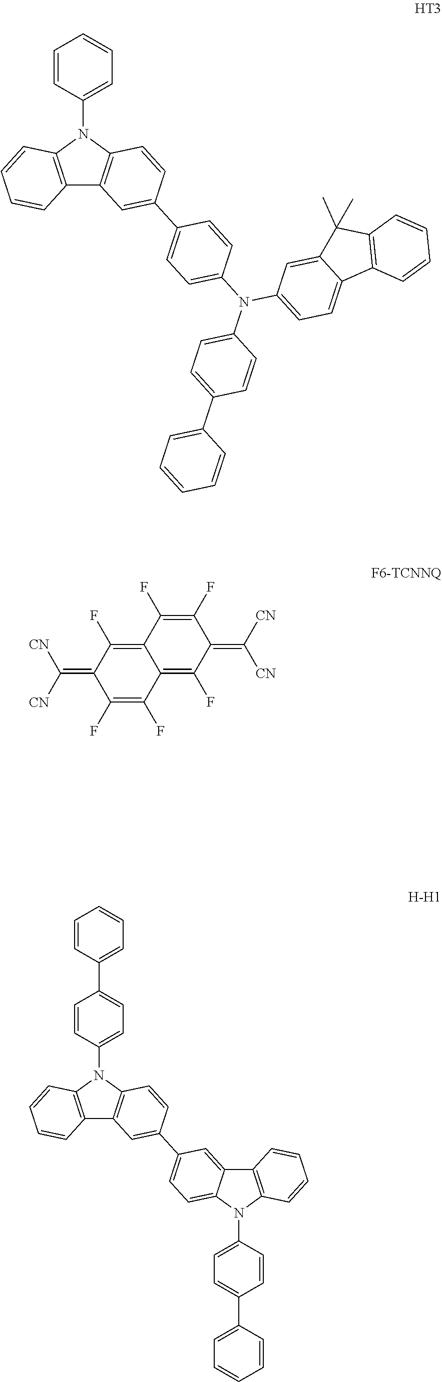

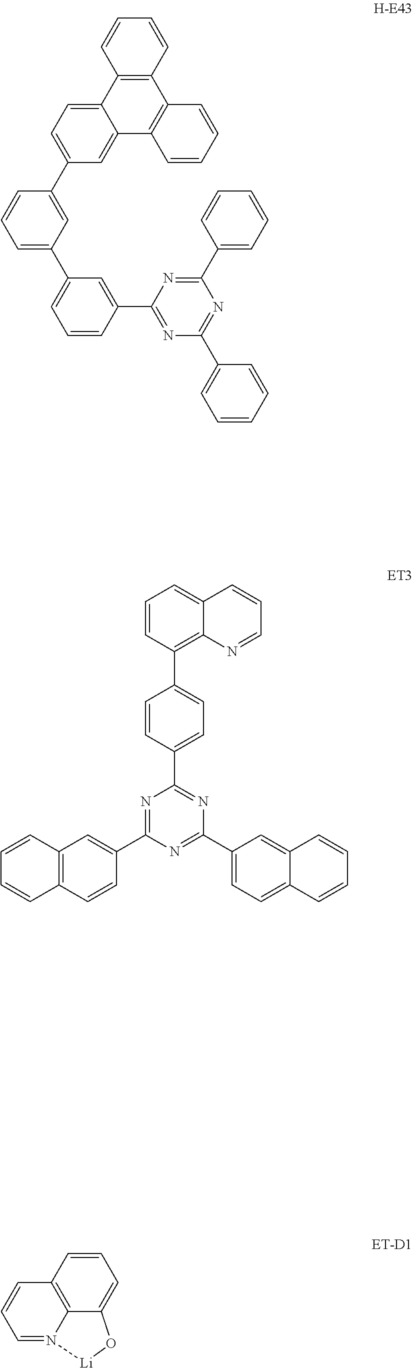

### Examples 2 to 4 and Comparative Example C1

Organic light-emitting devices were manufactured in the same manner as in Example 1, except that the compounds listed in Table 32 were used instead of Compound 141 as a dopant when forming the emission layer.

### Evaluation Example 1: Characterization of Organic Light-Emitting Device

The FWHM of the emission peak in the electroluminescence spectrum, a relative value (%) of maximum value of external quantum efficiency (Max EQE), and lifespan (LT₉₇)(hr) of the organic light-emitting devices manufactured according to Examples 1 to 4 and Comparative Example C1 were evaluated, and results thereof are shown in Table 32. A current-voltmeter (Keithley 2400) and a luminance meter (Minolta Cs-1000A) were used as evaluation devices, and lifespan (LT₉₇) (at 16,000 nit) was evaluated as time (hr) to achieve 97% of luminance compared to 100% of initial luminance. In Table 32, each of FWHM, Max EQE and lifespan (LT₉₇) was described as a relative value (%).

TABLE 32

| | Compound No. of | | | LT₉₇ (relative |
|---|---|---|---|---|
| | dopant in | FWHM | Max EQE (relative | value, %) |
| | emission layer | (relative value, %) | value, %) | (at 16,000 nit) |
| Example 1 | 141 | 100 | 100 | 100 |
| Example 2 | 541 | 193 | 93 | 69 |
| Example 3 | 656 | 93 | 99 | 106 |
| Example 4 | 1239 | 152 | 101 | 89 |
| Comparative | C1 | 250 | 85 | 20 |
| Example C1 | | | | |

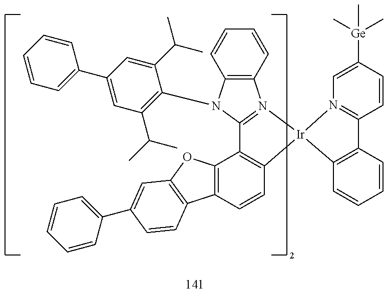

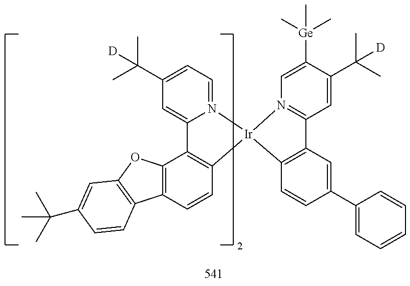

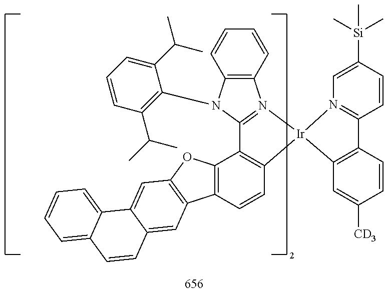

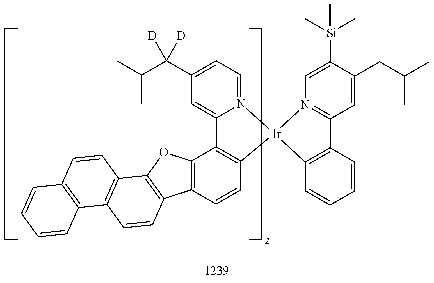

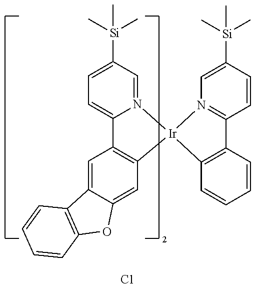

Referring to Table 32, it can be seen that the organic light-emitting devices of Examples 1 to 4 have relatively small FWHM, improved external quantum efficiency, and improved lifespan characteristics compared to the organic light-emitting device of Comparative Example C1.

Since the organometallic compounds have excellent electrical characteristics and heat resistance, an electronic device, for example, organic light-emitting device using the organometallic compound may have excellent driving voltage, excellent external quantum efficiency (EQE) and excellent lifespan characteristics. Therefore, the use of the organometallic compound may enable the embodiment of a high-quality organic light-emitting device and an electron device including the same.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An organometallic compound represented by Formula 1:
M(L₁)ₙ₁(L₂)ₙ₂ Formula 1
wherein, in Formula 1,
M is iridium,
L₁ is a ligand represented by Formula 2A,
n1 is 2, and two L₁(s) are identical to or different from each other,
L₂ is a ligand represented by Formula 2B,
n2 is 1,
L₁ and L₂ are different from each other, 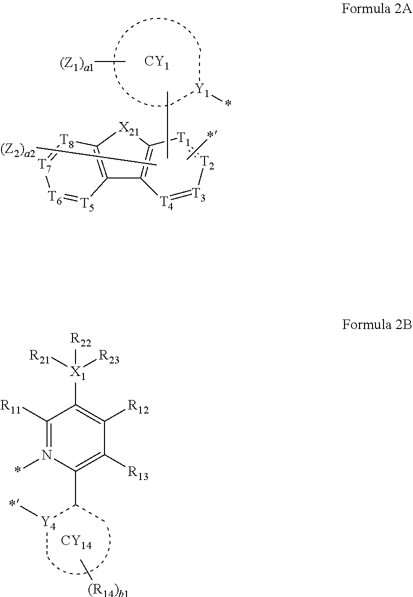
wherein, in Formulae 2A and 2B,
Y₁ and Y₄ are each independently C or N,
X₁ is Si or Ge,
X₂₁ is O, S, S(═O), N(Z₂₉), C(Z₂₉)(Z₃₀), or Si(Z₂₉)(Z₃₀),
T₁ to T₄ are each independently C, N, carbon bonded to ring CY₁, or carbon bonded to M in Formula 1, and one of T₁ to T₄ is carbon bonded to M in Formula 1, and one of the others of T₁ to T₄ which are not bonded to M is carbon bonded to ring CY₁,
T₅ to T₈ are each independently C or N,
ring CY₁ and ring CY₁₄ are each independently a C₅-C₃₀ carbocyclic group or a C₁-C₃₀ heterocyclic group,
R₂₁ to R₂₃ are each independently a C₁-C₆₀ alkyl group or a C₆-C₆₀ aryl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₃-C₁₀ cycloalkyl group, a phenyl group, or any combination thereof,
Z₁, Z₂, Z₂₉, Z₃₀, and R₁₁ to R₁₄ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
a1 and b1 are each independently an integer from 0 to 20, wherein when a1 is 2 or more, two or more of Z₁(s) are identical to or different from each other, and when b1 is 2 or more, two or more of R₁₄(s) are identical to or different from each other, a2 is an integer from 0 to 6, wherein, when a2 is 2 or more, two or more of Z₂(s) are identical to or different from each other,
at least one of Z₁(s) in the number of a1 in Formula 2A is not hydrogen,
two or more of R₂₁ to R₂₃ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of Z₁(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of Z₂(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
R₁₂ and R₁₃ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of R₁₄(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of Z₁, Z₂ and R₁₁ to R₁₄ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
R₁₀ₐ is the same as described in connection with R₁₄,
* and *′ in Formulae 2A and 2B each indicate a binding site to M in Formula 1, and
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group,
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(O₂₅), —Ge(Q₂₃)(Q₂₄)(025), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof,
wherein Q₁ to Q₉, Q₁₁ to Q₁₉, Q₂₁ to Q₂₉, and Q₃₁ to Q₃₉ used herein are each independently: hydrogen; deuterium; —F; —Cl; —Br; —I; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group which is unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group which is unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

2. The organometallic compound of claim 1, wherein
two L₁(s) are identical to each other.

3. The organometallic compound of claim 1, wherein
X₂₁ in Formula 2A is O or S.

4. The organometallic compound of claim 1, wherein
each of T₁ to T₈ in Formula 2A is not N.

5. The organometallic compound of claim 1, wherein
ring CY₁ in Formula 2A is a pyridine group, a pyrimidine group, an imidazole group, an oxazole group, a thiazole group, a benzimidazole group, a benzoxazole group, a benzothiazole group, a pyridoimidazole group, a pyridooxazole group, a pyridothiazole group, a naphthoimidazole group, a naphthooxazole group, or a naphthothiazole group.

6. The organometallic compound of claim 1, wherein
Z₁, Z₂, Z₂₉, Z₃₀, and R₁₁ to R₁₄ in Formulae 2A and 2B are each independently:
hydrogen, deuterium, —F, or a cyano group;
a C₁-C₂₀ alkyl group, unsubstituted or substituted with deuterium, —F, a cyano group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, or any combination thereof; or
a phenyl group, a biphenyl group, a terphenyl group, a naphthyl group, a dibenzofuranyl group, or a dibenzothiophenyl group, each unsubstituted or substituted with —F, a cyano group, a C₁-C₂₀ alkyl group, a deuterated C₁-C₂₀ alkyl group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), —Ge(Q₃₃)(Q₃₄)(Q₃₅), or any combination thereof.

7. The organometallic compound of claim 1, wherein
at least one of Z₁(s) in the number of a1 in Formula 2A is deuterium, —F, or a cyano group;
a C₁-C₂₀ alkyl group, unsubstituted or substituted with deuterium, —F, a cyano group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, or any combination thereof; or
a phenyl group, a biphenyl group, a terphenyl group, a naphthyl group, a dibenzofuranyl group, or a dibenzothiophenyl group, each unsubstituted or substituted with —F, a cyano group, a C₁-C₂₀ alkyl group, a deuterated C₁-C₂₀ alkyl group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), —Ge(Q₃₃)(Q₃₄)(Q₃₅), or any combination thereof.

8. The organometallic compound of claim 1, wherein
wherein, in Formula 2A,
Y₁ is N,
ring CY₁ is a pyridine group, and
at least one of Z₁(s) in the number of a1 is a C₁-C₂₀ alkyl group, unsubstituted or substituted with deuterium, —F, a cyano group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, or any combination thereof.

9. The organometallic compound of claim 1, wherein
in Formula 2A,
Y₁ is N,
ring CY₁ is a benzimidazole group, a benzoxazole group, a benzothiazole group, a pyridoimidazole group, a pyridooxazole group, a pyridothiazole group, a naphthoimidazole group, a naphthooxazole group, or a naphthothiazole group, and
at least one of Z₁(s) in the number of a1 is a phenyl group, a biphenyl group, a terphenyl group, a naphthyl group, a dibenzofuranyl group, or a dibenzothiophenyl group, each unsubstituted or substituted with —F, a cyano group, a C₁-C₂₀ alkyl group, a deuterated C₁-C₂₀ alkyl group, a C₃-C₁₀ cycloalkyl group, a deuterated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a (C₁-C₂₀ alkyl)C₁-C₁₀ heterocycloalkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), —Ge(Q₃₃)(Q₃₄)(Q₃₅), or any combination thereof.

10. The organometallic compound of claim 1, wherein
R₁₂ in Formula 2B is not hydrogen or a methyl group.

11. The organometallic compound of claim 1, wherein
in Formula 2A, Y₁ is N and ring CY₁ is a benzimidazole group, a benzoxazole group, a benzothiazole group, a pyridoimidazole group, a pyridooxazole group, a pyridothiazole group, a naphthoimidazole group, a naphthooxazole group, or a naphthothiazole group, and
in Formula 2B, R₁₂ is hydrogen or a methyl group.

12. The organometallic compound of claim 1, wherein
the organometallic compound satisfies at least one of Condition (1), Condition (2), or a combination thereof:
Condition (1)
in Formula 2B, R₁₄ is not hydrogen and b1 is an integer from 1 to 20;
Condition (2)
in Formula 2A, Z₂ is not hydrogen and a2 is an integer from 1 to 6.

13. The organometallic compound of claim 1, wherein
a group represented by 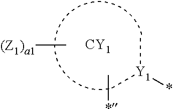
in Formula 2A is a group represented by one of Formulae CY1-1 to CY1-26: 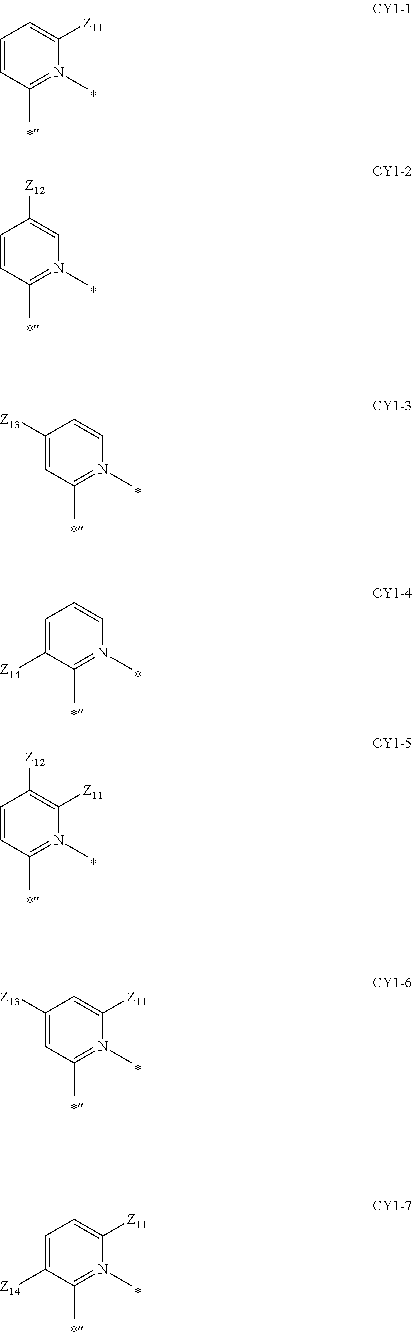 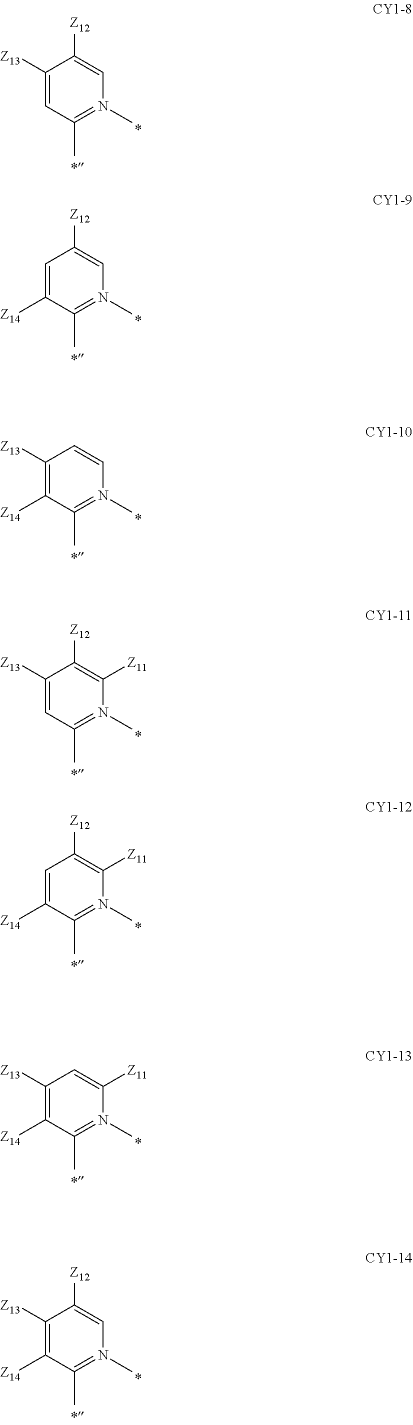 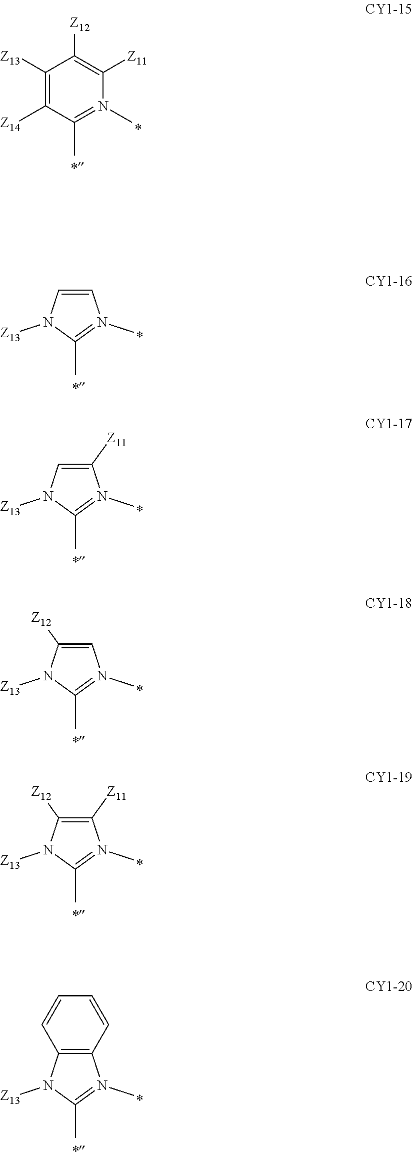 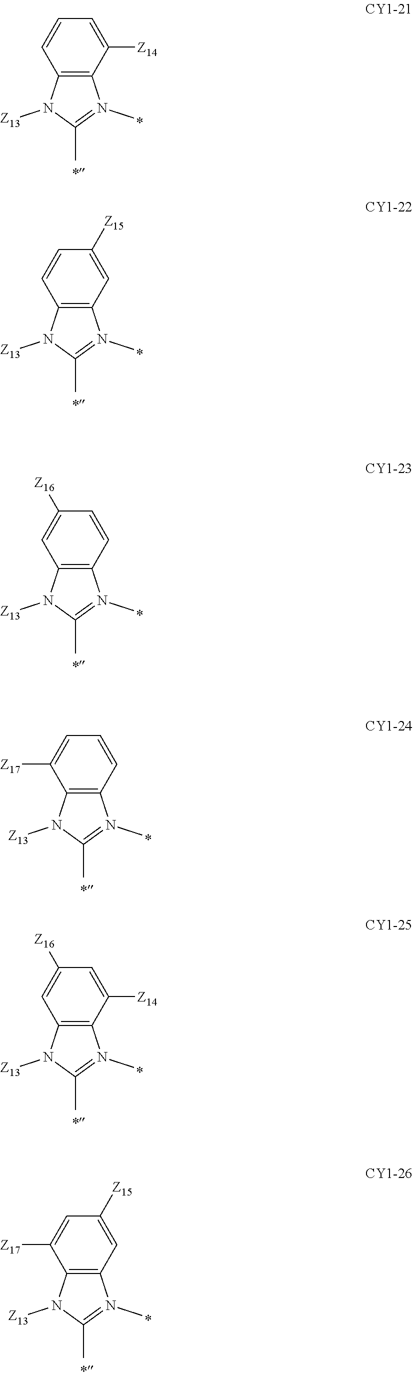
wherein, in Formulae CY1-1 to CY1-26,
Z₁₁ to Z₁₇ are the same as described in connection with Z₁, and each of Z₁₁ to Z₁₇ is not hydrogen,
* indicates a binding site to M in Formula 1, and
*″ is a binding site to one of T₁ to T₄ in Formula 2A.

14. The organometallic compound of claim 1, wherein
a group represented by 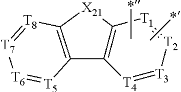
in Formula 2A is a group represented by one of Formulae CY2-1 to CY2-6: 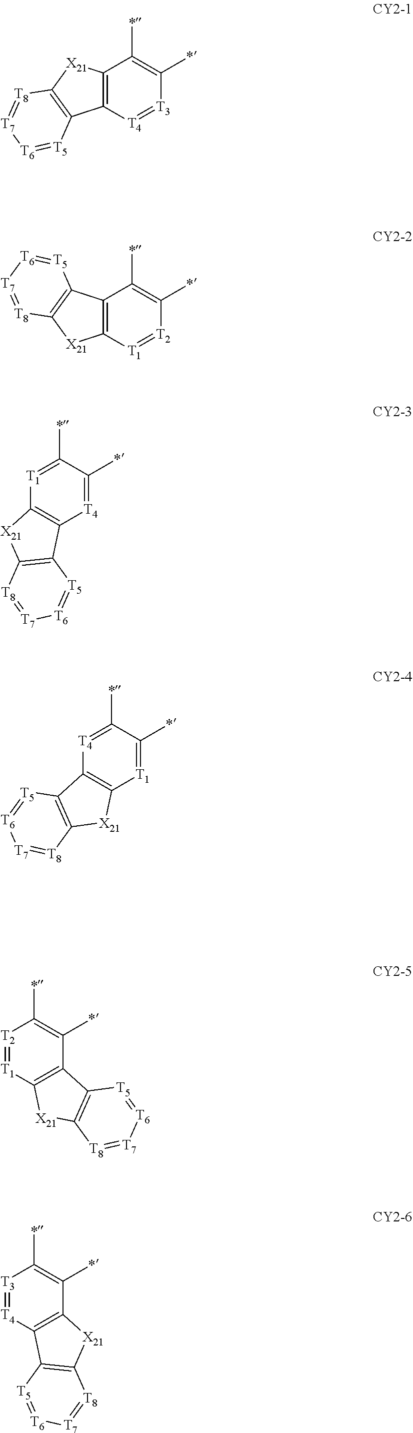
wherein, in Formulae CY2-1 to CY2-6,
T₁ to T₈ are each independently C or N,
X₂₁ is the same as described in claim 1,
*″ is a binding site to ring CY₁ in Formula 2A, and
*′ is a binding site to M in Formula 1.

15. The organometallic compound of claim 1, wherein
a group represented by 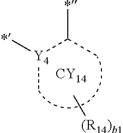
in Formula 2B is represented by one of Formulae CY14(1) to CY14(63): 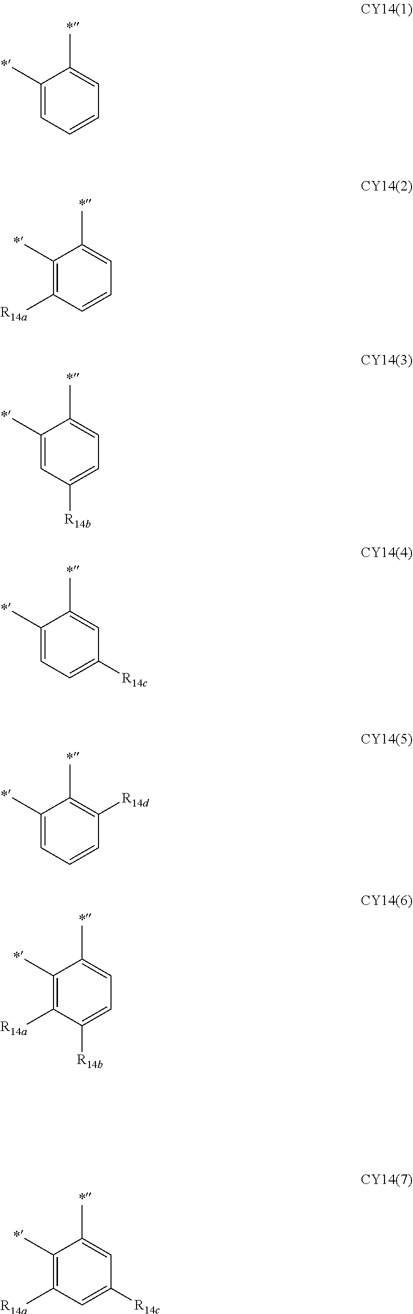 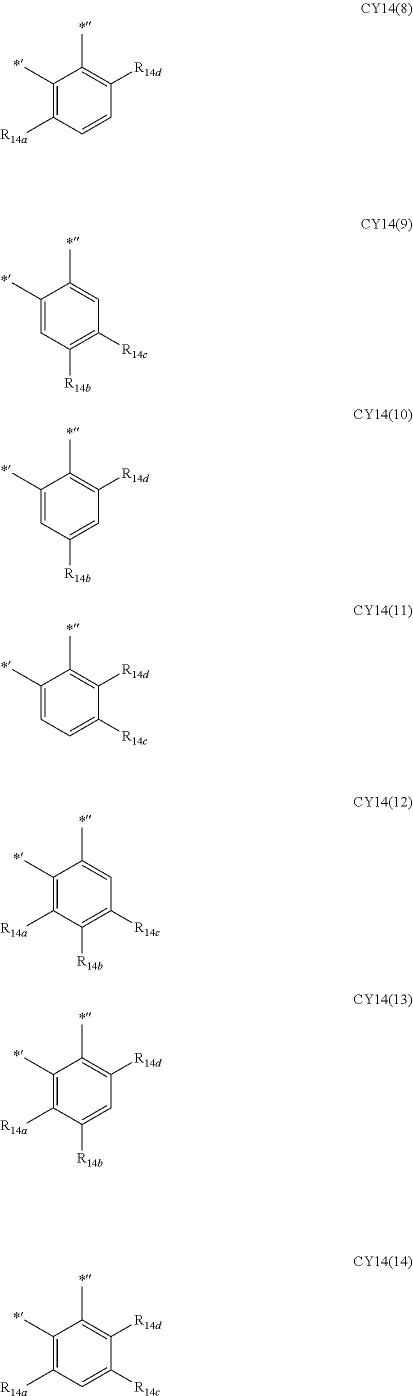 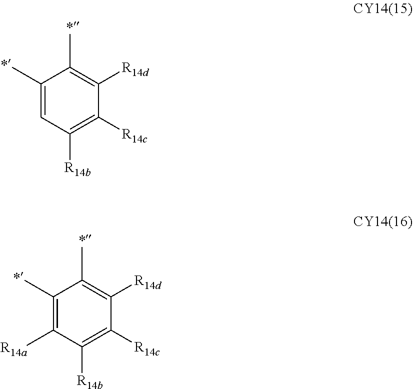 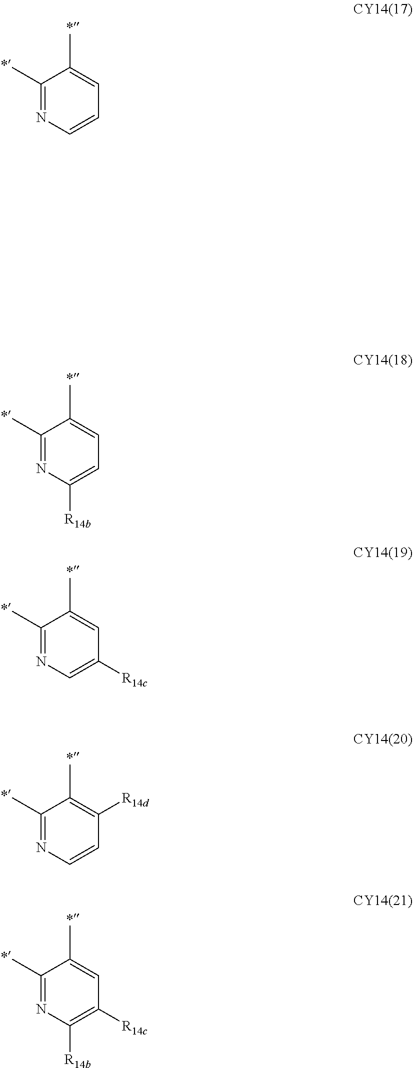 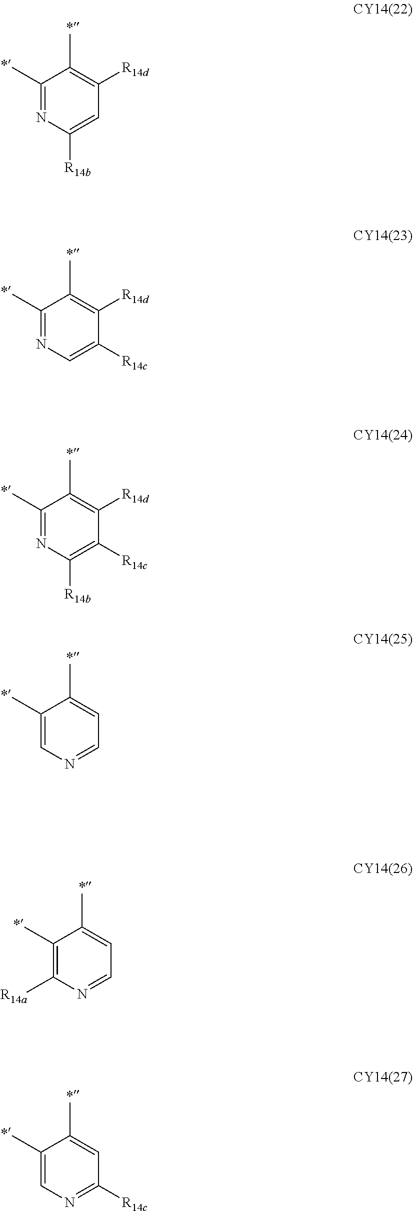 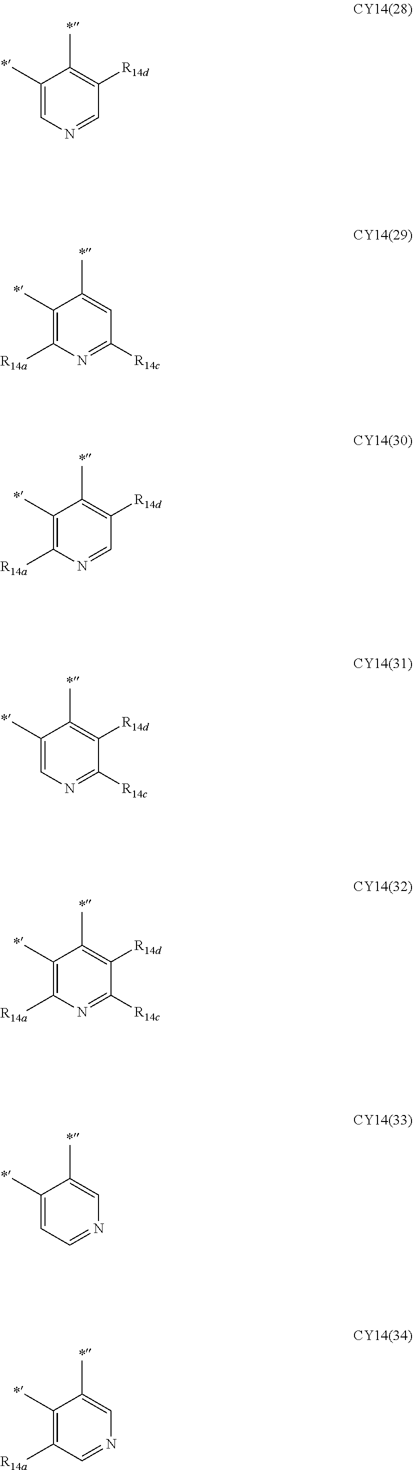 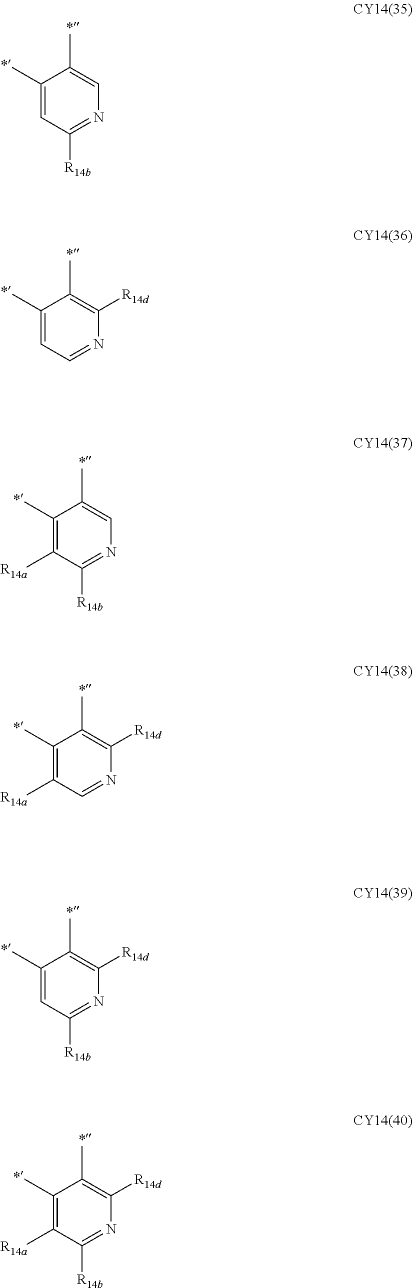 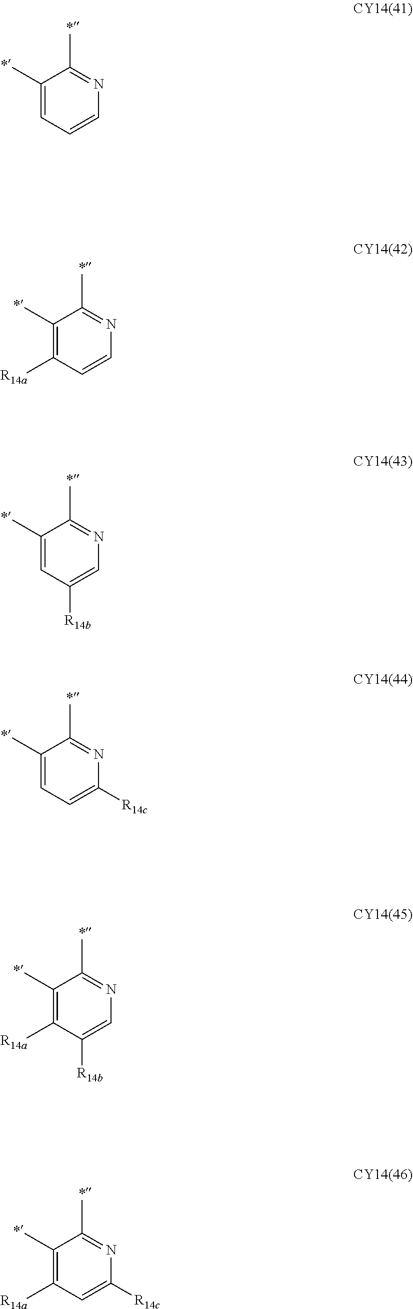 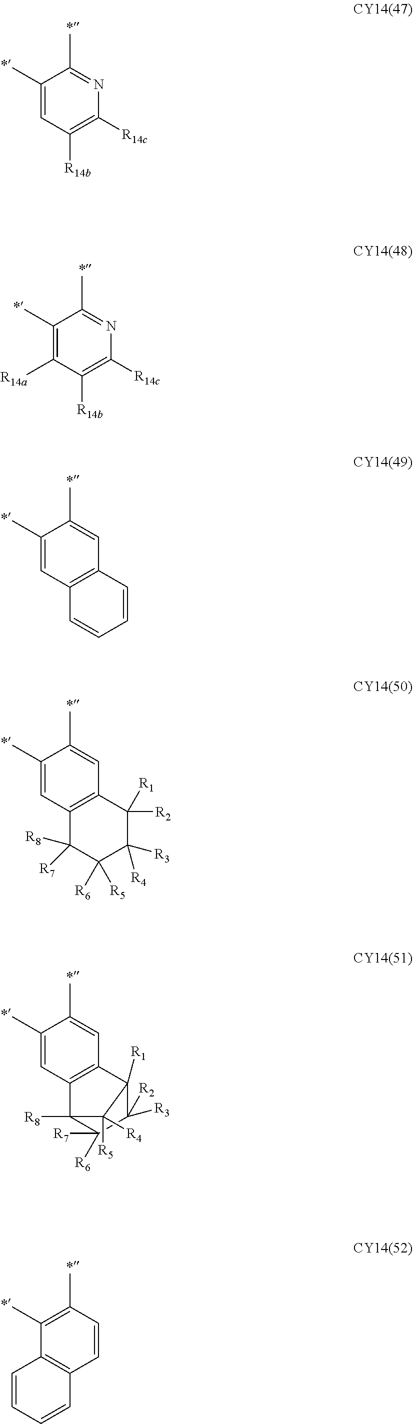 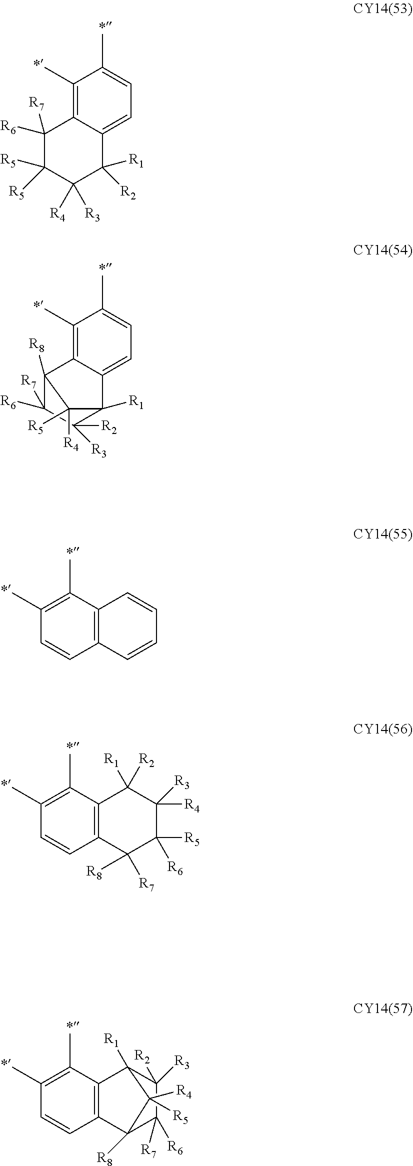 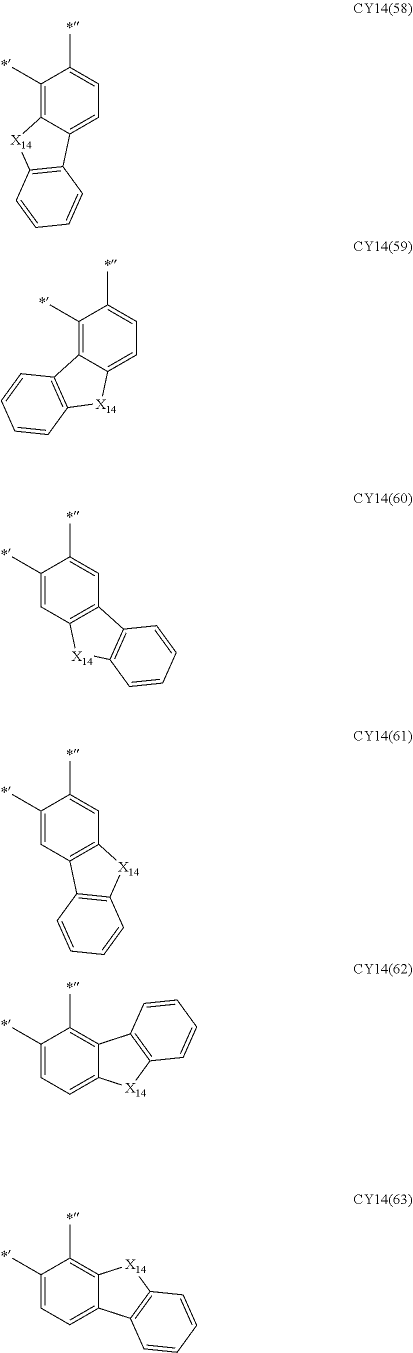
wherein, in Formulae CY14(1) to CY14(63),
R₁₄ₐ to R_{14d} are each the same as described in connection with R₁₄ in claim 1, and each of R₁₄ₐ to R_{14d} is not hydrogen,
X₁₄ is C(R₁)(R₂), N(R₁), O, S, or Si(R₁)(R₂),
R₁ to R₈ are each the same as described in connection with R₁₄ in claim 1,
*″ is a binding site to a carbon atom of a neighboring pyridine ring in Formula 2B, and
*′ is a binding site to M in Formula 1.

16. An organic light-emitting device comprising:
a first electrode,
a second electrode, and
an organic layer located between the first electrode and the second electrode and comprising an emission layer, wherein
the organic layer comprises at least one organometallic compound of claim 1.

17. The organic light-emitting device of claim 16, wherein
the first electrode is an anode,
the second electrode is a cathode,
the organic layer further comprises a hole transport region located between the first electrode and the emission layer and an electron transport region located between the emission layer and the second electrode, wherein
the hole transport region comprises a hole injection layer, a hole transport layer, an electron-blocking layer, a buffer layer, or a combination thereof, and
the electron transport region comprises a hole-blocking layer, an electron transport layer, an electron injection layer, or a combination thereof.

18. The organic light-emitting device of claim 16, wherein
the at least one organometallic compound is included in the emission layer.

19. The organic light-emitting device of claim 18, wherein
the emission layer further comprises a host and the amount of the host is greater than the amount of the least one organometallic compound.

20. An electronic apparatus comprising the organic light-emitting device of claim 16.
